(19) United States
(12) Patent Application Publication
(10) Pub. No.: US 2026/0239744 A1
(43) Pub. Date: Aug. 13, 2026

(54) SEMICONDUCTOR DEVICE, DISPLAY APPARATUS, AND ELECTRONIC DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Hajime KIMURA, Atsugi (JP); Hidetomo KOBAYASHI, Isehara (JP)

(21) Appl. No.: 19/149,633

(22) PCT Filed: Feb. 9, 2024
(86) PCT No.: PCT/IB2024/051187

§ 371 Date: Jul. 21, 2025

(30) Foreign Application Priority Data
Feb. 17, 2023 (JP) 2023-023665

(51) Int. Cl. H10D 86/60; G02F 1/1368; H10D 86/40; H10H 29/32; H10K 59/121

(52) U.S. Cl. CPC H10D 86/60; G02F 1/1368; H10D 86/421; H10D 86/481; H10H 29/32; H10K 59/1213

(57) ABSTRACT

A semiconductor device that operates stably is provided. The semiconductor device retains the potential of a floating node stably with use of a transistor with a long channel length. The transistor includes first to third conductive layers, a semiconductor layer, and an insulating film. The first and second conductive layers each include a region in contact with a top surface of a first insulating layer. The semiconductor layer includes a region in contact with a side surface of an opening formed in the first insulating layer, a top surface of a second insulating layer in a bottom portion of the opening, a top surface of the first conductive layer, and a top surface of the second conductive layer. The insulating film includes a region in contact with a top surface of the semiconductor layer, the top surface of the first conductive layer, and the top surface of the second conductive layer. The third conductive layer includes a region overlapping with at least part of the semiconductor layer and in contact with a top surface of the insulating film. The transistor includes a channel formation region in the semiconductor layer. In a display apparatus, the semiconductor device can be provided in a driver circuit having a function of transmitting a signal for displaying an image.

### TECHNICAL FIELD

One embodiment of the present invention relates to a semiconductor device, a display apparatus, and an electronic device.

Note that one embodiment of the present invention is not limited to the above technical field. The technical field of the invention disclosed in this specification and the like relates to an object, an operation method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus (including a liquid crystal display apparatus), a light-emitting apparatus, a power storage device, an imaging device, a memory device, a signal processing device, a sensor, a processor, an electronic device, a system, an operation method thereof, a manufacturing method thereof, and a testing method thereof.

### BACKGROUND ART

Display apparatuses included in, for example, electronic devices for XR (Extended Reality or Cross Reality) such as VR (virtual reality) or AR (augmented reality), mobile phones (e.g., smartphones), tablet information terminals, and laptop PCs (personal computers) have been improved in various aspects in recent years. For example, display apparatuses have been developed aiming for improvement such as a higher screen resolution, higher color reproducibility (NTSC ratio), a smaller driver circuit, and lower power consumption.

For example, a circuit for reducing variations in the characteristics of a driving transistor included in a pixel has also been under development in order to improve the display quality of a display apparatus. In particular, Patent Document 1 discloses the invention of a pixel circuit that includes a circuit for correcting the threshold voltage of a driving transistor.

Another example is a technique of using a transistor including an oxide semiconductor in a semiconductor thin film, as a switching element included in a pixel circuit of a display apparatus.

A silicon-based semiconductor material is widely known as a material for a semiconductor thin film applicable to a transistor. Other than the silicon-based semiconductor material, an oxide semiconductor has attracted attention. Examples of oxide semiconductors include not only single-component metal oxides, such as indium oxide and zinc oxide, but also multi-component metal oxides. Among the multi-component metal oxides, in particular, an In-Ga-Zn oxide (hereinafter also referred to as IGZO) has been actively researched.

A transistor including IGZO in an active layer has an extremely low off-state current (see Non-Patent Document 1), and LSI (Large Scale Integration) and a display apparatus that utilize the characteristics have been reported (see Non-Patent Document 2 and Non-Patent Document 3). Patent Document 2 discloses the invention in which a transistor including IGZO in an active layer is used in a pixel circuit of a display apparatus.

### REFERENCES

### Patent Documents

[Patent Document 1] Japanese Published Patent Application No. 2017-10000

[Patent Document 2] Japanese Published Patent Application No. 2010-156963

### Non-Patent Documents

[Non-Patent Document 1] K. Kato et al., “Japanese Journal of Applied Physics”, 2012, volume 51, p. 021201-1-021201-7

[Non-Patent Document 2] S. Matsuda et al., “2015 Symposium on VLSI Technology Digest of Technical Papers”, 2015, p. T216-T217

[Non-Patent Document 3] S. Amano et al., “SID Symposium Digest of Technical Papers”, 2010, volume 41, issue 1, p. 626-629

### SUMMARY OF THE INVENTION

### Problems to be Solved by the Invention

A display apparatus displays an image by the operation of a driver circuit provided in the display apparatus. The driver circuit is an essential circuit for displaying an image on the display apparatus, and the display quality of the image sometimes depends on the performance of the driver circuit. For example, the display apparatus requires a high frame frequency to display a smooth image, so that the display apparatus is preferably provided with a driver circuit compatible with the frame frequency.

One example of circuits included in the driver circuit is a shift register circuit. The shift register circuit is a circuit in which a plurality of retention circuits (e.g., flip-flop circuits) are connected in series and has a function of transferring data retained in the retention circuit to the next retention circuit every time a pulse signal is input. The frequency of the pulse signal input to the shift register circuit depends on the frame frequency of the display apparatus; thus, in the case where the display apparatus displays an image with a high frame frequency, it is necessary to provide a shift register circuit that can stably operate even when a pulse signal with a high frequency is input.

As an example of the retention circuit included in the shift register circuit, a structure in which a potential corresponding to data is retained in a floating node is considered. Such a retention circuit preferably has a structure in which a potential retained in a floating node can be stably retained while the shift register circuit operates. For example, when a transistor for retaining a potential for a floating node has a high leakage current (current that flows between a source and a drain when the transistor is in an off state and is sometimes also referred to as off-state current), electric charge is charged slowly to the floating node; as a result, the operation of the shift register circuit might be delayed. When the operation of the shift register circuit is delayed, the driving speed of the driver circuit also decreases, which reduces the frame frequency of the display apparatus.

An increase in the channel length of the transistor can reduce the amount of an off-state current but increases the area occupied by the transistor, resulting in an increase in the area of the retention circuit.

One object of one embodiment of the present invention is to provide a semiconductor device that operates stably. Another object of one embodiment of the present invention is to provide a semiconductor device having a high driving speed. Another object of one embodiment of the present invention is to provide a highly reliable semiconductor device. Another object of one embodiment of the present invention is to provide a display apparatus including the semiconductor device. Another object of one embodiment of the present invention is to provide an electronic device including the display apparatus. Another object of one embodiment of the present invention is to provide a novel semiconductor device, a novel display apparatus, or a novel electronic device.

Note that the objects of one embodiment of the present invention are not limited to the above objects. The above objects do not preclude the existence of other objects. Note that the other objects are objects that are not described in this section and will be described below. The objects that are not described in this section can be derived from the description of the specification, the drawings, and the like and can be extracted as appropriate from the description by those skilled in the art. Note that one embodiment of the present invention achieves at least one of the above objects and the other objects and does not necessarily achieve all of the above objects and the other objects.

### Means for Solving the Problems

A semiconductor device of one embodiment of the present invention is a retention circuit that can be provided in a shift register circuit and can retain data stably. The retention circuit is configured to retain the data in a floating node and includes a transistor for stably retaining the data, which has a long channel length and occupies a small area.

The transistor includes a conductive layer, and the conductive layer is positioned over an insulating layer. The conductive layer is provided with an opening together with the insulating layer and is divided into a pair of conductive layers. A semiconductor layer of the transistor is provided along the top surface of the pair of conductive layers, the side surface of the opening provided in the insulating layer, and a bottom portion of the opening. Owing to this structure, a channel formation region of the transistor has a U-shape in the opening, and thus the channel length can be increased. Thus, the amount of an off-state current of the transistor can be reduced. Since the channel formation region of the transistor is provided along the side surface of the opening provided in the insulating layer and the bottom portion of the opening, the transistor occupies a smaller area than a planar transistor.

A structure of a semiconductor device, a display apparatus, or an electronic device of one embodiment of the present invention is described below.

(1)

One embodiment of the present invention is a semiconductor device including a first transistor, a second transistor, a third transistor, a fourth transistor, a fifth transistor, a sixth transistor, a seventh transistor, a first capacitor, and a second capacitor.

A first gate of the first transistor is electrically connected to a first gate of the second transistor. One of a source and a drain of the third transistor is electrically connected to one of a source and a drain of the second transistor, a first gate of the fourth transistor, a first gate of the seventh transistor, and one of a pair of electrodes of the first capacitor. One of a source and a drain of the first transistor is electrically connected to one of a source and a drain of the fourth transistor and one of a source and a drain of the fifth transistor. The other of the source and the drain of the fifth transistor is electrically connected to one of a pair of electrodes of the second capacitor and a gate of the sixth transistor. One of a source and a drain of the sixth transistor is electrically connected to the other of the pair of electrodes of the second capacitor and one of a source and a drain of the seventh transistor.

The second transistor and the fourth transistor each include a first conductive layer functioning as the one of the source and the drain, a second conductive layer functioning as the other of the source and the drain, a third conductive layer functioning as the first gate, a semiconductor layer, and a gate insulating film.

The first conductive layer and the second conductive layer each include a region in contact with a top surface of a first insulating layer. The semiconductor layer includes a region in contact with a side surface of an opening formed in the first insulating layer, a top surface of a second insulating layer in a bottom portion of the opening, a top surface of the first conductive layer, and a top surface of the second conductive layer. The gate insulating film includes a region in contact with a top surface of the semiconductor layer, the top surface of the first conductive layer, and the top surface of the second conductive layer. The third conductive layer includes a region overlapping with at least part of the semiconductor layer and in contact with a top surface of the gate insulating film. The second transistor and the fourth transistor each include a channel formation region in the semiconductor layer.

(2)

Another embodiment of the present invention may have a structure in which the second transistor and the fourth transistor each include a fourth conductive layer functioning as a second gate in (1) above. It is particularly preferable that the fourth conductive layer include a region overlapping with at least part of the semiconductor layer and in contact with a bottom surface of the second insulating layer.

(3)

Another embodiment of the present invention may have a structure in which the semiconductor layer contains one or more selected from indium, zinc, and an element M in (2) above.

Note that the element Mis one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.

(4)

Another embodiment of the present invention may have a structure including an eighth transistor in (3) above. It is particularly preferable that a gate of the eighth transistor be electrically connected to the one of the source and the drain of the sixth transistor, the other of the pair of electrodes of the second capacitor, and the one of the source and the drain of the seventh transistor and one of a source and a drain of the eighth transistor be electrically connected to the one of the source and the drain of the first transistor, the one of the source and the drain of the fourth transistor, and the one of the source and the drain of the fifth transistor.

(5)

Another embodiment of the present invention is a display apparatus including a driver circuit and a display device. The driver circuit includes the semiconductor device of any one of (1) to (4) above, and the driver circuit has a function of transmitting a signal for displaying an image to the display device.

(6)

Another embodiment of the present invention may have a structure in which the display device includes a light-emitting device or a liquid crystal display device in (5) above.

(7)

Another embodiment of the present invention is an electronic device including the display apparatus described in (6) above and a housing.

### Effect of the Invention

With the above structure, the leakage current of a transistor can be reduced, so that the potential of a floating node can be retained stably. As a result, a semiconductor device capable of stably retaining data can be obtained.

When the semiconductor device is provided in a shift register circuit as a retention circuit, an unintentional potential change at a floating node can be inhibited, so that delay in data transmission between two retention circuits can be inhibited. Thus, a shift register circuit with no decrease in driving speed can be formed.

One embodiment of the present invention can provide a semiconductor device that operates stably. Another embodiment of the present invention can provide a semiconductor device having a high driving speed. Another embodiment of the present invention can provide a highly reliable semiconductor device. Another embodiment of the present invention can provide a display apparatus including the semiconductor device. Another embodiment of the present invention can provide an electronic device including the display apparatus. Another embodiment of the present invention can provide a novel semiconductor device, a novel display apparatus, or a novel electronic device.

Note that the effects of one embodiment of the present invention are not limited to the above effects. The above effects do not preclude the existence of other effects. Note that the other effects are effects that are not described in this section and will be described below. The effects that are not described in this section can be derived from the description of the specification, the drawings, and the like and can be extracted as appropriate from the description by those skilled in the art. Note that one embodiment of the present invention has at least one of the above effects and the other effects. Accordingly, one embodiment of the present invention sometimes does not have the effects depending on the case.

### BRIEF DESCRIPTION OF THE DRAWINGS

FIG. 1 is a circuit diagram showing an example of a semiconductor device.

FIG. 2A and FIG. 2B are circuit diagrams showing examples of a circuit included in a semiconductor device.

FIG. 3A is a schematic plan view illustrating a transistor included in a semiconductor device, and FIG. 3B and FIG. 3C are schematic cross-sectional views illustrating the transistor included in the semiconductor device.

FIG. 4A is a schematic plan view illustrating a transistor included in a semiconductor device, and FIG. 4B and FIG. 4C are schematic cross-sectional views illustrating the transistor included in the semiconductor device.

FIG. 5A is a schematic plan view illustrating a transistor included in a semiconductor device, and FIG. 5B and FIG. 5C are schematic cross-sectional views illustrating the transistor included in the semiconductor device.

FIG. 6A is a schematic plan view illustrating a transistor included in a semiconductor device, and FIG. 6B and FIG. 6C are schematic cross-sectional views illustrating the transistor included in the semiconductor device.

FIG. 7A is a schematic plan view illustrating a transistor included in a semiconductor device, and FIG. 7B and FIG. 7C are schematic cross-sectional views illustrating the transistor included in the semiconductor device.

FIG. 8A to FIG. 8G are circuit diagrams showing examples of circuits included in a semiconductor device.

FIG. 9 is a circuit diagram showing an example of a semiconductor device.

FIG. 10 is a block diagram showing an example of a display apparatus.

FIG. 11A and FIG. 11B are block diagrams showing examples of a driver circuit.

FIG. 12 is a circuit diagram showing an example of a semiconductor device included in a driver circuit.

FIG. 13 is a circuit diagram showing an example of a semiconductor device included in a driver circuit.

FIG. 14 is a circuit diagram showing an example of a semiconductor device included in a driver circuit.

FIG. 15 is a circuit diagram showing an example of a semiconductor device included in a driver circuit.

FIG. 16 is a timing chart showing an operation example of a circuit included in a driver circuit.

FIG. 17 is a block diagram showing an example of a driver circuit.

FIG. 18 is a timing chart showing an operation example of a driver circuit.

FIG. 19 is a circuit diagram showing an example of a semiconductor device included in a driver circuit.

FIG. 20 is a circuit diagram showing an example of a semiconductor device included in a driver circuit.

FIG. 21 is a block diagram showing an example of a driver circuit.

FIG. 22 is a circuit diagram showing an example of a circuit included in a driver circuit.

FIG. 23 is a circuit diagram showing an example of a semiconductor device included in a driver circuit.

FIG. 24 is a circuit diagram showing an example of a circuit included in a driver circuit.

FIG. 25 is a circuit diagram showing an example of a circuit included in a driver circuit.

FIG. 26 is a timing chart showing an operation example of a driver circuit.

FIG. 27 is a circuit diagram showing an example of a circuit included in a driver circuit.

FIG. 28 is a layout diagram showing an example of an amplifier circuit.

FIG. 29A to FIG. 29D are circuit diagrams showing structure examples of pixel circuits.

FIG. 30A and FIG. 30B are circuit diagrams showing structure examples of pixel circuits.

FIG. 31A and FIG. 31B are circuit diagrams showing structure examples of pixel circuits.

FIG. 32 is a circuit diagram showing a structure example of a pixel circuit.

FIG. 33 is a circuit diagram showing a structure example of a pixel circuit.

FIG. 34A is a schematic plan view showing an example of a method for manufacturing a semiconductor device, and FIG. 34B to FIG. 34D are schematic cross-sectional views showing the example of the method for manufacturing a semiconductor device.

FIG. 35A is a schematic plan view showing an example of a method for manufacturing a semiconductor device, and FIG. 35B to FIG. 35D are schematic cross-sectional views showing the example of the method for manufacturing a semiconductor device.

FIG. 36A is a schematic plan view showing an example of a method for manufacturing a semiconductor device, and FIG. 36B to FIG. 36D are schematic cross-sectional views showing the example of the method for manufacturing a semiconductor device.

FIG. 37A is a schematic plan view showing an example of a method for manufacturing a semiconductor device, and FIG. 37B to FIG. 37D are schematic cross-sectional views showing the example of the method for manufacturing a semiconductor device.

FIG. 38A is a schematic plan view showing an example of a method for manufacturing a semiconductor device, and FIG. 38B to FIG. 38D are schematic cross-sectional views showing the example of the method for manufacturing a semiconductor device.

FIG. 39A is a schematic plan view showing an example of a method for manufacturing a semiconductor device, and FIG. 39B to FIG. 39D are schematic cross-sectional views showing the example of the method for manufacturing a semiconductor device.

FIG. 40A is a schematic plan view showing an example of a method for manufacturing a semiconductor device, and FIG. 40B to FIG. 40D are schematic cross-sectional views showing the example of the method for manufacturing a semiconductor device.

FIG. 41A is a schematic plan view showing an example of a method for manufacturing a semiconductor device, and FIG. 41B and FIG. 41C are schematic cross-sectional views showing the example of the method for manufacturing a semiconductor device.

FIG. 42A is a schematic plan view showing an example of a method for manufacturing a semiconductor device, and FIG. 42B to FIG. 42D are schematic cross-sectional views showing the example of the method for manufacturing a semiconductor device.

FIG. 43A is a schematic plan view showing an example of a method for manufacturing a semiconductor device, and FIG. 43B to FIG. 43D are schematic cross-sectional views showing the example of the method for manufacturing a semiconductor device.

FIG. 44A is a schematic plan view showing an example of a method for manufacturing a semiconductor device, and FIG. 44B to FIG. 44D are schematic cross-sectional views showing the example of the method for manufacturing a semiconductor device.

FIG. 45A is a schematic plan view showing an example of a method for manufacturing a semiconductor device, and FIG. 45B to FIG. 45D are schematic cross-sectional views showing the example of the method for manufacturing a semiconductor device.

FIG. 46A is a schematic plan view showing an example of a method for manufacturing a semiconductor device, and FIG. 46B to FIG. 46D are schematic cross-sectional views showing the example of the method for manufacturing a semiconductor device.

FIG. 47A and FIG. 47B are schematic perspective views showing structure examples of display apparatuses.

FIG. 48 is a block diagram showing a structure example of a display apparatus.

FIG. 49 is a schematic cross-sectional view showing a structure example of a display apparatus.

FIG. 50A to FIG. 50C are cross-sectional views showing structure examples of a display apparatus.

FIG. 51 is a schematic cross-sectional view showing a structure example of a display apparatus.

FIG. 52 is a schematic cross-sectional view showing a structure example of a display apparatus.

FIG. 53 is a schematic cross-sectional view showing a structure example of a display apparatus.

FIG. 54 is a schematic cross-sectional view showing a structure example of a display apparatus.

FIG. 55 is a schematic cross-sectional view showing a structure example of a display apparatus.

FIG. 56 is a schematic cross-sectional view showing a structure example of a display apparatus.

FIG. 57 is a schematic cross-sectional view showing a structure example of a display apparatus.

FIG. 58 is a schematic cross-sectional view showing a structure example of a display apparatus.

FIG. 59 is a schematic cross-sectional view showing a structure example of a display apparatus.

FIG. 60A and FIG. 60B are diagrams showing a structure example of a display module.

FIG. 61A to FIG. 61I are perspective views showing examples of electronic devices.

FIG. 62A is a schematic perspective view illustrating a structure example of a memory device, and FIG. 62B is a block diagram illustrating a structure example of a semiconductor device.

FIG. 63A is a block diagram illustrating a structure example of a memory device.

FIG. 64A and FIG. 64B are circuit diagrams showing structure examples of a memory cell included in a memory device.

FIG. 65A and FIG. 65B are diagrams showing examples of electronic devices, and FIG. 65C to FIG. 65E are diagrams showing an example of a large computer.

FIG. 66 is a diagram showing an example of space equipment.

FIG. 67 is a diagram illustrating an example of a storage system that can be used in a data center.

FIG. 68 is a block diagram illustrating a structure example of an imaging device.

FIG. 69 is a circuit diagram showing a structure example of an imaging pixel circuit included in an imaging device.

### MODE FOPR CARRYING OUT THE INVENTION

In this specification and the like, a semiconductor device refers to a device that utilizes semiconductor characteristics, and means a circuit including a semiconductor element (e.g., a transistor, a diode, and a photodiode), or a device including the circuit. The semiconductor device also means all devices that can function by utilizing semiconductor characteristics. An example of a semiconductor device is an integrated circuit. Another example of a semiconductor device is a chip that includes an integrated circuit. Another example of a semiconductor device is an electronic component in which a chip is stored in a package. Moreover, a memory device, a display apparatus, a light-emitting apparatus, a lighting device, an electronic device, and the like themselves are semiconductor devices in some cases and include semiconductor devices in other cases.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relationship, for example, a connection relationship shown in drawings or texts, a connection relationship other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow electrical connection between X and Y (e.g., a switch, a transistor, a capacitor, an inductor, a resistor, a diode, a display device, a light-emitting device, and a load) can be connected between X and Y. Note that a switch has a function of being controlled to be turned on or off. That is, the switch has a function of being in a conduction state (on state) or a non-conduction state (off state) to control whether a current flows or not.

In the case where an element and a power supply line (e.g., a wiring for supplying VDD (high power supply potential), VSS (low power supply potential), GND (ground potential), or a desired potential) are both provided between X and Y, X and Y are not defined as being electrically connected. In the case where only a power supply line is provided between X and Y, there is no element between X and Y; therefore, X and Y are directly connected. Accordingly, in the case where only a power supply line is provided between X and Y, X and Y can be expressed as being “electrically connected”. However, in the case where an element and a power supply line are both provided between X and Y, X and Y are not defined as being electrically connected, although X and the power supply line are electrically connected (through the element) and Y and the power supply line are electrically connected. Note that in the case where a gate and a source of a transistor are provided between X and Y, X and Y are not defined as being electrically connected. Note that in the case where a gate and a drain of a transistor are provided between X and Y, X and Y are not defined as being electrically connected. That is, in the case where a drain and a source of a transistor are provided between X and Y, X and Y are defined as being electrically connected. Note that in the case where a capacitor is provided between X and Y, X and Y are defined as being electrically connected in some cases and not defined in other cases. For example, in the case where a capacitor is provided between X and Y in a structure of a digital circuit or a logic circuit, X and Y are not defined as being electrically connected in some cases. On the other hand, for example, in the case where a capacitor is provided between X and Y in a structure of an analog circuit, X and Y are defined as being electrically connected in some cases.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-to-analog converter circuit, an analog-digital converter circuit, or a gamma correction circuit); a potential level converter circuit (e.g., a power supply circuit such as a step-up circuit or a step-down circuit, or a level shifter circuit for changing the potential level of a signal); a voltage source; a current source; a switching circuit; an amplifier circuit (e.g., a circuit that can increase signal amplitude, the amount of current, or the like, an operational amplifier, a differential amplifier circuit, a source follower circuit, or a buffer circuit); a signal generation circuit; a memory circuit; or a control circuit) can be connected between X and Y. For instance, even if another circuit is provided between X and Y, X and Y are regarded as being functionally connected when a signal output from X is transmitted to Y.

For example, an expression “X, Y, a source (sometimes called one of a first terminal and a second terminal) of a transistor, and a drain (sometimes called the other of the first terminal and the second terminal) of the transistor are electrically connected to each other, and X, the source of the transistor, the drain of the transistor, and Y are electrically connected to each other in this order” can be used. Alternatively, an expression “a source of a transistor is electrically connected to X; a drain of the transistor is electrically connected to Y; and X, the source of the transistor, the drain of the transistor, and Y are electrically connected to each other in this order” can be used. Alternatively, an expression “X is electrically connected to Y through a source and a drain of a transistor, and X, the source of the transistor, the drain of the transistor, and Y are provided in this connection order” can be used. When the connection order in a circuit structure is defined by an expression like the above examples, a source and a drain of a transistor can be distinguished from each other to specify the technical scope. Note that these expressions are non-limiting examples. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has both a function of a wiring and a function of an electrode. Thus, electrical connection in this specification includes, in its category, such a case where one conductive film has functions of a plurality of components.

In this specification and the like, a “resistor” can be, for example, a circuit element having a resistance value higher than 0 22 or a wiring having a resistance value higher than 0 22. Therefore, in this specification and the like, a “resistor” includes a wiring having a resistance value, a transistor in which a current flows between a source and a drain, a diode, and a coil. Thus, the term “resistor” can sometimes be replaced with the terms “resistance”, “load”, or “region having a resistance value”. Conversely, the terms “resistance”, “load”, or “region having a resistance value” can sometimes be replaced with the term “resistor”. The resistance value can be, for example, preferably higher than or equal to 1 mΩ and lower than or equal to 10 22, further preferably higher than or equal to 5 mΩ and lower than or equal to 5 Ω, still further preferably higher than or equal to 10 mΩ and lower than or equal to 1 Ω. For another example, the resistance value may be higher than or equal to 1 Ω and lower than or equal to 1×10⁹ Ω.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. The term “capacitor”, “parasitic capacitance”, or “gate capacitance” can be replaced with the term “capacitance” in some cases. Conversely, the term “capacitance” can be replaced with the term “capacitor”, “parasitic capacitance”, or “gate capacitance” in some cases. In addition, a “capacitor” (including a “capacitor” with three or more terminals) includes an insulator and a pair of conductors between which the insulator is interposed. Thus, the term “pair of conductors” of “capacitor” can be replaced with “pair of electrodes”, “pair of conductive regions”, “pair of regions”, or “pair of terminals”. In addition, the terms “one of a pair of terminals” and “the other of the pair of terminals” are referred to as a first terminal and a second terminal, respectively, in some cases. Note that the electrostatic capacitance value can be higher than or equal to 0.05 fF and lower than or equal to 10 pF, for example. For another example, the electrostatic capacitance value may be higher than or equal to 1 pF and lower than or equal to 10 μF.

In this specification and the like, a transistor includes three terminals called a gate, a source, and a drain. The gate is a control terminal for controlling the conduction state of the transistor. Two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Thus, the terms “source” and “drain” can sometimes be replaced with each other in this specification and the like. In this specification and the like, expressions “one of a source and a drain” (or a first electrode or a first terminal) and “the other of the source and the drain” (or a second electrode or a second terminal) are used in description of the connection relationship of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, a third gate, and the like in this specification and the like.

In this specification and the like, for example, a transistor with a multi-gate structure having two or more gate electrodes can be used as the transistor. With the multi-gate structure, channel formation regions are connected to each other in series; accordingly, a plurality of transistors are connected to each other in series. Thus, with the multi-gate structure, the amount of an off-state current can be reduced, and the breakdown voltage of the transistor can be increased (the reliability can be improved). Alternatively, with the multi-gate structure, drain-source current does not change very much even if drain-source voltage changes at the time of an operation in a saturation region, so that a flat slope of voltage-current characteristics can be obtained. By utilizing the flat slope of the voltage-current characteristics, an ideal current source circuit or an active load having an extremely high resistance value can be obtained. Accordingly, a differential circuit, a current mirror circuit, and the like having excellent properties can be obtained.

The case where a single circuit element is illustrated in a circuit diagram may include a case where the circuit element includes a plurality of circuit elements. For example, the case where a single resistor is illustrated in a circuit diagram may include a case where two or more resistors are electrically connected to each other in series. For another example, the case where a single capacitor is illustrated in a circuit diagram may include a case where two or more capacitors are electrically connected to each other in parallel. For another example, the case where a single transistor is illustrated in a circuit diagram may include a case where two or more transistors are electrically connected to each other in series and gates of the transistors are electrically connected to each other. Similarly, for another example, the case where a single switch is illustrated in a circuit diagram may include a case where the switch includes two or more transistors, the two or more transistors are electrically connected to each other in series or in parallel, and gates of the transistors are electrically connected to each other.

In this specification and the like, a node can be referred to as a terminal, a wiring, an electrode, a conductive layer, a conductor, or an impurity region depending on the circuit structure and the device structure. Furthermore, a terminal, a wiring, or the like can be referred to as a node.

In this specification and the like, a “voltage” and a “potential” can be replaced with each other as appropriate. A “voltage” refers to a potential difference from a reference potential, and when the reference potential is a ground potential, for example, a “voltage” can be replaced with a “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, the terms “high-level potential” and “low-level potential” do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

A “current” means an electric charge transfer phenomenon (electrical conduction); for example, the description “electrical conduction of positively charged particles occurs” can be rephrased as “electrical conduction of negatively charged particles occurs in the opposite direction”. Therefore, unless otherwise specified, a “current” in this specification and the like refers to an electric charge transfer phenomenon (electrical conduction) accompanying carrier movement. Examples of a carrier here include an electron, a hole, an anion, a cation, and a complex ion, and the type of carrier differs between current flow systems (e.g., a semiconductor, a metal, an electrolyte solution, and a vacuum). The “direction of a current” in a wiring or the like refers to the direction in which a carrier with positive electric charge moves, and the amount of the current is expressed as a positive value. In other words, the direction in which a carrier with negative electric charge moves is opposite to the direction of a current, and the amount of the current is expressed as a negative value. Thus, in the case where the polarity of a current (or the direction of a current) is not specified in this specification and the like, the description “a current flows from element A to element B” can be rephrased as “a current flows from element B to element A”. The description “a current is input to element A” can be rephrased as “a current is output from element A”.

Ordinal numbers such as “first”, “second”, and “third” in this specification and the like are used in order to avoid confusion among components. Thus, the terms do not limit the number of components. The terms do not limit the order of components, either. For example, a “first” component in one embodiment in this specification and the like can be referred to as a “second” component in other embodiments or the scope of claims. For another example, a “first” component in one embodiment in this specification and the like can be omitted in other embodiments or the scope of claims.

In this specification and the like, the terms for describing positioning, such as “over” and “under”, are sometimes used for convenience to describe the positional relationship between components with reference to drawings. The positional relationship between components is changed as appropriate in accordance with the direction in which the components are described. Thus, the positional relationship is not limited to the terms described in the specification and the like, and can be described with another term as appropriate depending on the situation. For example, the expression “an insulator located over (on) a top surface of a conductor” can be replaced with the expression “an insulator located under (on) a bottom surface of a conductor” when the direction of a drawing illustrating these components is rotated by 180°.

Furthermore, the terms “over” and “under” do not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B. Similarly, for example, the expression “electrode B above insulating layer A” does not necessarily mean that the electrode B is formed above and in direct contact with the insulating layer A, and does not exclude the case where another component is provided between the insulating layer A and the electrode B. Similarly, for example, the expression “electrode B under insulating layer A” does not necessarily mean that the electrode B is formed under and in direct contact with the insulating layer A, and does not exclude the case where another component is provided between the insulating layer A and the electrode B.

In this specification and the like, components arranged in a matrix and their positional relationship are sometimes described using terms such as “row” and “column”. The positional relationship between components is changed as appropriate in accordance with the direction in which the components are described. Thus, the positional relationship is not limited to the terms described in the specification and the like, and can be described with another term as appropriate depending on the situation. For example, the term “row direction” can be replaced with the term “column direction” when the direction of the drawing is rotated by 90°.

In this specification and the like, the terms “film” and “layer” can be interchanged with each other depending on the situation. For example, the term “conductive layer” can be replaced with the term “conductive film” in some cases. For another example, the term “insulating film” can be changed into the term “insulating layer” in some cases. Moreover, the terms “film” and “layer” are not used and can be interchanged with another term depending on the case or the situation. For example, the term “conductive layer” or “conductive film” can be changed into the term “conductor” in some cases. Furthermore, for example, the term “insulating layer” or “insulating film” can be changed into the term “insulator” in some cases.

In this specification and the like, the terms “electrode”, “wiring”, “terminal”, and the like do not limit the functions of such components. For example, an “electrode” is used as part of a “wiring” in some cases, and vice versa. Furthermore, the term “electrode” or “wiring” also refers to, for example, the case where a plurality of “electrodes” or “wirings” are formed in an integrated manner. For example, a “terminal” is used as part of a “wiring” or an “electrode” in some cases, and vice versa. Furthermore, the term “terminal” also refers to the case where one or more selected from “electrodes”, “wirings”, and “terminals” are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, or “terminal” is sometimes replaced with the term “region” depending on the case.

In this specification and the like, the terms “wiring”, “signal line”, and “power supply line” can be interchanged with each other depending on the case or the situation. For example, the term “wiring” can be changed into the term “signal line” in some cases. For another example, the term “wiring” can be changed into the term “power supply line” or the like in some cases. Conversely, the term “signal line” or “power supply line” can be changed into the term “wiring” in some cases. The term “power supply line” can be changed into the term “signal line” in some cases. Conversely, the term “signal line” can be changed into the term “power supply line” in some cases. The term “potential” that is applied to a wiring can be changed into the term “signal” depending on the case or the situation. Conversely, the term “signal” can be changed into the term “potential” in some cases.

In this specification and the like, a timing chart is used in some cases to describe an operation method of a semiconductor device. The timing chart used in this specification and the like shows an ideal operation example and a period, a level of a signal (e.g., a potential or a current), and a timing described in the timing chart are not limited unless otherwise specified. In the timing chart described in this specification and the like, the level of a signal (e.g., a potential or a current) input to a wiring (including a node) and a timing can be changed depending on the situation. For example, even when two periods are shown to have an equal length in the timing chart, the two periods have different lengths in some cases. Furthermore, for example, even when one of two periods is shown long and the other is shown short, the two periods can have the equal length in some cases, or the one period can have a short length and the other can have a long length in other cases. To clearly show the timing chart, two or more overlapping signals are sometimes shown to be intentionally shifted from each other, for example.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is included in a channel formation region of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS transistor is mentioned, the OS transistor can also be referred to as a transistor including a metal oxide or an oxide semiconductor.

In this specification and the like, a metal oxide containing nitrogen is also referred to as a metal oxide in some cases. Alternatively, a metal oxide containing nitrogen may be called a metal oxynitride.

In this specification and the like, an impurity in a semiconductor refers to, for example, an element other than a main component of a semiconductor layer. For example, an element with a concentration of lower than 0.1 atomic % is an impurity. When an impurity is contained, for example, one or more selected from an increase in the density of defect states in a semiconductor, a decrease in carrier mobility, and a decrease in crystallinity occur in some cases. In the case where the semiconductor is an oxide semiconductor, examples of an impurity that changes characteristics of the semiconductor include Group 1 elements, Group 2 elements, Group 13 elements, Group 14 elements, Group 15 elements, and transition metals other than the main components; specific examples are hydrogen (contained also in water), lithium, sodium, silicon, boron, phosphorus, carbon, and nitrogen.

In this specification and the like, a switch refers to an element having a function of being in a conduction state (on state) or a non-conduction state (off state) to control whether a current flows or not. Alternatively, a switch refers to an element having a function of selecting and changing a current path. Thus, a switch may have two terminals or three or more terminals through which a current flows, in addition to a control terminal. For example, an electrical switch or a mechanical switch can be used. That is, a switch can be any element capable of controlling a current, and is not limited to a particular element.

Examples of an electrical switch include a transistor (e.g., a bipolar transistor and a MOS transistor), a diode (e.g., a PN diode, a PIN diode, a Schottky diode, a MIM (Metal Insulator Metal) diode, a MIS (Metal Insulator Semiconductor) diode, and a diode-connected transistor), and a logic circuit in which such elements are combined. Note that in the case of using a transistor as a switch, a “conduction state” of the transistor refers to a state where a source electrode and a drain electrode of the transistor can be regarded as being electrically short-circuited or a state where a current can be made to flow between the source electrode and the drain electrode. Furthermore, a “non-conduction state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

An example of a mechanical switch is a switch formed using a MEMS (micro electro mechanical systems) technology. Such a switch includes an electrode that can be moved mechanically, and operates by controlling conduction and non-conduction with movement of the electrode.

In this specification and the like, a device fabricated using a metal mask or an FMM (fine metal mask, high-resolution metal mask) may be referred to as a device having an MM (metal mask) structure. In this specification and the like, a device fabricated without using a metal mask or an FMM may be referred to as a device having an MML (metal maskless) structure.

In this specification and the like, a structure in which light-emitting layers in light-emitting devices of different colors (here, blue (B), green (G), and red (R)) are separately formed or separately patterned may be referred to as an SBS (Side By Side) structure. In this specification and the like, a light-emitting device capable of emitting white light may be referred to as a white-light-emitting device. Note that a combination of white-light-emitting devices with coloring layers (e.g., color filters) enables a full-color display apparatus.

Light-emitting devices can be classified roughly into a single structure and a tandem structure. A device having a single structure includes one light-emitting unit between a pair of electrodes, and the light-emitting unit preferably includes one or more light-emitting layers. When white light emission is obtained using two light-emitting layers, the two light-emitting layers are selected such that emission colors of the light-emitting layers are complementary colors. For example, when the emission color of a first light-emitting layer and the emission color of a second light-emitting layer have a relationship of complementary colors, a structure in which the light-emitting device emits white light as a whole can be obtained. When white light emission is obtained using three or more light-emitting layers, a light-emitting device is configured to emit white light as a whole by combining emission colors of the three or more light-emitting layers.

A device having a tandem structure includes two or more light-emitting units between a pair of electrodes, and each light-emitting unit preferably includes one or more light-emitting layers. To obtain white light emission, the light-emitting device is configured to obtain white light emission by combining light from light-emitting layers of the plurality of light-emitting units. Note that a structure for obtaining white light emission is similar to the structure of the case of a single structure. In the device having a tandem structure, an intermediate layer such as a charge-generation layer is suitably provided between the plurality of light-emitting units.

When the above white-light-emitting device (having a single structure or a tandem structure) and the above light-emitting device having an SBS structure are compared to each other, the light-emitting device having an SBS structure can have lower power consumption than the white-light-emitting device. To reduce power consumption, the light-emitting device having an SBS structure is suitably used. Meanwhile, the white-light-emitting device is suitable in terms of lower manufacturing cost or higher manufacturing yield because the manufacturing process of the white-light-emitting device is simpler than that of the light-emitting device having an SBS structure.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

In this specification and the like, one embodiment of the present invention can be constituted by appropriately combining a structure described in an embodiment with any of the structures described in the other embodiments. In addition, in the case where a plurality of structure examples are described in one embodiment, the structure examples can be combined as appropriate.

Note that a content (or part of the content) described in one embodiment can be applied to, combined with, or replaced with at least one of another content (or part of the content) in the embodiment and a content (or part of the content) described in one or a plurality of different embodiments.

Note that in each embodiment, a content described in the embodiment is a content described using a variety of diagrams or a content described with text disclosed in the specification. Note that by combining a diagram (or part thereof) described in one embodiment with at least one of another part of the diagram, a different diagram (or part thereof) described in the embodiment, and a diagram (or part thereof) described in one or a plurality of different embodiments, much more diagrams can be provided.

Embodiments described in this specification are described with reference to the drawings. Note that the embodiments can be implemented in many different modes, and it will be readily appreciated by those skilled in the art that modes and details can be changed in various ways without departing from the spirit and scope thereof. Thus, the present invention should not be interpreted as being limited to the description in the embodiments. Note that in the structures of the invention in the embodiments, the same portions or portions having similar functions are denoted by the same reference numerals in different drawings, and repeated description thereof is omitted in some cases. In perspective views and the like, illustration of some components may be omitted for clarity of the drawings.

In this specification and the like, when a plurality of components are denoted with the same reference numerals, and in particular need to be distinguished from each other, an identification sign such as “_1”, “[n]”, or “[m, n]” is sometimes added to the reference numerals. Components denoted with identification signs such as “_1”, “[n]”, and “[m, n]” in the drawings and the like are sometimes described without such identification signs in this specification and the like when the components do not need to be distinguished from each other.

In the drawings in this specification, the size, the layer thickness, or the region is exaggerated for clarity in some cases. Thus, the size, the layer thickness, or the region is not limited to the illustrated scale. The drawings are schematic views showing ideal examples, and embodiments of the present invention are not limited to shapes, values, or the like shown in the drawings.

### Embodiment 1

In this embodiment, a retention circuit that is a semiconductor device of one embodiment of the present invention will be described.

### Structure Example 1 of Retention Circuit

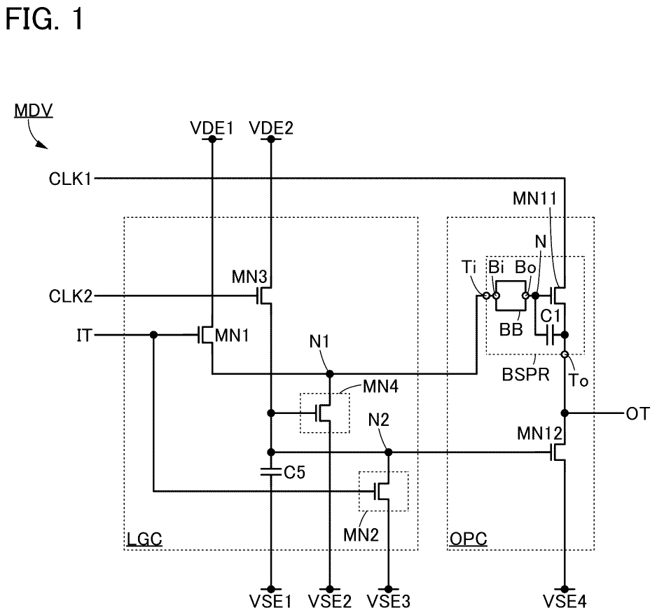

A circuit MDV illustrated in FIG. 1 is an example of the retention circuit that is the semiconductor device of one embodiment of the present invention and includes a terminal IT, a terminal CLK1, a terminal CLK2, a terminal OT, a circuit LGC, and a circuit OPC.

The terminal IT, the terminal CLK1, and the terminal CLK2 are each a terminal having a function of an input terminal in the circuit MDV, and the terminal OT is a terminal having a function of an output terminal in the circuit MDV.

The terminal IT has a function of a terminal that receives a 1-bit signal to be retained in the circuit MDV from the outside of the circuit MDV, for example. Thus, the signal can be, for example, a high-level potential or a low-level potential.

The terminal CLK1 has a function of a terminal that receives a clock signal for operating the circuit MDV, for example.

The terminal CLK2 has a function of a terminal that receives a clock signal for operating the circuit MDV, for example. Note that a clock signal input to the terminal CLK2 is preferably different from a clock signal input to the terminal CLK1. Note that depending on the case, clock signals input to the terminal CLK1 and the terminal CLK2 may be the same. In that case, the terminal CLK1 and the terminal CLK2 may be combined into one terminal.

The terminal OT has a function of a terminal that outputs a 1-bit signal retained in the circuit MDV.

The circuit MDV can be separated into the circuit LGC and the circuit OPC on the basis of the functions. The circuit LGC has a function of, for example, a logic circuit that processes a signal input to the terminal IT, and the circuit OPC has a function of, for example, a logic circuit that generates a signal output to the terminal OT. Note that one or both of the circuit LGC and the circuit OPC may be not a logic circuit but an analog circuit.

As illustrated in FIG. 1, the circuit LGC includes a transistor MN1 to a transistor MN4 and a capacitor C5, for example. The circuit OPC includes a transistor MN12 and a circuit BSPR, for example. The circuit BSPR includes a circuit BB, a transistor MN11, and a capacitor C1. The circuit BSPR includes, for example, a terminal Ti having a function of an input terminal and a terminal To having a function of an output terminal. The circuit BB includes, for example, a terminal Bi having a function of an input terminal and a terminal Bo having a function of an output terminal.

Note that FIG. 1 shows an example of separating the transistor MN1 to the transistor MN4, the transistor MN11, the transistor MN12, the capacitor C1, and the capacitor C5 into the circuit LGC and the circuit OPC, and the structures of the circuit LGC and the circuit OPC are not particularly limited. For example, the capacitor C5 included in the circuit LGC in FIG. 1 may be included in the circuit OPC.

As each of the transistor MN1 to the transistor MN4, the transistor MN11, and the transistor MN12, an OS transistor is preferably used, for example. In particular, a metal oxide contained in a channel formation region of the OS transistor is preferably an In-M-Zn oxide containing indium, an element M, and zinc (the element M is one or more kinds selected from aluminum, gallium, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony), for example. Alternatively, as each of the transistor MN1 to the transistor MN4, the transistor MN11, and the transistor MN12, a transistor containing silicon in a channel formation region (hereinafter referred to as a Si transistor) may be used. As the silicon, single crystal silicon, amorphous silicon (referred to as hydrogenated amorphous silicon in some cases), microcrystalline silicon, or polycrystalline silicon can be used, for example. As a transistor other than an OS transistor and a Si transistor, for example, a transistor containing germanium (Ge) or the like in a channel formation region, a transistor containing a compound semiconductor such as zinc selenide (ZnSe), cadmium sulfide (CdS), gallium arsenide (GaAs), indium phosphide (InP), gallium nitride (GaN), or silicon germanium (SiGe) in a channel formation region, a transistor containing a carbon nanotube in a channel formation region, or a transistor containing an organic semiconductor in a channel formation region can be used.

Although the transistor MN1 to the transistor MN4, the transistor MN11, and the transistor MN12 are n-channel transistors in FIG. 1, one or more selected from the transistor MN1 to the transistor MN4, the transistor MN11, and the transistor MN12 may be p-channel transistors depending on the situation.

Note that the above description of the transistor applies to a transistor described in other parts of the specification and a transistor illustrated in other drawings, not only to the transistors illustrated in FIG. 1.

The terminal IT is electrically connected to a gate of the transistor MN1 and a gate of the transistor MN2. A first terminal of the transistor MN1 is electrically connected to a wiring VDE1, and a second terminal of the transistor MN1 is electrically connected to a first terminal of the transistor MN4 and the terminal Ti of the circuit BSPR. The terminal CLK2 is electrically connected to a gate of the transistor MN3, a first terminal of the transistor MN3 is electrically connected to a wiring VDE2, and a second terminal of the transistor MN3 is electrically connected to a gate of the transistor MN4, a first terminal of the transistor MN2, a gate of the transistor MN12, and a first terminal of the capacitor C5. A second terminal of the capacitor C5 is electrically connected to a wiring VSE1, a second terminal of the transistor MN4 is electrically connected to a wiring VSE2, and a second terminal of the transistor MN2 is electrically connected to a wiring VSE3.

Note that in FIG. 1, a portion where the second terminal of the transistor MN1, the first terminal of the transistor MN4, and the terminal Ti of the circuit BSPR are electrically connected is referred to as a node N1, and a portion where the second terminal of the transistor MN3, the gate of the transistor MN4, the first terminal of the transistor MN2, the gate of the transistor MN12, and the first terminal of the capacitor C5 are electrically connected is referred to as a node N2.

The terminal Ti of the circuit BSPR is electrically connected to the terminal Bi of the circuit BB. The terminal Bo of the circuit BB is electrically connected to a gate of the transistor MN11 and a first terminal of the capacitor C1, a first terminal of the transistor MN11 is electrically connected to the terminal CLK1, and a second terminal of the transistor MN11 is electrically connected to a second terminal of the capacitor C1 and the terminal To of the circuit BSPR.

The terminal To of the circuit BSPR is electrically connected to the terminal OT and a first terminal of the transistor MN12. A second terminal of the transistor MN12 is electrically connected to a wiring VSE4.

The wiring VDE1 and the wiring VDE2 each has a function of a wiring for supplying a fixed potential, for example. The fixed potential can be a high-level potential, for example. Note that the wiring VDE1 and the wiring VDE2 may supply fixed potentials equal to each other or may supply fixed potentials different from each other. Note that in the case where the wiring VDE1 and the wiring VDE2 supply fixed potentials equal to each other, for example, the wiring VDE1 and the wiring VDE2 may be the same wiring.

One or both of the wiring VDE1 and the wiring VDE2 may be a wiring for supplying not a fixed potential but a variable potential (sometimes referred to as a pulse voltage, a pulse potential, a pulse signal, or the like).

The wiring VSE1 to the wiring VSE4 each have a function of a wiring for supplying a fixed potential, for example. The fixed potential can be, for example, a low-level potential, the ground potential, or a negative potential. Note that the wiring VSE1 to the wiring VSE4 may supply fixed potentials equal to each other or may supply fixed potentials different from each other. Alternatively, two or more wirings selected from the wiring VSE1 to the wiring VSE4 may supply fixed potentials equal to each other, and the other wiring(s) may supply a potential different from the fixed potentials. Furthermore, the two or more wirings among the wiring VSE1 to the wiring VSE4 which supply fixed potentials equal to each other may be the same wiring. For example, in the case where the wiring VSE1 and the wiring VSE2 supply fixed potentials equal to each other, the wiring VSE1 and the wiring VSE2 may be the same wiring.

One or more selected from the wiring VSE1 to the wiring VSE4 may have a function of a wiring for supplying not a fixed potential but a variable potential.

Here, the operation of the circuit LGC illustrated in FIG. 1 is described assuming that a high-level potential is input to each of the wiring VDE1 and the wiring VDE2 and a low-level potential is input to each of the wiring VSE1 to the wiring VSE3.

When the terminal IT is supplied with a low-level potential and the terminal CLK2 is supplied with a high-level potential in the circuit LGC in FIG. 1, for example, the transistor MN1 is in an off state and the transistor MN4 is in an on state, so that the potential of the node N1 is the low-level potential supplied by the wiring VSE2. In addition, the transistor MN2 is in an off state and the transistor MN3 is in an on state, so that the potential of the node N2 is a potential obtained by subtracting the threshold voltage of the transistor MN3 from the high-level potential supplied by the wiring VDE2. Note that the potential obtained by subtracting the threshold voltage of the transistor MN3 from the high-level potential supplied by the wiring VDE2 is input to the gate of the transistor MN4; thus, to be precise, the potential of the node N1 may be slightly higher than the low-level potential supplied by the wiring VSE2.

Next, for example, when the high-level potential supplied to the terminal CLK2 changes to the low-level potential, the transistor MN3 is turned off, the node N2 is brought into a floating state, and the potential obtained by subtracting the threshold voltage of the transistor MN3 from the high-level potential supplied by the wiring VDE2 is retained in the first terminal of the capacitor C5. Since the transistor MN4 remains in an on state, the potential of the node N1 does not change from the low-level potential supplied by the wiring VSE1 (or the potential slightly higher than the low-level potential).

When the terminal IT is supplied with a high-level potential and the terminal CLK2 is supplied with a low-level potential, the transistor MN2 is in an on state and the transistor MN3 is in an off state, so that the potential of the node N2 is the low-level potential supplied by the wiring VSE3. In addition, the transistor MN1 is in an on state and the transistor MN4 is in an off state, so that the potential of the node N1 is a potential obtained by subtracting the threshold voltage of the transistor MN1 from the high-level potential supplied by the wiring VDE1.

Next, for example, when the high-level potential supplied to the terminal IT changes to the low-level potential, the transistor MN1 is turned off, the node N1 is brought into a floating state, and ideally, the potential of the node N1 does not change from the potential obtained by subtracting the threshold voltage of the transistor MN1 from the high-level potential supplied by the wiring VDE1. Moreover, since the transistor MN2 is also turned off, the node N2 is also brought into a floating state, and the low-level potential supplied by the wiring VSE3 is retained in the first terminal of the capacitor C5.

The following is the summary of the above description. When a low-level potential is input to the terminal CLK2 and a high-level potential is input to the terminal IT, ideally, the potential of the node N1 is a high-level potential and the potential of the node N2 is a low-level potential. When a high-level potential is input to the terminal CLK2 and a low-level potential is input to the terminal IT, ideally, the potential of the node N1 is a low-level potential and the potential of the node N2 is a high-level potential. When a low-level potential is input to the terminal IT and the potential of the terminal CLK2 changes from a high-level potential to a low-level potential, the potentials of the node N1 and the node N2 do not change before and after the change in the potential of the terminal CLK2. Similarly, when a low-level potential is input to the terminal CLK2 and the potential of the terminal IT changes from a high-level potential to a low-level potential, the potentials of the node N1 and the node N2 do not change before and after the change in the potential of the terminal IT.

Next, the operation of the circuit OPC illustrated in FIG. 1 is described assuming that a low-level potential is input to the wiring VSE4.

The circuit BSPR illustrated in FIG. 1 is an example of an amplifier circuit and includes the circuit BB, the transistor MN11, and the capacitor C1. As described above, the circuit BB includes, for example, the terminal Bi having a function of an input terminal and the terminal Bo having a function of an output terminal.

The transistor MN11 is normally off and the threshold voltage of the transistor MN11 is set to V_{th_MN11}. The threshold voltage V_{th_MN11} is set to satisfy V_{High}−V_{Low}>V_{th_MN11}. Note that V_{High} is a high-level potential and V_{Low} is a low-level potential.

Note that in this specification and the like, normally off means a state where a current does not flow through a transistor when no potential is applied to a gate, a ground potential is applied to the gate, or a gate-source voltage is 0 V. Moreover, normally off of an OS transistor means that a current per micrometer of channel width flowing through a transistor is lower than or equal to 1×10⁻²⁰ A at room temperature, lower than or equal to 1×10⁻¹⁸ A at 85° C., or lower than or equal to 1×10⁻¹⁶ A at 125° C. when no potential is applied to a gate, a ground potential is applied to the gate, or a gate-source voltage is 0 V. Meanwhile, normally on means a state where a channel exists even when no potential is applied to a gate, and a current flows through a transistor. Alternatively, normally on means a state where a channel exists even when a gate-source voltage is 0 V, and a current flows through a transistor.

Note that in this embodiment, a portion where the terminal Bo of the circuit BB, the gate of the transistor MN11, and the first terminal of the capacitor C1 are electrically connected is referred to as a node N.

The circuit BB has a function of bringing the node N into a floating state, for example. Thus, the circuit BB can include a switching element, for example. The circuit BB also has a function of outputting, to the terminal Bo, a potential corresponding to the potential input to the terminal Bi. For example, the circuit BB can have a structure in which when the high-level potential V_{High} is supplied to the terminal Bi, a potential V_{Mid} is output to the terminal Bo. Note that V_{Mid} is a potential lower than the high-level potential V_{High} and higher than the low-level potential V_{Low}. In addition, V_{Mid} is a voltage satisfying V_{Mid}−V_{Low}>V_{th_MN11}.

Here, the potential of the node N of the circuit BSPR in FIG. 1 is assumed to be the potential V_{Mid}, which is lower than the high-level potential V_{High}. In this case, the node N is assumed not to be in a floating state. The potentials of the node N1 and the node N2 are low-level potentials. Thus, the transistor MN12 is in an off state. In addition, the low-level potential V_{Low} is assumed to be supplied to the first terminal of the transistor MN11 from the terminal CLK1.

At this time, the gate-source voltage (the gate-first terminal voltage at this timing) of the transistor MN11 is V_{Mid}−V_{Low}. Since V_{Mid}−V_{Low}>V_{th_MN11} is satisfied, the transistor MN11 is in an on state. Thus, in the circuit MDV, the potential of the terminal OT is the low-level potential V_{Low} input from the terminal CLK1 through the transistor MN11.

Next, the low-level potential V_{Low} supplied to the first terminal of the transistor MN11 from the terminal CLK1 is assumed to change to the high-level potential V_{High}. In addition, the node N is assumed to be brought into a floating state by the circuit BB. At this time, the gate-source voltage (the gate-second terminal voltage at this timing) of the transistor MN11 is V_{Mid}−V_{Low}, whereby the transistor MN11 is turned on. Consequently, current flows from the terminal CLK1 to the terminal OT through the transistor MN11, which renders the potential of the terminal OT higher than V_{Low}. Note that since the node N is in a floating state, the capacitive coupling with a capacitor Ca causes an increase in the potential of the node N from V_{Mid} in response to the increase in the potential of the terminal OT. The gate-source voltage of the transistor MN11 is retained by the capacitor C1, whereby the potential of the terminal OT increases to V_{High}. Ideally, the potential of the node N becomes V_{Mid}+V_{High}−V_{Low}.

As described above, in the circuit BSPR, when V_{Mid} lower than the high-level potential is input to the node N and the potential of the terminal CLK1 changes from the low-level potential V_{Low} to the high-level potential V_{High}, the potential of the terminal OT becomes V_{High}. In this specification and the like, increasing the gate potential of a transistor with an increase in the potential of the first terminal or the second terminal of a transistor by utilizing capacitive coupling in such a manner is referred to as a bootstrap.

In the circuit BSPR in FIG. 1, when the potential of the first terminal of the transistor MN11 changes from the low-level potential V_{Low} to the high-level potential V_{High} owing to the terminal CLK1 and the potential V_{Mid} is supplied to the node N, the potential of the node N increases to V_{Mid}+V_{High}−V_{Low} by bootstrap, and the potential output to the terminal To of the circuit BSPR becomes V_{High}.

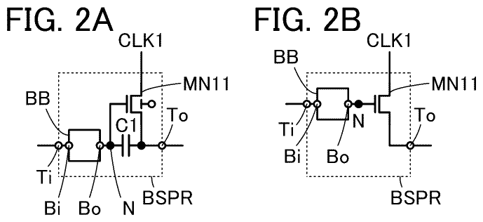

Note that the transistor MN11 illustrated in FIG. 1 may include a back gate, for example. Specifically, for example, the transistor MN11 of the circuit BSPR in FIG. 1 may be a transistor having a multi-gate structure including gates over and under a channel. For example, the transistor MN11 illustrated in FIG. 2A is an n-channel transistor having a multi-gate structure including gates over and under a channel; the transistor MN11 includes a second gate in addition to a first gate. Note that in this specification and the like, for convenience, the first gate is referred to as a gate (sometimes referred to as a front gate) and the second gate is referred to as a back gate so that they are distinguished from each other in some cases. In this specification and the like, the first gate and the second gate can be interchanged, and thus the term “gate” can be replaced with the term “back gate”. Similarly, the term “back gate” can be replaced with the term “gate”. As a specific example, a connection structure in which “a gate is electrically connected to a first wiring and a back gate is electrically connected to a second wiring” can be replaced with a connection structure in which “a back gate is electrically connected to a first wiring and a gate is electrically connected to a second wiring”.

In FIG. 2A, the back gate of the transistor MN11 is illustrated, but the connection structure of the back gate is not illustrated. Note that the destination to which the back gate is electrically connected can be determined at the design stage. For example, in a transistor including a back gate, a gate and the back gate may be electrically connected to each other to increase the on-state current of the transistor. In other words, for example, the gate and back gate of the transistor MN11 may be electrically connected. Alternatively, for example, in a transistor including a back gate, a wiring for electrically connecting the back gate of the transistor to an external circuit may be provided and a potential may be supplied to the back gate of the transistor with the external circuit to change the threshold voltage of the transistor or to reduce the off-state current of the transistor.

Note that although it has been described above that the transistor MN11 may include a back gate, transistors described in other parts of the specification or transistors illustrated in other drawings may each also include a back gate. For example, the transistor MN1 to the transistor MN4 included in the circuit LGC, the transistor MN12 included in the circuit OPC, and the like may each have a structure including a back gate.

Note that in the case where the gate capacitance between the gate of the transistor MN11 and the channel formation region (sometimes including one or both of the first terminal and the second terminal depending on the situation) thereof is large, the circuit BSPR can have a structure in which the capacitor C1 is not provided as illustrated in FIG. 2B. In this case, the circuit area of the circuit BSPR can be reduced.

In order to stabilize the potential V_{High} of the terminal OT increased by bootstrap using the circuit BSPR, it is preferable that the potential of the terminal Bi of the circuit BB do not change. For example, in the case where the potential of the terminal Bi decreases due to any factor, the potential of the terminal Bo may also decrease through the circuit BB; as a result, the potential of the node N also decreases.

One factor of a decrease in the potential of the terminal Bi is a leakage current flowing when the transistor included in the circuit LGC is in an off state. For example, in a transistor for retaining the potential of the terminal Bi (the node N1) (e.g., the transistor MN4 of the circuit LGC), the potential of the terminal Bi (the node N1) decreases when the off-state current flowing between the source and the drain or the leakage current flowing between the gate and the source or between the gate and the drain becomes large. Accordingly, the potential supplied to the terminal Bi of the circuit BB changes and thus the potential of the node N is also affected, which might make the potential of the terminal OT, which is increased by bootstrap, unstable in the circuit BSPR. That is, it is preferable that the potential of the terminal Bi (the node N1) do not change while the circuit MDV outputs the potential V_{High} of the terminal OT, which is increased by bootstrap, in the circuit BSPR.

Similarly, it is preferable that the potential of the gate of the transistor MN12 (the node N2) do not change while the circuit MDV outputs the potential V_{High} of the terminal OT. In the case where the potential of the gate of the transistor MN12 (the node N2) changes due to any factor, the gate-source voltage of the transistor MN12 may also change and the amount of an off-state current of the transistor MN12 may increase; as a result, the potential of the terminal OT output from the circuit MDV may decrease from V_{High}.

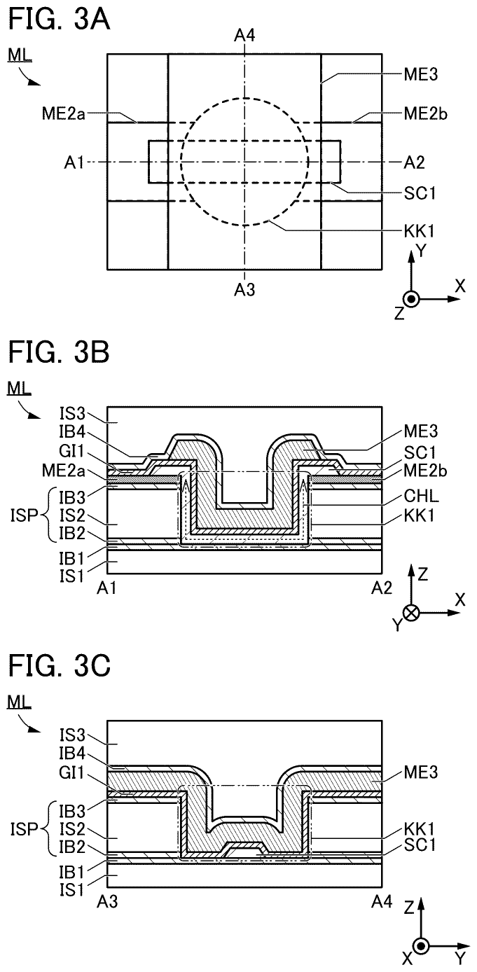

To solve the above problem, a transistor illustrated in FIG. 3A to FIG. 3C is preferably used as each of the transistor MN2 and the transistor MN4.

### Structure Example 1 of Transistor

A transistor ML illustrated in FIG. 3A to FIG. 3C is a transistor referred to as a VLFET (Vertical Lateral Field Effect Transistor) and has a structure in which current flows in both the vertical direction and the lateral direction. Specifically, a semiconductor layer is positioned in contact with the side surface of an opening provided in a first insulating layer and the top surface of a second insulating layer corresponding to a bottom portion of the opening, and the semiconductor layer includes a channel formation region of the transistor ML. In other words, the channel length of the transistor ML includes a component along the side surface of the opening and a component along the bottom portion of the opening, and thus is easily made longer than the channel length in a conventional transistor structure. Note that the channel length here can be the length of the channel formation region between a source and a drain.

Note that in the transistor ML in FIG. 3B, a channel length CHL of the channel formation region included in a semiconductor layer SC1 is illustrated.

By increasing the channel length, the off-state current (leakage current) of the transistor can be reduced; thus, by using the transistor ML illustrated in FIG. 3A to FIG. 3C as each of the transistor MN2 and the transistor MN4 in FIG. 1, the potential of the node N1 or the node N2 in a floating state can be retained for a long time. In other words, a change in the potential of the node N1 or the node N2 can be prevented.

FIG. 3A is a schematic plan view of the transistor ML. Moreover, FIG. 3B is a schematic cross-sectional view corresponding to a portion along the dashed-dotted line A1-A2 illustrated in FIG. 3A, and is also a schematic cross-sectional view of the transistor ML. Furthermore, FIG. 3C is a schematic cross-sectional view corresponding to a portion along the dashed-dotted line A3-A4 illustrated in FIG. 3A, and is also a schematic cross-sectional view of the transistor ML.

Note that in FIG. 3A to FIG. 3C, the direction of the dashed-dotted line A1-A2 is an X direction, and the direction of the dashed-dotted line A3-A4 is a Y direction. Moreover, a direction perpendicular to the X direction and the Y direction is a Z direction. The X direction and the Y direction can be directions perpendicular to each other. The definition of the X direction, the Y direction, and the Z direction applies to some of the following drawings and does not apply to other drawings. In the description of the schematic plan view in FIG. 3A and the like, in some cases, the right side, the left side, the upper side, and the lower side are referred to as a +X direction, a −X direction, a +Y direction, and a −Y direction, respectively. In the description of the schematic cross-sectional view in FIG. 3B and the like, in some cases, the right side, the left side, the upper side, and the lower side are referred to as the +X direction, the −X direction, a +Z direction, and a −Z direction, respectively. In the description of the schematic cross-sectional views such as FIG. 3C and the like, in some cases, the right side, the left side, the upper side, and the lower side are referred to as the-Y direction, the +Y direction, the +Z direction, and the −Z direction, respectively.

The transistor ML in FIG. 3A to FIG. 3C includes an insulating layer IS1 to an insulating layer IS3, an insulating layer IB1 to an insulating layer IB4, an insulating layer GI1, a conductive layer ME2a, a conductive layer ME2b, a conductive layer ME3, and the semiconductor layer SC1.

The insulating layer IS1 has a function of, for example, a base film above which the transistor ML is to be provided.

The insulating layer IB1 and the insulating layer IB2 each have a function of a barrier film that inhibits diffusion of impurities into the conductive layer or the semiconductor layer SC1 positioned above the insulating layer IB1 and the insulating layer IB2 from below the insulating layer IB1 and the insulating layer IB2, for example.

Examples of the impurities in the conductive layer include oxygen that reduces conductivity by oxidation. Moreover, examples of the impurities in the semiconductor layer include elements, atoms, molecules, and ions that increase a carrier in the semiconductor layer. In particular, in the transistor ML in FIG. 3A to FIG. 3C, the insulating layer IB1 and the insulating layer IB2 each preferably function as a barrier film that inhibits diffusion of impurities into the semiconductor layer SC1.

The insulating layer IB2, the insulating layer IS2, and the insulating layer IB3 each have a function of an insulating layer for forming the semiconductor layer SC1, for example. As illustrated in FIG. 3A to FIG. 3C, the insulating layer IB2, the insulating layer IS2, and the insulating layer IB3 have an opening KK1, and the transistor ML has a structure in which part of the semiconductor layer SC1 is included in the opening KK1. Specifically, in the insulating layer IB2, the insulating layer IS2, and the insulating layer IB3, the opening KK1 is provided so that the semiconductor layer SC1 includes a region in contact with the sidewalls of the insulating layer IB2, the insulating layer IS2, and the insulating layer IB3 corresponding to the side surface of the opening KK1 and the top surface of the insulating layer IB1 corresponding to a bottom portion of the opening KK1. Note that the transistor ML has a structure in which the semiconductor layer SC1 provided in the opening KK1 includes the channel formation region of the transistor ML. In FIG. 3B and FIG. 3C, the insulating layer IB2, the insulating layer IS2, and the insulating layer IB3 are collectively referred to as an insulating layer ISP.

Although the opening KK1 has a perfect circular shape in the schematic top view in FIG. 3A, for example, one embodiment of the present invention is not limited thereto. The shape of the opening KK1 may be, for example, a shape with a single closed curve as an edge (including an elliptical shape) or a polygon with rounded corners.

The side surface of the opening KK1 in the insulating layer IS2 and the insulating layer IB3, in which the semiconductor layer SC1 of the transistor ML is provided, is preferably substantially perpendicular (a taper angle of greater than or equal to 70° and less than or equal to 110°) to an X-Y plane. In particular, when the taper angle is closer to 90°, the opening area of the opening KK1 can be reduced and thus the area where the transistor ML is formed can be reduced.

The insulating layer IB3 also has a function of a barrier film that inhibits diffusion of impurities from the insulating layer IS2 below the insulating layer IB3 into the conductive layer ME2a and the conductive layer ME2b that are positioned above the insulating layer IB3, for example. In particular, in the transistor ML in FIG. 3A to FIG. 3C, the insulating layer IB3 preferably functions as a barrier film that inhibits diffusion of oxygen into the conductive layer ME2a and the conductive layer ME2b. When the insulating layer IB3 functions as a barrier film that inhibits diffusion of oxygen, oxidation of the conductive layer ME2a and the conductive layer ME2b can be prevented and a reduction in conductivity of the conductive layer ME2a and the conductive layer ME2b can be prevented.

The conductive layer ME2a has a function of one of the source and the drain of the transistor ML, for example. The conductive layer ME2b has a function of the other of the source and the drain of the transistor ML, for example. Note that, for example, the whole or part of the conductive layer ME2a and the conductive layer ME2b may be rephrased as an electrode, a terminal, a wiring, or the like.

The conductive layer ME2a and the conductive layer ME2b are each positioned above the insulating layer IB3. In particular, the conductive layer ME2a and the conductive layer ME2b are each divided into a pair of conductive layers by the opening KK1 in the schematic top view in FIG. 3A and the schematic cross-sectional view in FIG. 3B. Thus, in the transistor ML in FIG. 3A to FIG. 3C, the widths of the conductive layer ME2a and the conductive layer ME2b in the Y direction are preferably smaller than the width of the opening KK1 in the Y direction in the schematic top view in FIG. 3A. Note that in the schematic top view in FIG. 3A, for example, the opening KK1 is a perfect circle, and the width of the opening KK1 in the Y direction corresponds to the diameter of the perfect circle.

Note that in FIG. 3A to FIG. 3C, a conductor ME2a is provided as a wiring to extend in the-X direction, for example. A conductor ME2b is provided as a wiring to extend in the +X direction, for example.

As described above, the semiconductor layer SC1 includes the region in contact with the sidewalls of the insulating layer IS2 and the insulating layer IB3 corresponding to the side surface of the opening KK1 and the top surface of the insulating layer IB1 corresponding to the bottom portion of the opening KK1. Furthermore, the semiconductor layer SC1 includes regions in contact with the top surface of the conductive layer ME2a and the top surface of the conductive layer ME2b. As described above, the semiconductor layer SC1 includes the channel formation region of the transistor ML. Note that the channel length CHL of the channel formation region of the transistor ML depends on the area of the bottom portion of the opening KK1 and the depth of the opening KK1 (the length of the side surface of the opening KK1 or the thickness of the insulating layer ISP).

The insulating layer GI1 has a function of a gate insulating layer (sometimes referred to as a gate insulating film) of the transistor ML, for example. The insulating layer GI1 includes a region in contact with the top surface of the semiconductor layer SC1, the top surface of the conductor ME2a, and the top surface of the conductor ME2b.

In particular, the thickness of the insulating layer GI1 greatly contributes to the electrical characteristics of the transistor ML. In the case where the insulating layer GI1 is thick (the transistor ML includes a thick gate insulating layer), the transistor ML can have a gentle gradient of voltage between a gate (a conductor ME3) and the channel formation region in the semiconductor layer SC1, so that the transistor ML can have high resistance to a gate potential. Meanwhile, in the case where a transistor includes a thin gate insulating film, an electric field applied from a gate to a channel formation region in a semiconductor rapidly changes when a gate potential is changed, so that the transistor can have a high driving frequency.

Thus, when the thickness of the insulating layer GI1 serving as the gate insulating layer is determined for each of a plurality of the transistors ML, for example, the transistor having high resistance to the gate source voltage (or gate-drain voltage) and the transistor having a high driving frequency can be separately formed in a simplified manner.

The conductor ME3 has a function of the gate of the transistor ML, for example. The conductor ME3 includes a region overlapping with at least part of the semiconductor layer SC1 and in contact with the top surface of the insulating layer GI1.

Note that in FIG. 3A to FIG. 3C, the conductor ME3 is provided as a wiring to extend in the +Y direction and the −Y direction, for example.

The insulating layer IB4 has a function of a barrier film that inhibits diffusion of impurities from the insulating layer IS3 above the insulating layer IB4 into the conductive layer ME3 positioned below the insulating layer IB4, for example. In particular, in the transistor ML in FIG. 3A to FIG. 3C, the insulating layer IB4 preferably functions as a barrier film that inhibits diffusion of oxygen into the conductive layer ME3. When the insulating layer IB4 functions as a barrier film that inhibits diffusion of oxygen, oxidation of the conductive layer ME3 can be prevented and a reduction in conductivity of the conductive layer ME3 can be prevented.

The insulating layer IS3 has a function of a planarization film for eliminating unevenness formed by the formation of the transistor ML, for example. When the insulating layer IS3 is a planarization film, another circuit element can be easily provided above the transistor ML. This allows formation of a stacked-layer structure of the transistor ML and another circuit element with the insulating layer IS3 therebetween.

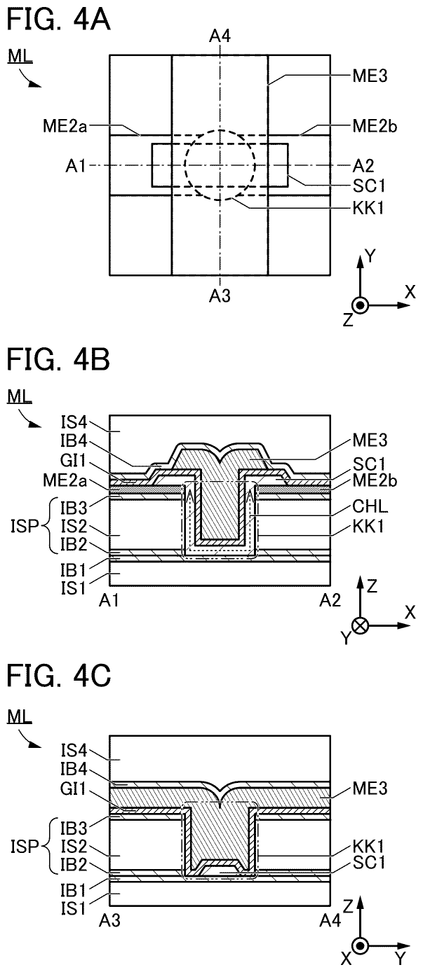

Although the transistor ML in FIG. 3A to FIG. 3C has a structure in which the opening KK1 includes the insulating layer IB4 and the insulating layer IS3, one embodiment of the present invention is not limited thereto. For example, the transistor ML may have a structure in which the opening KK1 is filled with the conductor ME3 as illustrated in FIG. 4A to FIG. 4C. Note that the structure illustrated in FIG. 4A to FIG. 4C corresponds to a modification example of the structure illustrated in FIG. 3A to FIG. 3C.

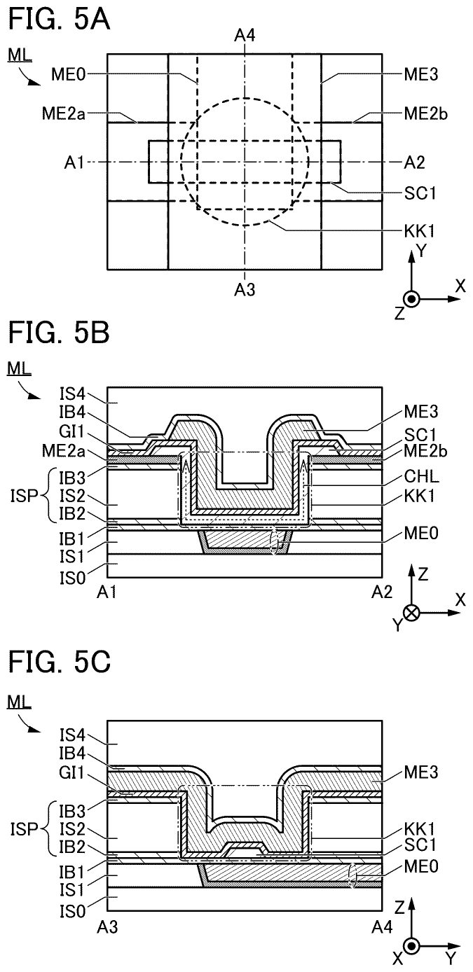

The transistor ML in FIG. 3A to FIG. 3C can be additionally provided with a conductive layer having a function of a back gate. The transistor ML illustrated in FIG. 5A to FIG. 5C has a structure obtained by providing the transistor ML in FIG. 3A to FIG. 3C with a conductive layer MEO functioning as a back gate. Note that the structure illustrated in FIG. 5A to FIG. 5C corresponds to a modification example of the structure illustrated in FIG. 3A to FIG. 3C.

In FIG. 5A to FIG. 5C, the insulating layer IS1 is positioned above an insulating layer ISO. The insulating layer IS1 is provided with an opening, and the conductive layer ME0 is embedded in the opening. Note that the insulating layer IS1 has the opening in a region overlapping with at least part of the semiconductor layer SC1, for example. In other words, the conductive layer ME0 includes a region overlapping with at least part of the semiconductor layer SC1.

In FIG. 5A to FIG. 5C, the conductive layer MEO has a function of a back gate; thus, the insulating layer IB1 also has a function of a gate insulating layer. The transistor ML in FIG. 5A to FIG. 5C includes the two gates; thus, in some cases, the insulating layer GI1 is referred to as a first gate insulating layer and the insulating layer IB1 is referred to as a second gate insulating layer (back gate insulating layer).

Note that in FIG. 5A to FIG. 5C, a conductor ME0 is provided as a wiring to extend in the +Y direction, for example.

Although the example in which the transistor ML in FIG. 3A to FIG. 3C is used as each of the transistor MN2 and the transistor MN4 is described above, a transistor having another structure may be used as each of the transistor MN2 and the transistor MN4 depending on the case.

### Structure Example 2 of Transistor

In the case where the circuit MDV in FIG. 1 is desired to be driven at higher speed, a transistor that has a high on-state current or can be driven at a high frequency is desired to be used as the transistor included in the circuit MDV. Specifically, for example, a transistor that has a high on-state current or can be driven at a high frequency is preferably used as each of the transistor MN1, the transistor MN3, the transistor MN11, and the transistor MN12.

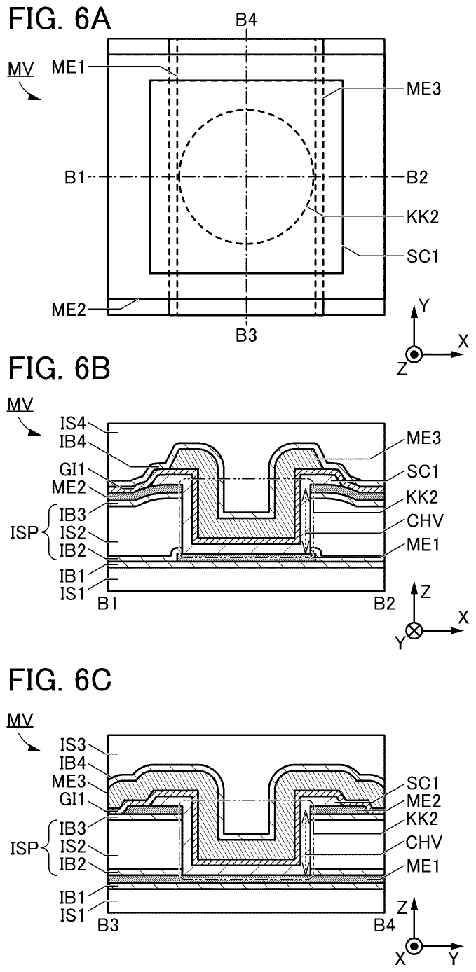

FIG. 6A to FIG. 6C shows an example of a transistor that has a high on-state current or can be driven at a high frequency. A transistor MV illustrated in FIG. 6A to FIG. 6C has a structure in which a source electrode and a drain electrode are positioned at different levels, and a current flowing through a semiconductor layer flows in the height direction. In other words, the channel length direction can be regarded as including a height (vertical) component. Thus, the transistor MV can also be referred to as a VFET (Vertical Field Effect Transistor), a vertical transistor, a vertical-channel transistor, a vertical-channel-type transistor, or the like. Moreover, the channel length of the transistor MV includes a component along the side surface of the opening, and thus is easily made shorter than the channel length in a conventional transistor structure.

Note that in the transistor MV in FIG. 6B and FIG. 6C, a channel length CHV of the channel formation region included in the semiconductor layer SC1 is illustrated. The channel length CHV can be regarded as the shortest distance between a portion in contact with a conductive layer ME1 and a portion in contact with a conductive layer ME2 in the semiconductor layer SC1 in the cross-sectional view.

The reduction in the channel length can increase the on-state current of the transistor; thus, when the transistor MV illustrated in FIG. 6A to FIG. 6C is used as each of the transistor MN1, the transistor MN3, the transistor MN11, and the transistor MN12 in FIG. 1, the on-state current of each of the transistor MN1, the transistor MN3, the transistor MN11, and the transistor MN12 is increased, so that the time taken for charging electric charge can be shortened. That is, the driving speed of the circuit MDV can be increased.

FIG. 6A is a schematic plan view of the transistor MV. Moreover, FIG. 6B is a schematic cross-sectional view corresponding to a portion along the dashed-dotted line B1-B2 illustrated in FIG. 6A, and is also a schematic cross-sectional view of the transistor MV. Furthermore, FIG. 6C is a schematic cross-sectional view corresponding to a portion along the dashed-dotted line B3-B4 illustrated in FIG. 6A, and is also a schematic cross-sectional view of the transistor ML.

Note that in FIG. 6A to FIG. 6C, the direction of the dashed-dotted line B1-B2 is an X direction, and the direction of the dashed-dotted line B3-B4 is a Y direction. Moreover, a direction perpendicular to the X direction and the Y direction is a Z direction. The X direction and the Y direction can be directions perpendicular to each other. The definition of the X direction, the Y direction, and the Z direction applies to some of the following drawings and does not apply to other drawings. In the description of the schematic plan view in FIG. 6A and the like, in some cases, the right side, the left side, the upper side, and the lower side are referred to as the +X direction, the-X direction, the +Y direction, and the −Y direction, respectively. In the description of the schematic cross-sectional view in FIG. 6B and the like, in some cases, the right side, the left side, the upper side, and the lower side are referred to as the +X direction, the −X direction, the +Z direction, and the −Z direction, respectively. In the description of the schematic cross-sectional views such as FIG. 6C and the like, in some cases, the right side, the left side, the upper side, and the lower side are referred to as the −Y direction, the +Y direction, the +Z direction, and the −Z direction, respectively.

The transistor MV in FIG. 6A to FIG. 6C includes the insulating layer IS1 to the insulating layer IS3, the insulating layer IB1 to the insulating layer IB4, the insulating layer GI1, the conductive layer ME1, the conductive layer ME2, the conductive layer ME3, and the semiconductor layer SC1.

The insulating layer IS1 has a function of, for example, a base film above which the transistor MV is to be provided.

The insulating layer IB1 has a function of a barrier film that inhibits diffusion of impurities into the conductive layer ME1 or the semiconductor layer SC1 positioned above the insulating layer IB1 from below the insulating layer IB1, for example.

Examples of the impurities in the conductive layer ME1 include oxygen that reduces conductivity by oxidation. When the insulating layer IB1 functions as a barrier film that inhibits diffusion of oxygen, oxidation of the conductive layer ME1 can be prevented and a reduction in conductivity of the conductive layer ME1 can be prevented.

Examples of the impurities in the semiconductor layer include elements, atoms, molecules, and ions that increase a carrier in the semiconductor layer. In particular, in the transistor MV in FIG. 6A to FIG. 6C, the insulating layer IB1 preferably functions as a barrier film that inhibits diffusion of impurities into the semiconductor layer SC1.

The conductive layer ME1 has a function of one of a source and a drain of the transistor MV, for example. The conductive layer ME1 is positioned above the insulating layer IB1. Note that in FIG. 6A to FIG. 6C, a conductor ME1 is provided as a wiring to extend in the +Y direction and the −Y direction, for example.

The insulating layer IB2 has a function of a barrier film that inhibits diffusion of oxygen from above the insulating layer IB2 into the conductive layer ME1 positioned below the insulating layer IB2, for example. When the insulating layer IB2 functions as a barrier film that inhibits diffusion of oxygen, the insulating layer IB2 can prevent, like the insulating layer IB1, oxidation of the conductive layer ME1 and a reduction in conductivity of the conductive layer ME1.

The insulating layer IS2 and the insulating layer IB3 each have a function of an insulating layer for forming the semiconductor layer SC1, for example. The insulating layer IS2 and the insulating layer IB3 each also have a function of an interlayer film that separates the source and the drain of the transistor MV from each other.

As illustrated in FIG. 6A to FIG. 6C, the insulating layer IS2, the insulating layer IB3, and the conductive layer ME2 have an opening KK2, and the transistor MV has a structure in which part of the semiconductor layer SC1 is included in the opening KK2. Specifically, in the insulating layer IS2, the insulating layer IB3, and the conductive layer ME2, the opening KK2 is provided so that the semiconductor layer SC1 includes a region in contact with the sidewalls of the insulating layer IS2, the insulating layer IB3, and the conductive layer ME2 corresponding to the side surface of the opening KK2 and the top surface of the conductive layer ME1 corresponding to the bottom portion of the opening KK1. Note that the transistor MV has a structure in which the semiconductor layer SC1 provided in the opening KK2 includes the channel formation region of the transistor MV.

For the shape of the opening KK2 illustrated in the schematic top view in FIG. 6A, the description of the opening KK1 can be referred to. For the taper angle of the opening KK2, the description of the opening KK1 can be referred to.

The insulating layer IB3 also has a function of a barrier film that inhibits diffusion of impurities from the insulating layer IS2 below the insulating layer IB3 into the conductive layer ME2 positioned above an insulating layer 3, for example. In particular, in the transistor MV in FIG. 6A to FIG. 6C, the insulating layer IB3 preferably functions as a barrier film that inhibits diffusion of oxygen into the conductive layer ME2. When the insulating layer IB3 functions as a barrier film that inhibits diffusion of oxygen, oxidation of the conductive layer ME2 can be prevented and a reduction in conductivity of the conductive layer ME2 can be prevented.

The conductive layer ME2 has a function of the other of the source and the drain of the transistor MV, for example. Note that, for example, the whole or part of the conductive layer ME2 may be rephrased as an electrode, a terminal, a wiring, or the like.

The conductive layer ME2 is positioned on the top surface of the insulating layer IB3. In particular, the conductive layer ME2 is positioned also on an upper portion of the insulating layer IB3 on an edge of the opening KK2 in the schematic top view in FIG. 6A and the schematic cross-sectional view in FIG. 6B. Thus, in the transistor MV in FIG. 6A to FIG. 6C, the width of the conductive layer ME2 in the Y direction is preferably larger than the width of the opening KK2 in the Y direction in the schematic top view in FIG. 6A. Note that in the schematic top view in FIG. 6A, for example, the opening KK2 is a perfect circle, and the width of the opening KK2 in the Y direction corresponds to the diameter of the perfect circle.

Note that in FIG. 6A to FIG. 6C, a conductor ME2 is provided as a wiring to extend in the +X direction and the −X direction, for example.

As described above, the semiconductor layer SC1 includes the region in contact with the sidewalls of the insulating layer IS2, the insulating layer IB3, and the conductive layer ME2 corresponding to the side surface of the opening KK2 and the top surface of the conductive layer ME1 corresponding to a bottom portion of the opening KK2. Furthermore, the semiconductor layer SC1 includes a region in contact with the top surface of the conductive layer ME2. As described above, the semiconductor layer SC1 includes the channel formation region of the transistor MV. Note that the channel length CHV of the channel formation region of the transistor MV depends on the depth of the opening KK2 (the length of the side surface of the opening KK2 or the thickness of the insulating layer ISP).

The insulating layer GI1 has a function of a gate insulating layer (sometimes referred to as a gate insulating film) of the transistor MV, for example. The insulating layer GII includes a region in contact with the top surface of the semiconductor layer SC1 and the top surface of the conductor ME2.

In particular, the thickness of the insulating layer GI1 greatly contributes to the electrical characteristics of the transistor MV. For example, as in the description of the transistor ML in FIG. 3A to FIG. 3C, by increasing the thickness of the insulating layer GI1 of the transistor MV, the resistance to the gate-source voltage (or gate drain voltage) can be increased. Meanwhile, in the case where the thickness of the insulating layer GI1 of the transistor MV is reduced, the transistor MV can be driven at a high frequency. That is, when the thickness of the insulating layer GII serving as the gate insulating layer is determined for each of the plurality of transistors ML, the transistor having high resistance to the gate-source voltage (or gate-drain voltage) and the transistor having a high driving frequency can be separately formed in a simplified manner.

The conductor ME3 has a function of a gate of the transistor MV, for example. The conductor ME3 includes a region overlapping with at least part of the semiconductor layer SC1 and in contact with the top surface of the insulating layer GI1.

Note that in FIG. 6A to FIG. 6C, the conductor ME3 is provided as a wiring to extend in the +Y direction and the −Y direction, for example.

As in the description of the transistor ML in FIG. 3A to FIG. 3C, the insulating layer IB4 has a function of a barrier film that inhibits diffusion of impurities from the insulating layer IS3 above the insulating layer IB4 into the conductive layer ME3 positioned below the insulating layer IB4, for example.

As in the description of the transistor ML in FIG. 3A to FIG. 3C, the insulating layer IS3 has a function of a planarization film for eliminating unevenness formed by the formation of the transistor MV, for example.

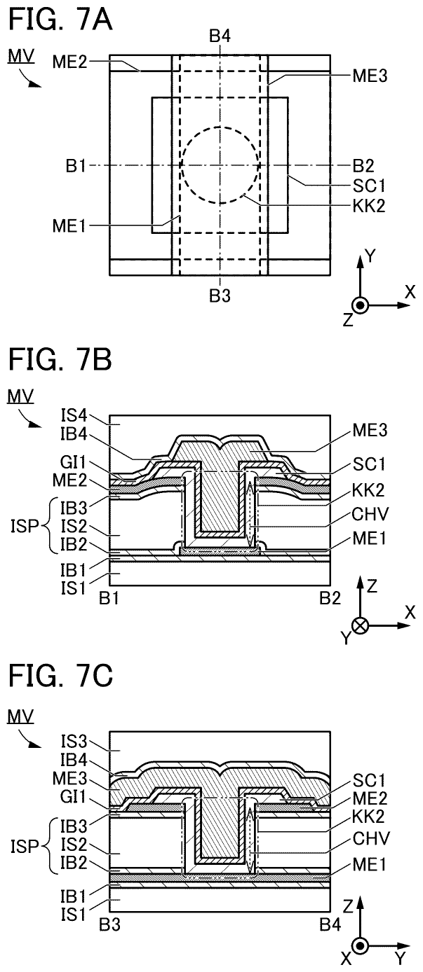

Although the transistor MV in FIG. 6A to FIG. 6C has a structure in which the opening KK2 includes the insulating layer IB4 and the insulating layer IS3, one embodiment of the present invention is not limited thereto. For example, the transistor MV may have a structure in which the opening KK2 is filled with the conductor ME3 as illustrated in FIG. 7A to FIG. 7C. Note that the structure illustrated in FIG. 7A to FIG. 7C corresponds to a modification example of the structure in FIG. 3A to FIG. 3C.

As illustrated in FIG. 6A to FIG. 6C, when the channel formation region of the transistor is provided along the side surface of the opening in the insulator functioning as an interlayer film, the transistor formation area can be smaller than that in the case where the channel formation region of the transistor is provided along the X-Y plane. In the transistor MV, the source electrode, the semiconductor, and the drain electrode can be provided to overlap with each other; thus, the area occupied by the transistor can be significantly smaller than the area occupied by what is called a planar transistor in which a semiconductor is provided in a planar shape. Thus, when a circuit is formed using the transistor MV, the area of the circuit can be small. This results in a reduction in size of a semiconductor device or a display apparatus including the circuit.

The channel length CHV of the transistor MV corresponds to the length in the height direction of the opening KK2 in the insulating layer IS2 in the cross-sectional view. In other words, the channel length CHV is determined in accordance with the thickness of the insulating layer IS2. In the case where the opening KK2 has a tapered shape, the channel length CHV is also determined by the angle formed between the opening KK2 and the X-Y plane (or the formation surface of the conductive layer ME1). Thus, the channel length CHV can have a value smaller than that of the resolution limit of a light-exposure apparatus, for example, which enables a transistor having a minute size. Specifically, it is possible to obtain a transistor with an extremely short channel length that could not be obtained with use of a conventional light-exposure apparatus for mass production of flat panel displays (the minimum line width: approximately 2 μm or approximately 1.5 μm, for example). Moreover, it is also possible to obtain a transistor with a channel length less than 10 nm without using an extremely expensive light-exposure apparatus used in the latest LSI technology.

The channel length CHV can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 um, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length CHV can be greater than or equal to 100 nm and less than or equal to 1 μm.

By shortening the channel length CHV, the on-state current of the transistor MV can be increased. Thus, for example, by using the transistor MV in a driver circuit of a large-sized display apparatus or a driver circuit of a high-definition display apparatus, power consumption of these driver circuits can be reduced. Moreover, when the transistor MV is used in a large-sized display apparatus or a high-definition display apparatus, signal delay in wirings can be reduced and display unevenness can be inhibited even when the number of wirings is increased. Furthermore, since the area occupied by the circuit can be reduced, the bezel of the display apparatus can be narrowed.

The transistor MV that is a VFET illustrated in FIG. 6A to FIG. 6C is different from the transistor ML that is a VLFET illustrated in FIG. 3A to FIG. 3C in that the conductive layer ME1 is in the bottom portion of the opening KK2 in the insulating layer IS2. In addition, the transistor MV is different from the transistor ML in that, for example, the width of the conductor ME2 in the Y direction is larger than the width of the opening KK2 in the Y direction in the schematic top view of the transistor MV, whereas the widths of the conductor ME2a and the conductor ME2b in the Y direction are smaller than the width of the opening KK 1 in the Y direction in the schematic top view of the transistor ML. Thus, it can be said that the transistor ML that is a VLFET and the transistor MV that is a VFET are easily manufactured separately. Note that a method for simultaneously manufacturing a VLFET and a VFET will be described in detail in Embodiment 4.

Although the example in which the transistor MV in FIG. 6A to FIG. 6C is used as each of the transistor MN1, the transistor MN3, the transistor MN11, and the transistor MN12 is described above, a transistor having another structure may be used as each of the transistor MN2 and the transistor MN4 depending on the case.

### Structure Example 1 of Circuit BB

Next, structure examples of the circuit BB included in each of the circuit structures in FIG. 1, FIG. 2A, and FIG. 2B are described.

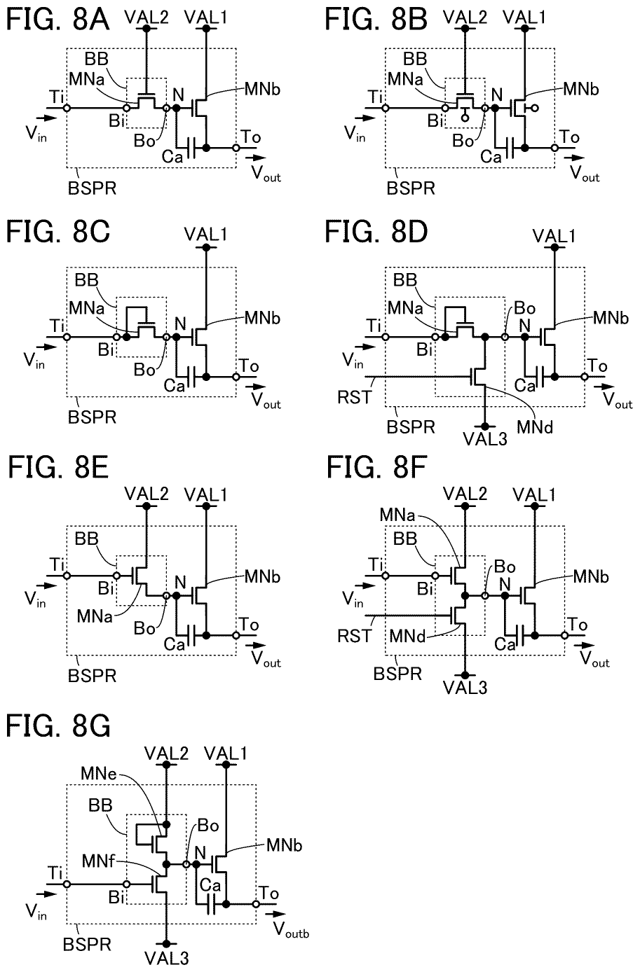

FIG. 8A to FIG. 8G show structure examples of the circuit BB. A transistor MNb illustrated in FIG. 8A to FIG. 8G corresponds to the transistor MN11 in FIG. 1, FIG. 2A, and FIG. 2B, and the capacitor Ca illustrated in FIG. 8A to FIG. 8G corresponds to the capacitor C1 in FIG. 1 and FIG. 2A. A wiring VAL1 illustrated in FIG. 8A to FIG. 8G is a wiring electrically connected to the terminal CLK1 in FIG. 1, FIG. 2A, and FIG. 2B.

The circuit BSPR illustrated in FIG. 8A includes a transistor MNa in the circuit BB. As the transistor MNa, a transistor that can be used as the transistor MNb (the transistor MN11) can be used, for example.

A first terminal of the transistor MNa is electrically connected to the terminal Bi, and a second terminal of the transistor MNa is electrically connected to the terminal Bo. A gate of the transistor MNa is electrically connected to a wiring VAL2.

Like the wiring VAL1, the wiring VAL2 functions as a wiring for supplying a fixed potential or a variable potential, for example. Examples of the fixed potential include a high-level potential, a low-level potential, the ground potential, and a negative potential. Examples of the variable potential include a pulse signal and a clock signal.

The wiring VAL2 may be electrically connected to the wiring VAL1. In other words, the wiring VAL1 and the wiring VAL2 may be the same wiring.

Here, an operation example of the circuit BSPR in FIG. 8A is described. The high-level potential V_{High} is assumed to be input to the input terminal Ti of the circuit BSPR, for example. That is, Vᵢₙ=V_{High}. In addition, the high-level potential V_{High} is supplied to the gate of the transistor MNa from the wiring VAL2. The potential of the node N is the low-level potential V_{Low}.

The transistor MNa is normally off and the threshold voltage of the transistor MNa is set to V_{th_MNa}. The threshold voltage V_{th_MNa} is set to satisfy V_{High}-V_{Low}>V_{th_MNa}.

Since the gate-source voltage (the gate-second terminal voltage at this timing) of the transistor MNa is V_{High}−V_{Low}, the transistor MNa is in an on state. Consequently, electric charge is accumulated in the node N from the terminal Ti through the source and the drain of the transistor MNa, so that the potential of the node N increases until the transistor MNa is turned off. Specifically, the transistor MNa is turned off when the gate-source voltage of the transistor MNa decreases to V_{th_MNa}, thus, the potential of the node N (the second terminal of the transistor MNa) at this time is V_{High}−V_{th_MNa}. Note that V_{High}−V_{th_MNa} corresponds to V_{Mid} described in FIG. 2A.

Like the transistor MN11 illustrated in FIG. 2A, the transistor MNa may be a transistor having a multi-gate structure including gates over and under a channel. For example, the transistor MNa illustrated in FIG. 8B is an n-channel transistor having a multi-gate structure including gates over and under a channel; the transistor MNa includes a second gate in addition to a first gate.

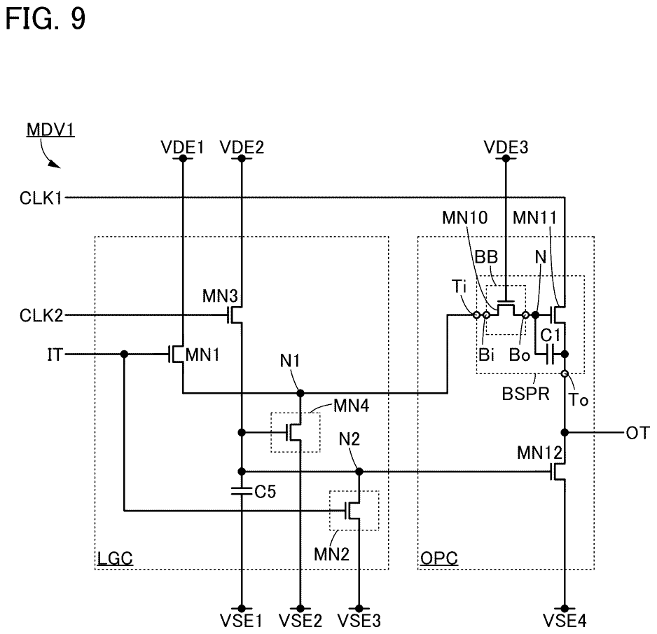

A structure example in which the circuit BB in FIG. 8A is used as the circuit BB in the circuit MDV in FIG. 1 is described. FIG. 9 shows the structure example. A circuit MDV1 in FIG. 9 has a circuit structure in which the circuit BSPR in FIG. 8A is used as the circuit BSPR in the circuit MDV in FIG. 1. In this case, the transistor MV in FIG. 6A to FIG. 6C or the transistor MV in FIG. 7A to FIG. 7C is preferably used as a transistor MN10 included in the circuit BB. Depending on the case, the transistor ML in FIG. 3A to FIG. 3C, the transistor ML in FIG. 4A to FIG. 4C, the transistor ML in FIG. 5A to FIG. 5C, or a transistor having another structure may be used as the transistor MN10.

### Structure Example 2 of Circuit BB

The circuit BB of the circuit BSPR illustrated in FIG. 8C is a modification example of the circuit BB of the circuit BSPR in FIG. 8A and is different from the circuit BB of the circuit BSPR in FIG. 8A in that the gate of the transistor MNa is electrically connected not to the wiring VAL2 but to the first terminal of the transistor MNa.

In FIG. 8C, since the first terminal of the transistor MNa and the gate of the transistor MNa are electrically connected to each other, the transistor MNa can be said to be diode-connected. Hence, for example, when the high-level potential V_{High} is input to the terminal Ti of the circuit BSPR, the potentials of the first terminal and the gate of the transistor MNa each become the high-level potential V_{High}; thus, the potential of the node N (the second terminal of the transistor MNa) becomes V_{High}−V_{th_MNa}.

When the potential V_{High}−V_{th_MNa} of the node N (the second terminal of the transistor MNa) is to be decreased, that is, when the electric charge accumulated in the node N is to be released, the circuit BB of the circuit BSPR in FIG. 8C should be further modified.

The circuit BB of the circuit BSPR illustrated in FIG. 8D is a modification example of the circuit BB of the circuit BSPR in FIG. 8C and is different from the circuit BB of the circuit BSPR in FIG. 8C in that electric charge accumulated in the node N can be released.

In the circuit BSPR in FIG. 8D, the circuit BB includes a transistor MNd in addition to the transistor MNa.

As the transistor MNd, a transistor that can be used as the transistor MNa or the transistor MNb can be used, for example.

A first terminal of the transistor MNd is electrically connected to the second terminal of the transistor MNa and the terminal Bo, a second terminal of the transistor MNd is electrically connected to a wiring VAL3, and a gate of the transistor MNd is electrically connected to a wiring RST.

Like the wiring VAL1 or the wiring VAL2, the wiring VAL3 functions as a wiring for supplying a fixed potential, for example. An example of the fixed potential is a low-level potential. Other examples of the fixed potential include a ground potential and a negative potential. Depending on the circumstances, the wiring VAL3 may function as a wiring for supplying a variable potential.

The wiring RST functions as a wiring for transmitting a signal for selecting whether the electric charge accumulated in the node N is released or not, for example. Specifically, for example, when electric charge in the node N is not released, the wiring RST is supplied with the low-level potential V_{Low} as a signal to turn off the transistor MNd. For example, when the electric charge accumulated in the node N is released, the wiring RST is supplied with the high-level potential V_{High} as a signal to turn on the transistor MNd.

When the potential of the node N is to be increased (when the potential of the node N is to be V_{High}−V_{th_MNa}), for example, the low-level potential V_{Low} is supplied to the wiring RST to turn off the transistor MNd and then the high-level potential V_{High} is supplied to the terminal Ti. When the potential of the node N is to be decreased (when the potential of the node N is to be V_{Low}), for example, the low-level potential V_{Low} is supplied to the terminal Ti to turn off the transistor MNa and then the high-level potential V_{High} is supplied to the wiring RST to turn on the transistor MNd. Here, when the potential supplied by the wiring VAL3 is the low-level potential V_{Low}, the electric charge in the node N flows to the wiring VAL3, whereby the potential of the node N becomes V_{Low}.

### Structure Example 3 of Circuit BB

The circuit BB of the circuit BSPR illustrated in FIG. 8E is a modification example of the circuit BB of the circuit BSPR in FIG. 8A and is different from the circuit BB of the circuit BSPR in FIG. 8A in that the gate of the transistor MNa is electrically connected not to the wiring VAL2 but to the terminal Bi and that the first terminal of the transistor MNa is electrically connected not to the terminal Bi but to the wiring VAL2.

An operation example of the circuit BSPR in FIG. 8E is described. The high-level potential V_{High} is assumed to be input to the input terminal Ti of the circuit BSPR, for example. In addition, the high-level potential V_{High} is supplied to the first terminal of the transistor MNa from the wiring VAL2. The potential of the node N is the low-level potential V_{Low}.

Since the gate-source voltage (the gate-second terminal voltage at this timing) of the transistor MNa is V_{High}−V_{Low}, the transistor MNa is in an on state. Consequently, electric charge is accumulated in the node N because of current flowing from the wiring VAL2 through the transistor MNa, so that the potential of the node N increases until the transistor MNa is turned off. Specifically, the transistor MNa is turned off when the gate-source voltage of the transistor MNa decreases to V_{th_MNa}, thus, the potential of the node N (the second terminal of the transistor MNa) at this time is V_{High}−V_{th_MNa}. Note that V_{High}−V_{th_MNa} corresponds to V_{Mid} described in FIG. 2A.

When the potential V_{High}−V_{th_MNa} of the node N (the second terminal of the transistor MNa) is to be decreased, that is, when the electric charge accumulated in the node N is to be released, the circuit BB of the circuit BSPR in FIG. 8E should be further modified.

The circuit BB of the circuit BSPR illustrated in FIG. 8F is a modification example of the circuit BB of the circuit BSPR in FIG. 8E and is different from the circuit BB of the circuit BSPR in FIG. 8E in that electric charge accumulated in the node N can be released.

In the circuit BSPR in FIG. 8F, the circuit BB includes the transistor MNd in addition to the transistor MNa.

The first terminal of the transistor MNd is electrically connected to the second terminal of the transistor MNa and the terminal Bo, the second terminal of the transistor MNd is electrically connected to the wiring VAL3, and the gate of the transistor MNd is electrically connected to the wiring RST.

For the transistor MNd, the wiring VAL3, and the wiring RST, the description of the transistor MNd, the wiring VAL3, and the wiring RST in the circuit BSPR in FIG. 8D can be referred to.

When the potential of the node N is to be increased (when the potential of the node N is to be V_{High}-V_{th_MNa}), for example, the low-level potential V_{Low} is supplied to the wiring RST to turn off the transistor MNd and then the high-level potential V_{High} is supplied to the terminal Ti. When the potential of the node N is to be decreased (when the potential of the node N is to be V_{Low}), for example, the low-level potential V_{Low} is supplied to the terminal Ti to turn off the transistor MNa and then the high-level potential V_{High} is supplied to the wiring RST to turn on the transistor MNd. Here, when the potential supplied by the wiring VAL3 is the low-level potential V_{Low}, the electric charge in the node N flows to the wiring VAL3, whereby the potential of the node N becomes V_{Low}.

### Structure Example 4 of Circuit BB

The circuit BSPR illustrated in FIG. 8G includes an inverter circuit in the circuit BB. Specifically, the circuit BB includes a transistor MNe and a transistor MNf, and the transistor MNe and the transistor MNf form the inverter circuit.

As each of the transistor MNe and the transistor MNf, a transistor that can be used as the transistor MNb can be used, for example.

A first terminal of the transistor MNe is electrically connected to a gate of the transistor MNe and the wiring VAL2, and a second terminal of the transistor MNe is electrically connected to the terminal Bo and a first terminal of the transistor MNf. A second terminal of the transistor MNf is electrically connected to the wiring VAL3, and a gate of the transistor MNf is electrically connected to the terminal Bi.

For the wiring VAL2, the description of the wiring VAL2 of the circuit BSPR in FIG. 8A can be referred to. For the wiring VAL3, the description of the wiring VAL3 of the circuit BSPR in FIG. 8D can be referred to.

Note that in FIG. 8G, a potential output from the terminal To is not Vₒᵤₜ but V_{outb}.

Here, an operation example of the circuit BSPR in FIG. 8G is described. The high-level potential V_{High} is assumed to be input to the gate and the first terminal of the transistor MNe from the wiring VAL2, for example. In addition, the low-level potential V_{Low} is assumed to be supplied to the second terminal of the transistor MNf from the wiring VAL3. The potential of the node N is the low-level potential V_{Low}.

The transistor MNe and the transistor MNf are normally off; in particular, the threshold voltage of the transistor MNe is V_{th_MNe}, and V_{th_MNe} is the voltage satisfying the formula: V_{High} V_{Low}>V_{th_MNe}.

First, a case is considered where the low-level potential V_{Low} is input to the terminal Ti. In this case, V_{Low} is input to the gate of the transistor MNf, so that the transistor MNf is turned off. The gate source voltage (the gate second terminal voltage at this timing) of the transistor MNe is V_{High}-V_{Low}, whereby the transistor MNe is turned on. Consequently, electric charge is accumulated in the node N because of current flowing from the wiring VAL2 through the transistor MNe, so that the potential of the node N increases until the transistor MNe is turned off. Specifically, the transistor MNe is turned off when the gate-source voltage of the transistor MNe decreases to V_{th_MNe}; thus, the potential of the node N (the second terminal of the transistor MNe) at this time is V_{High}−V_{th_MNe}. Note that V_{High}−V_{th_MNe} corresponds to V_{Mid} described in FIG. 2A.

Then, a case is considered where the high-level potential V_{High} is input to the terminal Ti. In this case, V_{High} is input to the gate of the transistor MNf, so that the transistor MNf is turned on. Since the transistor MNf is turned on, current flows from the node N to the wiring VAL3 through the transistor MNf, and electric charge is released, whereby the potential of the node N ideally becomes the low-level potential V_{Low} supplied by the wiring VAL3. Note that a reduction in the potential of the second terminal of the transistor MNe (the node N) turns on the transistor MNe, so that the potential of the node N actually becomes higher than or equal to the low-level potential V_{Low} and lower than or equal to the high-level potential V_{High}.

### Application Example to Display Apparatus

Next, a driver circuit including the retention circuit that is the semiconductor device of one embodiment of the present invention and a display apparatus including the driver circuit are described.

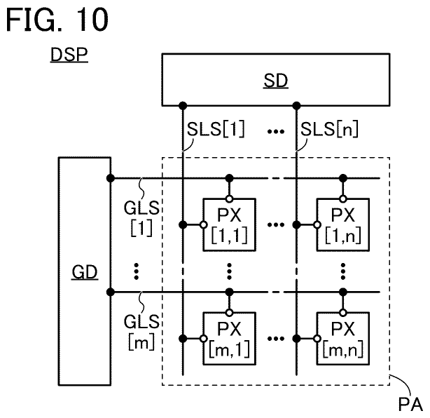

First, the display apparatus is described. FIG. 10 shows a structure example of the display apparatus including the driver circuit including the retention circuit described above. As an example, a display apparatus DSP illustrated in FIG. 10 includes a driver circuit GD, a driver circuit SD, and a pixel array PA.

Note that in FIG. 10, the driver circuit GD, the driver circuit SD, the pixel array PA, a wiring GLS[1], a wiring GLS[m], a wiring SLS[1], a wiring SLS[n], a pixel circuit PX[1,1], a pixel circuit PX[m, 1], a pixel circuit PX[1,n], and a pixel circuit PX[m, n] are selectively illustrated (m is an integer greater than or equal to 1 and n is an integer greater than or equal to 1).

The pixel array PA includes a plurality of pixel circuits PX, for example. The pixel circuits PX are arranged in a matrix of m rows and n columns in the pixel array PA.

Note that the symbol accompanying the reference characters of the pixel circuit PX in FIG. 10 represents an address in the pixel circuit. For example, the symbol in the reference characters of the pixel circuit PX[1,1] means that the pixel circuit PX is placed in the first row and the first column in the pixel array PA. For another example, the symbol in the reference characters of the pixel circuit PX[m, 1] means that the pixel circuit PX is placed in the m-th row and the first column in the pixel array PA. For another example, the symbol in the reference characters of the pixel circuit PX[1,n] means that the pixel circuit PX is placed in the first row and the n-th column in the pixel array PA. For another example, the symbol in the reference characters of the pixel circuit PX[m, n] means that the pixel circuit PX is placed in the m-th row and the n-th column in the pixel array PA.

The pixel circuit PX placed in the i-th row and the j-th column (i is an integer greater than or equal to 1 and less than or equal to m, and j is an integer greater than or equal to 1 and less than or equal to n) in the pixel array PA is referred to as a pixel circuit PX[i,j] (not illustrated). The pixel circuit PX[i,j] is electrically connected to a wiring GLS[i] (not illustrated), for example. The pixel circuit PX[i,j] is electrically connected to a wiring SLS[j] (not illustrated), for example.

The driver circuit GD is electrically connected to the wiring GLS[1] to the wiring GLS[m], for example. The driver circuit SD is electrically connected to the wiring SLS[1] to the wiring SLS[n], for example.

The wiring GLS[1] to the wiring GLS[m] can each be a wiring extending in the row direction in the pixel array PA, for example. Furthermore, [x] added to the wiring GLS represents the number of the row in which the wiring extends. For example, the reference of the wiring GLS[1] represents a wiring extending in the first row in the pixel array PA. For another example, the reference of the wiring GLS[m] represents a wiring extending in the m-th row in the pixel array PA.

The wiring SLS[1] to the wiring SLS[n] can each be a wiring extending in the column direction in the pixel array PA, for example. Furthermore, [y] added to the wiring SLS represents the number of the column in which the wiring extends. For example, the reference of the wiring SLS[1] represents a wiring extending in the first column in the pixel array PA. For another example, the reference of the wiring SLS[n] represents a wiring extending in the n-th column in the pixel array PA.

Note that the wiring GLS[i] may be one wiring or a wiring group including a large number of wirings. Similarly, the wiring SLS[j] may be one wiring or a wiring group including a large number of wirings.

The pixel circuit PX can be a pixel circuit including, for example, one or more selected from a liquid crystal display device, a light-emitting device including an organic EL material, a light-emitting device including an inorganic EL material, and a light-emitting device including a light-emitting diode (e.g., a micro LED). Note that in the description in this embodiment, the pixel circuit PX in the pixel array PA includes a light-emitting device including an organic EL material. The luminance of light emitted from a light-emitting device capable of high luminance light emission can be, for example, higher than or equal to 500 cd/m², preferably higher than or equal to 1000 cd/m² and lower than or equal to 10000 cd/m², further preferably higher than or equal to 2000 cd/m² and lower than or equal to 5000 cd/m².

The driver circuit GD has a function of selecting the pixel circuit PX to which image data is to be transmitted in the pixel array PA of the display apparatus DSP, for example. Accordingly, the driver circuit GD can be referred to as a gate driver circuit or the like.

The wiring GLS, which electrically connects the driver circuit GD and the pixel circuit PX, functions as a wiring for transmitting a selection signal. Note that the wiring GLS may function as, for example, a wiring for supplying a fixed potential, not a wiring for transmitting a selection signal.

The driver circuit SD has a function of transmitting image data to the pixel circuit PX in the pixel array PA of the display apparatus DSP, for example. Accordingly, the driver circuit SD can be referred to as a source driver circuit or the like.

The wiring SLS, which electrically connects the driver circuit SD and the pixel circuit PX as described above, functions as a wiring for transmitting image data as a signal, for example. Note that the wiring SLS may function as, for example, a wiring for supplying a fixed potential, not a wiring for transmitting image data.

Note that in the display apparatus DSP illustrated in FIG. 10, a wiring other than the wiring GLS[1] to the wiring GLS[m] and the wiring SLS[1] to the wiring SLS[n] may extend. For example, a wiring for supplying a fixed potential to the pixel circuit PX may extend in the display apparatus DSP.

### Structure Example of Driver Circuit GD

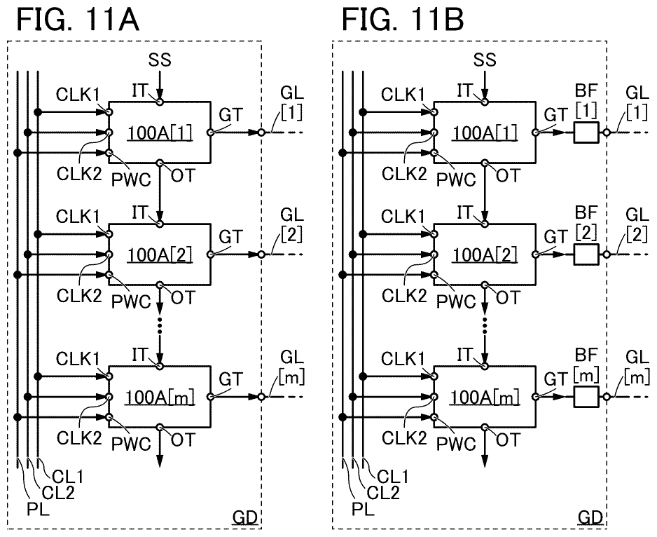

FIG. 11A shows a structure example of the driver circuit GD of one embodiment of the present invention which can be used for the display apparatus DSP in FIG. 10. The driver circuit GD illustrated in FIG. 11A includes a circuit 100A[1] to a circuit 100A[m], for example.

Each of the circuit 100A[1] to the circuit 100A[m] includes, for example, the terminal IT, the terminal OT, the terminal CLK1, the terminal CLK2, a terminal PWC, and a terminal GT.

In each of the circuit 100A[1] to the circuit 100A[m], for example, the terminal CLK1 is electrically connected to a wiring CL1, the terminal CLK2 is electrically connected to a wiring CL2, and the terminal PWC is electrically connected to a wiring PL.

Each of the wiring CL1, the wiring CL2, and the wiring PL functions as, for example, a wiring for supplying a variable potential (referred to as a pulse voltage in some cases in this specification), such as a clock signal. Note that one or more selected from the wiring CL1, the wiring CL2, and the wiring PL may be a wiring for supplying a fixed potential, not the variable potential.

The terminal OT of the circuit 100A[k] (k is an integer greater than or equal to 1 and less than or equal to m-1) is electrically connected to the terminal IT of the circuit 100A[k+1], for example.

The terminal GT of the circuit 100A[i] is electrically connected to a wiring GL[i], for example. Note that the wiring GL[i] is a wiring corresponding to the wiring GLS[i] illustrated in FIG. 10.

Each of the circuit 100A[1] to the circuit 100A[m] has functions of, for example, retaining data input to the terminal IT and outputting the retained data to one or both of the terminal OT and the terminal GT.

For example, the circuit 100A[i] has a function of outputting data retained in the circuit 100A[i] to the terminal OT when the high-level potential is input to the terminal CLK1. For another example, the circuit 100A[i] has a function of outputting data retained in the circuit 100A[i] to the terminal GT when the high-level potential is input to the terminal PWC. For another example, the circuit 100A[i] has a function of resetting data retained in the circuit 100A[i] when the high-level potential is input to the terminal CLK2. The circuit 100A[i] is preferably configured to retain new data that is input to the terminal IT of the circuit 100A[i] after the data retained in the circuit 100A[i] is reset.

As described above, in the circuit 100A[1] to the circuit 100A[m], data is input to the terminal IT of the circuit 100A[1] and then a variable potential is input to the terminal CLK1 and the terminal CLK2 at an appropriate timing, whereby the data can be transmitted to the circuit 100A[2] and the subsequent circuits. Furthermore, data is input to the terminal IT of the circuit 100A[1] and then a variable potential is input to the terminal PWC at an appropriate timing, whereby data retained in the circuit 100A[1] to the circuit 100A[m] can be output from the terminals GT of the circuit 100A[1] to the circuit 100A[m]. Accordingly, the structure of the circuit 100A[1] to the circuit 100A[m] can be referred to as a shift register circuit in this specification and the like.

The above-described data can be, for example, a selection signal for selecting the pixel circuit PX to which image data is to be written in the pixel array PA. Note that in FIG. 11A, the selection signal is illustrated as a signal SS.

Note that although the circuit 100A[m] in the driver circuit GD in FIG. 11A includes the terminal OT, the circuit 100A[m] is not necessarily provided with the terminal OT because the circuit 100A[1] to the circuit 100A[m] form a shift register circuit.

The structure of the driver circuit GD applicable to the display apparatus DSP in FIG. 10 is not limited to the structure in FIG. 11A. For example, the driver circuit GD illustrated in FIG. 11B may be employed as the driver circuit GD applicable to the display apparatus DSP in FIG. 10. The driver circuit GD in FIG. 11B is different from the driver circuit GD in FIG. 11A in including a circuit BF[1] to a circuit BF[m].

In the driver circuit GD in FIG. 11B, input terminals of the circuit BF[1] to the circuit BF[m] are electrically connected to the respective terminals GT of the circuit 100A[1] to the circuit 100A[m], and output terminals of the circuit BF[1] to the circuit BF[m] are electrically connected to the wiring GL[1] to the wiring GL[m], respectively.

Each of the circuit BF[1] to the circuit BF[m] can include an amplifier circuit such as a buffer circuit, an inverter circuit, or a latch circuit, for example. Specifically, each of the circuit BF[1] to the circuit BF[m] can have a function of referring to and amplifying a potential of the terminal GT and outputting the amplified potential to the wiring GL.

Note that a wiring other than the wiring CL1, the wiring CL2, and the wiring PL may extend in the driver circuits GD illustrated in FIG. 11A and FIG. 11B. For example, a wiring for supplying a fixed potential to drive the circuit 100A[1] to the circuit 100A[m] may extend.

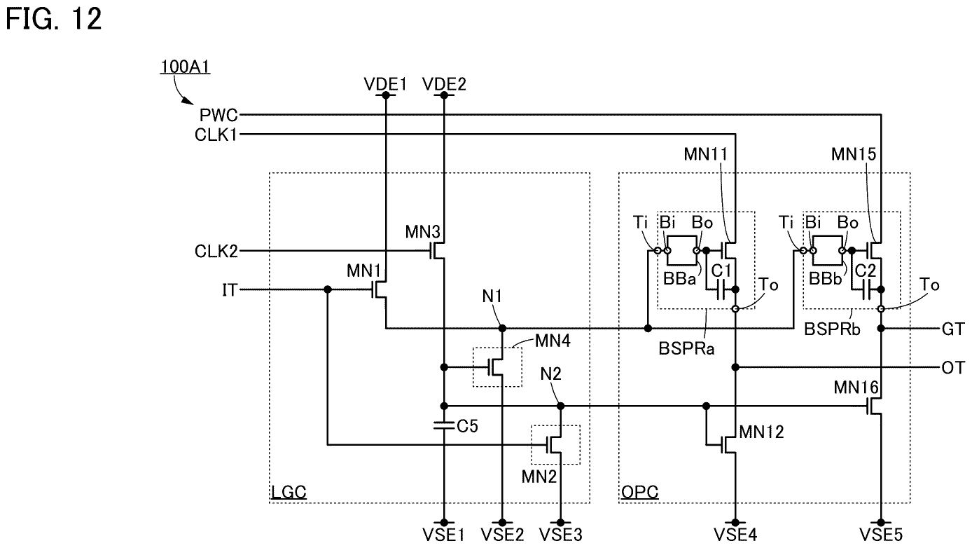

A circuit 100A1 in FIG. 12 has a circuit structure that can be employed for each of the circuit 100A[1] to the circuit 100A[m] included in the driver circuit GD illustrated in each of FIG. 11A and FIG. 11B.

The circuit 100A1 in FIG. 12 is a modification example of the circuit MDV in FIG. 1 and is different from the circuit MDV in that the circuit OPC includes a circuit BSPRa, a circuit BSPRb, the transistor MN12, and a transistor MN16. In addition, the circuit 100A1 is different from the circuit MDV in including the terminal PWC and the terminal GT.

The circuit BSPRa illustrated in FIG. 12 has a circuit structure similar to that of the circuit BSPR illustrated in FIG. 1, and a circuit BBa included in the circuit BSPRa in FIG. 12 can have a circuit structure similar to that of the circuit BB included in the circuit BSPR in FIG. 1.

The circuit BSPRb can have a circuit structure similar to that of the circuit BSPR illustrated in FIG. 1. In FIG. 12, the circuit BSPRb includes a circuit BBb, a transistor MN15, and a capacitor C2. Note that the circuit BBb can also have a circuit structure similar to that of the circuit BB included in the circuit BSPR in FIG. 1.

As each of the transistor MN15 and the transistor MN16, a transistor that can be used as the transistor MN11 illustrated in FIG. 1 can be used, for example.

As each of the transistor MN2 and the transistor MN4, the above-described transistor ML (VLFET) in FIG. 3A to FIG. 3C, FIG. 4A to FIG. 4C, or FIG. 5A to FIG. 5C can be used, for example. As each of the transistor MN1, the transistor MN3, the transistor MN11, the transistor MN12, the transistor MN15, and the transistor MN16, the above-described transistor MV (VFET) in FIG. 6A to FIG. 6C or FIG. 7A to FIG. 7C can be used, for example.

Hereinafter, a circuit structure of the circuit 100A1 is described. Note that the description of the contents overlapping with those of the circuit MDV in FIG. 1 is omitted.

The terminal Bi of the circuit BBb is electrically connected to the terminal Bi of the circuit BBa, the second terminal of the transistor MN1, and the first terminal of the transistor MN4. The terminal Bo of the circuit BBb is electrically connected to a gate of the transistor MN15 and a first terminal of the capacitor C2. A first terminal of the transistor MN15 is electrically connected to the terminal PWC, and a second terminal of the transistor MN15 is electrically connected to a second terminal of the capacitor C2, a first terminal of the transistor MN16, and the terminal GT. A gate of the transistor MN16 is electrically connected to the gate of the transistor MN12, the first terminal of the transistor MN2, the second terminal of the transistor MN3, the gate of the transistor MN4, and the first terminal of the capacitor C5. A second terminal of the transistor MN16 is electrically connected to a wiring VSE5.

The wiring VSE5 has a function of a wiring for supplying a fixed potential, for example. The fixed potential can be, for example, a low-level potential, the ground potential, or a negative potential. The wiring VSE5 may have a function of a wiring for supplying not a fixed potential but a variable potential.

Note that the wiring VSE1 to the wiring VSE5 may supply fixed potentials equal to each other or may supply fixed potentials different from each other. Alternatively, two or more wirings selected from the wiring VSE1 to the wiring VSE5 may supply fixed potentials equal to each other, and the other wiring(s) may supply a potential different from the fixed potentials. Furthermore, the two or more wirings among the wiring VSE1 to the wiring VSE5 which supply fixed potentials equal to each other may be the same wiring. For example, in the case where the wiring VSE4 and the wiring VSE5 supply fixed potentials equal to each other, the wiring VSE4 and the wiring VSE5 may be the same wiring.

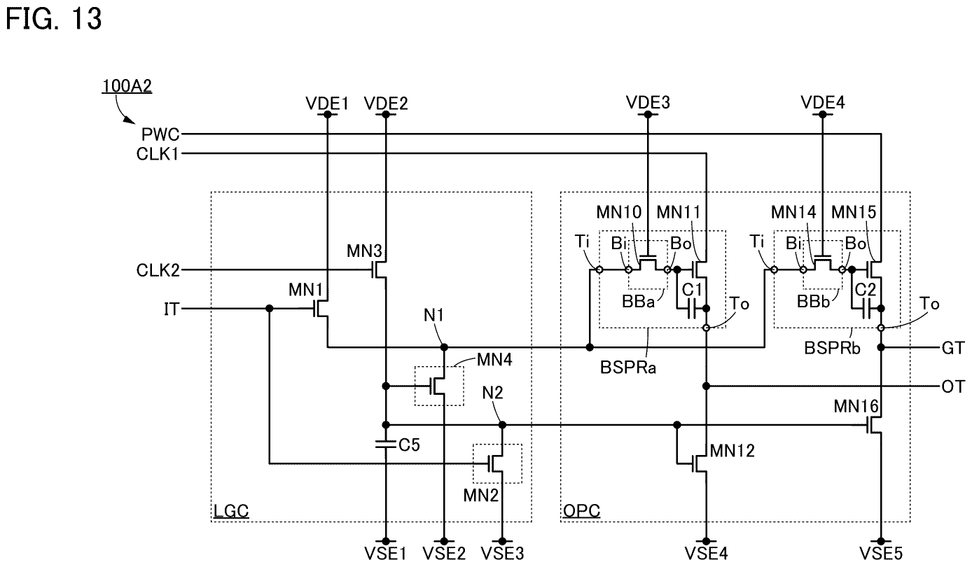

FIG. 13 shows another specific example of the circuit 100A1. A circuit 100A2 illustrated in FIG. 13 has a circuit structure in which the circuit BSPR in FIG. 8A is used as each of the circuit BSPRa and the circuit BSPRb in the circuit 100A1 in FIG. 12. In this case, the transistor MV in FIG. 6A to FIG. 6C or the transistor MV in FIG. 7A to FIG. 7C is preferably used as each of the transistor MN10 and a transistor MN14 included in the circuit BBa and the circuit BBb, respectively. Depending on the case, the transistor ML in FIG. 3A to FIG. 3C, the transistor ML in FIG. 4A to FIG. 4C, the transistor ML in FIG. 5A to FIG. 5C, or a transistor having another structure may be used as each of the transistor MN10 and the transistor MN14.

Although the circuit 100A2 in FIG. 13, which is the semiconductor device of one embodiment of the present invention, is a single-polarity circuit including an n-channel transistor, the structure of the circuit 100A2 in FIG. 13 may be changed into the structure of a single-polarity circuit including a p-channel transistor.

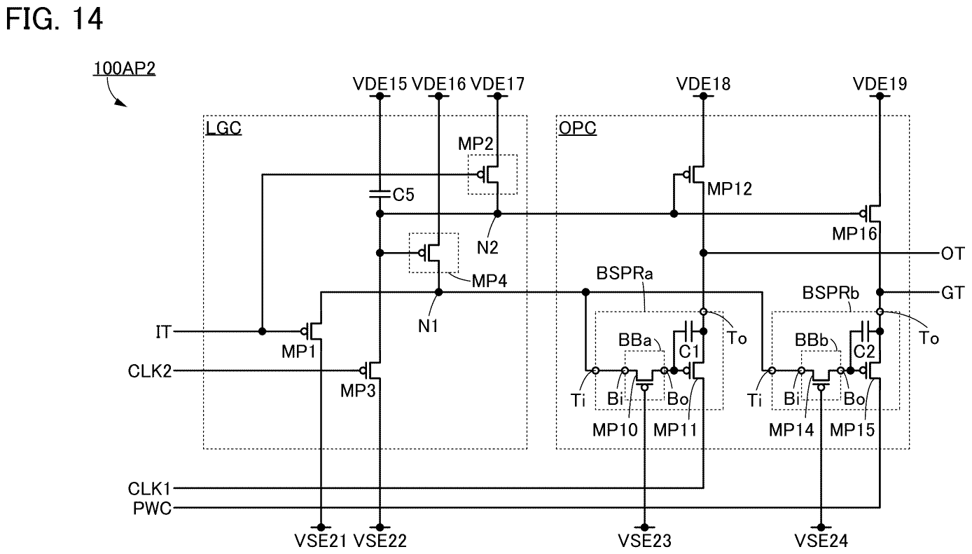

FIG. 14 shows a specific structure example. A circuit 100AP2 illustrated in FIG. 14 is a modification example of the circuit 100A2 in FIG. 13 and has a structure in which the transistor MN1 to the transistor MN4, the transistor MN10 to the transistor MN12, and the transistor MN14 to the transistor MN16 are changed into a transistor MP1 to a transistor MP4, a transistor MP10 to a transistor MP12, and a transistor MP14 to a transistor MP16, respectively; the wiring VDE1 to a wiring VDE4 are changed into a wiring VSE21 to a wiring VSE24; and the wiring VSEl to the wiring VSE5 are changed into a wiring VDE15 to a wiring VDE19. Note that the transistor MP1 to the transistor MP4, the transistor MP10 to the transistor MP12, and the transistor MP14 to the transistor MP16 are p-channel transistors as described above.

The terminal IT is electrically connected to a gate of the transistor MP1 and a gate of the transistor MP2. A first terminal of the transistor MP1 is electrically connected to the wiring VSE21, and a second terminal of the transistor MP1 is electrically connected to a first terminal of the transistor MP4, a first terminal of the transistor MP10, and a first terminal of the transistor MP14. The terminal CLK2 is electrically connected to a gate of the transistor MP3, a first terminal of the transistor MP3 is electrically connected to the wiring VSE22, and a second terminal of the transistor MP3 is electrically connected to a gate of the transistor MP4, a first terminal of the transistor MP2, a gate of the transistor MP12, a gate of the transistor MP16, and the first terminal of the capacitor C5. The second terminal of the capacitor C5 is electrically connected to the wiring VDE15, a second terminal of the transistor MP4 is electrically connected to the wiring VDE16, and a second terminal of the transistor MP2 is electrically connected to the wiring VDE17.

A second terminal of the transistor MP10 is electrically connected to a gate of the transistor MP11 and the first terminal of the capacitor C1, a first terminal of the transistor MP11 is electrically connected to the terminal CLK1, and a second terminal of the transistor MP11 is electrically connected to the second terminal of the capacitor C1, a first terminal of the transistor MP12, and the terminal OT. A second terminal of the transistor MP12 is electrically connected to the wiring VDE18.

A second terminal of the transistor MP14 is electrically connected to a gate of the transistor MP15 and the first terminal of the capacitor C2, a first terminal of the transistor MP15 is electrically connected to the terminal PWC, and a second terminal of the transistor MP15 is electrically connected to the second terminal of the capacitor C2, a first terminal of the transistor MP16, and the terminal GT. A second terminal of the transistor MP16 is electrically connected to the wiring VDE19.

The wiring VDE15 to the wiring VDE19 each function as a wiring for supplying a fixed potential, for example. The fixed potential can be, for example, a high-level potential. Note that the wiring VDE15 to the wiring VDE19 may supply fixed potentials equal to each other or may supply fixed potentials different from each other. Alternatively, two or more wirings selected from the wiring VDE15 to the wiring VDE19 may supply fixed potentials equal to each other, and the other wiring(s) may supply a potential different from the fixed potentials. Furthermore, the two or more wirings among the wiring VDE15 to the wiring VDE19 which supply fixed potentials equal to each other may be the same wiring. For example, in the case where the wiring VDE15 and the wiring VDE16 supply fixed potentials equal to each other, the wiring VDE15 and the wiring VDE16 may be the same wiring.

One or more of the wiring VDE15 to the wiring VDE19 may be a wiring for supplying not a fixed potential but a variable potential.

The wiring VSE21 to the wiring VSE24 each function as a wiring for supplying a fixed potential, for example. The fixed potential can be, for example, a low-level potential, the ground potential, or a negative potential. Note that the wiring VSE21 to the wiring VSE24 may supply fixed potentials equal to each other or may supply fixed potentials different from each other. Alternatively, two or more wirings selected from the wiring VSE21 to the wiring VSE24 may supply fixed potentials equal to each other, and the other wiring(s) may supply a potential different from the fixed potentials. Furthermore, the two or more wirings among the wiring VSE21 to the wiring VSE24 which supply fixed potentials equal to each other may be the same wiring. For example, in the case where the wiring VSE21 and the wiring VSE22 supply fixed potentials equal to each other, the wiring VSE21 and the wiring VSE22 may be the same wiring.

One or more of the wiring VSE21 to the wiring VSE24 may be a wiring for supplying not a fixed potential but a variable potential.

For the operation of the circuit 100AP2, the description of an operation example of the circuit 100A1 described later can be referred to. The circuit 100AP2 is a single-polarity circuit including a p-channel transistor; thus, it should be noted that the logic of a signal, a potential, or the like handled in the circuit 100AP2 is inverted from the logic of a signal, a potential, or the like handled in the circuit 100A1 in FIG. 12, which is a single-polarity circuit including an n-channel transistor.

Note that the semiconductor device of one embodiment of the present invention is not limited to the circuit 100A1 illustrated in FIG. 12 and the circuit 100A2 illustrated in FIG. 13. For example, in the circuit 100A2 in FIG. 13, at least one or more of the transistor MN1 to the transistor MN4, the transistor MN10 to the transistor MN12, and the transistor MN14 to the transistor MN16 may be a transistor including a back gate.

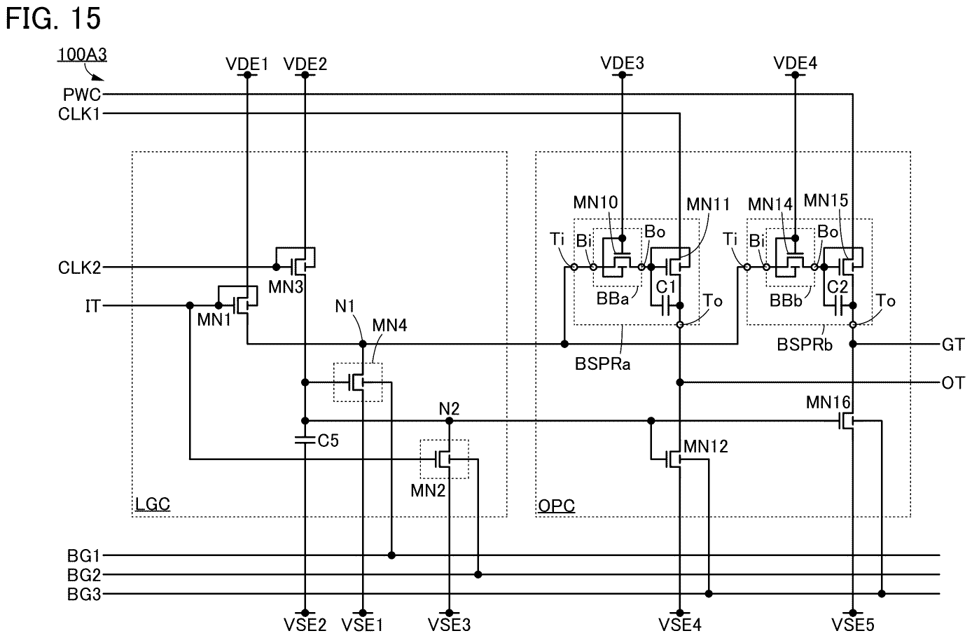

FIG. 15 shows a specific structure example. A circuit 100A3 illustrated in FIG. 15 is a modification example of the circuit 100A2 in FIG. 13 and is different from the circuit 100A2 in that the transistor MN1 to the transistor MN4, the transistor MN10 to the transistor MN12, and the transistor MN14 to the transistor MN16 each include a back gate.

In the circuit 100A3 illustrated in FIG. 15, portions to which the back gates of the transistor MN1 to the transistor MN4, the transistor MN10 to the transistor MN12, and the transistor MN14 to the transistor MN16 are connected are defined clearly.

In each of the transistor MN1, the transistor MN3, the transistor MN10, and the transistor MN14, the gate is electrically connected to the second gate. The back gate of the transistor MN2 is electrically connected to a wiring BG2. The back gate of the transistor MN4 is electrically connected to a wiring BG1. The back gate of each of the transistor MN12 and the transistor MN16 is electrically connected to a wiring BG3.

The wiring BG1 to the wiring BG3 each function as a wiring for supplying a fixed potential, for example. The fixed potential can be, for example, a low-level potential, the ground potential, or a negative potential. Note that the wiring BG1 to the wiring BG3 may supply fixed potentials equal to each other or may supply fixed potentials different from each other. In the case where two or more selected from the wiring BG1 to the wiring BG3 are wirings for supplying fixed potentials equal to each other, the two or more wirings may be the same wiring. One or more selected from the wiring BG1 to the wiring BG3 may be a wiring for supplying not a fixed potential but a variable potential.

In the case where the wiring BG1 to the wiring BG3 are wirings different from one another, different fixed potentials can be supplied to the back gates of the transistor MN2, the transistor MN4, the transistor MN12, and the transistor MN16. That is, the threshold voltage of the transistor MN2, the threshold voltage of the transistor MN4, and the threshold voltages of the transistor MN12 and the transistor MN16 can be controlled independently of one another.

With this structure, for example, when a negative potential is supplied to the back gate of the transistor MN2 and the ground potential or a low-level potential (a potential higher than the negative potential) is supplied to the back gates of the transistor MN12 and the transistor MN16, the amounts of off-state currents of the transistor MN12 and the transistor MN16 can be larger than the amount of an off-state current of the transistor MN2. Accordingly, in the case where the circuit 100A3 in FIG. 15 is employed for each of the circuit 100A[1] to the circuit 100A[m] in the driver circuit GD in each of FIG. 11A and FIG. 11B, the driving speed of the driver circuit GD can be further increased.

### Operation Example of Circuit 100A1

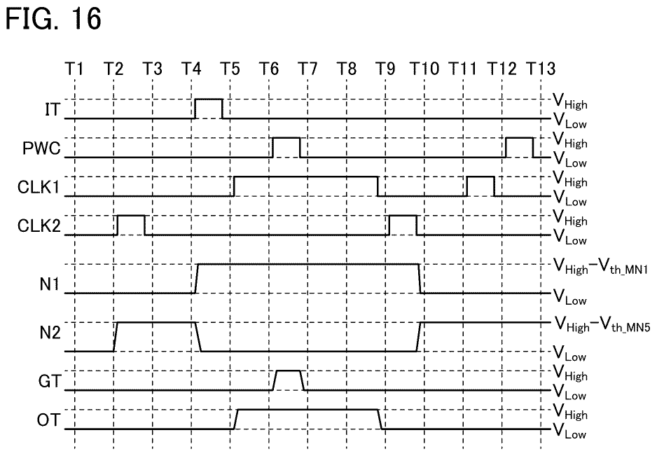

FIG. 16 is a timing chart showing the operation example of the circuit 100A1. The timing chart in FIG. 16 shows, as an example, changes in potentials of the terminal IT, the terminal PWC, the terminal CLK1, the terminal CLK2, the node N1, the node N2, the terminal GT, and the terminal OT. In FIG. 16, high-level potentials are expressed as V_{High}, and low-level potentials are expressed as V_{Low}.

In the timing chart in FIG. 16, to simply describe the operation of the circuit 100A1, the length of an input period, the length of an output period, and the like of a signal shown in the timing chart in FIG. 16 are different from those in the actual circuit operation in some cases.

In this operation example, the fixed potentials supplied by the wiring VDE1 and the wiring VDE2 are the high-level potentials V_{High} that are equal to each other. The fixed potentials supplied by the wiring VSE1 to the wiring VSE5 are the low-level potentials V_{Low} that are equal to each other.

Preferably, the high-level potential V_{High} and the low-level potential V_{Low} are each set such that a difference between the high-level potential V_{High} and the low-level potential V_{Low} is greater than the threshold voltage of each of the transistors described in FIG. 12.

[from Time T1 to Time T2]

In a period from Time T1 to Time T2, the low-level potential V_{Low} is supplied to the terminal IT, the low-level potential V_{Low} is supplied to the terminal PWC, V_{Low} is supplied to the terminal CLK1, and the low-level potential V_{Low} is supplied to the terminal CLK2. At the node N1 and the node N2, the low-level potential V_{Low} is retained as an example.

When the low-level potential V_{Low} is supplied to the terminal CLK2, the potential of the gate of the transistor MN3 is the low-level potential V_{Low}. It is also assumed that the threshold voltage of the transistor MN3 is within an appropriate range. Consequently, the transistor MN3 is in an off state.

The potential of the gate of the transistor MN4 (the node N2) is the low-level potential V_{Low} and the low-level potential V_{Low} is supplied from the wiring VSE1 to the second terminal of the transistor MN4, so that the transistor MN4 is in an off state.

It is assumed that when the low-level potential V_{Low} is supplied to the terminal IT, the potential of the first gate of the transistor MN1 is the low-level potential V_{Low}. It is also assumed that the threshold voltage of the transistor MN1 is within an appropriate range. Thus, the transistor MN1 is in an off state.

The potential of the gate of the transistor MN12 (the node N2) is the low-level potential V_{Low} and the low-level potential V_{Low} is supplied from the wiring VSE4 to the second terminal of the transistor MN12, so that the transistor MN12 is in an off state.

The potential of the gate of the transistor MN16 (the node N2) is the low-level potential V_{Low}, and the low-level potential V_{Low} is supplied from the wiring VSE5 to the second terminal of the transistor MN16, so that the transistor MN16 is in an off state.

The potential of the gate of the transistor MN2 (the terminal IT) is the low-level potential V_{Low}, and the second terminal of the transistor MN2 is supplied with the low-level potential V_{Low} from the wiring VSE3, so that the transistor MN2 is in an off state.

Note that in the period from Time T1 to Time T2 in the timing chart in FIG. 16, each of the potentials of the terminal OT and the terminal GT is the low-level potential V_{Low}, for example. In the period from Time T1 to Time T2, each of the potentials of the terminal OT and the terminal GT may be the high-level potential V_{High}.

### [From Time T2 to Time T3]

In the period from Time T2 to Time T3, the high-level potential V_{High} is supplied to the terminal CLK2.

When the high-level potential V_{High} is supplied to the terminal CLK2, the potential of the gate of the transistor MN3 becomes the high-level potential V_{High}.

Here, the transistor MN3 is normally off and the threshold voltage of the transistor MN3 is set to V_{th_MN3}. The threshold voltage V_{th_MN3} is set to satisfy V_{High}−V_{Low}>V_{th_MN3}.

When the potential of the second terminal of the transistor MN3 (the node N2) is the low-level potential V_{Low}, the transistor MN3 is turned on, and electric charge from the wiring VDE2 is accumulated in the second terminal of the transistor MN3 (the node N2). When electric charge is accumulated in the node N2 until the gate source voltage (the gate-second terminal voltage at this timing) of the transistor MN3 becomes V_{High}−V_{th_MN3}, the transistor MN3 is turned off. Thus, the potential V_{High}−V_{th_MN3} is retained in the node N2.

Note that when the potential of the second terminal of the transistor MN3 (the node N2) is higher than the high-level potential V_{High}, the first terminal of the transistor MN3 serves as a source, and electric charge is released from the wiring VDE1 to the node N2. When the potential of the second terminal of the transistor MN3 (the node N2) becomes V_{High}−V_{th_MN3}, the transistor MN3 is turned off. Thus, the potential V_{High}−V_{th_MN3} is retained in the node N2 in a manner similar to the above.

In the period from Time T2 to Time T3, after the high-level potential V_{High} is supplied to the terminal CLK2, the low-level potential V_{Low} is supplied to the terminal CLK2. Thus, the potential of the first gate of the transistor MN3 is assumed to be the low-level potential V_{Low}.

By the above operation, in the circuit 100A1, the high-level potential V_{High} is supplied to the terminal CLK2, whereby the potential of the node N2 can be refreshed to be the high-level potential V_{High}.

Since the potential of the node N2 is V_{High}−V_{th_MN3}, the potential of the first gate of the transistor MN12 (the node N2) is V_{High}−V_{th_MN3}. The low-level potential V_{Low} is supplied from the wiring VSE4 to the second terminal of the transistor MN12, and thus the transistor MN12 is in an on state. Thus, electrical continuity is established between the terminal OT and the wiring VSE4, whereby the potential of the terminal OT becomes the low-level potential V_{Low}.

Since the potential of the node N2 is V_{High}−V_{th_MN3}, the potential of the first gate of the transistor MN16 (the node N2) is V_{High}−V_{th_MN3}. The low-level potential V_{Low} is supplied from the wiring VSE5 to the second terminal of the transistor MN16, and thus the transistor MN16 is in an on state. Thus, electrical continuity is established between the terminal GT and the wiring VSE5, whereby the potential of the terminal GT becomes the low-level potential V_{Low}.

### [From Time T3 to Time T4]

In a period from Time T3 to Time T4, the low-level potential V_{Low} is supplied to the terminal IT, the low-level potential V_{Low} is supplied to the terminal PWC, V_{Low} is supplied to the terminal CLK1, and the low-level potential V_{Low} is supplied to the terminal CLK2. Potentials input to the terminal IT, the terminal PWC, the terminal CLK1, and the terminal CLK2 in the period from Time T3 to Time T4 are equal to the potentials input to the terminal IT, the terminal PWC, the terminal CLK1, and the terminal CLK2 in the period from Time T1 to Time T2; therefore, for an operation example of the circuit 100A1 in the period from Time T3 to Time T4, the description of the operation example in the period from Time T1 to Time T2 is referred to.

### [From Time T4 to Time T5]

In a period from Time T4 to Time T5, the high-level potential V_{High} is supplied to the terminal IT.

The high-level potential V_{High} is supplied from the terminal IT to the first gate of the transistor MN2, and V_{Low} is supplied from the wiring VSE3 to the second terminal of the transistor MN2, whereby the transistor MN2 is turned on. Thus, electrical continuity is established between the node N2 and the wiring VSE3, so that the potential of the node N2 changes from the high-level potential V_{High} to the low-level potential V_{Low}.

In the above manner, the potential of the first gate of the transistor MN4 (the node N2) becomes the low-level potential V_{Low} and the low-level potential V_{Low} is supplied from the wiring VSE1 to the second terminal of the transistor MN4, whereby the transistor MN4 is turned off.

In the above manner, the potential of the first gate of the transistor MN12 (the node N2) becomes the low-level potential V_{Low} and the low-level potential V_{Low} is supplied from the wiring VSE4 to the second terminal of the transistor MN12, whereby the transistor MN12 is turned off.

In the above manner, the potential of the first gate of the transistor MN16 (the node N2) becomes the low-level potential V_{Low} and the low-level potential V_{Low} is supplied from the wiring VSE5 to the second terminal of the transistor MN16, whereby the transistor MN16 is turned off.

When the high-level potential V_{High} is supplied to the terminal IT, the potential of the gate of the transistor MN1 becomes the high-level potential V_{High}. Since the potential of the second terminal of the transistor MN1 (the node N1) is the low-level potential V_{Low}, the transistor MN1 is turned on. Thus, electric charge from the wiring VDE1 is accumulated in the second terminal of the transistor MN1 (the node N1).

Here, the transistor MN1 is normally off and the threshold voltage of the transistor MN1 is set to V_{th_MN1}. The threshold voltage V_{th_MN1} is set to satisfy V_{High}−V_{Low}>V_{th_MN1}.

Accordingly, when electric charge is accumulated in the node N1 until the gate-source voltage (the gate second terminal voltage at this timing) of the transistor MN1 becomes V_{High} V_{th_MN1}, the transistor MN1 is turned off. Thus, the potential V_{High}−V_{th_MN1} is retained in the node N1.

In the period from Time T4 to Time T5, the terminal IT is supplied with the high-level potential V_{High} and then the terminal IT is supplied with the low-level potential V_{Low}. Thus, the potential of the gate of the transistor MN1 is assumed to be the low-level potential V_{Low}.

The low-level potential V_{Low} is supplied from the terminal IT to the gate of the transistor MN2, and the low-level potential V_{Low} is supplied from the wiring VSE3 to the second terminal of the transistor MN2, whereby the transistor MN2 is turned off. Thus, the low-level potential V_{Low} is retained in the node N2.

### [From Time T5 to Time T6]

In a period from Time T5 to Time T6, the high-level potential V_{High} is supplied to the terminal CLK1.

In the period from Time T4 to Time T5, the potential of the node N1 is the high-level potential V_{High}−V_{th_MN1}. At this time, the high-level potential V_{High} is supplied to the terminal CLK1, whereby the potential of the second terminal (the terminal OT) of the transistor MN11 becomes the high-level potential V_{High} in accordance with the description of the circuit BSPR in FIG. 2A.

### [From Time T6 to Time T7]

In a period from Time T6 to Time T7, the high-level potential V_{High} is supplied to the terminal PWC.

In the period from Time T4 to Time T6, the potential of the node NI is V_{High}−V_{th_MN1}. At this time, the high-level potential V_{High} is supplied to the terminal PWC, whereby the potential of the second terminal (the terminal GT) of the transistor MN15 also becomes the high-level potential V_{High} in accordance with the description of the circuit BSPR in FIG. 2A.

In the period from Time T6 to Time T7, after the high-level potential V_{High} is supplied to the terminal PWC, the low-level potential V_{Low} is supplied to the terminal PWC. Thus, the potential of the second terminal (the terminal GT) of the transistor MN15 becomes the low-level potential V_{Low} as in the operation example in the period from Time T5 to Time T6.

### [From Time T8 to Time T9]

In a period from Time T8 to Time T9, the low-level potential V_{Low} is supplied to the terminal CLK1.

Thus, the potential of the second terminal (the terminal OT) of the transistor MN11 becomes the low-level potential V_{Low} as in the operation example in the period from Time T4 to Time T5.

### [From Time T9 to Time T10]

In a period from Time T9 to Time T10, the high-level potential V_{High} is supplied to the terminal CLK2. At this time, operation of the circuit 100A1 in the period from Time T9 to Time T10 is similar to that in the period from Time T2 to Time T3.

For example, when the high-level potential V_{High} is supplied to the terminal CLK2, the potential of the second terminal of the transistor MN3 (the node N2) becomes the high-level potential V_{High}−V_{th_MN3}. Thus, the transistor MN4, the transistor MN12, and the transistor MN16 are turned on, and each of the potentials of the node N1, the terminal OT, and the terminal GT becomes V_{Low}.

### [After Time T10]

After Time T10, for example, a variable potential with the low-level potential V_{Low} is input to the terminal CLK2 to set the potential of the node N1 to V_{Low} and the potential of the node N2 to V_{High}−V_{th_MN3}, and after that, V_{High} is supplied to the terminal CLK1 or the terminal PWC without input of V_{High} to the terminal IT. A specific operation example is described below.

### [From Time T11 to Time T12]

In a period from Time T11 to Time T12, V_{High} is supplied to the terminal CLK1.

The potential of the gate of the transistor MN11 is set to V_{Low}. The first terminal of the transistor MN11 is supplied with V_{High} from the terminal CLK1, and the potential of the second terminal of the transistor MN11 is V_{Low}. At this time, the potential of the second terminal of the transistor MN11 is lower than the potential of the first terminal thereof, so that the second terminal of the transistor MN11 serves as a source, and the transistor MN11 is turned off. Thus, electrical continuity is not established between the terminal CLK1 and the terminal OT.

The potential of the gate of the transistor MN12 is V_{High}−V_{th_MN3}, and the second terminal of the transistor MN12 is supplied with V_{Low} from the wiring VSE4, whereby the transistor MN12 is turned on. Thus, electrical continuity is established between the terminal OT and the wiring VSE4, so that the potential of the terminal OT becomes V_{Low}.

In the period from Time T11 to Time T12, after V_{High} is supplied to the terminal CLK1, V_{Low} is supplied to the terminal CLK1. The potential of the first gate of the transistor MN11 is V_{Low}, the first terminal of the transistor MN11 is supplied with V_{Low} from the terminal CLK1, and the potential of the second terminal of the transistor MN11 is V_{Low}; thus, the transistor MN11 is turned off when the threshold voltage of the transistor MN11 is in an appropriate range.

The transistor MN11 remains in an off state even when the variable potential with V_{Low} is input to the terminal CLK2 to set the potential of the node N1 to V_{Low} and the potential of the node N2 to V_{High}−V_{th_MN3}, and then V_{High} is supplied to the terminal CLK1 without input of V_{High} to the terminal IT as described above. After that, even when V_{Low} is supplied to the terminal CLK1, the transistor MN11 remains in an off state.

### [From Time T12 to Time T13]

In a period from Time T12 to Time T13, V_{High} is supplied to the terminal PWC.

The potential of the first gate of the transistor MN15 is set to V_{Low}. The first terminal of the transistor MN15 is supplied with V_{High} from the terminal PWC, and the potential of the second terminal of the transistor MN15 is V_{Low}. At this time, the potential of the second terminal of the transistor MN15 is lower than the potential of the first terminal thereof, so that the second terminal of the transistor MN15 serves as a source, and the transistor MN15 is turned off. Thus, electrical continuity is not established between the terminal PWC and the terminal GT.

The potential of the first gate of the transistor MN16 is V_{High}−V_{th_MN3}, and the second terminal of the transistor MN16 is supplied with V_{Low} from the wiring VSE5, whereby the transistor MN16 is turned on. Thus, electrical continuity is established between the terminal GT and the wiring VSE5, so that the potential of the terminal GT becomes V_{Low}.

In the period from Time T12 to Time T13, after V_{High} is supplied to the terminal PWC, V_{Low} is supplied to the terminal PWC. The potential of the first gate of the transistor MN15 is V_{Low}, the first terminal of the transistor MN15 is supplied with V_{Low} from the terminal PWC, and the potential of the second terminal of the transistor MN15 is V_{Low}; thus, the transistor MN15 is turned off.

The transistor MN15 remains in an off state even when the variable potential with V_{Low} is input to the terminal CLK2 to set the potential of the node N1 to V_{Low} and the potential of the node N2 to V_{High}−V_{th_MN3}, and then V_{High} is supplied to the terminal PWC without input of V_{High} to the terminal IT as described above. After that, even when V_{Low} is supplied to the terminal PWC, the transistor MN15 remains in an off state.

Although the operation example of the circuit 100A1 is described above, the operation method of the semiconductor device of one embodiment of the present invention is not limited thereto. For example, the operation method of the circuit 100A1 (the timing chart in FIG. 16) may be changed depending on the circumstances.

### Structure Example of Driver Circuit SD

Next, a structure example of the driver circuit SD is described.

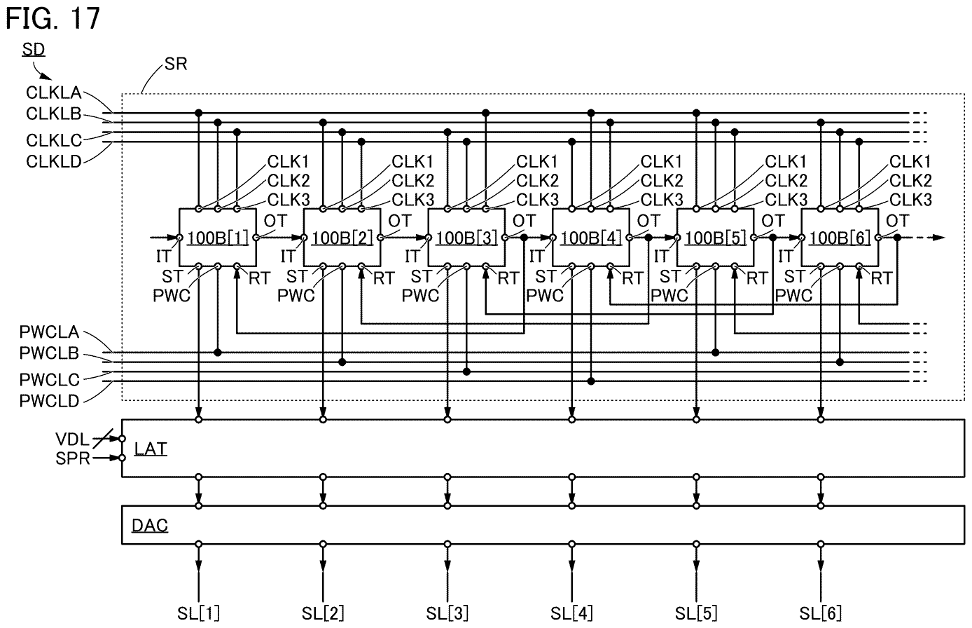

FIG. 17 shows a structure example of the driver circuit SD of one embodiment of the present invention which can be used for the display apparatus DSP in FIG. 10. The driver circuit SD illustrated in FIG. 17 includes a circuit SR, a circuit LAT, and a circuit DAC, for example. Specifically, the circuit SR includes a circuit 100B[1] to a circuit 100B[n+2], for example. Note that the circuit 100B[n+1] is a circuit for transmitting data from the terminal OT of the circuit 100B[n+1] to a terminal RT of the circuit 100B[n−1], and the circuit 100B[n+2] is a circuit for transmitting data from the terminal OT of the circuit 100B[n+2] to the terminal RT of the circuit 100B[n]. FIG. 17 selectively illustrates the circuit 100B[1] to a circuit 100B[6].

Each of the circuit 100B[1] to the circuit 100B[n] includes, for example, the terminal IT, a terminal ST, the terminal CLK1, the terminal CLK2, a terminal CLK3, the terminal OT, the terminal PWC, and the terminal RT.

In the circuit SR, a wiring CLKLA to a wiring CLKLD and a terminal PWCLA to a terminal PWCLD extend.

In the circuit 100B[4k−3], the terminal CLK1 is electrically connected to the wiring CLKLA, the terminal CLK2 is electrically connected to the wiring CLKLB, the terminal CLK3 is electrically connected to the wiring CLKLC, and the terminal PWC is electrically connected to the terminal PWCLA (here, k is an integer greater than or equal to 1 and satisfies the formula: 1≤4k−3≤n). In the circuit 100B[4k−2], the terminal CLK1 is electrically connected to the wiring CLKLB, the terminal CLK2 is electrically connected to the wiring CLKLC, the terminal CLK3 is electrically connected to the wiring CLKLD, and the terminal PWC is electrically connected to the terminal PWCLB (here, k is an integer greater than or equal to 1 and satisfies the formula: 2≤4k−2≤n). In the circuit 100B[4k−1], the terminal CLK1 is electrically connected to the wiring CLKLC, the terminal CLK2 is electrically connected to the wiring CLKLD, the terminal CLK3 is electrically connected to the wiring CLKLA, and the terminal PWC is electrically connected to the terminal PWCLC (here, k is an integer greater than or equal to 1 and satisfies the formula: 3≤4k−1≤n). In the circuit 100B[4k], the terminal CLK1 is electrically connected to the wiring CLKLD, the terminal CLK2 is electrically connected to the wiring CLKLA, the terminal CLK3 is electrically connected to the wiring CLKLB, and the terminal PWC is electrically connected to the terminal PWCLD (here, k is an integer greater than or equal to 1 and satisfies the formula: 4≤4k≤n).

The terminal OT of the circuit 100B[j] (here, j is an integer greater than or equal to 1 and less than or equal to n) is electrically connected to the terminal IT of the circuit 100B[j+1]. The terminal RT of the circuit 100B[j] is electrically connected to the terminal OT of the circuit 100B[j+2].

The terminals ST of the circuit 100B[1] to the circuit 100B[n] are electrically connected to the respective input terminals of the circuit LAT. The output terminals of the circuit LAT are electrically connected to the respective input terminals of the circuit DAC. The circuit LAT is electrically connected to a wiring VDL. The circuit LAT is electrically connected to a wiring SPR. The output terminals of the circuit DAC are electrically connected to the wiring SL[1] to the wiring SL[n]. Note that the wiring SL[1] to the wiring SL[n] are wirings corresponding to the wiring SLS[1] to the wiring SLS[n] illustrated in FIG. 10. FIG. 17 selectively illustrates the wiring SL[1] to the wiring SL[6].

Each of the circuit 100B[1] to the circuit 100B[n] has functions of, for example, retaining data input to the terminal IT and outputting the retained data to one or both of the terminal ST and the terminal OT.

For example, the circuit 100B[j] has a function of outputting data retained in the circuit 100B[j] to the terminal OT when the high-level potential is input to the terminal CLK1. For another example, the circuit 100B[j] has a function of outputting data retained in the circuit 100B[j] to the terminal ST when the high-level potential is input to the terminal PWC. For another example, the circuit 100B[j] has a function of resetting data retained in the circuit 100B[j] when the high-level potential is input to one or both of the terminal RT and the terminals CLK2 and CLK3. The circuit 100B[j] is preferably configured to retain new data that is input to the terminal IT of the circuit 100B[j] after the data retained in the circuit 100B[j] is reset.

That is, the circuit SR illustrated in FIG. 17 functions as a shift register circuit like the driver circuit GD illustrated in FIG. 11A and FIG. 11B.

The wiring VDL functions as a wiring for transmitting a video signal for display in the pixel circuit PX included in the pixel array PA, for example. Note that in FIG. 17, the wiring VDL is illustrated as a wiring for transmitting digital data.

The circuit LAT includes retention circuits of n columns, for example. The circuit LAT has a function of retaining video signals, which are input to the wiring VDL, in retention circuits in response to the signals from the terminals ST of the circuit 100B[1] to the circuit 100B[n]. Specifically, for example, when the potential of the terminal ST in the circuit 100B[j] is a high-level potential, the circuit LAT retains the video signal, which is input to the wiring VDL, in the retention circuit in the j-th column. For example, the circuit LAT has a function of collectively outputting the video signals, which are retained in the retention circuits of the n columns, to the output terminals of the circuit LAT when a high-level potential is input to the wiring SPR.

The circuit DAC has a function of converting a video signal which is digital data output from the output terminals of the circuit LAT into analog data (analog potential), for example. Note that the analog data (analog potential) is transmitted to the wiring SL in the column.

A wiring other than the wiring CLKLA to the wiring CLKLD and the wiring PWCLA to the wiring PWCLD may extend in the driver circuit SD illustrated in FIG. 17. The structure of the driver circuit SD illustrated in FIG. 17 is an example, and the number of wirings, electrical connections, and the like may be modified as appropriate.

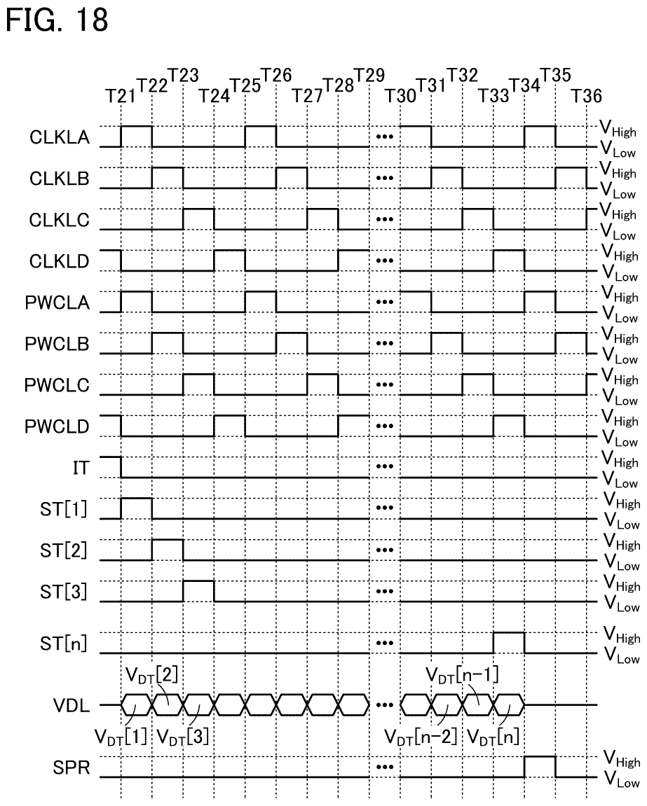

FIG. 18 is a timing chart showing an operation example of the driver circuit SD. FIG. 18 shows potential changes of the wiring CLKLA to the wiring CLKLD and the wiring PWCLA to the wiring PWCLD, the terminal IT, a terminal ST[1], a terminal ST[2], a terminal ST[3], a terminal ST[n], and the wiring SPR in a period from Time T21 to Time T36 and around the period. Note that a terminal ST[j] is the terminal ST included in the circuit 100B[j]. In the example shown in FIG. 18, a video signal VDT[1] to a video signal VDT[n] are sequentially input to the wiring VDL.

In the period from Time T21 to Time T22, the high-level potential V_{High} is supplied to the wiring CLKLA and the wiring PWCLA. In the period from Time T22 to Time T23, the high-level potential V_{High} is supplied to the wiring CLKLB and the wiring PWCLB. In the period from Time T23 to Time T24, the high-level potential V_{High} is supplied to the wiring CLKLC and the wiring PWCLC. In the period from Time T24 to Time T25, the high-level potential V_{High} is supplied to the wiring CLKLD and the wiring PWCLD. After Time T25, the high-level potential V_{High} is supplied to the wiring CLKLA to the wiring CLKLD and the wiring PWCLA to the wiring PWCLD at the same timing as that in the period from Time T21 to Time T25.

Since the high-level potential V_{High} is supplied to the wiring CLKLA to the wiring CLKLD and the wiring PWCLA to the wiring PWCLD at the above timings, the terminal ST[1] to the terminal ST[n] sequentially output the high-level potential V_{High} at predetermined timings when the high-level potential V_{High} is supplied to the terminal IT in the period before Time T21. For example, the terminal ST[1] outputs the high-level potential V_{High} in the period from Time T21 to Time T22, the terminal ST[2] outputs the high-level potential V_{High} in the period from Time T22 to Time T23, and the terminal ST[3] outputs the high-level potential V_{High} in the period from Time T23 to Time T24. For example, the terminal ST[n-2] outputs the high-level potential V_{High} in the period from Time T31 to Time T32, the terminal ST[n-1] outputs the high-level potential V_{High} in the period from Time T32 to Time T33, and the terminal ST[n] outputs the high-level potential V_{High} in the period from Time T33 to Time T34.

Note that the timing chart of FIG. 18 shows the case where n is a multiple of 4. In the case where n is not a multiple of 4 in the driver circuit SD, potentials supplied to the wiring CLKLA to the wiring CLKLD and the wiring PWCLA to the wiring PWCLD in the period from Time T30 to Time T34 are replaced as appropriate.

The circuit LAT retains the video signal VDT[1], which is input to the wiring VDL, in the retention circuit of the first column at the timing when the high-level potential V_{High} is output from the terminal ST[1]. The circuit LAT retains the video signal VDT[2], which is input to the wiring VDL, in the retention circuit of the second column at the timing when the high-level potential V_{High} is output from the terminal ST[2], and retains the video signal VDT[3], which is input to the wiring VDL, in the retention circuit of the third column at the timing when the high-level potential V_{High} is output from the terminal ST[3]. Similar operations are sequentially continued, and the video signal VDT[n], which is input to the wiring VDL, is retained in the retention circuit of the n-th column at the timing when the high-level potential V_{High} is output from the terminal ST[n].

When the potential of the wiring SPR changes to the high-level potential V_{High} in the period from Time T34 to Time T35, the circuit LAT outputs the video signal VDT[1] to the video signal VDT[n], which have been retained in the retention circuits of the n columns in the circuit LAT, to the circuit DAC through the output terminals of the circuit LAT.

The driver circuit SD is capable of transmitting the video signals to the pixel circuits in the pixel array PA by performing the above operation as an example in the timing chart in FIG. 18.

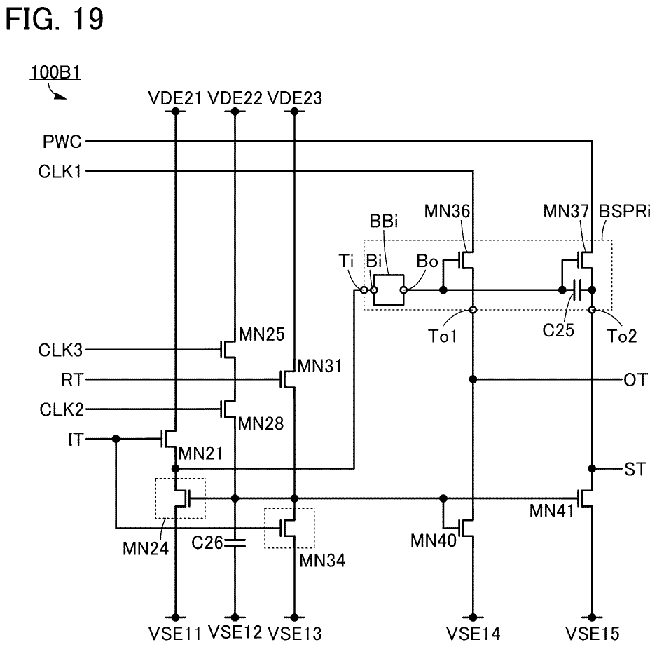

A circuit 100B1 in FIG. 19 has a circuit structure that can be employed for each of the circuit 100B[1] to the circuit 100B[n] included in the driver circuit SD.

The circuit 100B1 includes a circuit BSPRi, a transistor MN21, a transistor MN24, a transistor MN25, a transistor MN28, a transistor MN31, a transistor MN34, a transistor MN40, a transistor MN41, and a capacitor C26, for example. The circuit 100B1 further includes the terminal IT, the terminal PWC, the terminal CLK1, the terminal CLK2, the terminal CLK3, the terminal RT, the terminal OT, and the terminal ST, for example.

The transistor that can be used as each of the transistor MN1, the transistor MN3, the transistor MN11, and the transistor MN12 can be used as each of the transistor MN21, the transistor MN25, the transistor MN28, the transistor MN31, a transistor MN36, a transistor MN37, the transistor MN40, and the transistor MN41, for example. Specifically, the transistor MV in FIG. 6A to FIG. 6C or FIG. 7A to FIG. 7C can be used as each of the transistor MN21, the transistor MN25, the transistor MN28, the transistor MN31, the transistor MN36, the transistor MN37, the transistor MN40, and the transistor MN41, for example. Note that depending on the case, as each of the above-described transistors, the transistor ML in FIG. 3A to FIG. 3C, FIG. 4A to FIG. 4C, or FIG. 5A to FIG. 5C may be used, or a transistor having another structure may be used.

The transistor that can be used as each of the transistor MN2 and the transistor MN4 can be used as each of the transistor MN24 and the transistor MN34, for example. Specifically, the transistor ML in FIG. 3A to FIG. 3C, the transistor in FIG. 4A to FIG. 4C, or the transistor in FIG. 5A to FIG. 5C can be used as each of the transistor MN24 and the transistor MN34, for example. Note that depending on the case, as each of the above-described transistors, the transistor MV in FIG. 6A to FIG. 6C or the transistor MV in FIG. 7A to FIG. 7C may be used, or a transistor having another structure may be used.

In the circuit 100B1 in FIG. 19, the circuit BSPRi employs a circuit structure obtained by modifying the circuit BSPR illustrated in FIG. 2A. Specifically, the circuit BSPRi employs a circuit structure obtained by further adding one transistor to the circuit BSPR illustrated in FIG. 2A.

The circuit BSPRi includes a circuit BBi corresponding to the circuit BB of the circuit BSPR in FIG. 2A, the transistor MN37 corresponding to the transistor MNb of the circuit BSPR in FIG. 2A, a capacitor C25 corresponding to the capacitor Ca of the circuit BSPR in FIG. 2A, and the transistor MN36.

A first gate of the transistor MN21 is electrically connected to a first gate of the transistor MN34 and the terminal IT, and a first terminal of the transistor MN21 is electrically connected to a wiring VDE21. A second terminal of the transistor MN21 is electrically connected to a first terminal of the transistor MN24, and the terminal Bi of the circuit BBi.

A gate of the transistor MN25 is electrically connected to the terminal CLK3, and a first terminal of the transistor MN25 is electrically connected to a wiring VDE22. A second terminal of the transistor MN25 is electrically connected to a first terminal of the transistor MN28. A gate of the transistor MN28 is electrically connected to the terminal CLK2.

A first gate of the transistor MN31 is electrically connected to the terminal RT, and a first terminal of the transistor MN31 is electrically connected to a wiring VDE23. A second terminal of the transistor MN31 is electrically connected to a second terminal of the transistor MN28, a gate of the transistor MN24, a first terminal of the capacitor C26, a first terminal of the transistor MN34, a gate of the transistor MN40, and a gate of the transistor MN41.

A gate of the transistor MN36 is electrically connected to the terminal Bo of the circuit BBi, a first terminal of the capacitor C25, and a gate of the transistor MN37, and a first terminal of the transistor MN36 is electrically connected to the terminal CLK1. A second terminal of the transistor MN36 is electrically connected to a first terminal of the transistor MN40 and the terminal OT. A first terminal of the transistor MN37 is electrically connected to the terminal PWC. A second terminal of the transistor MN37 is electrically connected to a second terminal of the capacitor C25, a first terminal of the transistor MN41, and the terminal ST.

A second terminal of the transistor MN24 is electrically connected to a wiring VSE11. A second terminal of the capacitor C26 is electrically connected to a wiring VSE12. A second terminal of the transistor MN34 is electrically connected to a wiring VSE13. A second terminal of the transistor MN40 is electrically connected to a wiring VSE14. A second terminal of the transistor MN41 is electrically connected to a wiring VSE15.

For the wiring VDE21 to the wiring VDE23, the description of the wiring VDE1 to the wiring VDE4 can be referred to, for example.

For the wiring VSE11 to the wiring VSE15, the description of the wiring VSE1 to the wiring VSE5 can be referred to, for example.

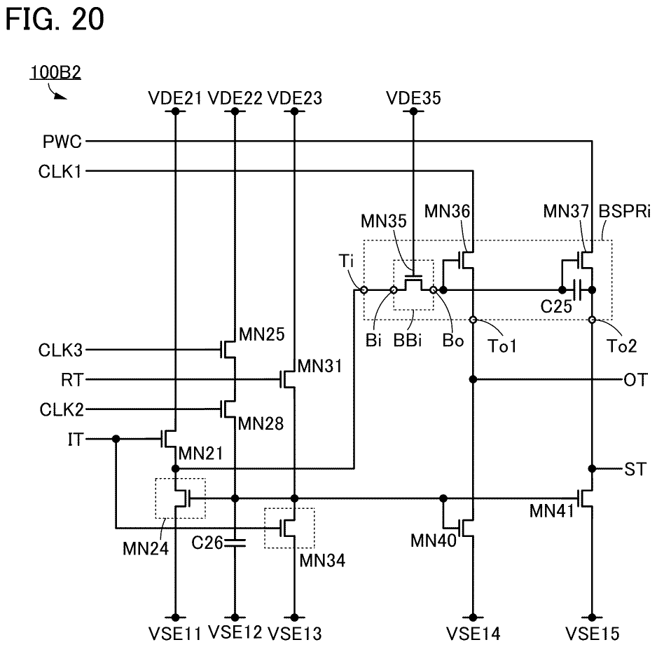

FIG. 20 shows another specific example of the circuit 100B1. A circuit 100B2 illustrated in FIG. 20 has a circuit structure in which the circuit BSPR in FIG. 8A is used as the circuit BSPRi in the circuit 100B1 in FIG. 19. In this case, the transistor MV in FIG. 6A to FIG. 6C or the transistor MV in FIG. 7A to FIG. 7C is preferably used as a transistor MN35 included in the circuit BBi. Depending on the case, the transistor ML in FIG. 3A to FIG. 3C, the transistor ML in FIG. 4A to FIG. 4C, the transistor ML in FIG. 5A to FIG. 5C, or a transistor having another structure may be used as the transistor MN35.

In FIG. 20, a gate of the transistor MN35 is electrically connected to a wiring VDE35. A first terminal of the transistor MN35 is electrically connected to the terminal Bi, and a second terminal of the transistor MN35 is electrically connected to the terminal Bo.

The wiring VDE35 has a function of a wiring for supplying a fixed potential, for example. The fixed potential can be, for example, a high-level potential. The wiring VDE35 may be a wiring for supplying not a fixed potential but a variable potential.

Note that the wiring VDE35 and at least one or more of the wiring VDE21 to the wiring VDE23 may supply fixed potentials equal to each other or may supply fixed potentials different from each other. In the case where the wiring VDE35 and at least one or more of the wiring VDE21 to the wiring VDE23 supply fixed potentials equal to each other, the wiring VDE35 and at least one or more of the wiring VDE21 to the wiring VDE23 may be the same wiring.

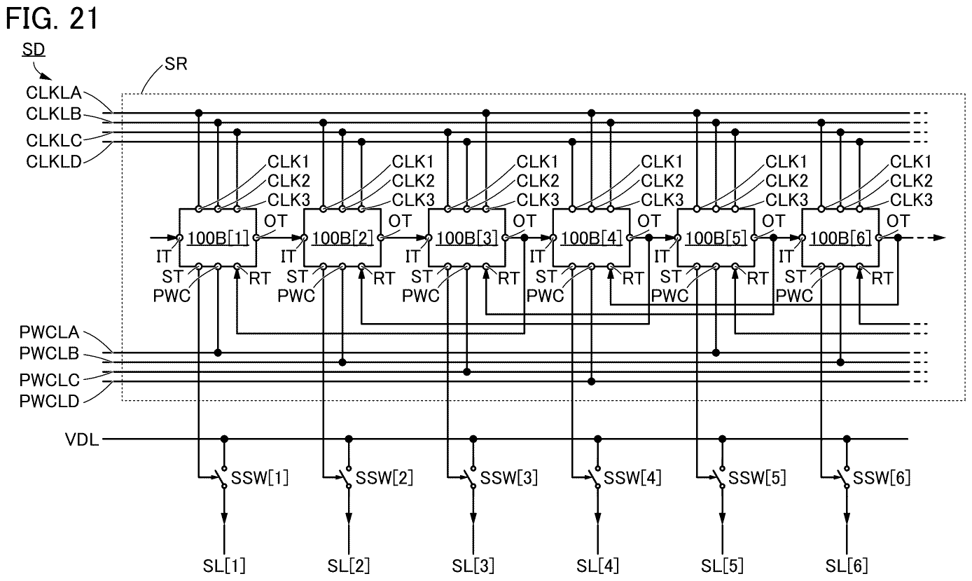

Note that the structure of the driver circuit SD of the semiconductor device of one embodiment of the present invention is not limited to the structure in FIG. 17. For example, the driver circuit SD in FIG. 17 may have a circuit structure illustrated in FIG. 21.

The driver circuit SD illustrated in FIG. 21 is different from the driver circuit SD in FIG. 17 in not being provided with the circuit LAT and the circuit DAC and in including a switch SSW[1] to a switch SSW[n] (the switch SSW[1] to a switch SSW[6] are selectively illustrated in FIG. 21).

As each of the switch SSW[1] to the switch SSW[n], an electrical switch such as an analog switch or a transistor can be used, for example. When a transistor is used as each of the switch SSW[1] to the switch SSW[n], for example, the transistor can be a transistor having a structure similar to that of the transistor MN1 or the transistor MN2. A mechanical switch may be used other than the electrical switch.

The switch SSW[1] to the switch SSW[n] each include a control terminal. The control terminal has a function of a terminal that receives a signal for controlling the switch SSW[j]. In this specification and the like, it is assumed that the switch SSW[j] is turned on when a high-level potential is input to the control terminal of the switch SSW[j], and the switch SSW[j] is turned off when a low-level potential is input to the control terminal of the switch SSW[j].

In FIG. 21, the terminal ST of the circuit 100B[j] (here, j is an integer greater than or equal to 1 and less than or equal to n) is electrically connected to the control terminal of the switch SSW[j]. A first terminal of the switch SSW[j] is electrically connected to the wiring VDL, and a second terminal of the switch SSW[j] is electrically connected to the wiring SL[j].

The wiring VDL in FIG. 21 functions as a wiring for transmitting a video signal, which is analog data, to each of first terminals of the switch SSW[1] to the switch SSW[n].

Although not illustrated in FIG. 21, a video signal generation circuit is assumed to be electrically connected to the wiring VDL. The video signal generation circuit includes, for example, a digital-to-analog converter circuit and a buffer circuit. The video signal generation circuit has a function of converting a video signal, which is digital data, into analog data with use of the digital-to-analog converter circuit and outputting the video signal, which has been converted into the analog data, to the wiring VDL through the buffer circuit, for example.

The driver circuit SD in FIG. 21 inputs a start pulse signal to the terminal IT and then periodically inputs clock signals to the terminal IT, whereby high-level potentials can be successively output from the terminals ST of the circuit 100B[1] to the circuit 100B[n]. Thus, the switch SSW[1] to the switch SSW[n] can be turned on one by one from the first column. Moreover, when a video signal is transmitted from the video signal generation circuit to the wiring VDL in accordance with the timing at which the switch SSW[j] is turned on, the video signal can be written to the pixel circuit PX positioned in the j-th column of the pixel array PA. That is, the use of the driver circuit SD in FIG. 21 enables line sequential driving.

In the driver circuit SD in FIG. 17, the scale of the circuit LAT and the circuit DAC is increased in accordance with the number of columns; meanwhile, in the driver circuit SD in FIG. 21, the video signal generation circuit is connected to only the wiring VDL. Thus, the circuit area of the driver circuit SD in FIG. 21 can be smaller than the circuit area of the driver circuit SD in FIG. 17.

Note that the above-described operation of the switch SSW[j] is an example, and the switch SSW[j] may be turned on when a low-level potential is input to the control terminal of the switch SSW[j], and the switch SSW[j] may be turned off when a high-level potential is input to the control terminal of the switch SSW[j].

### Structure Example 2 of Retention Circuit

A structure example of a retention circuit that is different from the circuit 100A1 and the circuit 100B1 and can be provided in the shift register circuit illustrated in FIG. 11A and FIG. 11B, the circuit SR in FIG. 17, or the like is described.

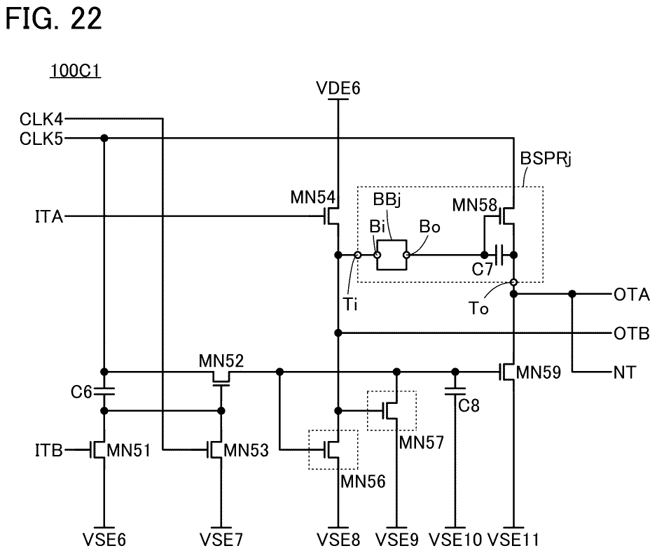

A circuit 100C1 illustrated in FIG. 22 includes a terminal ITA, a terminal ITB, the terminal CLK3, and a terminal CLK4 functioning as input terminals. The circuit 100C1 includes a terminal OTA, a terminal OTB, and a terminal NT functioning as output terminals.

In consideration of the shift register circuit, the terminal OTA of the circuit 100C1 in the previous stage is electrically connected to the terminal ITA of the circuit 100C1 in the subsequent stage, and the terminal OTB of the circuit 100C1 in the previous stage is electrically connected to the terminal ITB of the circuit 100C1 in the subsequent stage.

The circuit 100C1 includes the terminal CLK4 and a terminal CLK5. The terminal CLK4 and the terminal CLK5 are terminals corresponding to the terminal CLK1 to the terminal CLK3 in the circuit 100B1, for example. Thus, pulse potentials are input to the terminal CLK4 and the terminal CLK5 of the circuit 100C1. The pulse potentials input to the terminal CLK4 and the terminal CLK5 may be equal to each other or different from each other. Note that pulse potentials equal to each other are assumed to be at the same timing and have the same pulse width.

The circuit 100C1 includes the terminal NT. The terminal NT is a terminal corresponding to the terminal GT in the circuit 100A1 or the terminal ST in the circuit 100B1.

The circuit 100C1 includes, for example, a transistor MN51 to a transistor MN54, a transistor MN56, a transistor MN57, a transistor MN59, a capacitor C6, a capacitor C8, and a circuit BSPRj. As illustrated in FIG. 22, the circuit 100C1 is a single-polarity circuit not including a p-channel transistor but including an n-channel transistor.

The circuit BSPRj illustrated in FIG. 22 has a circuit structure similar to that of the circuit BSPR illustrated in FIG. 1. Thus, the circuit BSPRj includes a transistor MN58, a capacitor C7, and a circuit BBj, for example. Note that the circuit BBj included in the circuit BSPRj in FIG. 22 can also have a circuit structure similar to that of the circuit BB included in the circuit BSPR in FIG. 1.

In the circuit 100C1 in FIG. 22, each of the transistor MN51 to the transistor MN57 and the transistor MN59 has a single-gate structure, but may be a transistor having a multi-gate structure including gates over and under a channel.

A first terminal of the capacitor C6 is electrically connected to a first terminal of the transistor MN52 and the terminal CLK5, and a second terminal of the capacitor C6 is electrically connected to a first terminal of the transistor MN51, a gate of the transistor MN52, and a first terminal of the transistor MN53. A second terminal of the transistor MN51 is electrically connected to a wiring VSE6, and a gate of the transistor MN51 is electrically connected to the terminal ITB. A second terminal of the transistor MN53 is electrically connected to a wiring VSE7, and a gate of the transistor MN53 is electrically connected to the terminal CLK4. A second terminal of the transistor MN52 is electrically connected to a gate of the transistor MN56, a first terminal of the transistor MN57, a gate of the transistor MN59, and a first terminal of the capacitor C8. A second terminal of the transistor MN57 is electrically connected to a wiring VSE9. A second terminal of the capacitor C8 is electrically connected to a wiring VSE10.

A first terminal of the transistor MN54 is electrically connected to a wiring VDE6, and a second terminal of the transistor MN54 is electrically connected to the terminal Bi of the circuit BBj, a gate of the transistor MN57, a first terminal of the transistor MN56, and the terminal OTB. A second terminal of the transistor MN56 is electrically connected to a wiring VSE8. The terminal Bo of the circuit BBj is electrically connected to a gate of the transistor MN58 and a first terminal of the capacitor C7. A first terminal of the transistor MN58 is electrically connected to the terminal CLK5, a second terminal of the transistor MN58 is electrically connected to a second terminal of the capacitor C7, a first terminal of the transistor MN59, the terminal OTA, and the terminal NT, and a second terminal of the transistor MN59 is electrically connected to the wiring VSE11.

The wiring VDE6 has a function of a wiring for supplying a fixed potential, for example. The fixed potential can be, for example, a high-level potential.

The wiring VSE6 to the wiring VSE11 each have a function of a wiring for supplying a fixed potential, for example. The fixed potential can be, for example, a low-level potential, the ground potential, or a negative potential. Note that the wiring VSE6 to the wiring VSE11 may supply fixed potentials equal to each other or may supply fixed potentials different from each other. Alternatively, two or more wirings selected from the wiring VSE6 to the wiring VSE11 may supply fixed potentials equal to each other, and the other wiring(s) may supply a potential different from the fixed potentials. Furthermore, the two or more wirings among the wiring VSE6 to the wiring VSE11 which supply fixed potentials equal to each other may be the same wiring. For example, in the case where the wiring VSE6 and the wiring VSE7 supply fixed potentials equal to each other, the wiring VSE6 and the wiring VSE7 may be the same wiring.

One or more of the wiring VSE6 to the wiring VSE11 may have a function of a wiring for supplying not a fixed potential but a variable potential.

In the case of stabilizing the operation of the circuit 100C1, it is preferable that, as in the circuit 100A1 and the circuit 100B1, the potential of the terminal Bi of the circuit BBj (corresponding to the node N1 in the circuit 100A1) and the potential of the gate of the transistor MN59 (corresponding to the node N2 in the circuit 100A1) do not change due to any factor, e.g., an unintended factor such as leakage current. Thus, the transistor ML in FIG. 3A to FIG. 3C, the transistor ML in FIG. 4A to FIG. 4C, or the transistor ML in FIG. 5A to FIG. 5C is preferably used as each of the transistor MN56 and the transistor MN57, for example. As described above, the transistor ML can have an extremely low off-state current; thus, the use of the transistor ML as each of the transistor MN56 and the transistor MN57 can prevent changes in the potentials of the terminal Bi of the circuit BBj and the gate of the transistor MN59 due to leakage current. Note that depending on the case, as each of the transistor MN56 and the transistor MN57, the transistor MV in FIG. 6A to FIG. 6C or the transistor MV in FIG. 7A to FIG. 7C may be used, or a transistor having another structure may be used.

The transistor MV in FIG. 6A to FIG. 6C or the transistor MV in FIG. 7A to FIG. 7C is preferably used as each of the transistor MN51 to the transistor MN55, the transistor MN57, and the transistor MN59. Note that depending on the case, as each of the above-described transistors, the transistor ML in FIG. 3A to FIG. 3C, the transistor ML in FIG. 4A to FIG. 4C, or the transistor ML in FIG. 5A to FIG. 5C may be used, or a transistor having another structure may be used.

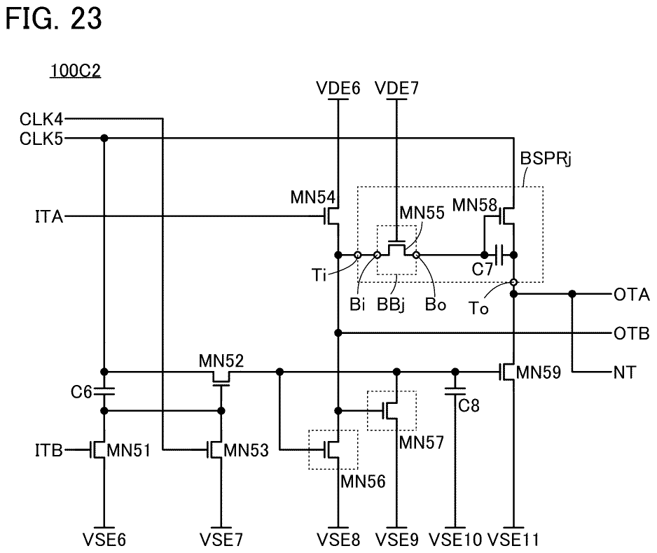

FIG. 23 shows another specific example of the circuit 100C1. A circuit 100C2 illustrated in FIG. 23 has a circuit structure in which the circuit BSPR in FIG. 8A is used as the circuit BSPRj in the circuit 100C1 in FIG. 22. In this case, the transistor MV in FIG. 6A to FIG. 6C or the transistor MV in FIG. 7A to FIG. 7C is preferably used as a transistor MN55 included in the circuit BBj. Depending on the case, the transistor ML in FIG. 3A to FIG. 3C, the transistor ML in FIG. 4A to FIG. 4C, the transistor ML in FIG. 5A to FIG. 5C, or a transistor having another structure may be used as the transistor MN55.

In FIG. 23, a gate of the transistor MN55 is electrically connected to a wiring VDE7. A first terminal of the transistor MN55 is electrically connected to the terminal Bi, and a second terminal of the transistor MN55 is electrically connected to the terminal Bo.

The wiring VDE7 has a function of a wiring for supplying a fixed potential, for example. The fixed potential can be, for example, a high-level potential.

Note that the wiring VDE6 and the wiring VDE7 may supply fixed potentials equal to each other or may supply fixed potentials different from each other. In the case where the wiring VDE6 and the wiring VDE7 supply fixed potentials equal to each other, the wiring VDE6 and the wiring VDE7 may be the same wiring. One or both of the wiring VDE6 and the wiring VDE7 may be a wiring for supplying not a fixed potential but a variable potential.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 2

In this embodiment, another structure example of the retention circuit described in Embodiment 1 will be described.

### Structure Example 3 of Retention Circuit

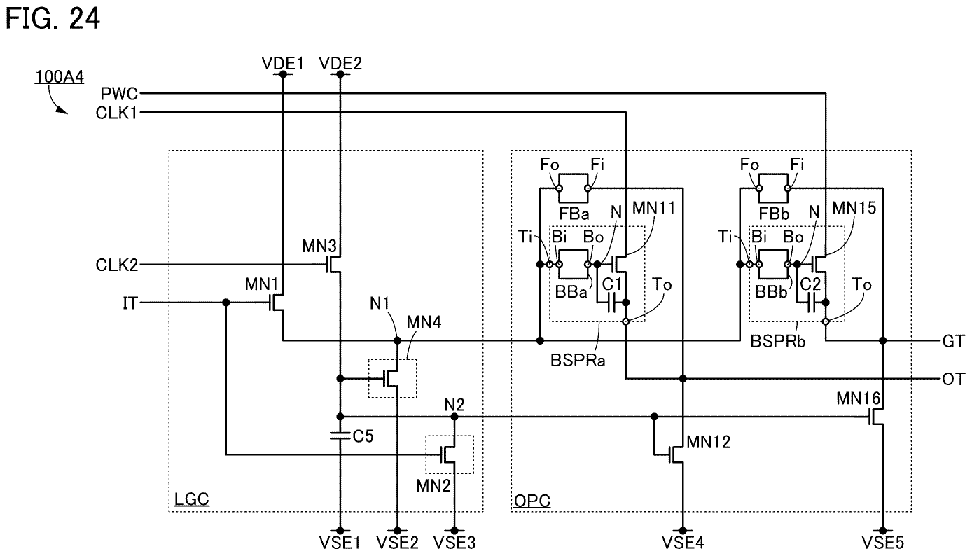

A circuit 100A4 illustrated in FIG. 24 is a modification example of the circuit 100A1 illustrated in FIG. 12 and is different from the circuit 100A1 in that the circuit OPC includes a circuit FBa and a circuit FBb.

The circuit FBa and the circuit FBb each include, for example, a terminal Fi having a function of an input terminal and a terminal Fo having a function of an output terminal.

The terminal Fi of the circuit FBa is electrically connected to the terminal OT, the second terminal of the capacitor C1, the second terminal of the transistor MN11, and the first terminal of the transistor MN12, and the terminal Fo of the circuit FBa is electrically connected to the terminal Bi of the circuit BBa, the terminal Bi of the circuit BBb, the second terminal of the transistor MN1, the first terminal of the transistor MN4, and the terminal Fo of the circuit FBb. The terminal Fi of the circuit FBb is electrically connected to the terminal GT, the second terminal of the capacitor C2, the second terminal of the transistor MN15, and the first terminal of the transistor MN16.

The circuit FBa (the circuit FBb) has a function of obtaining a potential output from the terminal To of the circuit BSPRa (the circuit BSPRb) and supplying a fixed potential to the terminal Ti of the circuit BSPRa (the circuit BSPRb), for example. That is, the circuit FBa (the circuit FBb) can be regarded as a circuit that supplies feedback to the circuit BSPRa (the circuit BSPRb) on the basis of the potential output from the terminal To of the circuit BSPRa (the circuit BSPRb). Specifically, for example, the circuit FBa (the circuit FBb) may have a structure in which a fixed potential (e.g., the high-level potential V_{High}) is output to the terminal Fo when the high-level potential V_{High} is input to the terminal Fi.

When the circuit FBa (the circuit FBb) has the above structure and the high-level potential V_{High} is output from the terminal To of the circuit BSPRa (the circuit BSPRb), for example, a fixed potential output from the terminal Fo of the circuit FBa (the circuit FBb) is supplied to the terminal Ti of the circuit BSPRa (the circuit BSPRb). Thus, for example, even when the amount of an off-state current flowing between a source and a drain or the amount of a leakage current flowing between a gate and the source or between the gate and the drain becomes large in a transistor for retaining the potential of the terminal Ti of the circuit BSPRa (the circuit BSPRb), the potential of the terminal Ti remains a fixed potential supplied from the circuit FBa (the circuit FBb). In addition, when a noise signal is input to the terminal Ti, the potential of the terminal Ti remains a fixed potential supplied from the circuit FBa (the circuit FBb). Thus, the potential of the terminal To of the circuit BSPRa (the circuit BSPRb) does not change due to the above-described factors, whereby the potential of the node N is less likely to be affected. Accordingly, the potential output from the terminal To of the circuit BSPRa (the circuit BSPRb) becomes stable.

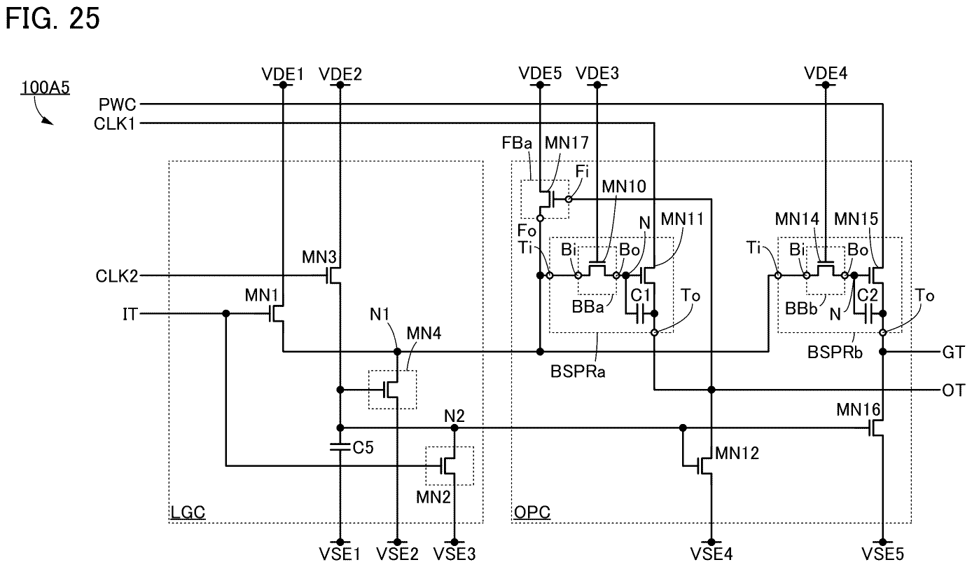

FIG. 25 shows a specific example of the circuit FBa of the circuit 100A4 in FIG. 24. A circuit 100A5 illustrated in FIG. 25 is a structure example of a circuit, which specifically illustrates the circuit FBa of the circuit 100A4 in FIG. 24. The circuit BSPR in FIG. 8A is used as the circuit BSPRa of the circuit 100A5. Note that the circuit FBb is not provided in the structure example of the circuit 100A5 in FIG. 25.

In the circuit 100A5, the circuit FBa includes a transistor MN17. A gate of the transistor MN17 is electrically connected to the terminal Fi, and a first terminal of the transistor MN17 is electrically connected to the terminal Fo. A second terminal of the transistor MN17 is electrically connected to a wiring VDE5.

Note that the transistor MV in FIG. 6A to FIG. 6C or the transistor MV in FIG. 7A to FIG. 7C is preferably used as the transistor MN17. Depending on the case, the transistor ML in FIG. 3A to FIG. 3C, the transistor ML in FIG. 4A to FIG. 4C, the transistor ML in FIG. 5A to FIG. 5C, or a transistor having another structure may be used as the transistor MN17.

The wiring VDE5 has a function of a wiring for supplying a fixed potential, for example. The fixed potential can be, for example, a high-level potential. Note that a low-level potential, the ground potential, or a negative potential may be used depending on the case. For another example, the wiring VDE5 may have a function of a wiring for supplying a variable potential.

Here, an operation example of the circuit FBa illustrated in FIG. 25 is described. The high-level potential V_{High} is assumed to be input to the second terminal of the transistor MN17 from the wiring VDE5, for example.

### Operation Example of Circuit 100A4

For an operation example of the circuit 100A4, part of the operation shown in the timing chart of the circuit 100A1 in FIG. 16 can be referred to. Thus, in the operation example of the circuit 100A4, differences from the timing chart of the circuit 100A1 are mainly described.

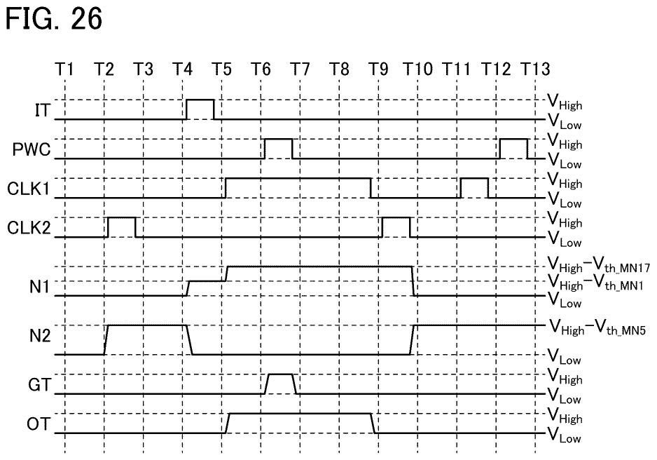

FIG. 26 is a timing chart showing the operation example of the circuit 100A4. The timing chart in FIG. 26 is different from the timing chart in FIG. 16 in the operation in the period from Time T5 to Time T10.

The high-level potential V_{High} is assumed to be input to the second terminal of the transistor MN17 from the wiring VDE5.

In the period from Time T4 to Time T5, the high-level potential V_{High} is input to the terminal IT, whereby the potential of the node N1 becomes V_{High}−V_{th_MN1}, and V_{High}−V_{th_MN1} is input to the terminal Ti of the circuit BSPRa. At this time, the circuit BBa outputs the potential V_{Mid} to the terminal Bo. Thus, V_{Mid} is supplied to the gate of the transistor MN11 (the first terminal of the capacitor C1).

The low-level potential V_{Low} is supplied to the first terminal of the transistor MN11 from the terminal CLK1. At this time, the gate source voltage (the gate-first terminal voltage at this timing) of the transistor MN11 is V_{Mid}−V_{Low}, whereby the transistor MN11 is turned on. Consequently, the terminal CLK1 outputs the low-level potential V_{Low} to the terminal To of the circuit BSPRa through the transistor MN11. That is, the potential of the terminal OT becomes V_{Low}.

Thus, V_{Low}, which is the same as the potential of the terminal To, is input to the terminal Fi of the circuit FBa. In this manner, the low-level potential V_{Low} is supplied to the gate of the transistor MN17.

In addition, the transistor MN17 is normally off and the threshold voltage of the transistor MN17 is set to V_{th_MN17}. The threshold voltage V_{th_MN17} is set to satisfy V_{High}−V_{Low} >V_{th_MN17}.

Here, the gate-source voltage (here, the gate-first terminal voltage) of the transistor MN17 satisfies V_{Low}−V_{High}<V_{th_MN17}; thus, the transistor MN17 is turned off.

The potential supplied to the first terminal of the transistor MN11 from the terminal CLK1 is assumed to change from the low-level potential V_{Low} to the high-level potential V_{High} in the period from Time T5 to Time T6. In addition, the node N is assumed to be brought into a floating state by the circuit BBa. At this time, the gate-source voltage (the gate-second terminal voltage at this timing) of the transistor MN11 is V_{Mid}−V_{Low}, whereby the transistor MN11 is turned on. Consequently, current flows from the terminal CLK1 to the terminal To of the circuit BSPR through the transistor MN11, which renders the potential of the terminal To higher than V_{Low}. Note that since the node N is in a floating state, the capacitive coupling with the capacitor C1 causes an increase in the potential of the node N from V_{Mid} in response to the increase in the potential of the terminal To. Accordingly, the gate-source voltage of the transistor MN11 is retained by the capacitor C1, whereby the potential of the terminal To increases to V_{High}. Ideally, the potential of the node N becomes V_{Mid}+V_{High}−V_{Low}.

At this time, V_{High}, which is the same as the potential of the terminal To (the terminal OT), is input to the terminal Fi of the circuit FBa. In this manner, the high-level potential V_{High} is supplied to the gate of the transistor MN17.

Here, the gate-source voltage of the transistor MN17 (here, the gate-first terminal voltage) is V_{High}−(V_{High}−V_{th_MN1})=V_{th_MN1}, for example. In the case where V_{th_MN1} is higher than V_{th_MN17}, the transistor MN17 is turned on and the potential of the node N1 increases to V_{High}−V_{th_MN17}. When the potential of the node N1 becomes V_{High}−V_{th_MN17}, the transistor MN17 is turned off. In the case where V_{th_MN1} is lower than V_{th_MN17}, the transistor MN17 is normally off and thus the transistor MN17 is in an off state. As the potential of the node N1 at this time, the transistor MN17 is normally off and thus the transistor MN17 is in an off state. Note that FIG. 26 shows the case where V_{th_MN1} is higher than V_{th_MN17}.

In this state, when the potential of the terminal Ti of the circuit BSPRa (the first terminal of the transistor MN17) becomes lower than V_{High}−V_{th_MN17} and the gate-first terminal voltage of the transistor MN17 becomes higher than the threshold voltage, the transistor MN17 is turned on. At this time, electric charge from the wiring VDE5 is accumulated in the terminal Ti of the circuit BSPRa, and the potential of the terminal Ti of the circuit BSPRa increases. Specifically, the transistor MN17 is turned off when the gate-source voltage of the transistor MN17 becomes V_{th_MN17}, thus, the potential of the terminal Ti of the circuit BSPRa (the first terminal of the transistor MN17) at this time returns to V_{High}−V_{th_MN17}.

As described above, in the circuit FBa, when the high-level potential V_{High} is output from the terminal To of the circuit BSPRa and the potential of the terminal Ti of the circuit BSPRa decreases, the circuit FBa can supply the potential V_{High}−V_{th_MN17} to the terminal Ti. Thus, the potential of the terminal Ti is almost kept at V_{High}−V_{th_MN17}, whereby the potential output from the terminal To of the circuit BSPRa becomes stable.

Note that the semiconductor device of one embodiment of the present invention is not limited to the circuit 100A4 illustrated in FIG. 24 and the circuit 100A5 illustrated in FIG. 25. For example, in the circuit 100A5 in FIG. 25, at least one or more of the transistor MN1 to the transistor MN4, the transistor MN10 to the transistor MN12, and the transistor MN14 to the transistor MN17 may be a transistor including a back gate.

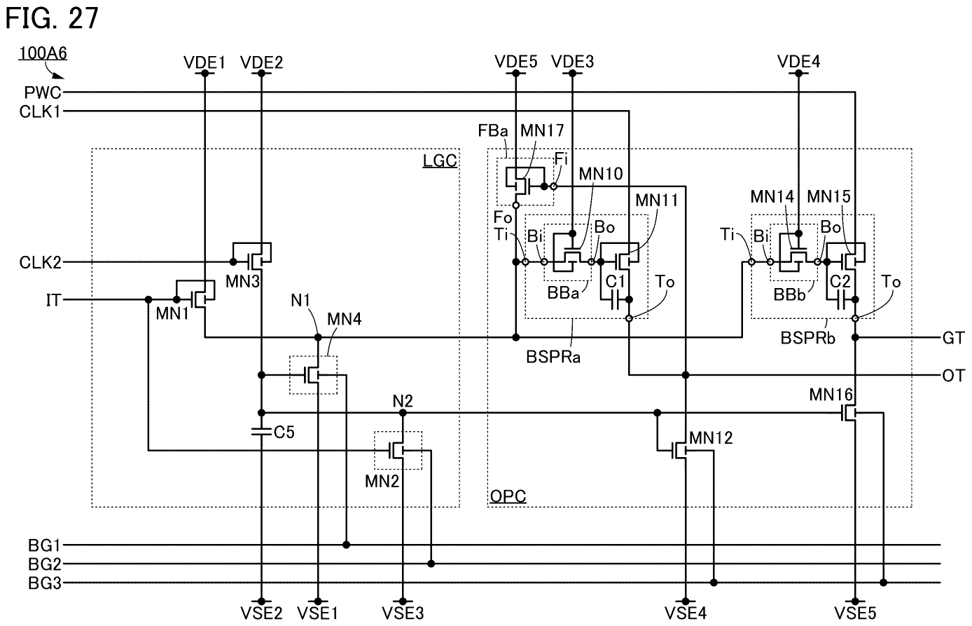

FIG. 27 shows a specific structure example. A circuit 100A6 illustrated in FIG. 27 is a modification example of the circuit 100A5 in FIG. 25 and is different from the circuit 100A5 in that the transistor MN1 to the transistor MN4, the transistor MN10 to the transistor MN12, and the transistor MN14 to the transistor MN17 each include a back gate.

In the circuit 100A6 illustrated in FIG. 27, portions to which the back gates of the transistor MN1 to the transistor MN4, the transistor MN10 to the transistor MN12, and the transistor MN14 to the transistor MN17 are connected are defined clearly.

Note that portions to which the back gates of the transistor MN1 to the transistor MN4, the transistor MN10 to the transistor MN12, and the transistor MN14 to the transistor MN16 are similar to those in the structure of the circuit 100A3 in FIG. 15.

The back gate of the transistor MN17 is electrically connected to the gate of the transistor MN17. Accordingly, the amount of an on-state current of the transistor MN17 can be increased.

With the above structure, the driving speed of the circuit 100A6 can be higher than those of the circuit 100A4 and the circuit 100A5.

### Layout Example of Retention Circuit

Next, an example of a layout diagram (a plan view) of the above-described retention circuit is described.

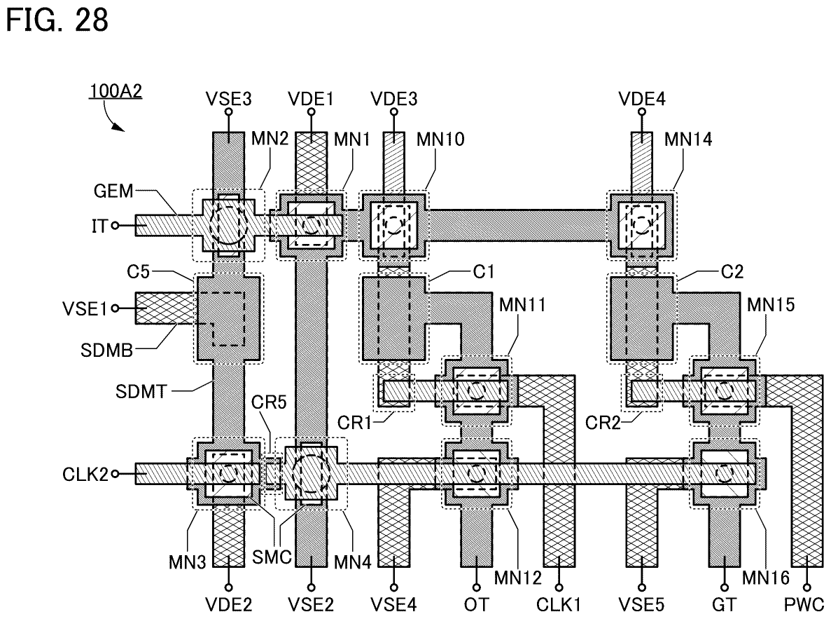

FIG. 28 is a layout diagram of the circuit 100A2 illustrated in FIG. 13. Note that although the back gates of the transistor MN1 to the transistor MN4, the transistor MN10 to the transistor MN12, and the transistor MN14 to the transistor MN16 are not illustrated in the layout diagram of FIG. 28, the back gates may be provided in the layout diagram of FIG. 28.

In FIG. 28, the circuit 100A2 includes a conductive layer GEM, a conductive layer SDMB, a conductive layer SDMT, and a semiconductor layer SMC. Note that an insulating layer included in the circuit 100A2 is not illustrated in FIG. 28.

The semiconductor layer SMC is positioned below the conductive layer GEM, for example. The conductive layer SDMT is positioned below the semiconductor layer SMC, for example. The conductive layer SDMB is positioned below the conductive layer SDMT, for example. That is, in the circuit 100A2 in FIG. 28, the conductive layer SDMB, the conductive layer SDMT, the semiconductor layer SMC, and the conductive layer GEM are formed in this order from the bottom.

Part of the conductive layer GEM functions as the gates (sometimes referred to as first gates) of the transistor MN1 to the transistor MN4, the transistor MN10 to the transistor MN12, and the transistor MN14 to the transistor MN16, for example.

Part of the conductive layer SDMT functions as the source or the drain of each of the transistor MN2 and the transistor MN4, for example.

Part of each of the conductive layer SDMB and the conductive layer SDMT functions as the source or the drain of each of the transistor MN1, the transistor MN3, the transistor MN10 to the transistor MN12, and the transistor MN14 to the transistor MN16.

The conductive layer SDMB, the conductive layer SDMT, the semiconductor layer SMC, and the conductive layer GEM can be formed by a lithography method, for example. Specifically, for example, in the case where the conductive layer GEM is formed, a conductive material to be the conductive layer GEM is formed by one or more methods selected from a sputtering method, a CVD (Chemical Vapor Deposition) method, a PLD (Pulsed Laser Deposition) method, and an ALD (Atomic Layer Deposition) method, and then a desired pattern is formed by a lithography method. The conductive layer SDMB, the conductive layer SDMT, and the semiconductor layer SMC can also be formed in a manner similar to the above.

Furthermore, insulating layers may be provided between the semiconductor layer SMC and the conductive layer GEM, between the conductive layer GEM and the conductive layer SDMT, and between the conductive layer SDMB and the conductive layer SDMT. In particular, an insulator provided between the semiconductor layer SMC and the conductive layer GEM functions as a gate insulating film (sometimes referred to as a first gate insulating film, a front gate insulating film, or the like) in some cases.

In a region CR5 where part of the conductive layer SDMT and part of the conductive layer GEM overlap with each other, electrical continuity is established between the part of the conductive layer SDMT and the part of the conductive layer GEM. That is, in this manner, electrical continuity is established between the conductive layer SDMT included in the transistor MN3 and the gate of the transistor MN4, the gate of the transistor MN12, and the gate of the transistor MN16.

In a region CR1 where part of the conductive layer SDMB and part of the conductive layer GEM overlap with each other, electrical continuity is established between the part of the conductive layer SDMB and the part of the conductive layer GEM. That is, in this manner, electrical continuity is established between the conductive layer SDMB included in the transistor MN10 and the gate of the transistor MN11.

In a region CR2 where part of the conductive layer SDMB and part of the conductive layer GEM overlap with each other, electrical continuity is established between the part of the conductive layer SDMB and the part of the conductive layer GEM. That is, in this manner, electrical continuity is established between the conductive layer SDMB included in the transistor MN14 and the gate of the transistor MN15.

The capacitor C1, the capacitor C2, and the capacitor C5 illustrated in FIG. 28 each include part of the conductive layer SDMB and part of the conductive layer GEM. Specifically, the capacitor C1 includes a region where the part of the conductive layer SDMB and the part of the conductive layer GEM overlap with each other, for example. That is, in the capacitor C1, the part of the conductive layer SDMB functions as one of a pair of electrodes, and the part of the conductive layer GEM functions as the other of the pair of electrodes. Note that also in each of the capacitor C2 and the capacitor C5, the part of the conductive layer SDMB functions as one of a pair of electrodes, and the part of the conductive layer GEM functions as the other of the pair of electrodes, as in the capacitor C1.

Note that the layout diagram of the display apparatus of one embodiment of the present invention is not limited to FIG. 28. The layout diagram of the display apparatus of one embodiment of the present invention may be FIG. 28 on which some modification is performed as appropriate.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 3

In this embodiment, circuit structures applicable to the pixel circuit PX described in Embodiment 1 above are described.

### Structure Example 1 of Pixel Circuit

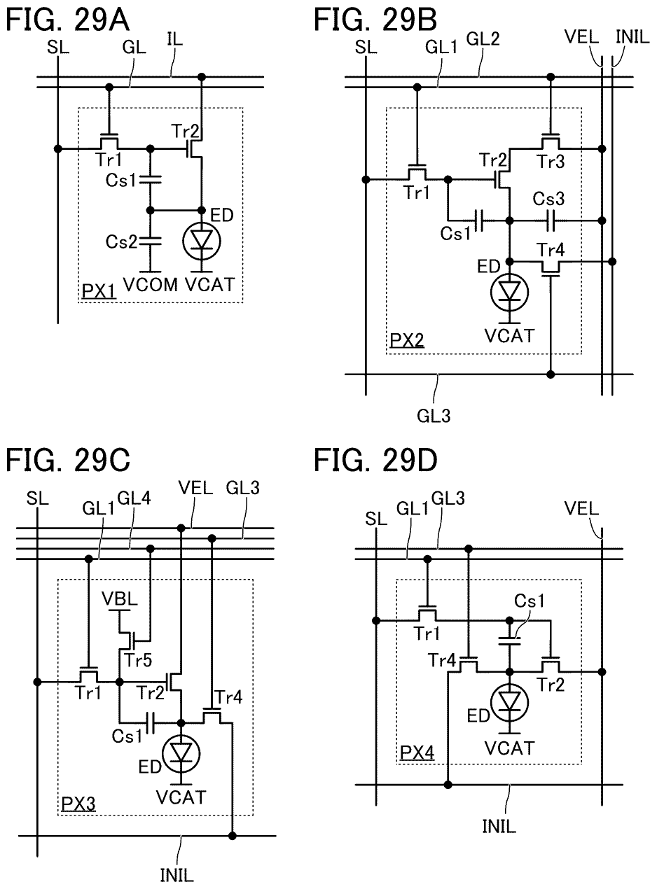

FIG. 29A is a circuit diagram showing a structure example of a circuit that can be used as the pixel circuit PX of the display apparatus DSP in FIG. 10 described in Embodiment 1.

A pixel circuit PX1 illustrated in FIG. 29A includes a transistor Tr1, a transistor Tr2, a capacitor Cs1, a capacitor Cs2, and a light-emitting device ED, for example.

Examples of the light-emitting device ED include a light-emitting device containing an organic EL material, a light-emitting device containing an inorganic EL material, and a light-emitting diode (e.g., a micro LED (Light Emitting Diode)). The pixel circuit PX1 can be a pixel circuit including one or more selected from the light-emitting devices ED described above. Note that in the description in this embodiment, the pixel circuit PX of the pixel array PA includes a light-emitting device containing an organic EL material. In particular, the luminance of light emitted from a light-emitting device capable of high luminance light emission can be, for example, higher than or equal to 500 cd/m², preferably higher than or equal to 1000 cd/m² and lower than or equal to 10000 cd/m², further preferably higher than or equal to 2000 cd/m² and lower than or equal to 5000 cd/m².

A first terminal of the transistor Tr1 is electrically connected to the wiring SL, a second terminal of the transistor Tr1 is electrically connected to a gate of the transistor Tr2 and a first terminal of the capacitor Cs1, and a gate of the transistor Tr1 is electrically connected to the wiring GL. A first terminal of the transistor Tr2 is electrically connected to a wiring IL, and a second terminal of the transistor Tr2 is electrically connected to a second terminal of the capacitor Cs1, a first terminal of the capacitor Cs2, and an anode of the light-emitting device ED. A second terminal of the capacitor Cs2 is electrically connected to a wiring VCOM. A cathode of the light-emitting device ED is electrically connected to a wiring VCAT.

The wiring SL is a wiring corresponding to the wiring SLS[1] to the wiring SLS[n] illustrated in FIG. 10 and the wiring SL[1] to the wiring SL[6] illustrated in FIG. 17 and functions as a wiring for transmitting an image signal from the driver circuit SD to the pixel circuit PX1.

The wiring GL is a wiring corresponding to the wiring GLS[1] to the wiring GLS[m] illustrated in FIG. 10 and the wiring GL[1] to the wiring GL[m] illustrated in FIG. 11A and FIG. 11B and functions as a wiring for transmitting a selection signal from the driver circuit GD to the pixel circuit PX1.

The wiring IL functions as a wiring for supplying a current to the anode of the light-emitting device ED. Thus, the wiring IL is referred to as a current supply line in some cases.

The wiring VCOM functions as a wiring for supplying a fixed potential to the second terminal of the capacitor Cs2. In particular, the fixed potential is referred to as a common potential in some cases. The common potential can be, for example, a low-level potential, the ground potential, or a negative potential. The wiring VCOM may be a wiring for supplying a common potential also to the second terminal of the capacitor Cs2 provided in another pixel circuit PX1 in the same pixel array PA.

The wiring VCAT functions as a wiring for supplying a fixed potential to the cathode of the light-emitting device ED. In particular, the fixed potential is referred to as a cathode potential in some cases. The cathode potential can be, for example, a low-level potential, the ground potential, or a negative potential. The wiring VCAT may be a wiring for supplying a cathode potential also to the cathode of the light-emitting device ED provided in another pixel circuit PX1 in the same pixel array PA.

Note that the common potential supplied by the wiring VCOM and the cathode potential supplied by the wiring VCAT may be potentials equal to each other. In this case, the wiring VCOM and the wiring VCAT may be the same wiring (not illustrated).

The transistor Tr1 functions as a transistor for writing an image signal in the pixel circuit PX. Therefore, in the case where an image signal is desired be retained for a long time, a transistor having a long channel length is preferably used as the transistor Tr1. Specifically, for example, the transistor ML described in the above embodiment is preferably used as the transistor Tr1. Note that in the case where a transistor that can be driven at a high frequency is desired to be used as the transistor Tr1, the transistor MV described in the above embodiment may be used, for example.

The transistor Tr2 functions as a driving transistor for controlling the amount of current flowing between the anode and the cathode of the light-emitting device ED in the pixel circuit PX. Therefore, in the case where a potential corresponding to an image signal is a high potential, a transistor having high resistance to voltage is preferably used as the transistor Tr2. For example, a transistor including a thick gate insulating film is preferably used as the transistor Tr2. Therefore, the transistor ML or MV that includes a thick gate insulating film is preferably used as the transistor Tr2, for example. Note that depending on the case, the transistor ML or MV that includes a thin gate insulating film may be used as the transistor Tr2.

### Structure Example 2 of Pixel Circuit

FIG. 29B is a circuit diagram showing a structure example of a circuit that can be used as the pixel circuit PX of the display apparatus DSP described in Embodiment 1 and is different from the pixel circuit in FIG. 29A.

A pixel circuit PX2 illustrated in FIG. 29B includes the transistor Tr1, the transistor Tr2, a transistor Tr3, a transistor Tr4, the capacitor Cs1, a capacitor Cs3, and the light-emitting device ED, for example.

For the transistor Tr1, the transistor Tr2, the capacitor Cs1, and the light-emitting device ED, the description of the transistor Tr1, the transistor Tr2, the capacitor Cs1, and the light-emitting device ED included in the pixel circuit PX1 can be referred to.

The pixel circuit PX2 not only emits light with an emission intensity corresponding to an input image signal but also has a function of correcting the threshold voltage of the transistor Tr2, which is a driving transistor.

The first terminal of the transistor Tr1 is electrically connected to the wiring SL, the second terminal of the transistor Tr1 is electrically connected to the gate of the transistor Tr2 and the first terminal of the capacitor Cs1, and the gate of the transistor Tr1 is electrically connected to a wiring GL1. The first terminal of the transistor Tr2 is electrically connected to a first terminal of the transistor Tr3, and the second terminal of the transistor Tr2 is electrically connected to the second terminal of the capacitor Cs1, a first terminal of the capacitor Cs3, a first terminal of the transistor Tr4, and the anode of the light-emitting device ED. A second terminal of the transistor Tr3 is electrically connected to a wiring VEL, and a gate of the transistor Tr3 is electrically connected to a wiring GL2. A second terminal of the capacitor Cs3 is electrically connected to the wiring VEL. A second terminal of the transistor Tr4 is electrically connected to a wiring INIL, and a gate of the transistor Tr4 is electrically connected to a wiring GL3. The cathode of the light-emitting device ED is electrically connected to the wiring VCAT.

For the wiring SL and the wiring VCAT, the description of the wiring SL and the wiring VCAT electrically connected to the pixel circuit PX1 in FIG. 29A can be referred to.

The wiring GL1, the wiring GL2, and the wiring GL3 are wirings corresponding to the wiring GLS[1] to the wiring GLS[m] illustrated in FIG. 10, and each function as a wiring for transmitting a selection signal from the driver circuit GD to the pixel circuit PX.

The wiring VEL functions as a wiring for supplying a potential to the anode of the light-emitting device ED.

The wiring INIL functions as a wiring for supplying a potential to the anode of the light-emitting device ED. In particular, the potential can be an initialization potential for resetting the anode potential of the light-emitting device ED, for example.

A transistor having high resistance to gate voltage (voltage between a gate and a source or a drain) is preferably used as each of the transistor Tr3 and the transistor Tr4. For example, a transistor including a thick gate insulating film is preferably used as each of the transistor Tr3 and the transistor Tr4. Specifically, for example, the transistor ML or MV that includes the thick gate insulating film is preferably used as each of the transistor Tr3 and the transistor Tr4. Note that in the case where a transistor having a low leakage current is desired to be used as the transistor Tr3 or the transistor Tr4, the transistor ML described in the above embodiment may be used, for example. In the case where a transistor having a high driving frequency is desired to be used as the transistor Tr3 or the transistor Tr4, the transistor MV described in the above embodiment may be used, for example.

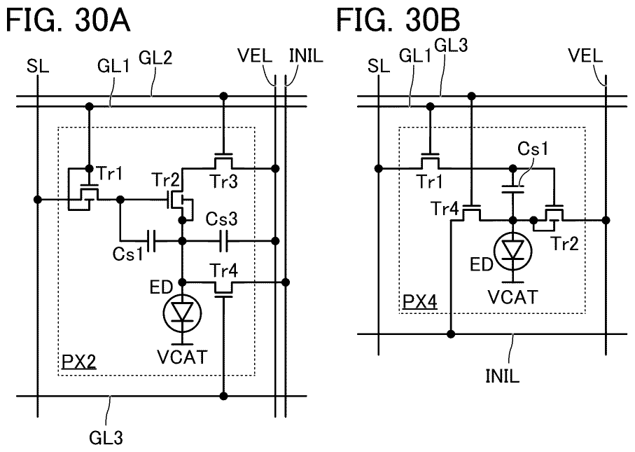

In the pixel circuit PX2, the transistor Tr1 and the transistor Tr2 may each be a transistor including a back gate. Specifically, as illustrated in FIG. 30A, the pixel circuit PX2 may have a structure in which the back gate of the transistor Tr1 is electrically connected to the gate of the transistor Tr1, and the back gate of the transistor Tr2 is electrically connected to the second terminal of the transistor Tr2. In that case, the transistor ML including a back gate electrode and described in the above embodiment is preferably used as the transistor Tr1, for example. In addition, the transistor ML including the back gate electrode and described in the above embodiment is preferably used as the transistor Tr2, for example.

### Structure Example 3 of Pixel Circuit

FIG. 29C is a circuit diagram showing a structure example of a circuit that can be used as the pixel circuit PX of the display apparatus DSP described in Embodiment 1 and is different from the pixel circuits in FIG. 29A and FIG. 29B.

A pixel circuit PX3 illustrated in FIG. 29C includes the transistor Tr1, the transistor Tr2, the transistor Tr4, a transistor Tr5, the capacitor Cs1, and the light-emitting device ED, for example.

For the transistor Tr1, the transistor Tr2, the transistor Tr4, the capacitor Cs1, and the light-emitting device ED, the description of the transistor Tr1, the transistor Tr2, the transistor Tr4, the capacitor Cs1, and the light-emitting device ED included in the pixel circuit PX2 can be referred to.

Like the pixel circuit PX2, the pixel circuit PX3 not only emits light with an emission intensity corresponding to an input image signal but also has a function of correcting the threshold voltage of the transistor Tr2, which is a driving transistor.

The first terminal of the transistor Tr1 is electrically connected to the wiring SL, the second terminal of the transistor Tr1 is electrically connected to the gate of the transistor Tr2, a first terminal of the transistor Tr5, and the first terminal of the capacitor Cs1, and the gate of the transistor Tr1 is electrically connected to the wiring GL1. The first terminal of the transistor Tr2 is electrically connected to the wiring VEL, and the second terminal of the transistor Tr2 is electrically connected to the second terminal of the capacitor Cs1, the first terminal of the transistor Tr4, and the anode of the light-emitting device ED. A second terminal of the transistor Tr5 is electrically connected to a wiring VBL, and a gate of the transistor Tr5 is electrically connected to a wiring GL4. The second terminal of the transistor Tr4 is electrically connected to the wiring INIL, and the gate of the transistor Tr4 is electrically connected to the wiring GL3. The cathode of the light-emitting device ED is electrically connected to the wiring VCAT.

For the wiring SL, the wiring VCAT, the wiring VEL, and the wiring INIL, the description of the wiring SL, the wiring VCAT, the wiring VEL, and the wiring INIL that are electrically connected to the pixel circuit PX2 in FIG. 29B can be referred to.

The wiring GL1, the wiring GL3, and the wiring GL4 are wirings corresponding to the wiring GLS[1] to the wiring GLS[m] illustrated in FIG. 10, and each function as a wiring for transmitting a selection signal from the driver circuit GD to the pixel circuit PX.

The wiring VBL functions as a wiring for supplying a fixed potential to the first terminal of the capacitor Cs1. The fixed potential is, for example, a potential input to the gate of the transistor Tr2 in correction of the threshold voltage of the transistor Tr2, and is preferably substantially equal to a potential supplied by the wiring VEL.

A transistor having high resistance to voltage is preferably used as the transistor Tr5. For example, a transistor including a thick gate insulating film is preferably used as the transistor Tr5. Specifically, for example, the transistor ML or MV that includes the thick gate insulating film is preferably used as the transistor Tr5. Note that in the case where a transistor having a high driving frequency is desired to be used as the transistor Tr5, the transistor MV described in the above embodiment may be used, for example. In the case where a transistor having a low leakage current is desired to be used as the transistor Tr5, the transistor ML described in the above embodiment may be used, for example.

### Structure Example 4 of Pixel Circuit

FIG. 29D is a circuit diagram showing a structure example of a circuit that can be used as the pixel circuit PX of the display apparatus DSP described in Embodiment 1 and is different from the pixel circuits in FIG. 29A to FIG. 29C.

A pixel circuit PX4 illustrated in FIG. 29D includes the transistor Tr1, the transistor Tr2, the transistor Tr4, the capacitor Cs1, and the light-emitting device ED, for example.

For the transistor Tr1, the transistor Tr2, the transistor Tr4, the capacitor Cs1, and the light-emitting device ED, the description of the transistor Tr1, the transistor Tr2, the transistor Tr4, the capacitor Cs1, and the light-emitting device ED included in the pixel circuit PX3 can be referred to.

Like the pixel circuit PX1, the pixel circuit PX4 also has a function of emitting light with an emission intensity corresponding to an input image signal.

The first terminal of the transistor Tr1 is electrically connected to the wiring SL, the second terminal of the transistor Tr1 is electrically connected to the gate of the transistor Tr2 and the first terminal of the capacitor Cs1, and the gate of the transistor Tr1 is electrically connected to the wiring GL1. The first terminal of the transistor Tr2 is electrically connected to the wiring VEL, and the second terminal of the transistor Tr2 is electrically connected to the second terminal of the capacitor Cs1, the first terminal of the transistor Tr4, and the anode of the light-emitting device ED. The second terminal of the transistor Tr4 is electrically connected to the wiring INIL, and the gate of the transistor Tr4 is electrically connected to the wiring GL3. The cathode of the light-emitting device ED is electrically connected to the wiring VCAT.

For the wiring SL, the wiring VCAT, the wiring INIL, the wiring GL1, and the wiring GL3, the description of the wiring SL and the wiring VCAT electrically connected to the pixel circuit PX3 in FIG. 29C can be referred to.

In the pixel circuit PX4, the transistor Tr2 may be a transistor including a back gate. Specifically, as illustrated in FIG. 30B, the pixel circuit PX4 may have a structure in which the back gate of the transistor Tr2 is electrically connected to the second terminal of the transistor Tr2. In that case, the transistor ML including the back gate electrode and described in the above embodiment is preferably used as the transistor Tr2, for example.

### Structure Example 5 of Pixel Circuit

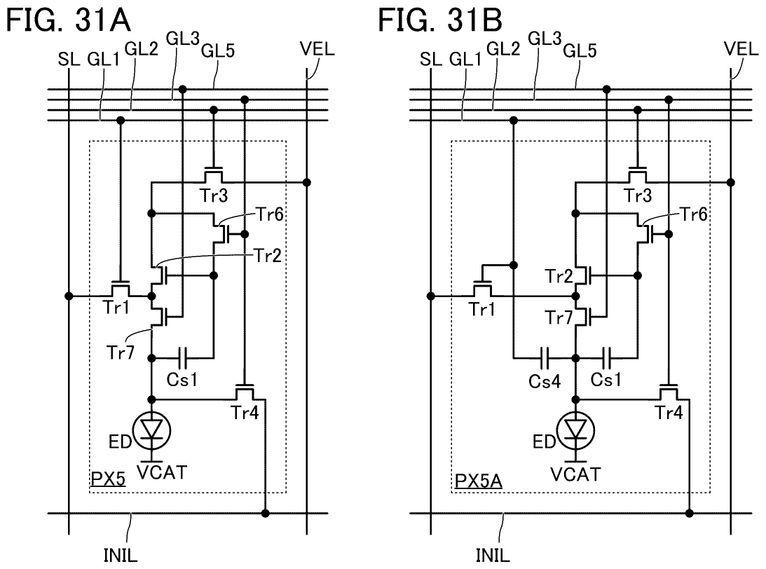

FIG. 31A is a circuit diagram showing a structure example of a circuit that can be used as the pixel circuit PX of the display apparatus DSP described in Embodiment 1 and is different from the pixel circuits in FIG. 29A to FIG. 29D.

A pixel circuit PX5 illustrated in FIG. 31A includes the transistor Tr1 to the transistor Tr4, a transistor Tr6, a transistor Tr7, the capacitor Cs1, and the light-emitting device ED, for example.

For the transistor Tr1 to the transistor Tr4, the capacitor Cs1, and the light-emitting device ED, the description of the transistor Tr1 to the transistor Tr4, the capacitor Cs1, and the light-emitting device ED included in the pixel circuit PX2 can be referred to.

Like the pixel circuit PX2 and the pixel circuit PX3, the pixel circuit PX5 not only emits light with an emission intensity corresponding to an input image signal but also has a function of correcting the threshold voltage of the transistor Tr2, which is a driving transistor.

The first terminal of the transistor Tr1 is electrically connected to the wiring SL, the second terminal of the transistor Tr1 is electrically connected to the first terminal of the transistor Tr2 and a first terminal of the transistor Tr7, and the gate of the transistor Tr1 is electrically connected to the wiring GL1. The second terminal of the transistor Tr2 is electrically connected to the first terminal of the transistor Tr3 and a first terminal of the transistor Tr6, and the gate of the transistor Tr2 is electrically connected to a second terminal of the transistor Tr6 and the first terminal of the capacitor Cs1. The second terminal of the transistor Tr3 is electrically connected to the wiring VEL, and the gate of the transistor Tr3 is electrically connected to the wiring GL2. A gate of the transistor Tr6 is electrically connected to the gate of the transistor Tr4 and the wiring GL3. A second terminal of the transistor Tr7 is electrically connected to the first terminal of the transistor Tr4, the second terminal of the capacitor Cs1, and the anode of the light-emitting device ED. The second terminal of the transistor Tr4 is electrically connected to the wiring INIL. The cathode of the light-emitting device ED is electrically connected to the wiring VCAT.

For the wiring SL, the wiring VCAT, the wiring VEL, and the wiring INIL, the description of the wiring SL, the wiring VCAT, the wiring VEL, and the wiring INIL that are electrically connected to the pixel circuit PX2 in FIG. 29B can be referred to.

The wiring GL1, the wiring GL2, the wiring GL3, and the wiring GL5 are wirings corresponding to the wiring GLS[1] to the wiring GLS[m] illustrated in FIG. 10, and each function as a wiring for transmitting a selection signal from the driver circuit GD to the pixel circuit PX.

A transistor having high resistance to voltage is preferably used as each of the transistor Tr6 and the transistor Tr7. For example, a transistor including a thick gate insulating film is preferably used as each of the transistor Tr6 and the transistor Tr7. Specifically, for example, the transistor ML or MV that includes the thick gate insulating film is preferably used as each of the transistor Tr6 and the transistor Tr7. Note that in the case where a transistor having a high driving frequency is desired to be used as each of the transistor Tr6 and the transistor Tr7, the transistor MV described in the above embodiment may be used, for example. In the case where a transistor having a low leakage current is desired to be used as each of the transistor Tr6 and the transistor Tr7, the transistor ML described in the above embodiment may be used, for example.

Note that the pixel circuit of the semiconductor device of one embodiment of the present invention is not limited to having the structure of the pixel circuit PX5 illustrated in FIG. 31A, and may have a circuit structure modified from that of the pixel circuit PX5 as appropriate.

For example, like a pixel circuit PX5A illustrated in FIG. 31B, the pixel circuit PX5 in FIG. 31A may be provided with a capacitor Cs4. A first terminal of the capacitor Cs4 is electrically connected to the gate of the transistor Tr1 and the wiring GL1, and a second terminal of the capacitor Cs4 is electrically connected to the first terminal of the transistor Tr4, the second terminal of the transistor Tr7, the second terminal of the capacitor Cs1, and the anode of the light-emitting device ED.

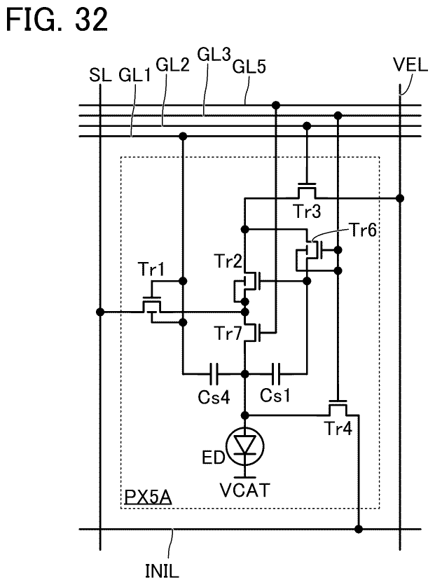

In the pixel circuit PX5A, the transistor Tr1, the transistor Tr2, and the transistor Tr6 may each be a transistor including a back gate. Specifically, as illustrated in FIG. 32, the pixel circuit PX5A may have a structure in which the back gate of the transistor Tr1 is electrically connected to the gate of the transistor Tr1, the back gate of the transistor Tr2 is electrically connected to the second terminal of the transistor Tr2, and the back gate of the transistor Tr6 is electrically connected to the gate of the transistor Tr6. In that case, the transistor ML including the back gate electrode and described in the above embodiment is preferably used as the transistor Tr1, for example. In addition, the transistor ML including the back gate electrode and described in the above embodiment is preferably used as each of the transistor Tr2 and the transistor Tr6, for example.

### Structure Example 6 of Pixel Circuit

In Structure example 1 of pixel circuit to Structure example 5 of pixel circuit above, the structure examples of the pixel circuit PX including the light-emitting device ED are described; for another example, the pixel circuit PX provided in the display apparatus DSP described in Embodiment 1 above may include a liquid crystal display device.

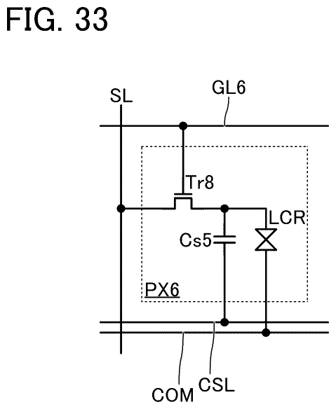

A pixel circuit PX6 illustrated in FIG. 33 is a pixel circuit that can be used as the pixel circuit PX described in Embodiment 1 above and is different from the pixel circuit PX1 to the pixel circuit PX5 and the pixel circuit PX5A in including a liquid crystal display device LCR.

The pixel circuit PX6 includes a transistor Tr8, a capacitor Cs5, and the liquid crystal display device LCR, for example.

A first terminal of the transistor Tr8 is electrically connected to a first terminal of the capacitor Cs5 and a first terminal of the liquid crystal display device LCR, a second terminal of the transistor Tr8 is electrically connected to the wiring SL, and a gate of the transistor Tr8 is electrically connected to a wiring GL6. A second terminal of the capacitor Cs5 is electrically connected to a wiring CSL. A second terminal of the liquid crystal display device LCR is electrically connected to a wiring COM.

The wiring SL is a wiring corresponding to the wiring SLS[1] to the wiring SLS[n] illustrated in FIG. 10 and the wiring SL[1] to the wiring SL[6] illustrated in FIG. 17 and functions as a wiring for transmitting an image signal from the driver circuit SD to the pixel circuit PX6.

The wiring GL6 is a wiring corresponding to the wiring GLS[1] to the wiring GLS[m] illustrated in FIG. 10 and the wiring GL[1] to the wiring GL[m] illustrated in FIG. 11A and FIG. 11B and functions as a wiring for transmitting a selection signal from the driver circuit GD to the pixel circuit PX6.

The wiring CSL functions as a wiring for supplying a fixed potential to the second terminal of the capacitor Cs5. The fixed potential can be, for example, a low-level potential, the ground potential, or a negative potential. The wiring CSL may be a wiring for supplying a common potential also to the second terminal of the capacitor Cs2 provided in another pixel circuit PX1 in the same pixel array PA.

The wiring COM functions as a wiring for supplying a fixed potential to the second terminal of the liquid crystal display device LCR. In particular, the fixed potential is referred to as a common potential in some cases. The common potential can be, for example, a low-level potential, the ground potential, or a negative potential. The wiring COM may be a wiring for supplying a common potential also to the second terminal of the liquid crystal display device LCR provided in another pixel circuit PX6 in the same pixel array PA.

Note that the fixed potential supplied by the wiring CSL and the common potential supplied by the wiring COM may be potentials equal to each other. In this case, the wiring CSL and the wiring COM may be the same wiring (not illustrated).

The transistor Tr8 functions as a transistor for writing an image signal in the pixel circuit PX6. Therefore, in the case where an image signal is desired be retained for a long time, a transistor having a long channel length is preferably used as the transistor Tr8. Specifically, for example, the transistor ML described in the above embodiment is preferably used as the transistor Tr8. Note that in the case where a transistor having a high driving frequency is desired to be used as the transistor Tr1, the transistor MV described in the above embodiment may be used, for example.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 4

In this embodiment, a method for concurrently manufacturing the transistor ML in FIG. 3A to FIG. 3C and the transistor MV in FIG. 7A to FIG. 7C, which are described in the above embodiment, will be described.

### Manufacturing Method Example

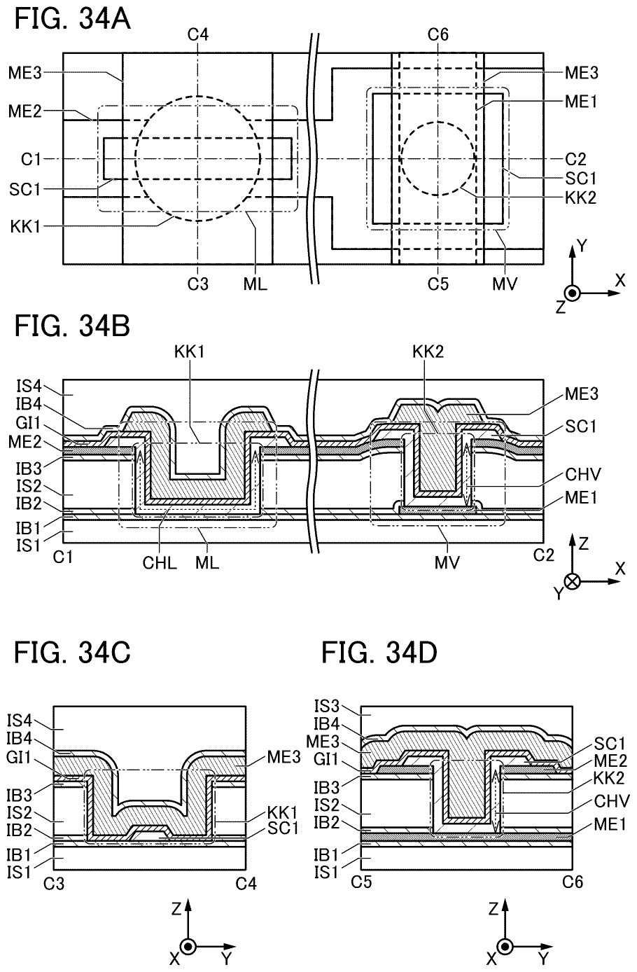

An example of the method for manufacturing the transistor ML in FIG. 3A to FIG. 3C and the transistor MV in FIG. 7A to FIG. 7C is described with reference to FIG. 34A to FIG. 46D.

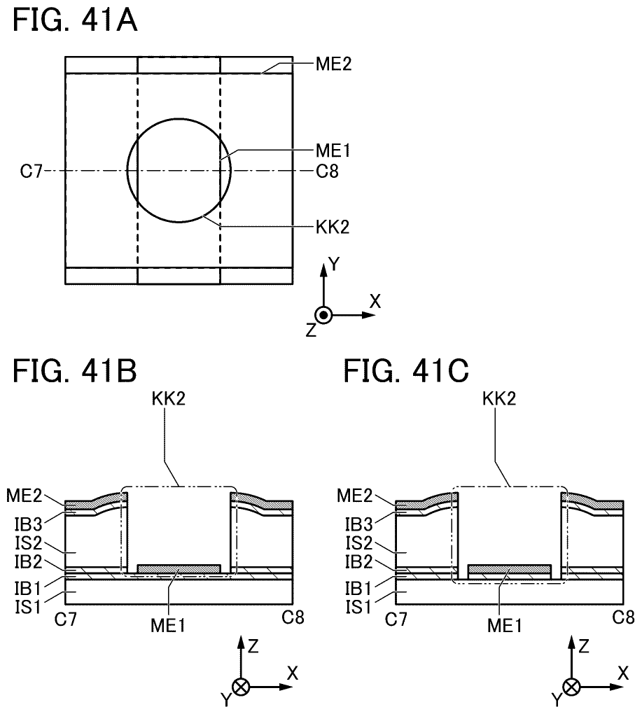

In each of FIG. 34A to FIG. 40D and FIG. 42A to FIG. 46D, A is a schematic plan view. Moreover, B of each drawing is a schematic cross-sectional view corresponding to a portion along the dashed-dotted line C1-C2 illustrated in A of the corresponding drawing, and is also a schematic cross-sectional view in the X direction. Furthermore, C of each drawing is a schematic cross-sectional view corresponding to a portion along the dashed-dotted line C3-C4 illustrated in A of the corresponding drawing, and is also a schematic cross-sectional view in the Y direction. Furthermore, D of each drawing is a schematic cross-sectional view corresponding to a portion along the dashed-dotted line C5-C6 illustrated in A of the corresponding drawing, and is also a schematic cross-sectional view in the Y direction. FIG. 41A is a schematic plan view, and FIG. 41B and FIG. 41C are each a schematic cross-sectional view corresponding to a portion along the dashed-dotted line C7-C8 illustrated in FIG. 41A. Note that for clarity of the drawing, some components are not illustrated in the schematic plan view of A of each drawing.

Hereinafter, a film of an insulating material for forming an insulating layer, a film of a conductive material for forming a conductive layer, or a film of a semiconductor material for forming a semiconductor can be formed by a film formation method such as a sputtering method, a CVD (Chemical Vapor Deposition) method, an MBE (Molecular Beam Epitaxy) method, a PLD (Pulsed Laser Depositon) method, or an ALD (Atomic Layer Deposition) method as appropriate.

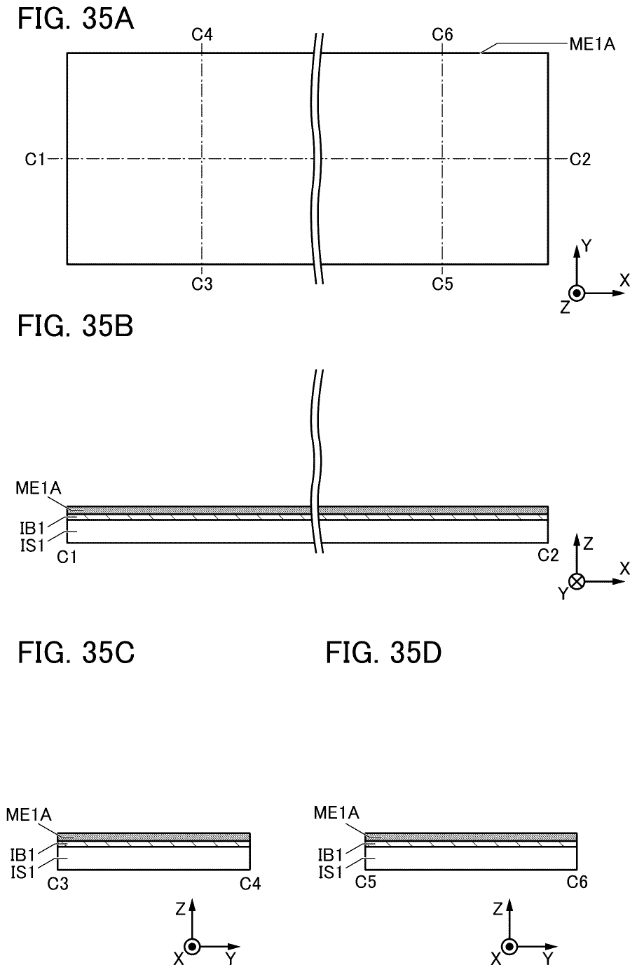

First, a substrate (not illustrated) is prepared, and the insulating layer IS1, the insulating layer IB1, and a conductive film ME1A are formed in this order over the substrate (see FIG. 35A to FIG. 35D).

As the substrate, a single crystal substrate (e.g., a semiconductor substrate containing silicon or germanium as a material) can be used, for example. Besides the single crystal substrate, for example, an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, or paper or a base material film containing a fibrous material can be used as the substrate. Examples of the glass substrate include barium borosilicate glass, aluminoborosilicate glass, and soda lime glass. As examples of the flexible substrate, the attachment film, and the base material film, the following is given. Examples include plastics typified by polyethylene terephthalate (PET), polyethylene naphthalate (PEN), polyethersulfone (PES), and polytetrafluoroethylene (PTFE). Another example is a synthetic resin such as an acrylic resin. Other examples include polypropylene, polyester, polyvinyl fluoride, and polyvinyl chloride. Other examples include polyamide, polyimide, aramid, an epoxy resin, an inorganic vapor deposition film, and paper. Note that in the case where the manufacturing process of the display apparatus DSP in Embodiment 1 involves heat treatment, a highly heat-resistant substrate is preferably selected as the substrate. Alternatively, these substrates provided with elements may be used. Examples of the element provided for the substrate include a capacitor, a resistor, a switching element, a light-emitting element, and a storage element.

The insulating layer IS1 functions as an interlayer film, for example. For the insulating layer IS1 functioning as an interlayer film, silicon oxide, silicon oxynitride, silicon nitride oxide, or silicon nitride can be used, for example. Alternatively, for the insulating layer IS1, silicon oxide to which fluorine is added, silicon oxide to which carbon is added, silicon oxide to which carbon and nitrogen are added, or porous silicon oxide can be used, for example. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Alternatively, for the insulating layer IS1, a resin can be used, for example. A material used for the insulating layer IS1 may be an appropriate combination of the above-described insulating materials. The insulating layer IS1 may be a single layer or have a stacked-layer structure obtained by sequentially forming two or more layers of insulating materials.

An insulating material with a low relative permittivity is preferably used for the insulating layer IS1. When an insulating material with a low relative permittivity is used for an interlayer film, parasitic capacitance generated between wirings can be reduced. Specifically, the relative permittivity of the insulating layer IS1 is preferably lower than 4, further preferably lower than 3, for example. Examples of an insulating material with a low relative permittivity include silicon oxide, silicon oxynitride, and silicon nitride oxide.

The insulating layer IB1 preferably functions as, for example, a barrier insulating film that inhibits entry of impurities such as water, hydrogen, nitrogen, and oxygen contained in the insulating layer IS1 into the conductive layer ME1 and the semiconductor layer SC1 that are to be formed later.

Accordingly, it is preferable to use, for the insulating layer IB1, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (an insulating material through which the impurities are unlikely to pass). Alternatively, it is preferable to use an insulating material having a function of inhibiting diffusion of oxygen (e.g., one or both of an oxygen atom and an oxygen molecule) (an insulating material through which the oxygen is unlikely to pass).

An insulator having a function of inhibiting the passage of oxygen and impurities such as water and hydrogen can be formed to have a single layer or a stacked layer including an insulator containing one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum, for example. Specific examples of the insulator having a function of inhibiting the passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulator having a function of inhibiting the passage of oxygen and impurities such as water and hydrogen include oxides containing aluminum and hafnium (hafnium aluminate). Other examples of the insulator having a function of inhibiting the passage of oxygen and impurities such as water and hydrogen include metal nitrides such as aluminum nitride, aluminum titanium nitride, titanium nitride, silicon nitride oxide, and silicon nitride.

In particular, aluminum oxide or silicon nitride is preferably used for the insulating layer IB1. Accordingly, it is possible to inhibit diffusion of impurities such as water and hydrogen into the transistor ML and the transistor MV from below an insulator IB1, for example.

The insulating layer IB1 may be a single layer or have a stacked-layer structure obtained by sequentially forming two or more layers of insulating materials.

As a method for forming the insulating layer IB1, for example, a method such as a sputtering method, a CVD method, an MBE method, a PLD method, or an ALD method is employed.

The conductive film ME1A is a film to be the conductive layer ME1 in a later step. Part of the conductive layer ME1 functions also as one of the source electrode and the drain electrode of the transistor MV. Therefore, a material having high conductivity is preferably used for the conductive film ME1A.

For the conductive film ME1A, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing two or more selected from the above metal elements; or an alloy containing a combination of two or more selected from the above metal elements, for example. Alternatively, for the conductive film ME1A, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, or an oxide containing lanthanum and nickel, for example. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. As the conductor, a semiconductor having high electrical conductivity, typified by polycrystalline silicon containing an impurity element (e.g., phosphorus or arsenic), or silicide (e.g., nickel silicide) may be used, for example.

A stack of a plurality of conductive films formed of the above-described materials may be used. For example, a stacked-layer structure combining a material containing the above metal element and a conductive material containing oxygen may be employed. Alternatively, a stacked-layer structure combining a material containing the above metal element and a conductive material containing nitrogen may be employed. A stacked-layer structure combining a material containing the above metal element, a conductive material containing oxygen, and a conductive material containing nitrogen may be employed.

The conductive layer ME1 may include, for example, a first conductor and a second conductor surrounded by the first conductor (not illustrated). For the first conductor, any of titanium, titanium nitride, tantalum, tantalum nitride, ruthenium, and ruthenium oxide, which are conductive materials having a function of inhibiting diffusion of oxygen, may be used, and for the second conductor, a conductive material containing any of tungsten, copper, and aluminum, which have high conductivity, as its main component may be used. When the second conductor is surrounded by the first conductor, a reduction in conductivity due to oxidation of the first conductor can be prevented.

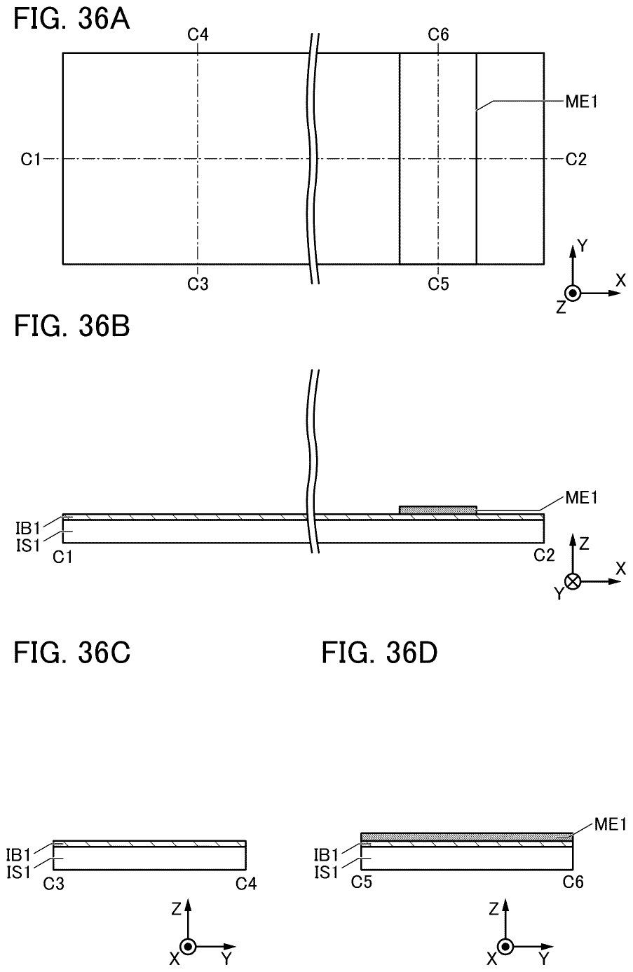

Next, the conductive film ME1A is processed into a band shape by a lithography method to form the conductive layer ME1 (see FIG. 36A to FIG. 36D). In particular, here, the conductive layer ME1 is formed so as to extend in a direction parallel to the dashed-dotted line C5-C6 (the +Y direction and the −Y direction). A dry etching method or a wet etching method can be employed for the processing, and processing by a dry etching method is particularly suitable for microfabrication.

Note that in a lithography method, first, a resist is exposed to light through a mask. Next, a region exposed to light is removed or left using a developing solution, so that a resist mask is formed. Then, etching treatment through the resist mask is performed, whereby a conductor, a semiconductor, an insulator, or the like can be processed into a desired shape. The resist mask is formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. The resist mask can be removed by dry etching treatment such as ashing, wet etching treatment, wet etching treatment after dry etching treatment, or dry etching treatment after wet etching treatment.

In addition, a hard mask formed of an insulator or a conductor may be used under the resist mask. In the case of using a hard mask, a hard mask with a desired shape can be formed in the following manner: an insulating film or a conductive film that is the hard mask material is formed over the conductive film ME1A, a resist mask is formed thereover, and then the hard mask material is etched. The etching of the conductive film ME1A and the like may be performed after removing the resist mask or with the resist mask remaining. In the latter case, the resist mask sometimes disappears during the etching. The hard mask may be removed by etching after the etching of the conductive film ME1A and the like. Meanwhile, the hard mask is not necessarily removed in the case where the hard mask material does not affect later steps or can be utilized in later steps.

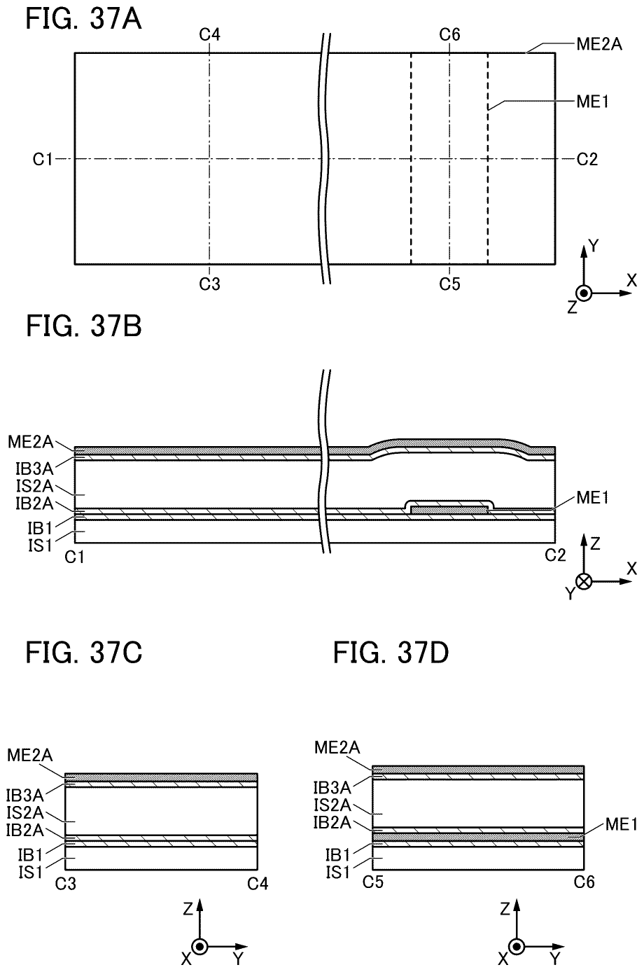

Next, an insulating film IB2A, an insulating film IS2A, an insulating film IB3A, and a conductive film ME2A are formed in this order over the conductive layer ME1 (see FIG. 37A to FIG. 37D). The insulating film IB2A, the insulating film IS2A, the insulating film IB3A, and the conductive film ME2A can each be formed by a film formation method such as a sputtering method, a CVD method, an MBE method, a PLD method, or an ALD method, for example.

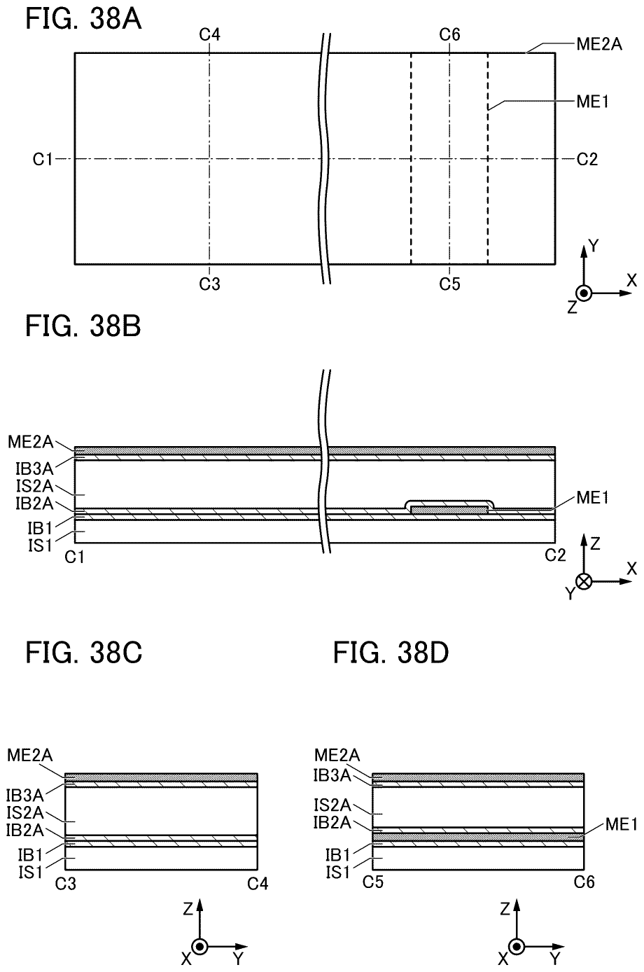

After the insulating film IS2A is formed (before the insulating film IB3A is formed), planarization treatment may be performed on the insulating film IS2A by a chemical mechanical polishing (CMP) method or the like to planarize the top surface of the insulating film IS2A (see FIG. 38A to FIG. 38D).

The insulating film IB2A is a film to be the insulating layer IB2 in a later step. Like the insulating layer IB1, the insulating layer IB2 preferably functions as, for example, a barrier insulating film that inhibits entry of impurities such as water, hydrogen, nitrogen, and oxygen contained in the insulating layer IS2 to be formed later into the conductive layer ME1. Thus, for the insulating layer IB2, a material or a structure that can be used for the insulating layer IB1 can be used.

The insulating film IS2A is a film to be the insulating layer IS2 in a later step. The insulating layer IS2 functions as an interlayer film, for example. Thus, the insulating layer IS2 preferably contains an insulating material with a low relative permittivity. When an insulating material with a low relative permittivity is used for an interlayer film, parasitic capacitance generated between wirings can be reduced.

The insulating film IS2A may be a single layer or have a stacked-layer structure obtained by sequentially forming two or more layers of insulating materials.

For the insulating film IS2A, a material that can be used for the insulating layer IS1 can be used, for example. In particular, in the case where the semiconductor layer SC1 formed in a later step is a metal oxide functioning as an oxide semiconductor, any of silicon oxide, silicon oxynitride, and porous silicon oxide is preferably used for the insulating film IS2A, for example. With these materials, a region containing oxygen released by heating can be easily formed, and the released oxygen can be supplied to the metal oxide. This reduces the carrier concentration of the metal oxide at the interface between the semiconductor layer SC1 and the insulating layer IS2 in contact with each other and the vicinity of the interface, so that the interface and the vicinity of the interface in the semiconductor layer SC1 become i-type or substantially i-type. Accordingly, the interface and the vicinity of the interface in the semiconductor layer SC1 function as the channel formation region in the transistor ML or the transistor MV.

The insulating film IB3A is a film to be the insulating layer IB3 in a later step. Like the insulating layer IB1 and the insulating layer IB2, the insulating layer IB3 preferably functions as, for example, a barrier insulating film that inhibits entry of impurities such as water, hydrogen, nitrogen, and oxygen contained in the insulating layer IS2 to be formed later into the conductive layer ME2 to be formed later. Thus, for the insulating layer IB3, a material or a structure that can be used for the insulating layer IB1 or the insulating layer IB2 can be used.

The conductive film ME2A is a film to be the conductive layer ME2 in a later step. Part of the conductive layer ME2 functions also as the other of the source electrode and the drain electrode of the transistor MV. Another part of the conductor ME2 functions also as the source electrode of the transistor ML. Another part of the conductor ME2 functions also as the drain electrode of the transistor ML. Therefore, a material having high conductivity is preferably used for the conductive film ME2A.

For the conductive film ME2A, a material or a structure that can be used for the conductive layer ME1 can be used, for example.

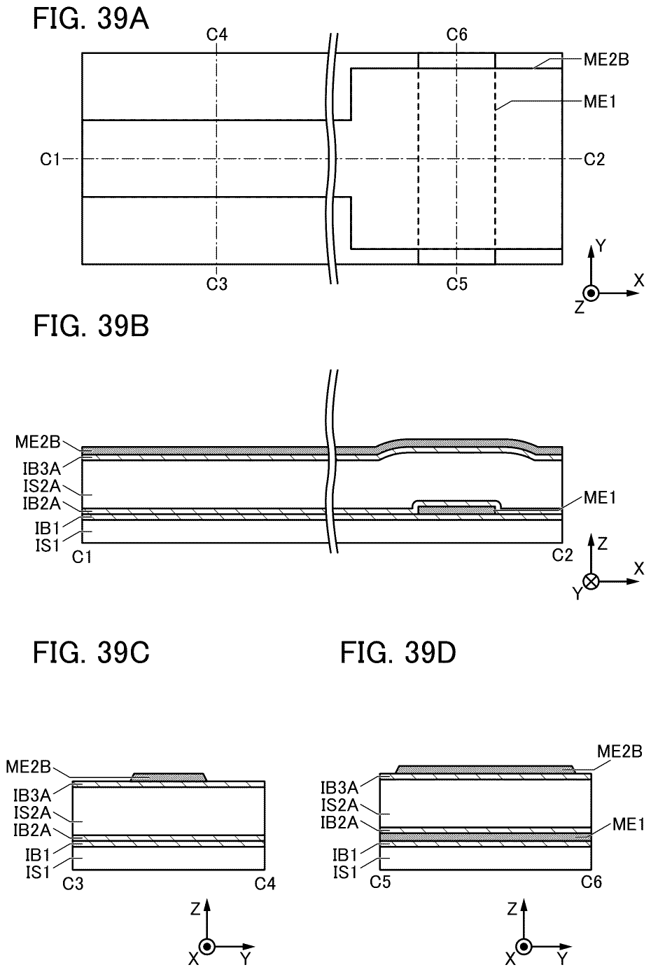

Next, the conductive film ME2A is processed into a band shape by a lithography method to form a conductive film ME2B (see FIG. 39A to FIG. 39D). In particular, here, the conductive film ME2B is formed so as to extend in a direction parallel to the dashed-dotted line C1-C2 (the +X direction and the −X direction) and include a region overlapping with part of the conductive layer ME1. For the lithography method, the lithography method described with reference to FIG. 36A to FIG. 36D can be referred to.

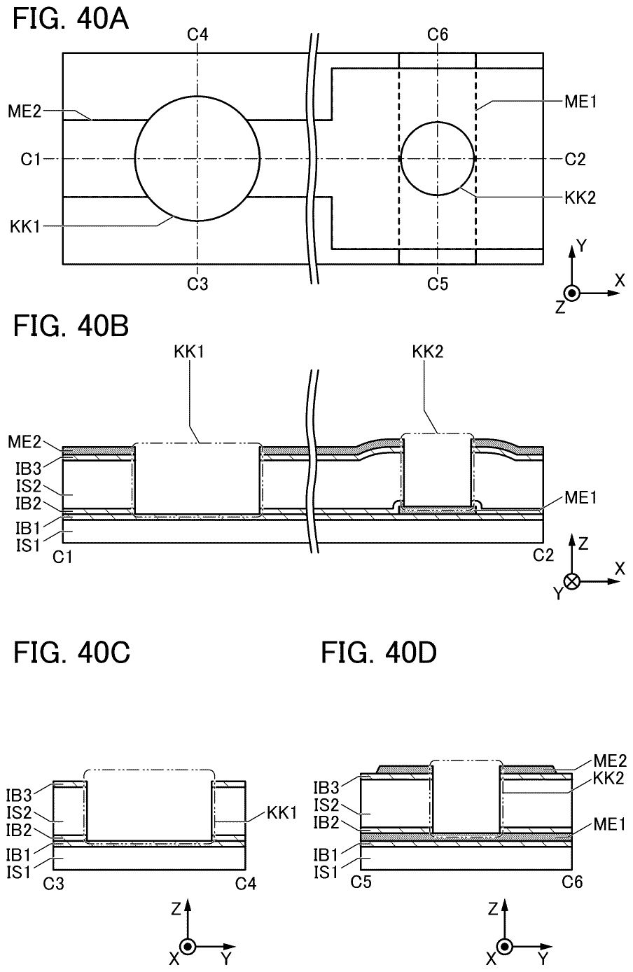

Next, the insulating film IB2A, the insulating film IS2A, the insulating film IB3A, and the conductive film ME2B are processed by a lithography method to form the insulating layer IB2, the insulating layer IS2, the insulating layer IB3, and the conductive layer ME2 (see FIG. 40A to FIG. 40D). Note that the insulating layer IB2, the insulating layer IS2, the insulating layer IB3, and the conductive layer ME2 have the opening KK1 and the opening KK2 that are provided by the lithography method. A dry etching method or a wet etching method can be employed for the processing, and processing by a dry etching method is particularly suitable for microfabrication. The insulating film IB2A, the insulating film IS2A, the insulating film IB3A, and the conductive film ME2B may be processed under different conditions.

In particular, the opening KK1 is preferably formed so that the top surface of the insulating layer IB1 is in the bottom portion of the opening KK1 as illustrated in FIG. 40B and FIG. 40C. Note that depending on the case, the opening KK1 may be formed so that the top surface of the insulating layer IB2 or the top surface of the insulating layer IS1 is in the bottom portion of the opening KK1.

The opening KK2 is preferably formed so that the top surface of the conductive layer ME1 is in the bottom portion of the opening KK2 as illustrated in FIG. 40B and FIG. 40D. Note that depending on the case, the opening KK2 may be formed so that the conductive layer ME1 and also the insulating layer IB1 or the insulating layer IS1 are exposed in the bottom portion of the opening KK2. Specifically, as illustrated in FIG. 41A and FIG. 41B, the opening KK2 may be formed so that the conductive layer ME1 and also the insulating layer IB1 are exposed in the bottom portion of the opening KK2, for example. Alternatively, as illustrated in FIG. 41A and FIG. 41C, the opening KK2 may be formed so that the conductive layer ME1 and also the insulating layer IS1 are exposed in the bottom portion of the opening KK2, for example. Note that FIG. 41A is a schematic plan view illustrating the opening KK2 different from that in FIG. 40A, and FIG. 41B and FIG. 41C are each a schematic cross-sectional view of a portion along the dashed-dotted line C7-C8 illustrated in FIG. 41A.

In FIG. 40A to FIG. 40D, the opening KK1 or the opening KK2 has a tapered shape with a taper angle (greater than or equal to 70° and less than or equal to 110°) with which the opening is substantially perpendicular to the X-Y plane, for example. Alternatively, the opening KK1 or the opening KK2 may have a tapered shape with a taper angle greater than or equal to 30° and less than 70° or a taper angle greater than 0° and less than 30° with respect to the X-Y plane, for example.

Note that in this specification and the like, a tapered shape refers to a shape in which at least part of a side surface of a structure is inclined to a substrate surface. An angle formed between an inclined side surface and a substrate surface is referred to as a taper angle. Specifically, in this specification and the like, a tapered shape having a taper angle greater than 0° and less than or equal to 90° is referred to as a forward tapered shape, and a tapered shape having a taper angle greater than 90° and less than 180° is referred to as an inverse tapered shape.

Although the shape of each of the opening KK1 and the opening KK2 in the plan view is a circle in FIG. 40A, the shape may be a shape with a curve (e.g., an ellipse or a polygon such as a triangle, a quadrangle, or a pentagon with a rounded corner) or a shape with a corner (e.g., a polygon such as a triangle, a quadrangle, or a pentagon).

A by-product generated in the above etching step is sometimes formed in a layered manner on the side surfaces of the opening KK1 and the opening KK2 (the side surfaces of the insulating layer IB2, the insulating layer IS2, the insulating layer IB3, and the conductive layer ME2). In that case, the layered by-product is formed between the insulating layer IB2, the insulating layer IS2, the insulating layer IB3, and the conductive layer ME2 and a semiconductor film SC1A described later. Hence, the layered by-product formed in contact with the insulating layer IB2, the insulating layer IS2, the insulating layer IB3, and the conductive layer ME2 is preferably removed.

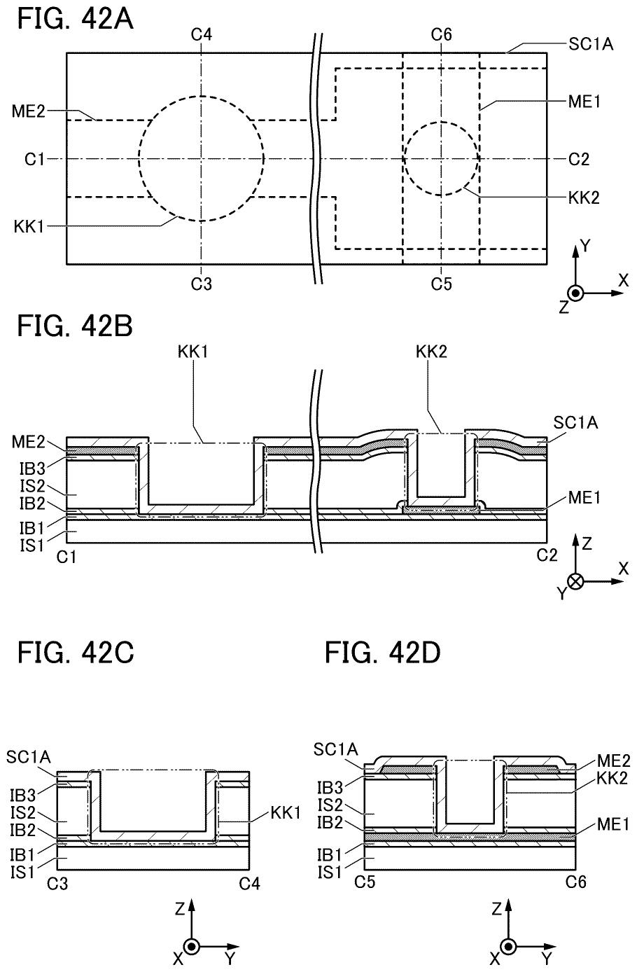

Next, the semiconductor film SC1A is formed over the conductive layer ME1, the insulating layer IB3, and the conductive layer ME2 (see FIG. 42A to FIG. 42D). Specifically, the semiconductor film SC1A is formed on the top surface of the conductive layer ME1, the side surface of the insulating layer IB2, the side surface of the insulating layer IS2, the side surface of the insulating layer IB3, and the side surface of the conductor ME2 inside the opening KK1 and the opening KK2. In addition, the semiconductor film SC1A is formed on the top surface of the conductive layer ME2 and the top surface of the insulating layer IB3 outside the opening KK1 and the opening KK2. That is, the semiconductor film SC1A is formed on the bottom surface and the inner side surface of the opening KK1 and the bottom surface and the inner side surface of the opening KK2 and over the conductive layer ME2 and the insulating layer IB3. The semiconductor film SC1A can be formed by a film formation method such as a sputtering method, a CVD method, an MBE method, a PLD method, or an ALD method. The semiconductor film SC1A is preferably formed by an ALD method. As described above, it is preferable to form the semiconductor film SC1A to have a small thickness, and an unevenness of the thickness needs to be reduced. Meanwhile, since an ALD method is a film formation method in which a precursor and a reactant (e.g., oxidizer) are alternately introduced and the thickness can be adjusted with the number of repetition times of the cycle, accurate control of the thickness is possible. Furthermore, as illustrated in FIG. 42B and FIG. 42D, the semiconductor film SC1A needs to be formed on the bottom surface and the inner side surface of the opening KK1 and the bottom surface and the inner side surface of the opening KK2 so as to have good coverage. In particular, it is preferable that the semiconductor film SC1A be formed with good coverage on the top surface of the conductive layer ME1 and the side surface of the conductive layer ME2 in each of the opening KK1 and the opening KK2. By an ALD method, atomic layers can be deposited one by one on the bottom surface and the side surface of each of the opening KK1 and the opening KK2, whereby the semiconductor film SC1A can be formed in each of the openings with good coverage.

In the case where the side surface of the opening KK1 or the opening KK2 has a tapered shape, the method for forming the semiconductor film SC1A is not limited to an ALD method. For example, a sputtering method may be employed.

The semiconductor film SC1A is a film to be the semiconductor layer SC1 in a later step. Part of the semiconductor layer SC1 functions as the channel formation region of each of the transistor ML and the transistor MV that are formed in a later step. Another part of the semiconductor layer SC1 may function as one of a pair of electrodes of the capacitor C1 that is formed in a later step.

The semiconductor film SC1A can be a metal oxide functioning as an oxide semiconductor, for example. In this case, the transistor ML and the transistor MV are OS transistors. The metal oxide preferably contains at least indium or zinc, for example. In particular, indium and zinc are preferably contained. In addition to them, an element M is preferably contained. As the element M, one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, magnesium, cobalt, and antimony can be used. In particular, the element Mis preferably one or more of aluminum, gallium, yttrium, and tin. The element M further preferably contains one or both of gallium and tin.

For the semiconductor film SC1A, for example, an In-Ga-Zn oxide is preferably used. In particular, the In-Ga-Zn oxide is further preferably a metal oxide with a composition of In:Ga:Zn=1:1:1 [atomic ratio] or in the neighborhood thereof, a composition of 4:2:3 [atomic ratio] or in the neighborhood thereof, or a composition of 3:1:2 [atomic ratio] or in the neighborhood thereof. For another example, an In-Zn oxide is preferably used for the semiconductor film SC1A. In particular, the In-Zn oxide is further preferably a metal oxide with a composition of In:Zn=4:1 [atomic ratio] or in the neighborhood thereof.

An oxide semiconductor having a low carrier concentration is particularly preferably used for the semiconductor film SC1A. For example, the carrier concentration in an oxide semiconductor in the channel formation region is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Electric charge trapped by the trap states in the oxide semiconductor takes a long time to disappear and might behave like fixed electric charge. Thus, a transistor whose channel formation region is formed in an oxide semiconductor having a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film also be reduced. Examples of the impurity include hydrogen and nitrogen. Note that an impurity in an oxide semiconductor refers to, for example, an element other than the main components of the oxide semiconductor. For example, an element with a concentration lower than 0.1 atomic % can be regarded as an impurity.

A transistor including an oxide semiconductor (an OS transistor) is likely to change its electrical characteristics when impurities or oxygen vacancies (hereinafter sometimes referred to as Vo) exist in a channel formation region in the oxide semiconductor, which might degrade the reliability. In the OS transistor, a defect that is Vo in the oxide semiconductor into which hydrogen enters (hereinafter sometimes referred to as VoH) may be formed and may generate an electron serving as a carrier. When VoH is formed in the channel formation region, the donor concentration in the channel formation region increases in some cases. As the donor concentration in the channel formation region increases, the threshold voltage might vary. Accordingly, when the channel formation region in the oxide semiconductor includes Vo, the transistor tends to be normally-on (a state where a channel exists and a current flows through the transistor even when the gate-source voltage is 0 V). Therefore, impurities, oxygen vacancies, and VoH are preferably reduced as much as possible in the channel formation region in the oxide semiconductor.

The semiconductor film SC1A preferably has a stacked-layer structure of a plurality of oxide layers that differ in the atomic ratio of metal atoms. As the metal oxide, for example, a first metal oxide and a second metal oxide formed over the first metal oxide are considered. For example, in the case where the metal oxides each contain at least indium (In) and the element M, the proportion of the number of atoms of the element M contained in the first metal oxide to the number of atoms of all elements that constitute the first metal oxide is preferably higher than the proportion of the number of atoms of the element M contained in the second metal oxide to the number of atoms of all elements that constitute the second metal oxide. In addition, the atomic ratio of the element M to In in the first metal oxide is preferably greater than the atomic ratio of the element M to In in the second metal oxide.

The energy of the conduction band minimum of the first metal oxide is preferably higher than the energy of the conduction band minimum of the second metal oxide. In other words, the electron affinity of the first metal oxide is preferably smaller than the electron affinity of the second metal oxide.

Here, the energy level of the conduction band minimum gently changes at junction portions between the first metal oxide and the second metal oxide. In other words, at junction portions between the first metal oxide and the second metal oxide, the energy level of the conduction band minimum continuously changes or the energy levels are continuously connected. This can be achieved by decreasing the density of defect states in a mixed layer formed at the interface between the first metal oxide and the second metal oxide.

Specifically, when the first metal oxide and the second metal oxide contain the same element (as a main component) in addition to oxygen, a mixed layer with a low density of defect states can be formed. For example, an In-Ga-Zn oxide (indium-gallium-zinc oxide), a Ga-Zn oxide, or gallium oxide can be used as the first metal oxide, in the case where the second metal oxide is an In-Ga-Zn oxide.

Specifically, as the first metal oxide, a metal oxide with a composition of In:Ga:Zn=1:3:4 [atomic ratio] or in the neighborhood thereof, 1:3:2 [atomic ratio] or in the neighborhood thereof, or 1:1:0.5 [atomic ratio] or in the neighborhood thereof can be used. As the second metal oxide, a metal oxide with a composition of In:Ga:Zn=1:1:1 [atomic ratio] or in the neighborhood thereof, 4:2:3 [atomic ratio] or in the neighborhood thereof, or 3:1:2 [atomic ratio] or in the neighborhood thereof can be used. Note that a composition in the neighborhood includes the range of ±30 % of an intended atomic ratio.

In this case, the second metal oxide serves as a main carrier path. When the first metal oxide has the above structure, the density of defect states at the interface between the first metal oxide and the second metal oxide can be made low. Thus, the influence of interface scattering on carrier conduction is small, and the transistor can have a high on-state current and high frequency characteristics.

Note that the metal oxide may have a stacked-layer structure of the second metal oxide and the first metal oxide formed over the second metal oxide. This structure can inhibit an increase in the contact resistance between the conductor ME1 or the conductor ME2 and the metal oxide. Furthermore, the second metal oxide can be inhibited from being damaged during formation of the insulator GI1 (described later in detail).

Using the metal oxide for the semiconductor film SC1A may reduce the oxygen concentration in the semiconductor layer SC1 in the vicinity of the conductor, which is the conductor (corresponding to the conductive layer ME1 and the conductive layer ME2 in FIG. 42A to FIG. 42D) provided in contact with the semiconductor layer SC1. In addition, a metal compound layer, which contains a metal contained in the conductor and a component of the semiconductor layer SC1, may be formed in the semiconductor layer SC1 in the vicinity of the conductor. In such cases, a region of the semiconductor layer SC1 in the vicinity of the conductor has a higher carrier density, thereby becoming a low-resistance region.

Besides a metal oxide, for example, a material containing silicon can be used for the semiconductor layer SC1. Examples of the silicon include amorphous silicon (sometimes referred to as hydrogenated amorphous silicon), microcrystalline silicon, polycrystalline silicon (including low-temperature polysilicon (LTPS)), and single crystal silicon. During formation of the semiconductor film SC1A in each of the opening KK1 and the opening KK2, a semiconductor region where the semiconductor film SC1A is formed is preferably changed into a low-resistance region at the interface between the semiconductor region and the conductive layer ME1 in contact with each other and the vicinity thereof and at the interface between the semiconductor region and the conductive layer ME2 in contact with each other and the vicinity thereof. In this case, the low-resistance region and the semiconductor region are formed in the semiconductor layer SC1; thus, the transistor ML and the transistor MV can be Si transistors.

Note that in the description in this embodiment, the semiconductor film SC1A includes a metal oxide functioning as an oxide semiconductor.

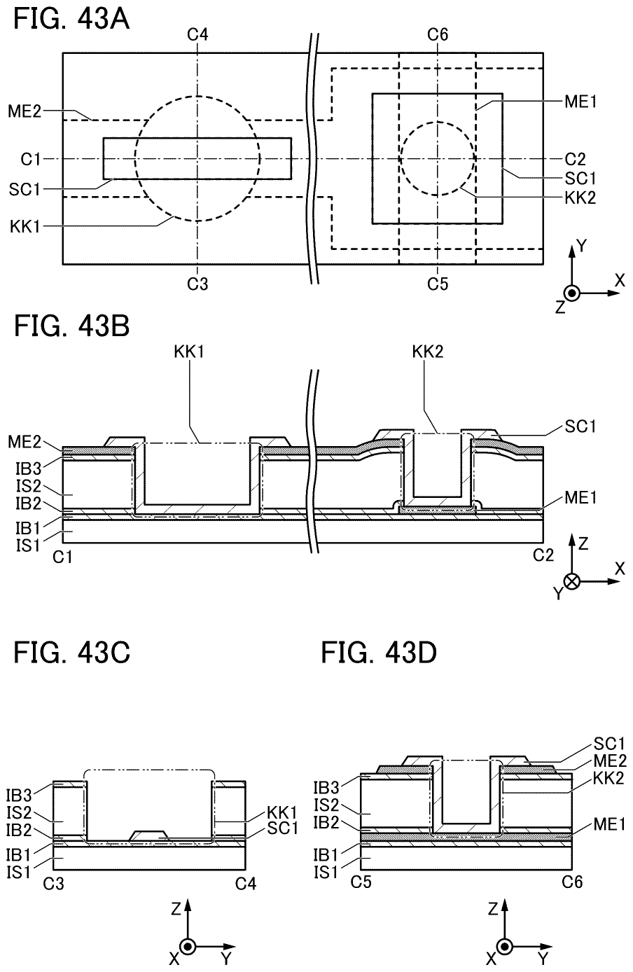

Next, the semiconductor film SC1A is processed by a lithography method to form the semiconductor layer SC1 so that part of the insulating layer IB1, part of the insulating layer IB2, part of the insulating layer IS2, part of the insulating layer IB3, and part of the conductive layer ME2 are exposed. In particular, part of the semiconductor layer SC1 is processed so as to overlap with the insulating layer IB2 and the conductive layer ME2, and another part of the semiconductor layer SC1 is processed so as to overlap with the conductive layer ME1 and the conductive layer ME2 (see FIG. 43A to FIG. 43D). For the lithography method, the lithography method described with reference to FIG. 36A to FIG. 36D can be referred to.

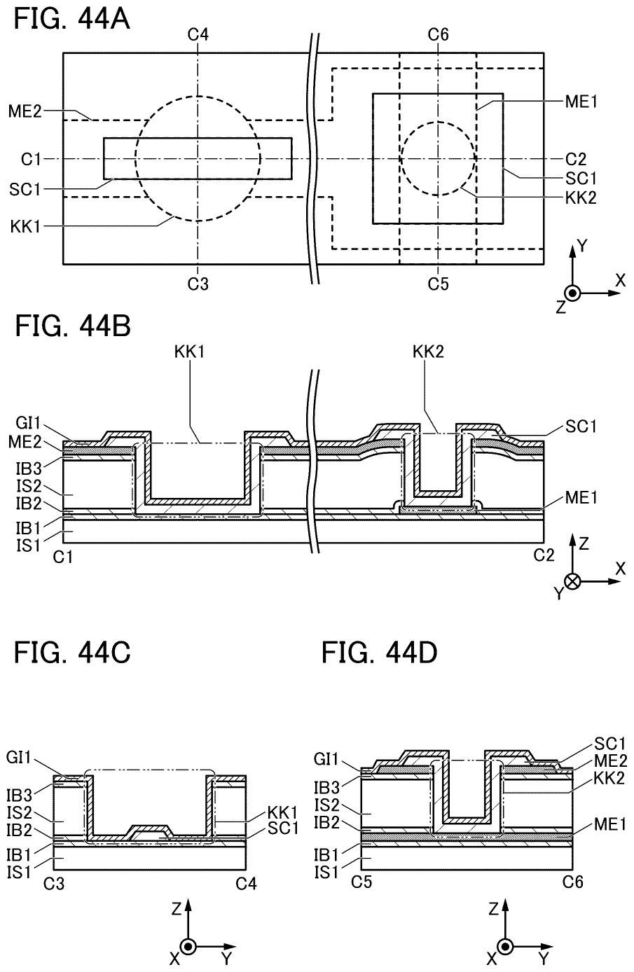

Next, the insulating layer GI1 is formed over the insulating layer IB1, the insulating layer IB2, the insulating layer IS2, the insulating layer IB3, the conductive layer ME2, and the semiconductor layer SC1 (see FIG. 44A to FIG. 44D). The insulating layer GII can be formed by a film formation method such as a sputtering method, a CVD method, an MBE method, a PLD method, or an ALD method, for example.

The insulating layer GII functions as the gate insulating film of each of the transistor ML and the transistor MV.

For the insulating layer GI1, a single layer or stacked layers of an insulator containing what is called a high-k material such as aluminum oxide, hafnium oxide, tantalum oxide, zirconium oxide, lead zirconate titanate (PZT), strontium titanate (SrTiO₃), or (Ba, Sr)TiO₃ (BST) is preferably used, for example. Alternatively, for the insulating layer GI1, as an insulator with a high relative permittivity, an oxide containing aluminum and hafnium, an oxynitride containing aluminum and hafnium, an oxide containing silicon and hafnium, an oxynitride containing silicon and hafnium, or a nitride containing silicon and hafnium may be used.

With further miniaturization and higher integration of a transistor, a problem such as generation of a leakage current may arise because of a thinned gate insulator. When a high-k material is used for the insulator functioning as a gate insulator, a gate potential at the time of the operation of the transistor can be reduced while the physical thickness is maintained.

For the insulating layer GI1, an insulating layer in which the above-described high-k material and silicon oxide or silicon oxynitride are stacked may be used. In this case, the insulating layer having high thermal stability in addition to a high relative permittivity can be used as the gate insulating film of each of the transistor ML and the transistor MV.

The insulating layer GII may be a single layer or have a stacked-layer structure obtained by sequentially forming two or more layers of insulating materials.

Note that in the case where the semiconductor layer SC1 contains a metal oxide functioning as an oxide semiconductor, after the insulating layer GI1 is formed (before a conductive film ME3A described later is formed at the latest), microwave treatment is preferably performed in an oxygen-containing atmosphere. Here, the microwave treatment refers to, for example, treatment using an apparatus including a power source that generates high-density plasma with use of a microwave. In this specification and the like, a microwave refers to an electromagnetic wave having a frequency greater than or equal to 300 MHz and less than or equal to 300 GHz. Note that in the case where the insulating layer GI1 has a stacked-layer structure, the microwave treatment may be performed at the time when the insulating layer GI1 is partially formed. For example, in the case where the insulating layer GI1 includes a silicon oxide film or a silicon oxynitride film, the microwave treatment may be performed at the time when the silicon oxide film or the silicon oxynitride film is formed.

For the microwave treatment, high-frequency waves such as microwaves or RF, oxygen plasma, oxygen radicals, or the like can be used. In the case of performing the microwave treatment, a microwave treatment apparatus including a power source for generating high-density plasma using microwaves is preferably used, for example. Here, the frequency of the microwave treatment apparatus is set to higher than or equal to 300 MHz and lower than or equal to 300 GHZ, preferably higher than or equal to 2.4 GHz and lower than or equal to 2.5 GHZ, for example, 2.45 GHz. Oxygen radicals at a high density can be generated with high-density plasma. The power of the power source that applies microwaves of the microwave treatment apparatus is set to higher than or equal to 1000 W and lower than or equal to 10000 W, preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be efficiently introduced into the semiconductor layer SC1, which is a metal oxide. The effect of plasma, microwaves, and the like enables VoH included in a region of the semiconductor layer SC1 to be cut off, and hydrogen to be removed from the region. That is, VoH included in the region can be reduced. As a result, oxygen vacancies and VoH in the region can be reduced to lower the carrier concentration. In addition, oxygen radicals generated by the oxygen plasma can be supplied to oxygen vacancies formed in the region, thereby further reducing oxygen vacancies in the region and lowering the carrier concentration.

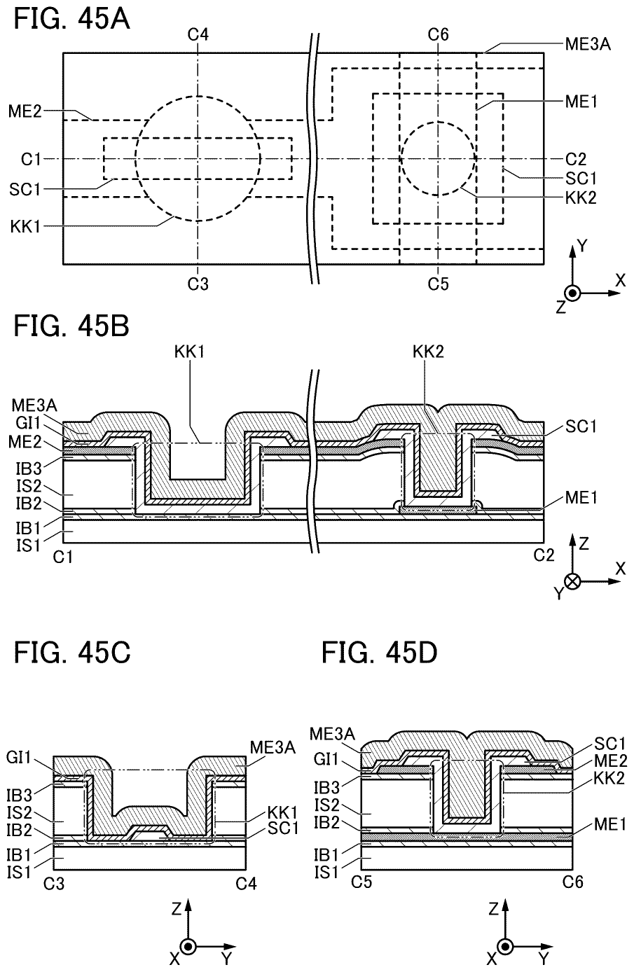

Next, the conductive film ME3A is formed over the insulating layer GI1 (see FIG. 45A to FIG. 45D). In particular, the conductive film ME3A is formed to fill the opening KK2 in FIG. 45A to FIG. 45D. The conductive film ME3A can be formed by a film formation method such as a sputtering method, a CVD method, an MBE method, a PLD method, or an ALD method, for example.

The conductive film ME3A is a film to be the conductive layer ME3 in a later step. Part of the conductive layer ME3 functions also as the gate electrode of the transistor ML. Another part of the conductive layer ME3 functions also as the gate electrode of the transistor MV. Therefore, a material having high conductivity is preferably used for the conductive film ME3A.

For the conductive film ME3A, a material or a structure that can be used for the conductor ME1 can be used, for example.

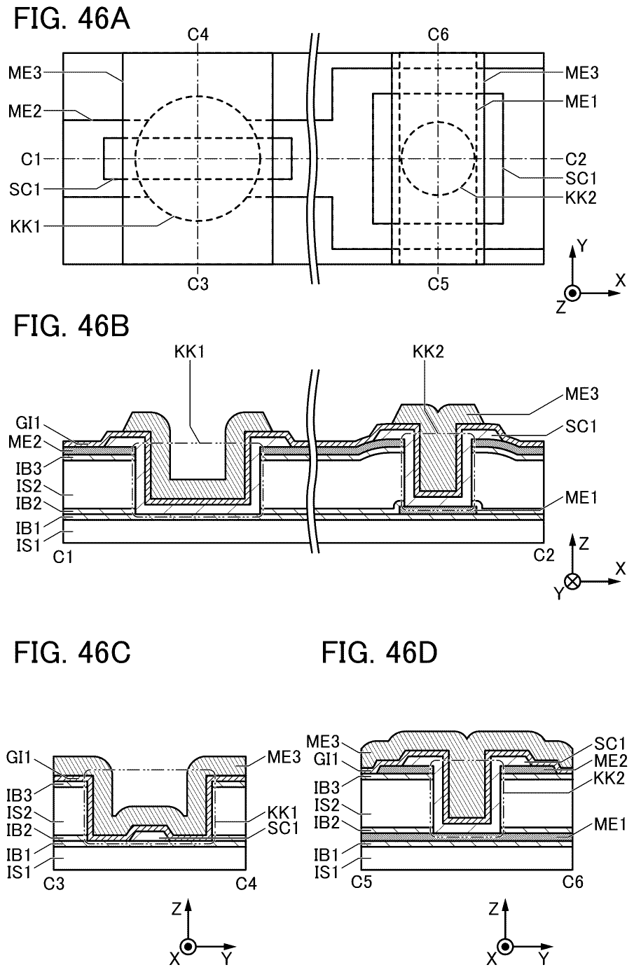

Next, the conductive film ME3 A is processed into a band shape by a lithography method to form the conductive layer ME3 (see FIG. 46A to FIG. 46D). In particular, here, the conductive layer ME3 is formed so that part thereof extends in a direction parallel to the dashed-dotted line C3-C4 (the +Y direction and the −Y direction) and overlaps with the semiconductor layer SC1 that is included in the opening KK1. In addition, the conductive layer ME3 is formed so that another part thereof extends in a direction parallel to the dashed-dotted line C5-C6 (the +Y direction and the −Y direction) and overlaps with another conductive layer ME1 and the semiconductor layer SC1 that is included in the opening KK2. For the lithography method, the lithography method described with reference to FIG. 36A to FIG. 36D can be referred to.

Next, the insulating layer IB4 and the insulating layer IS3 are formed in this order over the insulating layer GI1 and the conductive layer ME3 (see FIG. 34A to FIG. 34D).

Like the insulating layer IB1 to the insulating layer IB3, the insulating layer IB4 preferably functions as, for example, a barrier insulating film that inhibits entry of impurities such as water, hydrogen, nitrogen, and oxygen contained in the insulating layer IS3 to be formed later into the conductive layer ME3. Thus, for the insulating layer IB3, a material or a structure that can be used for the insulating layer IB1 can be used.

The insulating layer IS3 is a film functioning as an interlayer film, for example. Thus, the insulating layer IS3 preferably contains an insulating material with a low relative permittivity. When an insulating material with a low relative permittivity is used for an interlayer film, parasitic capacitance generated between wirings can be reduced.

By the above manufacturing method, the transistor ML (VLFET) illustrated in FIG. 3A to FIG. 3C and the transistor MV (VFET) illustrated in FIG. 7A to FIG. 7C can be manufactured concurrently.

Note that the method for manufacturing the semiconductor device of one embodiment of the present invention is not limited to the above. In manufacturing the semiconductor device of one embodiment of the present invention, the manufacturing method may be changed as appropriate. Even in the case where the structure of the semiconductor device is changed by a change in the manufacturing method, the semiconductor device can be regarded as one embodiment of the present invention.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 5

In this embodiment, a transistor whose channel formation region includes an oxide semiconductor (an OS transistor) is described. In the description of the OS transistor, comparison with a transistor whose channel formation region includes silicon (also referred to as a Si transistor) is also described briefly.

### [OS Transistor]

An oxide semiconductor having a low carrier concentration is preferably used for the OS transistor. For example, the carrier concentration of a channel formation region in an oxide semiconductor is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Electric charge trapped by the trap states in the oxide semiconductor takes a long time to disappear and might behave like fixed electric charge. Thus, a transistor whose channel formation region is formed in an oxide semiconductor having a high density of trap states has unstable electrical characteristics in some cases.

Accordingly, in order to obtain stable electrical characteristics of the transistor, reducing the concentration of impurities in the oxide semiconductor is effective. In order to reduce the impurity concentration in the oxide semiconductor, the impurity concentration in a film that is adjacent to the oxide semiconductor is preferably reduced. Examples of the impurity include hydrogen and nitrogen. Note that an impurity in an oxide semiconductor refers to, for example, elements other than the main components of the oxide semiconductor. For example, an element with a concentration lower than 0.1 atomic % is regarded as an impurity.

When impurities and oxygen vacancies are in a channel formation region in an oxide semiconductor in the OS transistor, electrical characteristics of the OS transistor easily change, which might degrade the reliability. In the OS transistor, a defect that is an oxygen vacancy in the oxide semiconductor into which hydrogen enters (hereinafter sometimes referred to as VoH) may be formed and may generate an electron serving as a carrier. When VoH is formed in the channel formation region, the donor concentration in the channel formation region increases in some cases. As the donor concentration in the channel formation region increases, the threshold voltage might vary. Accordingly, when the channel formation region in the oxide semiconductor includes oxygen vacancies, the transistor tends to have normally-on characteristics (a state where a channel exists and a current flows through the transistor even when no voltage is applied to the gate electrode). Therefore, impurities, oxygen vacancies, and VoH are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current (also referred to as off-leakage current or Ioff) of the transistor can be reduced.

In the Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a wide band gap, and thus can suppress the short-channel effect. In other words, a short-channel effect does not appear or hardly appears in the OS transistor.

The short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes referred to as S value), an increase in leakage current, and the like. Here, the S value means the amount of change in gate voltage in the subthreshold region by which the drain current is changed by one order of magnitude at a constant drain voltage.

The characteristic length is widely used as an indicator of resistance to a short-channel effect. The characteristic length is an indicator of curving of potential in a channel formation region. When the characteristic length is shorter, the potential rises more sharply, which means that the resistance to a short-channel effect is high.

The OS transistor is an accumulation-type transistor and a Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to a short-channel effect than the Si transistor. That is, in the case where a transistor with a short channel length is desired to be manufactured, the OS transistor is more suitable than the Si transistor.

Even in the case where the carrier concentration in an oxide semiconductor is reduced until a channel formation region becomes an i-type or substantially i-type region, the conduction band minimum of the channel formation region in a short-channel transistor decreases because of the Conduction-Band-Lowering (CBL) effect; thus, the energy difference between the conduction band minimum of a source region or a drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n-type region and the source region and the drain region become n⁺-type regions.

The OS transistor having the above structure enables a semiconductor device to have favorable electrical characteristics even when the semiconductor device is miniaturized or highly integrated. For example, the semiconductor device can have favorable electrical characteristics even when the OS transistor has a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for the Si transistor to have a gate length less than or equal to 20 nm or less than or equal to 15 nm because of appearance of a short-channel effect. Therefore, the OS transistor can be suitably used as a transistor having a short channel length as compared with the Si transistor. Note that the gate length refers to the length of a gate electrode in a direction in which carriers move inside a channel formation region during an operation of the transistor and to the width of a bottom surface of the gate electrode in a plan view of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz at room temperature, for example.

As described above, the OS transistor has an effect superior to that of the Si transistor, such as a low off-state current and capability of having a short channel length.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 6

In this embodiment, a structure example of a display apparatus of one embodiment of the present invention will be described.

### Structure Example of Display Apparatus

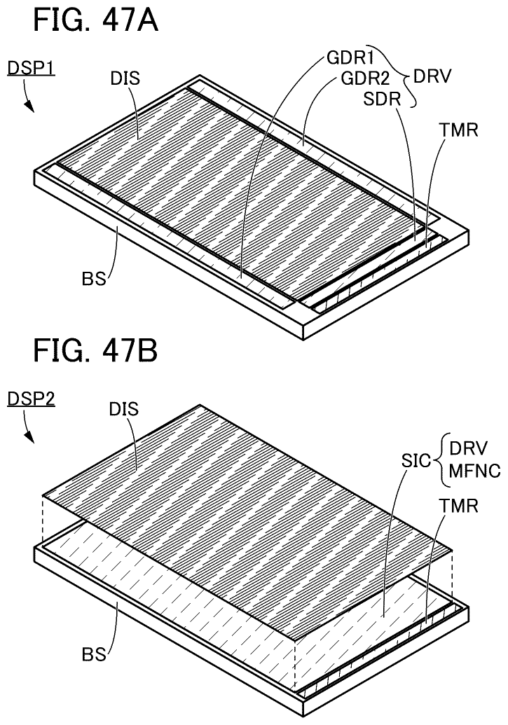

FIG. 47A is a schematic perspective view illustrating a display apparatus of one embodiment of the present invention. A display apparatus DSP1 includes a display region DIS, a driver circuit region DRV, and a terminal region TMR, for example. The display apparatus DSP1 includes a substrate BS, and the display region DIS, the driver circuit region DRV, and the terminal region TMR are located over the substrate BS.

The driver circuit region DRV includes, for example, a driver circuit GDR1, a driver circuit GDR2, and a driver circuit SDR.

As the substrate BS, a semiconductor substrate (e.g., a single crystal substrate containing silicon or germanium as a material) can be used, for example. Besides the semiconductor substrate, any of the following can be used as the substrate BS: an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, and paper or a base material film containing a fibrous material. Examples of the glass substrate include barium borosilicate glass, aluminoborosilicate glass, and soda lime glass. Examples of the flexible substrate, the attachment film, the base material film, and the like include plastics typified by polyethylene terephthalate (PET), polyethylene naphthalate (PEN), polyethersulfone (PES), and polytetrafluoroethylene (PTFE). Another example is a synthetic resin such as an acrylic resin. Other examples include polypropylene, polyester, polyvinyl fluoride, and polyvinyl chloride. Other examples include polyamide, polyimide, aramid, an epoxy resin, an inorganic vapor deposition film, and paper. Note that in the case where the manufacturing process of the display apparatus DSP1 involves heat treatment, a highly heat-resistant material is preferably used for the substrate BS.

In particular, in the case where a semiconductor substrate including silicon as a material is used as the substrate BS, transistors included in the display region DIS and the driver circuit region DRV can be Si transistors and can be formed over the substrate BS.

For example, in the case where transistors included in the display region DIS and the driver circuit region DRV are OS transistors, there is no particular limitation on the substrate where the OS transistor is formed, and as described above, a substrate that can be used as the substrate BS can sometimes be used.

One or more selected from the driver circuit GDR1, the driver circuit GDR2, and the driver circuit SDR included in the driver circuit region DRV may be mounted as an IC (Integrated Circuit) on the substrate BS by a COG (Chip On Glass) technique.

The driver circuit GDR1 and the driver circuit GDR2 each function as a driver circuit for displaying an image on the display region DIS, for example. Specifically, for example, the driver circuit GDR1 and the driver circuit GDR2 each function as a gate driver circuit for the display region DIS. For example, the driver circuit SDR functions as a source driver circuit for the display region DIS.

Thus, for example, the driver circuit GD in FIG. 10 described in the above embodiment can be employed for each of the driver circuit GDR1 and the driver circuit GDR2. In addition, for example, the driver circuit SD in FIG. 10 described in the above embodiment can be used for the driver circuit SDR.

The terminal region TMR includes a terminal for supplying an image signal and a power supply voltage into the display apparatus DSP1 from the outside of the display apparatus DSP1. An FPC (Flexible Printed Circuit) may be electrically connected to the terminal region TMR. A chip may be provided as an IC over the FPC by a COF (Chip On Film) technique. The IC, for example, may include a driver circuit for displaying an image on the display region DIS.

The display region DIS includes, for example, a plurality of pixels. The plurality of pixels may be arranged in a matrix in the display region DIS.

Each of the plurality of pixels can express one color or a plurality of colors. In particular, the plurality of colors can be, for example, three colors of red, green, and blue. Alternatively, the plurality of colors may be two or more colors selected from, for example, red, green, blue, cyan, magenta, yellow, and white. Note that in the case where each of pixels expressing different colors is called a subpixel and white is expressed by a plurality of subpixels expressing different colors, the plurality of subpixels are collectively called a pixel in some cases. In the description in this specification and the like, a subpixel is referred to as a pixel for convenience.

Note that the display apparatus of one embodiment of the present invention is not limited to having the structure of the display apparatus DSP1 illustrated in FIG. 47A. For example, the display apparatus of one embodiment of the present invention may have the structure of a display apparatus DSP2 illustrated in FIG. 47B.

The display apparatus DSP2 illustrated in FIG. 47B includes the display region DIS, a circuit region SIC, and the terminal region TMR, for example. The display apparatus DSP2 further includes the substrate BS, like the display apparatus DSP1. The display apparatus DSP2 is different from the display apparatus DSP1 in that the circuit region SIC and the terminal region TMR are provided over the substrate BS and the display region DIS is provided over the circuit region SIC.

The circuit region SIC includes, for example, the driver circuit region DRV described above. The circuit region SIC may include any of a variety of functional circuits other than the driver circuit region DRV. In this embodiment, the functional circuit is included in a functional circuit region MFNC.

The functional circuit region MFNC may include a GPU (Graphics Processing Unit), for example. In the case where the display apparatus DSP2 includes a touch panel, the functional circuit region MFNC may include a sensor controller for controlling a touch sensor included in the touch panel.

In the case where a light-emitting device containing an organic EL material is used as the display element of the display apparatus DSP2, an EL correction circuit may be included in the functional circuit region MFNC. The EL correction circuit has a function of appropriately adjusting the amount of current input to the light-emitting device containing an organic EL material. Since the emission luminance of the light-emitting device containing an organic EL material is proportional to the current, when the characteristics of a driving transistor electrically connected to the light-emitting device are not favorable, the luminance of light emitted from the light-emitting device might be lower than a desired luminance. For example, the EL correction circuit monitors the amount of current flowing through the light-emitting device and increases the amount of current when the amount of current is smaller than a desired amount, whereby the luminance of light emitted from the light-emitting device can be increased. By contrast, when the amount of current is larger than a desired amount, the amount of current flowing through the light-emitting device may be adjusted to be small.

In the case where a liquid crystal element is used as the display element of the display apparatus DSP2, a gamma correction circuit may be included in the functional circuit region MFNC.

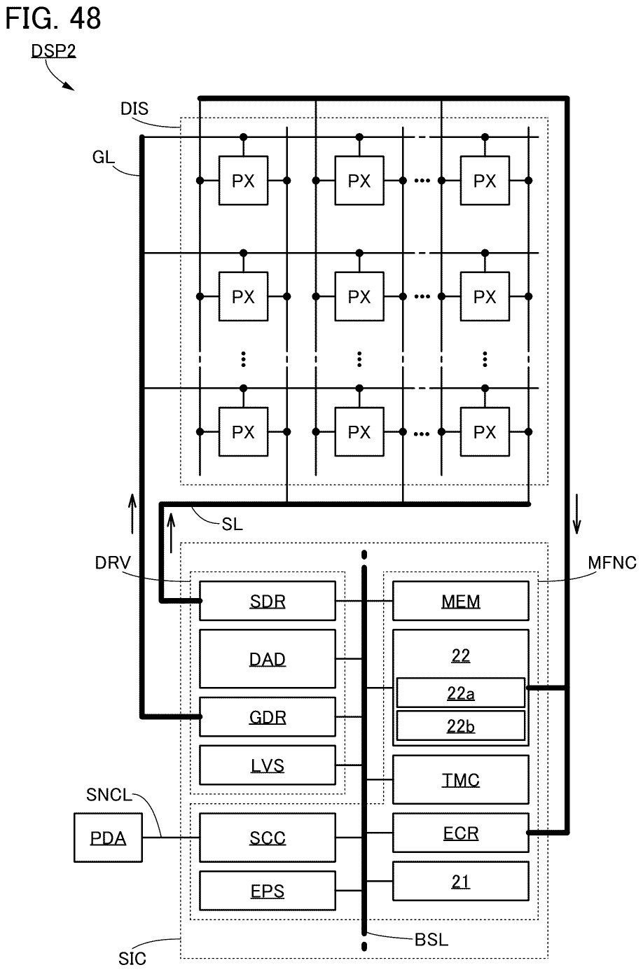

FIG. 48 is a block diagram showing a structure example of the display apparatus DSP2 illustrated in FIG. 47B. The display apparatus DSP2 illustrated in FIG. 48 includes the display region DIS and the circuit region SIC, for example. FIG. 48 illustrates a sensor PDA, and the sensor PDA may be placed inside or outside the display apparatus DSP2.

The display apparatus DSP1 in FIG. 47A may be electrically connected to the functional circuit region MFNC located outside the display apparatus DSP1 through the terminal region TMR. The structure of the display apparatus DSP1 in this case can be regarded as similar to the structure of the display apparatus DSP2 illustrated in FIG. 48.

In FIG. 48, the thick solid lines denote a plurality of wirings or bus wirings.

In FIG. 48, the plurality of pixel circuits PX are arranged in a matrix in the display region DIS, for example. The pixel circuit PX can be, for example, a pixel circuit provided with one or more selected from a liquid crystal display device, a light-emitting device including an organic EL material, a light-emitting device including an inorganic EL material, and a light-emitting device including a light-emitting diode such as a micro LED. Note that in the description in this embodiment, the pixel circuit PX in the display region DIS includes a light-emitting device including an organic EL material.

In FIG. 48, the circuit region SIC includes the driver circuit region DRV and the functional circuit region MFNC, as described above.

The driver circuit region DRV functions as a peripheral circuit for driving the display region DIS, for example. Specifically, the driver circuit region DRV includes, for example, the driver circuit SDR, a digital-to-analog converter circuit DAD, the driver circuit GDR, and a level shifter circuit LVS. Note that the driver circuit SDR corresponds to the driver circuit SD in FIG. 10, and the driver circuit GDR corresponds to the driver circuit GD in FIG. 10, for example.

The functional circuit region MFNC can be provided with, for example, a memory device storing image data to be displayed on the display region DIS, a decoder for decoding encoded image data, a GPU for processing image data, a power supply circuit, a correction circuit, and a CPU. In FIG. 48, the functional circuit region MFNC includes a memory device MEM, a GPU 22, an EL correction circuit ECR, a timing controller TMC, a CPU (NoffCPU (registered trademark)) 21, a sensor controller SCC, and a power supply circuit EPS, for example.

In the display apparatus DSP2 in FIG. 48, for example, a bus wiring BSL is electrically connected to each of the circuits included in the driver circuit region DRV and each of the circuits included in the functional circuit region MFNC.

The driver circuit SDR has a function of transmitting image data to the pixel circuit PX included in the display region DIS, for example. Thus, the driver circuit SDR is electrically connected to the pixel circuit PX through the wiring SL.

The digital-to-analog converter circuit DAD has a function of, for example, converting image data that has been digitally processed by the GPU or correction circuit described later, into analog data. The image data converted into analog data is transmitted to the display region DIS through the driver circuit SDR. Note that the digital-to-analog converter circuit DAD may be included in the driver circuit SDR, and the image data may be transmitted to the driver circuit SDR, the digital-to-analog converter circuit DAD, and the display region DIS in this order.

The driver circuit GDR has a function of selecting the pixel circuit PX to which image data is to be transmitted in the display region DIS, for example. Thus, the driver circuit GDR is electrically connected to the pixel circuit PX through the wiring GL.

The level shifter circuit LVS has a function of converting the signals to be input to the driver circuit SDR, the digital-to-analog converter circuit DAD, the driver circuit GDR, and the like into signals having appropriate levels, for example.

The memory device MEM has a function of storing image data to be displayed on the display region DIS, for example. Note that the memory device MEM can be configured to store the image data as digital data or analog data.

In the case where the memory device MEM stores image data, the memory device MEM is preferably a nonvolatile memory. In this case, a NAND memory or the like can be used as the memory device MEM.

In the case where the memory device MEM stores temporary data generated in the GPU 22, the EL correction circuit ECR, the CPU 21, or the like, the memory device MEM is preferably a volatile memory. In this case, an SRAM (Static Random Access Memory), a DRAM (Dynamic Random Access Memory), or the like can be used as the memory device MEM.

The GPU 22 has a function of performing processing for plotting the image data read from the memory device MEM on the display region DIS, for example. Specifically, the GPU 22 is configured to perform pipeline processing in parallel and thus can perform high-speed processing of the image data to be displayed on the display region DIS. The GPU 22 can also have a function of a decoder for decoding an encoded image.

The functional circuit region MFNC may include a plurality of circuits that can increase the display quality of the display region DIS. As such circuits, for example, correction circuits (dimming or toning correction circuits) that detect and correct color irregularity of an image displayed on the display region DIS to optimize the image may be provided. In the case where the pixel in the display region DIS includes a light-emitting device including an organic EL, the functional circuit region MFNC may be provided with an EL correction circuit. Note that because the description in this embodiment is made on the assumption that the pixel circuit PX in the display region DIS includes the light-emitting device including an organic EL material, the functional circuit region MFNC in this example is provided with the EL correction circuit ECR.

The above-described image correction may be performed using artificial intelligence. For example, it is possible that a current flowing in the display device included in the pixel (or a voltage applied to the display device) is monitored and acquired, an image displayed on the display region DIS is acquired with an image sensor or the like, the current (or voltage) and the image are used as input data in an arithmetic operation of the artificial intelligence (e.g., an artificial neural network), and the output result is used to determine whether the image should be corrected.

Such an arithmetic operation of artificial intelligence can be applied to not only image correction but also upconversion processing on image data. In this case, upconversion of low-screen resolution image data in accordance with the screen resolution of the display region DIS allows a high-display-quality image to be displayed on the display region DIS. The arithmetic operation of artificial intelligence can also be applied to downconversion processing on image data.

Note that the above-described arithmetic operation of artificial intelligence can be performed using the GPU 22 included in the functional circuit region MFNC. That is, the GPU 22 can be used to perform arithmetic operations for various kinds of correction (e.g., color irregularity correction or upconversion processing). The GPU 22 may include a circuit 22a that corrects color irregularity and a circuit 22b that performs upconversion processing.

Note that in this specification and the like, a GPU performing an arithmetic operation of artificial intelligence is referred to as an AI accelerator. That is, the GPU included in the functional circuit region MFNC may be replaced with an AI accelerator in the description in this specification and the like.

The timing controller TMC has a function of changing the frame rate at which an image is displayed on the display region DIS. For example, the display apparatus DSP2 can be driven at a frame rate reduced by the timing controller TMC in the case where the display region DIS displays a still image; for another example, the display apparatus DSP2 can be driven at a frame rate increased by the timing controller TMC in the case where the display region DIS displays a moving image. In other words, the display apparatus DSP2 provided with the timing controller TMC can be driven at a frame rate that is changed depending on which of a still image and a moving image is displayed. Specifically, since the frame rate can be lowered when the display region DIS displays a still image, the power consumption of the display apparatus DSP2 can be reduced.

The CPU 21 has a function of, for example, performing general-purpose processing such as execution of an operating system, control of data, and execution of various arithmetic operations and programs. In the display apparatus DSP2, the CPU 21 has a function of, for example, giving an instruction for an operation for writing or reading image data to/from the memory device MEM, an operation for correcting image data, an operation for a sensor described later, or the like. Furthermore, the CPU 21 may have a function of, for example, transmitting a control signal to at least one of the circuits included in the functional circuit region MFNC, such as the memory device, the GPU, the correction circuit, the timing controller, and a high frequency circuit.

The CPU 21 may include a circuit for temporarily backing up data (hereinafter referred to as a backup circuit). The backup circuit is preferably capable of retaining the data even after supply of a power supply voltage is stopped. For example, in the case where the display region DIS displays a still image, the CPU 21 can cease to work until an image different from the currently displayed still image is displayed. Accordingly, dynamic power consumption by the CPU 21 can be reduced in such a manner that the data under processing by the CPU 21 is backed up in the backup circuit and then supply of a power supply voltage to the CPU 21 is stopped to stop the CPU 21. In this specification and the like, a CPU including a backup circuit is referred to as a NoffCPU.

The sensor controller SCC has a function of, for example, controlling the sensor PDA. FIG. 48 illustrates a wiring SNCL as a wiring for electrically connecting the sensor PDA to the sensor controller SCC.

The sensor PDA is, for example, a touch sensor that can be provided above, below, or inside the display region DIS.

Alternatively, the sensor PDA may be an illuminance sensor, for example. Specifically, the illuminance sensor acquiring the intensity of the external light with which the display region DIS is irradiated makes it possible to change the brightness (luminance) of an image displayed on the display region DIS in accordance with the intensity of the external light. For example, under intense external light, the luminance of an image displayed on the display region DIS can be increased to enhance the viewability of the image. By contrast, under weak external light, the luminance of an image displayed on the display region DIS can be lowered to reduce the power consumption.

Alternatively, the sensor PDA can be an image sensor, for example. For example, an image or the like acquired with the image sensor can be displayed on the display region DIS.

The power supply circuit EPS has a function of, for example, generating voltages to be supplied to the circuits included in the driver circuit region DRV, the circuits included in the functional circuit region MFNC, the pixels included in the display region DIS, and the like. Note that the power supply circuit EPS may have a function of selecting a circuit to which a voltage is to be supplied. For example, the power supply circuit EPS stops supply of a voltage to the circuits included in the driver circuit region DRV (e.g., the driver circuit SDR and the digital-to-analog converter circuit DAD) and the circuits included in the functional circuit region MFNC (e.g., the CPU 21 and the GPU 22) during a period in which the display region DIS displays a still image, whereby the power consumption of the whole display apparatus DSP can be reduced.

### Cross-Sectional Structure Example 1 of Display Apparatus

Next, a cross-sectional structure example of the display apparatus DSP1 illustrated in FIG. 47A is described.

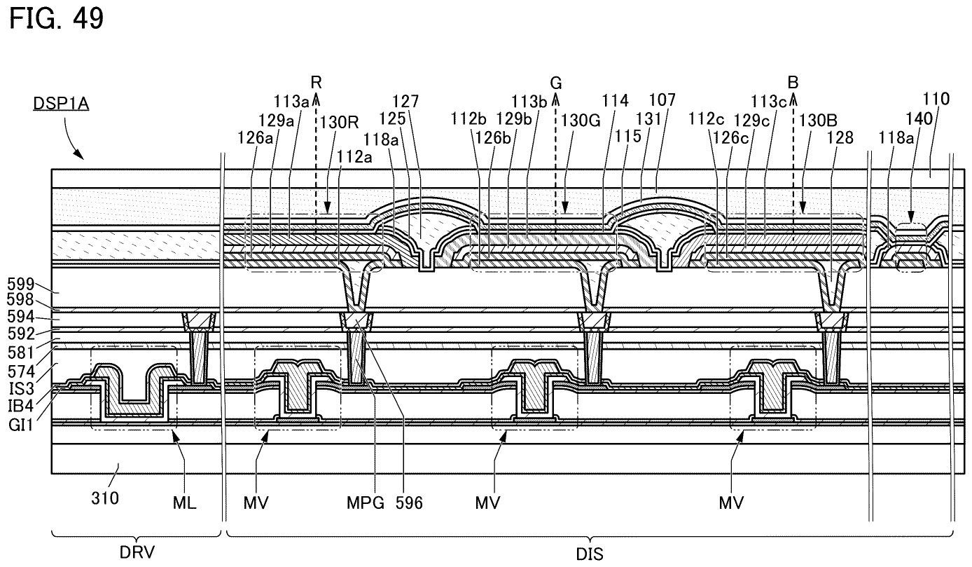

A display apparatus DSP1A illustrated in FIG. 49 is a cross-sectional structure example of the display apparatus DSP1 illustrated in FIG. 47A. The display apparatus DSP1A has a structure provided with a pixel circuit, a driver circuit, and the like over a substrate 310. In the display apparatus DSP1A in FIG. 49, the driver circuit region DRV and the display region DIS that are illustrated in FIG. 47A are illustrated.

The substrate 310 in FIG. 49 corresponds to the substrate BS illustrated in FIG. 47A. The diagonal size of the display apparatus DSP1A can be determined depending on the kind and the size of the substrate 310, for example. For example, in the case where a display apparatus with a diagonal size of greater than or equal to 30 inches, greater than or equal to 50 inches, greater than or equal to 70 inches, or greater than or equal to 100 inches is fabricated for a television device or an electronic device for digital signage application, a glass substrate may be used as the substrate 310. In the case where a display apparatus with a diagonal size of less than or equal to 10 inches, less than or equal to 5 inches, less than or equal to 1.5 inches, less than or equal to 1 inch, or less than or equal to 0.5 inches is fabricated for an XR device or a wearable information terminal, a semiconductor substrate may be used as the substrate 310.

There is no particular limitation on the screen ratio (aspect ratio) of the display apparatus DSP1A. For example, the display apparatus DSP1A is compatible with a variety of screen ratios such as 1:1 (a square), 4:3, 16:9, 16:10, 21:9, and 32:9.

In the display apparatus DSP1A in FIG. 49, the transistor ML and the transistor MV are formed over the substrate 310. Light-emitting devices 130 (a light-emitting device 130R, a light-emitting device 130G, and a light-emitting device 130B in FIG. 49) are provided above the transistor ML and the transistor MV.

In FIG. 49, the transistor MV is included in the display region DIS and functions as, for example, a transistor included in the pixel circuit PX. The transistor ML functions as a transistor included in the driver circuit region DRV. For example, the transistor MV can be the transistor MV described in Embodiment 1, and the transistor ML can be the transistor ML described in Embodiment 1. The light-emitting device 130 can be a light-emitting device included in the pixel circuit PX.

Although FIG. 49 shows an example in which the transistor ML is included in the driver circuit region DRV, the transistor MV may be included in the driver circuit region DRV. In addition, although FIG. 49 shows an example in which the transistor MV is included in the display region DIS, the transistor ML may be included in the display region DIS.

The transistor MV and the transistor ML are provided over the substrate 310. For the insulating layer, the conductive layer, and the semiconductor layer in the vicinity of the transistor MV and the transistor ML, Embodiment 1 and Embodiment 3 are referred to.

As described in Embodiment 1 and Embodiment 3, the insulating layer IS3 is formed above the transistor MV and the transistor ML. An insulating layer 574 and an insulating layer 581 are stacked in this order over the insulating layer IS3.

The insulating layer 574 preferably has a function of inhibiting diffusion of impurities such as water and hydrogen (e.g., one or both of a hydrogen atom and a hydrogen molecule). In other words, the insulating layer 574 preferably functions as a barrier insulating film that inhibits the entry of the impurities into the transistor ML and the transistor MV. Moreover, the insulating layer 574 preferably has a function of inhibiting diffusion of oxygen (e.g., one or both of an oxygen atom and an oxygen molecule). For example, the insulating layer 574 preferably has a lower oxygen permeability than the insulating layer IS2 and the insulating layer IS3.

Thus, the insulating layer 574 preferably functions as a barrier insulating film that inhibits diffusion of impurities such as water and hydrogen. Accordingly, it is preferable to use, for the insulating layer 574, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (an insulating material through which the impurities are unlikely to pass). Alternatively, it is preferable to use an insulating material having a function of inhibiting diffusion of oxygen (e.g., one or both of an oxygen atom and an oxygen molecule) (an insulating material through which the oxygen is unlikely to pass).

An insulator having a function of inhibiting the passage of oxygen and impurities such as water and hydrogen can be formed to have a single layer or a stacked layer including an insulator containing one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum, for example. Specific examples of the insulator having a function of inhibiting the passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulator having a function of inhibiting the passage of oxygen and impurities such as water and hydrogen include oxides containing aluminum and hafnium (hafnium aluminate). Other examples of the insulator having a function of inhibiting the passage of oxygen and impurities such as water and hydrogen include metal nitrides such as aluminum nitride, aluminum titanium nitride, titanium nitride, silicon nitride oxide, and silicon nitride.

In particular, aluminum oxide or silicon nitride is preferably used for the insulating layer 574. Accordingly, it is possible to inhibit diffusion of impurities such as water and hydrogen to the transistor ML side and into the transistor MV from above the insulating layer 574. In addition, it is possible to inhibit diffusion of oxygen contained in the insulating layer IS3 or the like to above the insulating layer 574.

The insulating layer 581 is preferably a film functioning as an interlayer film and having a lower permittivity than the insulating layer 574. When a material with a low permittivity is used for an interlayer film, parasitic capacitance generated between wirings can be reduced. The relative permittivity of the insulating layer 581 is preferably lower than 4, further preferably lower than 3, for example. The relative permittivity of the insulating layer 581 is, for example, preferably 0.7 times or less, further preferably 0.6 times or less the relative permittivity of the insulating layer 574. When a material with a low permittivity is used for the insulating layer 581 functioning as an interlayer film, parasitic capacitance generated between wirings can be reduced.

The concentration of impurities such as water and hydrogen in the insulating layer 581 is preferably reduced. In this case, for the insulating layer 581, silicon oxide, silicon oxynitride, silicon nitride oxide, or silicon nitride can be used, for example. Alternatively, for the insulating layer 581, silicon oxide to which fluorine is added, silicon oxide to which carbon is added, silicon oxide to which carbon and nitrogen are added, or porous silicon oxide can be used, for example. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Alternatively, for the insulating layer 581, a resin can be used. A material that can be used for the insulating layer 581 may be an appropriate combination of the above-described materials.

An insulating layer 592 and an insulating layer 594 are stacked in this order over the insulating layer 574 and the insulating layer 581.

For the insulating layer 592, it is preferable to use an insulating film having a barrier property (referred to as a barrier insulating film) which prevents diffusion of impurities such as water and hydrogen from the substrate 310, the transistor ML, and the transistor MV to a region above the insulating layer 592 (e.g., the region where the light-emitting device 130R, the light-emitting device 130G, the light-emitting device 130B, and the like are provided). Accordingly, for the insulating layer 592, it is preferable to use an insulating material that has a function of inhibiting diffusion of impurities such as a hydrogen atom, a hydrogen molecule, and a water molecule (through which the above impurities are less likely to pass). Furthermore, depending on the situation, it is preferable to use, for the insulating layer 592, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (an insulating material through which the oxygen is unlikely to pass). Alternatively, the insulating layer 592 preferably has a function of inhibiting diffusion of oxygen (e.g., one or both of an oxygen atom and an oxygen molecule).

For the film having a barrier property against hydrogen, silicon nitride formed by a CVD method can be used, for example.

The amount of released hydrogen can be analyzed by thermal desorption spectrometry (TDS), for example. The amount of hydrogen released from an insulating layer 324 that is converted into hydrogen atoms per area of the insulating layer 324 is less than or equal to 10×10¹⁵atoms/cm², preferably less than or equal to 5×10¹⁵ atoms/cm² in the TDS in a film-surface temperature range of 50° C. to 500° C., for example.

Like the insulating layer 581, the insulating layer 594 is preferably an interlayer film with a low permittivity. Thus, for the insulating layer 594, a material that can be used for the insulating layer 581 can be used.

Note that the insulating layer 594 preferably has a lower permittivity than the insulating layer 592. The relative permittivity of the insulating layer 594 is preferably lower than 4, further preferably lower than 3, for example. The relative permittivity of the insulating layer 594 is, for example, preferably 0.7 times or less, further preferably 0.6 times or less the relative permittivity of the insulating layer 592. When a material with a low permittivity is used for the insulating layer 594 functioning as an interlayer film, parasitic capacitance generated between wirings can be reduced.

A conductive layer MPG functioning as a plug or a wiring is embedded in the insulating layer GI1, the insulating layer IB4, and the insulating layer IS3, and a conductive layer 596 functioning as a plug or a wiring is embedded in the insulating layer 592 and the insulating layer 594. In particular, the conductive layer MPG and the conductive layer 596 are electrically connected to the light-emitting device or the like provided above the insulating layer 594. A plurality of conductors each having a function of a plug or a wiring are collectively denoted by the same reference numeral in some cases. Moreover, in this specification and the like, a wiring and a plug connected to the wiring may be a single component. That is, part of a conductor functions as a wiring in some cases and part of a conductor functions as a plug in other cases.

As a material of each of plugs and wirings (e.g., the conductive layer MPG and the conductive layer 596), a single layer or a stacked layer of one or more conductive materials selected from a metal material, an alloy material, a metal nitride material, and a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used for formation. The use of a low-resistance conductive material can reduce wiring resistance.

An insulating layer 598 and an insulating layer 599 are sequentially formed over the insulating layer 594 and the conductive layer 596.

Like the insulating layer 592, for example, the insulating layer 598 is preferably formed using an insulator having a barrier property against one or more selected from hydrogen, oxygen, and water. Like the insulating layer 594, the insulating layer 599 is preferably formed using an insulator having a relatively low dielectric constant to reduce parasitic capacitance generated between wirings. The insulating layer 599 has functions of an interlayer insulating film and a planarization film.

The light-emitting device 130 and a connection portion 140 are formed over the insulating layer 599.

The connection portion 140 is referred to as a cathode contact portion in some cases, and is electrically connected to cathode electrodes of the light-emitting device 130R, the light-emitting device 130G, and the light-emitting device 130B. The connection portion 140 in FIG. 49 includes one or more conductors selected from a conductive layer 112a to a conductive layer 112c described later, at least one of a conductive layer 126a to a conductive layer 126c described later, one or more conductors selected from a conductive layer 129a to a conductive layer 129c described later, a common layer 114 described later, and a common electrode 115 described later.

Note that the connection portion 140 may be provided to surround four sides of the display portion in the plan view, or may be provided in the display portion (e.g., between adjacent light-emitting devices 130) (not illustrated).

The light-emitting device 130R includes the conductive layer 112a, the conductive layer 126a over the conductive layer 112a, and the conductive layer 129a over the conductive layer 126a. All of the conductive layer 112a, the conductive layer 126a, and the conductive layer 129a can be referred to as a pixel electrode, or one or two of them can be referred to as a pixel electrode. The light-emitting device 130G includes the conductive layer 112b, the conductive layer 126b over the conductive layer 112b, and the conductive layer 129b over the conductive layer 126b. As in the light-emitting device 130R, all of the conductive layer 112b, the conductive layer 126b, and the conductive layer 129b can be referred to as a pixel electrode, or one or two of them can be referred to as a pixel electrode. The light-emitting device 130B includes the conductive layer 112c, the conductive layer 126c over the conductive layer 112c, and the conductive layer 129c over the conductive layer 126c. As in the light-emitting device 130R and the light-emitting device 130G, all of the conductive layer 112c, the conductive layer 126c, and the conductive layer 129c can be referred to as a pixel electrode, or one or two of them can be referred to as a pixel electrode.

For each of the conductive layer 112a to the conductive layer 112c and the conductive layer 126a to the conductive layer 126c, a conductive layer functioning as a reflective electrode can be used, for example. For the conductive layer functioning as a reflective electrode, a conductor with high visible-light reflectance such as silver, aluminum, or an alloy film of silver (Ag), palladium (Pd), and copper (Cu) (an Ag-Pd-Cu (APC) film) can be used. For each of the conductive layer 112a to the conductive layer 112c and the conductive layer 126a to the conductive layer 126c, a stacked-layer film in which a pair of titanium films sandwich aluminum (a film in which Ti, Al, and Ti are stacked in this order), or a stacked-layer film in which a pair of indium tin oxide films sandwich silver (a film in which ITO, Ag, and ITO are stacked in this order) can be used.

For example, a conductive layer functioning as a reflective electrode may be used for each of the conductive layer 112a to the conductive layer 112c, and a conductor with a high light-transmitting property may be used for each of the conductive layer 126a to the conductive layer 126c. Examples of the conductor with a high light-transmitting property include an alloy of silver and magnesium and indium tin oxide (sometimes referred to as ITO).

A conductive layer functioning as a transparent electrode can be used for each of the conductive layer 129a to the conductive layer 129c. For the conductive layer functioning as a transparent electrode, for example, the above-described conductor with a high light-transmitting property can be used.

A microcavity structure may be provided in the light-emitting device 130 to be described in detail later. The microcavity structure refers to a structure in which the distance between the bottom surface of the light-emitting layer and the top surface of a lower electrode is set to a thickness depending on a wavelength of color of light emitted from the light-emitting layer. In that case, a light-transmitting and light-reflective conductive material is preferably used for each of the conductive layer 129a to the conductive layer 129c which serve as an upper electrode (a common electrode), and a light-reflective conductive material is preferably used for each of the conductive layer 112a to the conductive layer 112c and the conductive layer 126a to the conductive layer 126c which serve as lower electrodes (pixel electrodes).

The microcavity structure refers to a structure in which the optical distance between the lower electrode and the light-emitting layer is adjusted to be (2n−1)λ/4 (n is a natural number greater than or equal to 1, and λ is a wavelength of emitted light desired to be amplified). Thus, light that is reflected back by the lower electrode (reflected light) considerably interferes with light that directly enters the upper electrode from the light-emitting layer (incident light). Accordingly, the phases of the reflected light and the incident light each having the wavelength λ can be aligned with each other, and the light emitted from the light-emitting layer can be further amplified. Meanwhile, in the case where the reflected light and the incident light each have a wavelength other than the wavelength λ, their phases are not aligned with each other, resulting in attenuation without resonation.

The conductive layer 112a is connected to the conductive layer 596 embedded in the insulating layer 594 through an opening formed in the insulating layer 599. An end portion of the conductive layer 112a is positioned on the outer side of an end portion of the conductive layer 126a. The end portion of the conductive layer 126a and an end portion of the conductive layer 129a are aligned or substantially aligned with each other.

The conductive layer 112b, the conductive layer 126b, and the conductive layer 129b of the light-emitting device 130G and the conductive layer 112c, the conductive layer 126c, and the conductive layer 129c of the light-emitting device 130B are not described in detail because they are similar to the conductive layer 112a, the conductive layer 126a, and the conductive layer 129a of the light-emitting device 130R.

Depression portions are formed in the conductive layer 112a, the conductive layer 112b, and the conductive layer 112c to cover the openings provided in the insulating layer 599. A layer 128 is embedded in the depression portions.

The layer 128 has a function of filling the depression portions of the conductive layer 112a to the conductive layer 112c. The conductive layer 126a to the conductive layer 126c electrically connected to the conductive layer 112a to the conductive layer 112c, respectively, are provided over the conductive layer 112a to the conductive layer 112c and the layer 128. Thus, regions overlapping with the depression portions of the conductive layer 112a to the conductive layer 112c can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used for the layer 128. For the layer 128, an acrylic resin, a polyimide resin, an epoxy resin, a polyamide resin, a polyimide-amide resin, a siloxane resin, a benzocyclobutene-based resin, a phenol resin, or a precursor of any of these resins can be used, for example. A photosensitive resin can also be used for the layer 128. As the photosensitive resin, a positive material or a negative material is given.

When a photosensitive resin is used, the layer 128 can be formed through only light-exposure and development steps, reducing the influence of dry etching or wet etching on the surfaces of the conductive layer 112a, the conductive layer 112b, and the conductive layer 112c. When the layer 128 is formed using a negative photosensitive resin, the layer 128 can sometimes be formed using the same photomask (light-exposure mask) as the photomask used for forming the opening in the insulating layer 599.

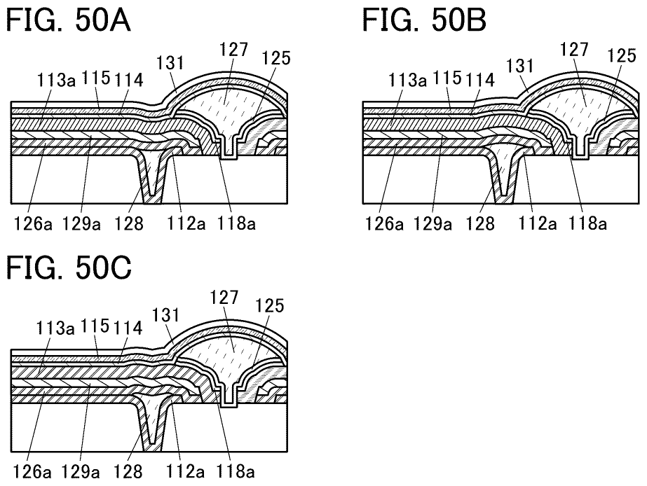

Although FIG. 49 shows an example in which the top surface of the layer 128 includes a flat portion, the shape of the layer 128 is not particularly limited. As illustrated in FIG. 50A, the middle and the vicinity of the top surface of the layer 128 may be concave in the cross-sectional view. Alternatively, as illustrated in FIG. 50B, the middle and the vicinity of the layer 128 may be convex in the cross-sectional view. As illustrated in FIG. 50C, the middle and the vicinity of the layer 128 may be concave and convex.

The light-emitting device 130R includes a first layer 113a, the common layer 114 over the first layer 113a, and the common electrode 115 over the common layer 114. The light-emitting device 130G includes a second layer 113b, the common layer 114 over the second layer 113b, and the common electrode 115 over the common layer 114. The light-emitting device 130B includes a third layer 113c, the common layer 114 over the third layer 113c, and the common electrode 115 over the common layer 114.

The first layer 113a is formed to cover the top surface and side surface of the conductive layer 126a and the top surface and side surface of the conductive layer 129a. Similarly, the second layer 113b is formed to cover the top surface and side surface of the conductive layer 126b and the top surface and side surface of the conductive layer 129b. Similarly, the third layer 113c is formed to cover the top surface and side surface of the conductive layer 126c and the top surface and side surface of the conductive layer 129c. Accordingly, regions provided with the conductive layer 126a, the conductive layer 126b, and the conductive layer 126c can be entirely used as the light-emitting regions of the light-emitting device 130R, the light-emitting device 130G, and the light-emitting device 130B, respectively, increasing the aperture ratio of the pixels.

In the light-emitting device 130R, the first layer 113a and the common layer 114 can be collectively referred to as an EL layer. Similarly, in the light-emitting device 130G, the second layer 113b and the common layer 114 can be collectively referred to as an EL layer. Similarly, in the light-emitting device 130B, the third layer 113c and the common layer 114 can be collectively referred to as an EL layer.

There is no particular limitation on the structure of the light-emitting device in this embodiment, and the light-emitting device can have a single structure or a tandem structure.

The first layer 113a, the second layer 113b, and the third layer 113c each have an island shape after being processed by a lithography method. Thus, at each of end portions of the first layer 113a, the second layer 113b, and the third layer 113c, an angle between the top surface and side surface is approximately 90°. By contrast, for example, an organic film formed using an FMM (Fine Metal Mask) tends to have a thickness that gradually decreases with decreasing distance to an end portion, and has the top surface forming a slope in an area extending greater than or equal to 1 μm and less than or equal to 10 μm from the end portion, for example; thus, such an organic film has a shape whose top surface and side surface cannot be easily distinguished from each other.

The top surface and side surface of each of the first layer 113a, the second layer 113b, and the third layer 113c are clearly distinguished from each other. Accordingly, as for the first layer 113a and the second layer 113b which are adjacent to each other, one of the side surfaces of the first layer 113a and one of the side surfaces of the second layer 113b face to each other. This applies to a combination of any two of the first layer 113a, the second layer 113b, and the third layer 113c.

The first layer 113a, the second layer 113b, and the third layer 113c each include at least a light-emitting layer. For example, a structure is preferable in which the first layer 113a includes a light-emitting layer that emits red light, the second layer 113b includes a light-emitting layer that emits green light, and the third layer 113c includes a light-emitting layer that emits blue light. Other than the above colors, cyan, magenta, yellow, or white can be employed for the light-emitting layers.

The first layer 113a, the second layer 113b, and the third layer 113c each preferably include a light-emitting layer and a carrier-transport layer (an electron-transport layer or a hole-transport layer) over the light-emitting layer. Since surfaces of the first layer 113a, the second layer 113b, and the third layer 113c may be exposed in the manufacturing process of the display apparatus, providing the carrier-transport layer over the light-emitting layers inhibits the light-emitting layers from being exposed on the outermost surface, so that damage to the light-emitting layers can be reduced. Accordingly, the reliability of the light-emitting devices can be improved.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting device 130R, the light-emitting device 130G, and the light-emitting device 130B.

The common electrode 115 is shared by the light-emitting device 130R, the light-emitting device 130G, and the light-emitting device 130B. As illustrated in FIG. 49, the common electrode 115 shared by the plurality of light-emitting devices is electrically connected to a conductor included in the connection portion 140.

An insulating layer 125 preferably has a function of a barrier insulating layer against one or both of water and oxygen. Alternatively, the insulating layer 125 preferably has a function of inhibiting diffusion of one or both of water and oxygen. Alternatively, the insulating layer 125 preferably has a function of capturing or fixing (also referred to as gettering) one or both of water and oxygen. When the insulating layer 125 has a function of a barrier insulating layer or a gettering function, entry of impurities (typically, one or both of water and oxygen) that would be diffused into the light-emitting devices from the outside can be inhibited. With this structure, a highly reliable light-emitting device and a highly reliable display panel can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against one or both of water and oxygen can be increased. For example, it is desirable that one or both of the hydrogen concentration and the carbon concentration in the insulating layer 125 be sufficiently low.

As an insulating layer 127, an insulating layer containing an organic material can be favorably used. As the organic material, a photosensitive organic resin is preferably used; for example, a photosensitive resin composition containing an acrylic resin may be used. The viscosity of the material of the insulating layer 127 is greater than or equal to 1 cP and less than or equal to 1500 cP, and is preferably greater than or equal to 1 cP and less than or equal to 12 cP. By setting the viscosity of the material of the insulating layer 127 in the above-described range, the insulating layer 127 having a tapered shape, which is described later, can be formed relatively easily. Note that in this specification and the like, an acrylic resin refers to not only a polymethacrylic acid ester or a methacrylic resin, but also all the acrylic polymer in a broad sense in some cases.

Note that in this specification and the like, a tapered shape refers to a shape in which at least part of a side surface of a structure is inclined to a substrate surface. For example, a tapered shape preferably includes a region where an angle formed between the inclined side surface and the substrate surface (such an angle is also referred to as a taper angle) is less than 90°.

Note that the organic material that can be used for the insulating layer 127 is not limited to the above as long as the insulating layer 127 has a tapered side surface as described later. For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, or a precursor of any of these resins can be used in some cases, for example. Alternatively, an organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be employed for the insulating layer 127 in some cases. For the insulating layer 127, for example, a photoresist can be used as the photosensitive resin in some cases. Note that as the photosensitive resin, a positive material or a negative material can be used.

For the insulating layer 127, a material absorbing visible light may be used. When the insulating layer 127 absorbs light from the light-emitting device, leakage of light (stray light) from the light-emitting device to the adjacent light-emitting device through the insulating layer 127 can be inhibited. Thus, the display quality of the display panel can be improved. Since the display quality of the display panel can be improved without using a polarizing plate, the weight and thickness of the display panel can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two colors or three or more colors is particularly preferred, in which case the effect of blocking visible light can be enhanced. In particular, mixing color filter materials of three or more colors enables the formation of a black or nearly black resin layer.

For example, the insulating layer 127 can be formed by a wet film-formation method such as spin coating, dipping, spray coating, ink-jetting, dispensing, screen printing, offset printing, doctor blade coating, slit coating, roll coating, curtain coating, or knife coating. Specifically, an organic insulating film to be the insulating layer 127 is preferably formed by spin coating.

The insulating layer 127 is formed at a temperature lower than the heat resistance temperature of the EL layer. The typical substrate temperature in formation of the insulating layer 127 is lower than or equal to 200° C., preferably lower than or equal to 180° C., further preferably lower than or equal to 160° C., still further preferably lower than or equal to 150° C., yet still further preferably lower than or equal to 140° C.

The description is made below on the structure of the insulating layer 127 or the like using the structure of the insulating layer 127 between the light-emitting device 130R and the light-emitting device 130G as an example. Note that the same applies to the insulating layer 127 between the light-emitting device 130G and the light-emitting device 130B, the insulating layer 127 between the light-emitting device 130B and the light-emitting device 130R, and the like. The description made below sometimes using an end portion of the insulating layer 127 over the second layer 113b as an example applies to an end portion of the insulating layer 127 over the first layer 113a and an end portion of the insulating layer 127 over the third layer 113c.

In a cross-sectional view of the display apparatus, the side surface of the insulating layer 127 preferably has a tapered shape with a taper angle θ1. The taper angle θ1 is an angle formed between the side surface of the insulating layer 127 and the substrate surface. Note that the taper angle θ1 is not limited to the angle with the substrate surface, and may be an angle formed between the side surface of the insulating layer 127 and the top surface of the flat portion of the insulating layer 125 or the top surface of the flat portion of the second layer 113b. When the side surface of the insulating layer 127 has a tapered shape, the side surface of the insulating layer 125 and the side surface of the mask layer 118a also have a tapered shape in some cases.

The taper angle θ1 of the insulating layer 127 is less than 90°, preferably less than or equal to 60°, and further preferably less than or equal to 45°. Such a forward tapered shape of the end portion of the side surface of the insulating layer 127 can prevent disconnection, local thinning, or the like from occurring in the common layer 114 and the common electrode 115 which are provided over the end portion of the side surface of the insulating layer 127, leading to film formation with good coverage. The common layer 114 and the common electrode 115 can have improved in-plane uniformity in this manner, whereby the display apparatus can have improved display quality.

The top surface of the insulating layer 127 preferably has a convex shape in a cross-sectional view of the display apparatus. The top surface of the insulating layer 127 preferably has a convex shape that bulges gradually toward the center. The insulating layer 127 preferably has a shape such that the projecting portion at the center portion of the top surface is connected smoothly to the tapered portion of the end portion of the side surface. When the insulating layer 127 has such a shape, the common layer 114 and the common electrode 115 can be formed with good coverage over the whole the insulating layer 127.

The insulating layer 127 is formed in a region between two EL layers (e.g., a region between the first layer 113a and the second layer 113b). At this time, part of the insulating layer 127 is placed at a position sandwiched between an end portion of the side surface of one of the EL layers (e.g., the first layer 113a) and an end portion of the side surface of the other of the EL layers (e.g., the second layer 113b).

One end portion of the insulating layer 127 preferably overlaps with the conductive layer 126a serving as a pixel electrode, and the other end portion of the insulating layer 127 preferably overlaps with the conductive layer 126b serving as a pixel electrode. With such a structure, the end portion of the insulating layer 127 can be formed over a substantially flat region of the first layer 113a (the second layer 113b). This makes it relatively easy to process the tapered shape of the insulating layer 127 as described above.

By providing the insulating layer 127 and the like in the above manner, a disconnected portion and a locally thinned portion can be prevented from being formed in the common layer 114 and the common electrode 115 from a substantially flat region in the first layer 113a to a substantially flat region in the second layer 113b. Thus, between the light-emitting devices, a connection defect caused by the disconnected portion and an increase in electric resistance caused by the locally thinned portion can be inhibited from occurring in the common layer 114 and the common electrode 115.

In the display apparatus of this embodiment, the distance between the light-emitting devices can be short. Specifically, the distance between the light-emitting devices, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus of this embodiment includes a region where a distance between two adjacent island-shaped EL layers is less than or equal to 1 μm, preferably less than or equal to 0.5 μm (500 nm), further preferably less than or equal to 100 nm. The distance between the light-emitting devices is shortened in this manner, whereby a display apparatus with high definition and a high aperture ratio can be provided.

A protective layer 131 is provided over the light-emitting device 130. The protective layer 131 is a film serving as a passivation film for protecting the light-emitting devices 130. Provision of the protective layer 131 covering the light-emitting device can inhibit an impurity such as water and oxygen from entering the light-emitting device, and increase the reliability of the light-emitting device 130. For the protective layer 131, aluminum oxide, silicon nitride, or silicon nitride oxide can be used, for example.

The protective layer 131 and a substrate 110 are bonded to each other with an adhesive layer 107. A solid sealing structure, a hollow sealing structure, or the like can be employed to seal the light-emitting devices. In FIG. 49, a solid sealing structure is employed in which a space between the substrate 310 and the substrate 110 is filled with the adhesive layer 107. Alternatively, a hollow sealing structure in which the space is filled with an inert gas (e.g., nitrogen or argon) may be employed. Here, the adhesive layer 107 may be provided not to overlap with the light-emitting devices. The space may be filled with a resin other than the frame-shaped adhesive layer 107.

For the adhesive layer 107, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-liquid-mixture-type resin may be used. An adhesive sheet may be used.

The display apparatus DSP1A has a top-emission structure. Light from the light-emitting device is emitted toward the substrate 110 side. Thus, for the substrate 110, a material having a high visible-light-transmitting property is preferably used. For example, a substrate having a high visible-light-transmitting property may be selected as the substrate 110 among substrates usable as the substrate 310 and the substrate BS. The pixel electrode contains a material that reflects visible light, and a counter electrode (the common electrode 115) contains a material that transmits visible light.

Note that the display apparatus of one embodiment of the present invention may be not a top-emission display apparatus but a bottom-emission display apparatus where light from the light-emitting device is emitted to the substrate 310 side. In that case, a substrate having a high visible-light-transmitting property is selected as the substrate 310.

### Cross-Sectional Structure Example 2 of Display Apparatus

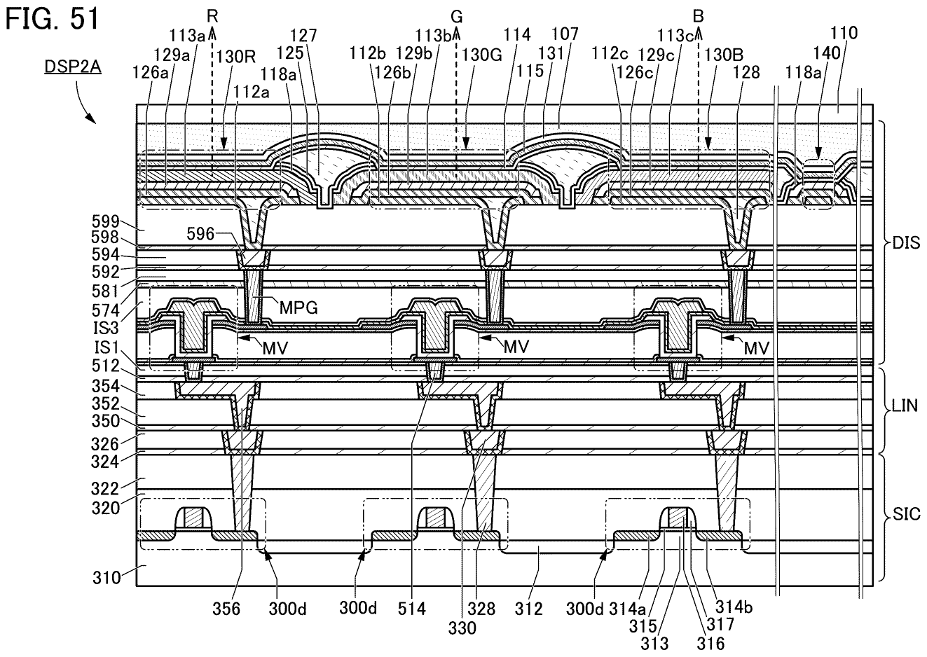

A display apparatus DSP2A illustrated in FIG. 51 is a cross-sectional structure example of the display apparatus DSP2 illustrated in FIG. 47B. The display apparatus DSP2A has a structure provided with a pixel circuit, a driver circuit, and the like over the substrate 310. Note that in the display apparatus DSP2A in FIG. 51, not only the circuit region SIC and the display region DIS that are illustrated in FIG. 47B but also a wiring region LIN are illustrated.

The circuit region SIC includes the substrate 310, for example, and a transistor 300d is formed over the substrate 310. The wiring region LIN is provided above the transistor 300d, and the wiring region LIN is provided with a wiring that electrically connects the transistor 300d, the transistor MV, the light-emitting device 130R, the light-emitting device 130G, and the light-emitting device 130B. The display region DIS is provided above the wiring region LIN, and the display region DIS includes, for example, the transistor MV, the light-emitting device 130 (the light-emitting device 130R, the light-emitting device 130G, and the light-emitting device 130B in FIG. 51), and the like.

That is, the transistor 300d can be a transistor included in the circuit region SIC. The transistor MV can be a transistor included in the pixel circuit PX. The light-emitting device 130 can be a light-emitting device included in the pixel circuit PX.

For the light-emitting devices 130 (the light-emitting device 130R, the light-emitting device 130G, and the light-emitting device 130B in FIG. 51) positioned above the transistor MV, the description of the light-emitting devices 130 in FIG. 49 can be referred to.

As the substrate 310, a substrate that can be used as the substrate BS can be used, for example. In the description in this embodiment, the substrate 310 is a semiconductor substrate containing silicon as a material. Therefore, a transistor included in the circuit region SIC can be a Si transistor.

For the screen ratio (aspect ratio) of the display apparatus DSP2A, the description of the screen ratio of the display apparatus DSP1 can be referred to. For the diagonal size of the display apparatus DSP2A, the description of the diagonal size of the display apparatus DSP1 can be referred to.

The transistor 300d includes an element isolation layer 312, a conductive layer 316, an insulating layer 315, an insulating layer 317, a semiconductor region 313 that is part of the substrate 310, and a low-resistance region 314a and a low-resistance region 314b that function as a source region and a drain region. Thus, the transistor 300 is a Si transistor. Although FIG. 51 illustrates a structure in which one of a source and a drain of the transistor 300d is electrically connected to a conductive layer 330, a conductive layer 356, and a conductive layer 514, which are described later, through a conductive layer 328 described later, the electrical connection structure in the display apparatus of one embodiment of the present invention is not limited thereto. The display apparatus of one embodiment of the present invention may have a structure in which, for example, a gate of the transistor 300d is electrically connected to the conductive layer 514 through the conductive layer 328.

The transistor 300d can be a fin type when, for example, the top surface of the semiconductor region 313 and the side surface thereof in the channel width direction are covered with the conductive layer 316 with the insulating layer 315 functioning as a gate insulator therebetween. The effective channel width can be increased in the fin-type transistor 300, so that the on-state characteristics of the transistor 300 can be improved. In addition, contribution of the electric field of a gate electrode can be increased, so that the off-state characteristics of the transistor 300 can be improved. The transistor 300 may have a planar structure instead of a fin-type structure.

Note that the transistor 300 may be either a p-channel transistor or an n-channel transistor. Alternatively, a plurality of the transistors 300 may be provided and both the p-channel transistor and the n-channel transistor may be used.

A region of the semiconductor region 313 where a channel is formed, a region in the vicinity thereof, and the low-resistance region 314a and the low-resistance region 314b that function as the source region and the drain region preferably contain a silicon-based semiconductor, specifically, preferably contain single crystal silicon. Alternatively, each of the regions may be formed using germanium, silicon germanium, gallium arsenide, aluminum gallium arsenide, or gallium nitride, for example. A structure using silicon whose effective mass is controlled by applying stress to the crystal lattice and changing the lattice spacing may be employed. Alternatively, the transistor 300d may be a HEMT (High Electron Mobility Transistor) using gallium arsenide and aluminum gallium arsenide, for example.

For the conductive layer 316 functioning as the gate electrode, a semiconductor material such as silicon containing an element that imparts n-type conductivity, such as arsenic or phosphorus, or an element that imparts p-type conductivity, such as boron or aluminum, can be used. Alternatively, for the conductive layer 316, a conductive material such as a metal material, an alloy material, or a metal oxide material can be used, for example.

Note that since the work function depends on the material of a conductor, the threshold voltage of the transistor can be adjusted by selecting the material of the conductor. Specifically, it is preferable to use one or both of titanium nitride and tantalum nitride as the material of the conductor. Moreover, in order to ensure both conductivity and embeddability, it is preferable to use stacked layers of metal materials of one or both of tungsten and aluminum for the conductor, and it is particularly preferable to use tungsten in terms of heat resistance.

The element isolation layer 312 is provided to separate a plurality of transistors formed on the substrate 310 from each other. The element isolation layer can be formed by, for example, a LOCOS (Local Oxidation Of Silicon) method, an STI (Shallow Trench Isolation) method, or a mesa isolation method.

Over the transistor 300 illustrated in FIG. 51, an insulating layer 320 and an insulating layer 322 are sequentially stacked from the substrate 310 side.

For each of the insulating layer 320 and the insulating layer 322, one or more selected from silicon oxide, silicon oxynitride, silicon nitride oxide, silicon nitride, aluminum oxide, aluminum oxynitride, aluminum nitride oxide, and aluminum nitride are used, for example.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

The insulating layer 322 may have a function of a planarization film for eliminating a level difference caused by the transistor 300 or the like covered with the insulating layer 320 and the insulating layer 322. For example, the top surface of the insulating layer 322 may be planarized by planarization treatment using a chemical mechanical polishing (CMP) method to improve planarity.

The conductive layer 328 connected to the transistor MV and the like provided above the insulating layer 322 is embedded in the insulating layer 320 and the insulating layer 322. Note that the conductive layer 328 has a function of a plug or a wiring. Therefore, for the conductive layer 328, a material that can be used for the conductive layer MPG described above can be used.

In the display apparatus DSP2A, the wiring region LIN is provided over the transistor 300d. The wiring region LIN includes, for example, the insulating layer 324, an insulating layer 326, the conductive layer 330, an insulating layer 350, an insulating layer 352, an insulating layer 354, and the conductive layer 356.

Over the insulating layer 322 and the conductive layer 328, the insulating layer 324 and the insulating layer 326 are sequentially stacked. An opening is formed in the insulating layer 324 and the insulating layer 326 in a region overlapping with the conductive layer 328. In addition, the conductive layer 330 is embedded in the opening.

The insulating layer 350, the insulating layer 352, and the insulating layer 354 are sequentially stacked over the insulating layer 326 and the conductive layer 330. An opening is formed in the insulating layer 350, the insulating layer 352, and the insulating layer 354 in a region overlapping with the conductive layer 330. The conductive layer 356 is embedded in the opening.

The conductive layer 330 and the conductive layer 356 have a function of a plug or a wiring that is connected to the transistor 300d. Note that the conductive layer 330 and the conductive layer 356 can be provided using a material similar to that for the conductive layer 328 or the conductive layer 596.

Note that like the insulating layer 592, for example, each of the insulating layer 324 and the insulating layer 350 is preferably formed using an insulator having a barrier property against one or more selected from hydrogen, oxygen, and water. Like the insulating layer 594, each of the insulating layer 326, the insulating layer 352, and the insulating layer 354 is preferably formed using an insulator having a relatively low dielectric constant to reduce parasitic capacitance generated between wirings. Each of the insulating layer 326, the insulating layer 352, and the insulating layer 354 has functions of an interlayer insulating film and a planarization film. Furthermore, each of the insulating layer 326, the insulating layer 352, and the insulating layer 354 preferably includes an insulator having a barrier property against one or more selected from hydrogen, oxygen, and water.

For the conductor having a barrier property against hydrogen, tantalum nitride is preferably used, for example. The use of a stack including tantalum nitride and tungsten that has high conductivity can inhibit diffusion of hydrogen from the transistor 300d while the conductivity of a wiring is maintained. In that case, a tantalum nitride layer having a barrier property against hydrogen is preferably in contact with the insulating layer 350 having a barrier property against hydrogen.

An insulating layer 512 is provided above the insulating layer 354 and the conductive layer 356. The insulating layer IS1 is provided over the insulating layer 512. The conductive layer 514 functioning as a plug or a wiring is embedded in the insulating layer IS1 and the insulating layer 512. Accordingly, one of the source and the drain of the transistor MV is electrically connected to one of the source and the drain of the transistor 300d. Note that for the conductive layer 514, a material that can be used for the conductive layer MPG can be used, for example.

The transistor MV is provided over the insulating layer IS1 and the conductive layer 514. The insulating layer 574 is formed over the transistor MV, and the insulating layer 581 is formed over the insulating layer 574. The conductive layer MPG functioning as a plug or a wiring is embedded in the insulating layer IS3, the insulating layer 574, and the insulating layer 581.

For the transistor MV and the insulating layer, the conductive layer, and the like in the vicinity of the transistor MV, the description of the transistor MV of the display apparatus DSP1A in FIG. 49 can be referred to.

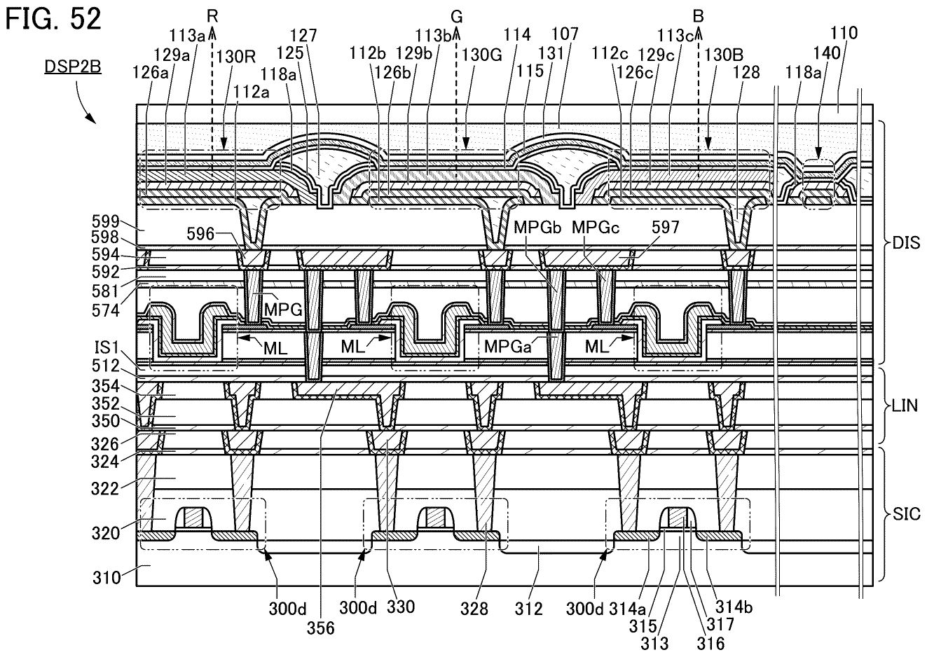

Although the display region DIS of the display apparatus DSP2A in FIG. 51 has a structure including the transistor MV, the display apparatus of one embodiment of the present invention may include the transistor ML instead of the transistor MV as in a display apparatus DSP2B illustrated in FIG. 52.

In the display apparatus DSP2B illustrated in FIG. 52, a conductive layer MPGa, a conductive layer MPGb, a conductive layer MPGc, and a conductive layer 597 each functioning as a plug or a wiring are embedded in insulators in the vicinity of the transistor ML to electrically connect the transistor ML and the transistor 300d. Specifically, the conductive layer MPGa is embedded in the insulating layer IS1 and the insulating layer IS2, the conductive layer MPGb and the conductive layer MPGc are embedded in the insulator GI1 and the insulating layer IS3, and the conductive layer 597 is embedded in the insulating layer 592 and the insulating layer 594. Thus, the transistor 300d and the transistor ML are electrically connected to each other through the conductive layer 328, the conductive layer 330, the conductive layer 356, the conductive layer MPGa, the conductive layer MPGb, the conductive layer 597, and the conductive layer MPGc.

For each of the conductive layer MPGa to the conductive layer MPGc, a material that can be used for the conductive layer MPG can be used. For the conductive layer 597, a material that can be used for the conductive layer 596 can be used.

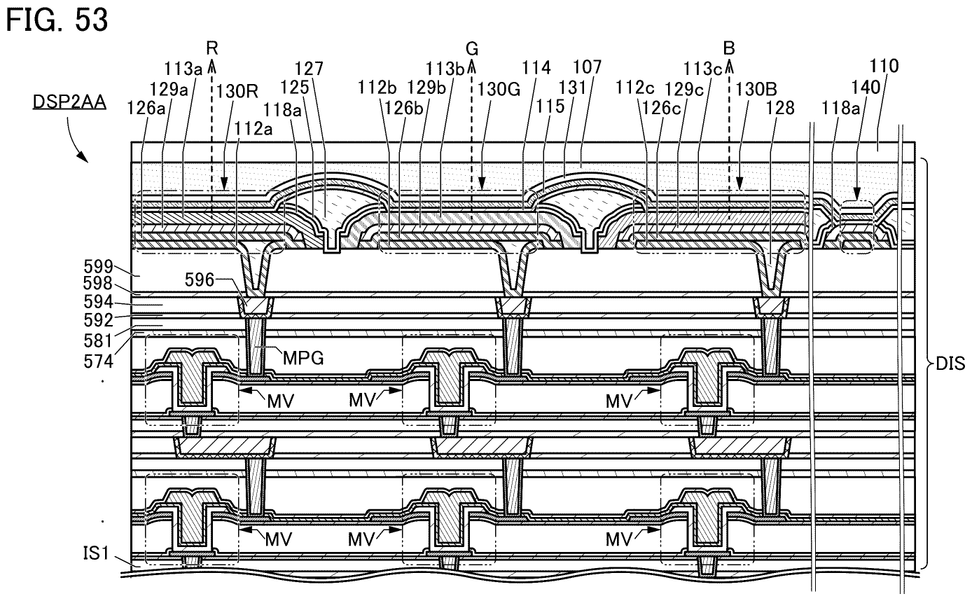

Although the display region DIS of the display apparatus DSP2A in FIG. 51 has a structure in which the transistor MV is included in one layer, the display apparatus of one embodiment of the present invention may have a structure in which a plurality of layers are provided in the display region DIS and the transistor MV is included in each of the plurality of layers as in a display apparatus DSP2AA illustrated in FIG. 53.

Note that although the display region DIS in the display apparatus DSP2AA in FIG. 53 is selectively illustrated, the wiring region LIN and the circuit region SIC are provided below the display region DIS.

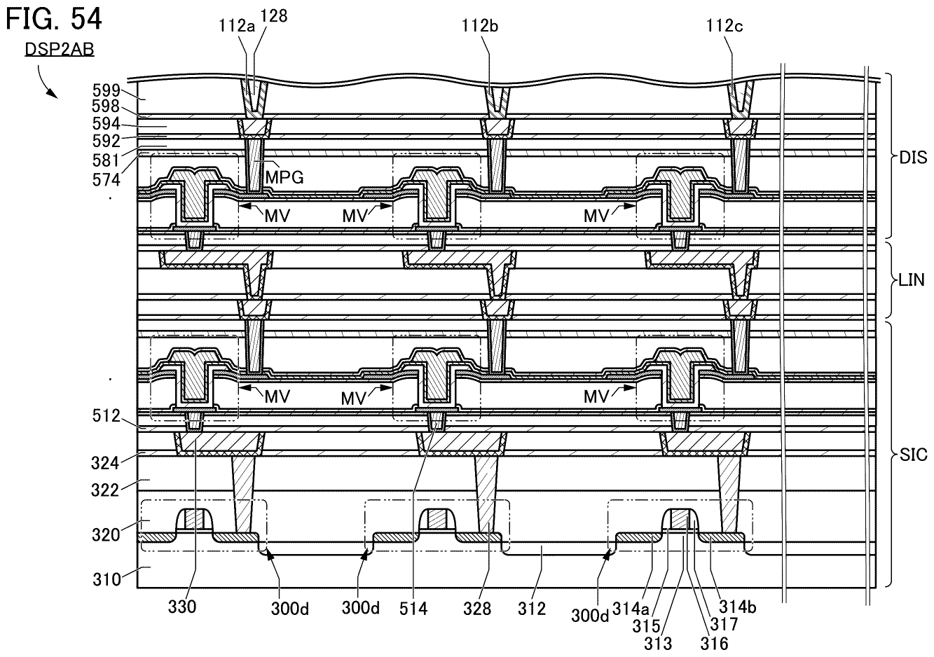

The display region DIS of the display apparatus DSP2A in FIG. 51 has a structure in which the transistor 300d is included in one layer in the circuit region SIC: alternatively, in the circuit region SIC of the display apparatus of one embodiment of the present invention, one layer including the transistor MV may be provided above the transistor 300d as in a display apparatus DSP2AB illustrated in FIG. 54. In the circuit region SIC, the number of layers including the transistor MV may be one or more (not illustrated).

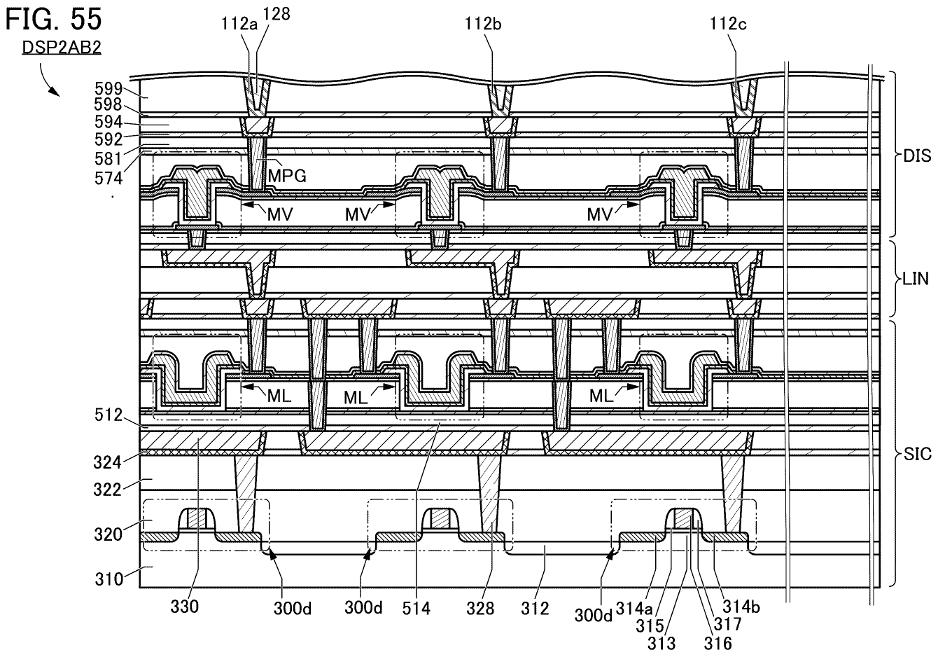

The display apparatus DSP2AB illustrated in FIG. 54 has a structure in which the transistor MV is included in the circuit region SIC: alternatively, in the circuit region SIC of the display apparatus of one embodiment of the present invention, one layer including the transistor ML may be provided as in a display apparatus DSP2AB2 illustrated in FIG. 55. In the circuit region SIC, the number of layers including the transistor ML may be one or more (not illustrated).

Note that although part of the display region DIS, the wiring region LIN, and the circuit region SIC in each of the display apparatus DSP2AB in FIG. 54 and the display apparatus DSP2AB2 in FIG. 55 are selectively illustrated, the light-emitting device 130 is provided above the transistor MV in the display region DIS.

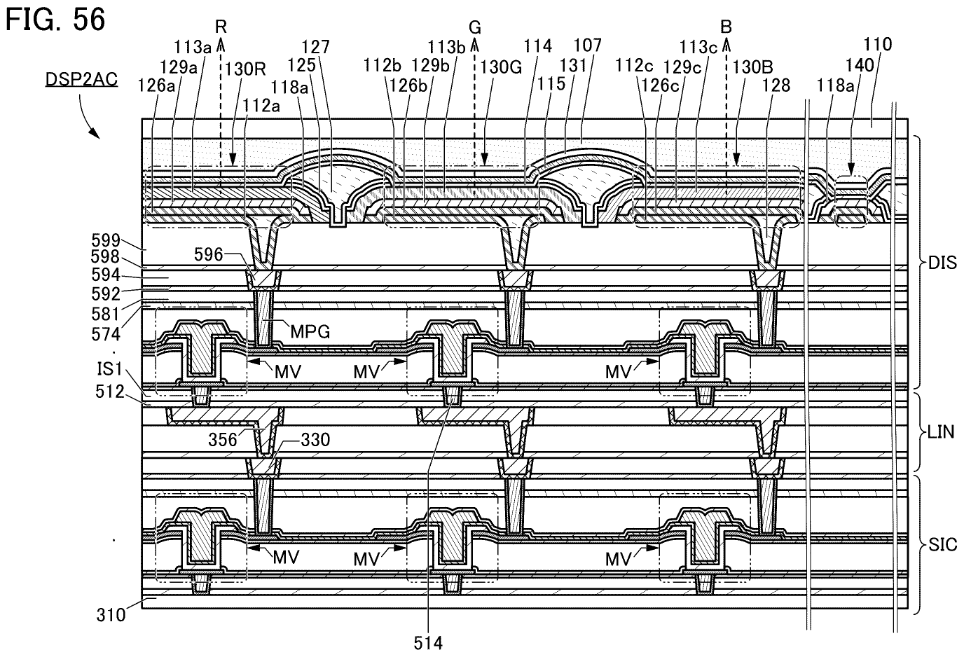

The structure of the transistor 300d in the display apparatus DSP2A in FIG. 51 may be modified to the structure of the transistor MV, for example. A display apparatus DSP2AC illustrated in FIG. 56 is a modification example of the display apparatus DSP2A in FIG. 51 and the transistor 300d has a structure similar to the structure of the transistor MV in FIG. 7A to FIG. 7C.

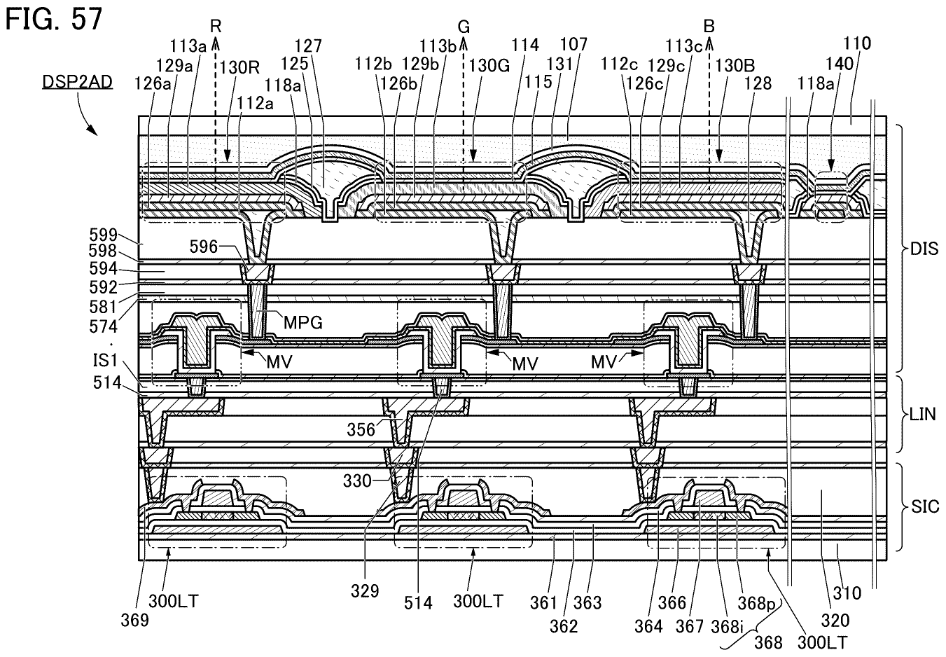

The transistor 300d in the display apparatus DSP2A in FIG. 51 may be a transistor containing low-temperature polysilicon in its channel formation region (hereinafter referred to as an LTPS transistor), for example. A display apparatus DSP2AD illustrated in FIG. 57 is a modification example of the display apparatus DSP2A in FIG. 51 and the structure of the transistor 300d is the structure of a transistor 300LT, which is an LTPS transistor. Note that the structure of the transistor 300LT is referred to as a TGTC structure in some cases.

The transistor 300LT is provided over the substrate 310. The transistor 300LT includes an insulating layer 361, an insulating layer 362, an insulating layer 363, an insulating layer 364, a conductive layer 366, a conductive layer 367, a low-resistance region 368p, a semiconductor region 368i, and a conductive layer 369. Here, a plurality of layers obtained by processing the same conductive film are shown with the same hatching pattern. In this specification and the like, the low-resistance region 368p and the semiconductor region 368i are collectively referred to as a semiconductor layer 368. In particular, when, for example, low-temperature polysilicon is used as a semiconductor material contained in the semiconductor layer 368, the transistor 300LT can be an LTPS transistor. The LTPS transistor has high field-effect mobility and excellent frequency characteristics.

In FIG. 57, the conductive layer 367 functions as a first gate (sometimes referred to as one of a gate and a back gate) of the transistor 300LT. The conductive layer 366 functions as a second gate (sometimes referred to as the other of the gate and the back gate) of the transistor 300LT. One of the pair of low-resistance regions 368p in the semiconductor layer 368 functions as one of a source and a drain of the transistor 300LT, and the other of the pair of low-resistance regions 368p in the semiconductor layer 368 functions as the other of the source and the drain of the transistor 300LT. The insulating layer 363 functions as a first gate insulating film in the transistor 300LT, and the insulating layer 362 functions as a second gate insulating film in the transistor 300LT.

In FIG. 57, the insulating layer 361 is formed over the substrate 310. The conductive layer 366 is formed in a region over the insulating layer 361. The insulating layer 362 is formed to cover the insulating layer 361 and the conductive layer 366. The semiconductor layer 368 is formed in a region overlapping with the conductive layer 366 and the insulating layer 362 and being over the insulating layer 362. The insulating layer 363 is formed to cover the insulating layer 362 and the semiconductor layer 368. The conductive layer 367 is formed in a region overlapping with the conductive layer 366, the insulating layer 362, the semiconductor layer 368, and the insulating layer 363 and being over the insulating layer 363. The insulating layer 364 is formed to cover the insulating layer 363 and the conductive layer 367. An opening portion is formed in the insulating layer 363 and the insulating layer 364 in regions overlapping with the low-resistance region 368p, and the conductive layer 369 is formed over the insulating layer 364 to fill the opening portion.

For each of the insulating layer 361, the insulating layer 362, the insulating layer 363, and the insulating layer 364, one or more selected from silicon oxide, silicon oxynitride, silicon nitride oxide, silicon nitride, aluminum oxide, aluminum oxynitride, aluminum nitride oxide, and aluminum nitride are used, for example.

In particular, a barrier insulating film that inhibits diffusion of impurities (e.g., a metal ion, a metal atom, an oxygen atom, an oxygen molecule, a hydrogen atom, a hydrogen molecule, and a water molecule) from a region below the insulating layer 361 (e.g., the substrate 310) is preferably used as the insulating layer 361.

The low-resistance region 368p is a region containing an impurity element. For example, in the case where the transistor 300LT is an n-channel transistor, phosphorus or arsenic is added to the low-resistance region 368p. In contrast, in the case where the transistor 300LT is a p-channel transistor, boron or aluminum is added to the low-resistance region 368p. In addition, in order to control the threshold voltage of the transistor 300, the above-described impurity may be added to the semiconductor region 368i.

Note that the transistor 300LT may be either a p-channel transistor or an n-channel transistor. Alternatively, a plurality of the transistors 300LT may be provided in the circuit region SIC and both the p-channel transistor and the n-channel transistor may be used.

For each of the conductive layer 366 and the conductive layer 367, a metal such as aluminum, titanium, chromium, nickel, copper, yttrium, zirconium, molybdenum, silver, tantalum, or tungsten can be used, for example. Alternatively, for each of the conductive layer 366 and the conductive layer 367, an alloy containing two or more selected from the above metals as its main components can be used. Alternatively, for each of the conductive layer 366 and the conductive layer 367, a light-transmitting conductive material such as indium oxide, indium tin oxide (ITO), indium oxide containing tungsten, indium zinc oxide containing tungsten, indium oxide containing titanium, ITO containing titanium, indium zinc oxide, zinc oxide (ZnO), ZnO containing gallium, or indium tin oxide containing silicon can be used. Alternatively, for each of the conductive layer 366 and the conductive layer 367, silicide (e.g., nickel silicide) or a semiconductor (e.g., polycrystalline silicon or an oxide semiconductor) whose resistance is lowered by, for example, containing an impurity element may be used. Alternatively, for each of the conductive layer 366 and the conductive layer 367, a film containing graphene can be used. The film containing graphene can be formed, for example, by reducing a film containing graphene oxide. Alternatively, a conductive paste (e.g., a conductive paste containing silver, carbon, or copper) or a conductive polymer (e.g., polythiophene) may be used for forming the conductive layer 366 and the conductive layer 367. A conductive paste is preferable because it is inexpensive. A conductive polymer is preferable because it is easily applied. Alternatively, one or both of the conductive layer 366 and the conductive layer 367 can have a single-layer structure containing any of the above materials or a structure (a stacked-layer structure) in which two or more selected from the above materials overlap each other.

The conductive layer 369 functions as a wiring electrically connected to the low-resistance region 368p of the transistor 300LT. That is, the conductive layer 369 functions as the source or the drain of the transistor 300LT. Note that for the conductive layer 369, any of the materials usable for the conductive layer 366 and the conductive layer 367 can be used.

A conductive layer 329 functioning as a plug or a wiring is embedded in the insulating layer 320. Accordingly, the transistor 300LT can be electrically connected to the transistor MV. Note that for the conductive layer 329, a material that can be used for the conductive layer 330 can be used.

Note that the display apparatus of one embodiment of the present invention is not limited to having the structures of the display apparatus DSP2A in FIG. 51, the display apparatus DSP2B in FIG. 52, the display apparatus DSP2AA in FIG. 53, the display apparatus DSP2AB in FIG. 54, the display apparatus DSP2AB2 in FIG. 55, the display apparatus DSP2AC in FIG. 56, and the display apparatus DSP2AD in FIG. 57. The structure of the display apparatus of one embodiment of the present invention may be the structure of the display apparatus which is modified as appropriate.

For example, the display apparatus of one embodiment of the present invention may have a structure in which a plurality of substrates are bonded to each other. Specifically, for example, a structure may be employed in which a first substrate provided with the display region DIS is bonded over a second substrate provided with the circuit region SIC by Cu-to-Cu (copper-to-copper) direct bonding technique or the like (not illustrated).

### Cross-Sectional Structure Example 4 of Display Apparatus

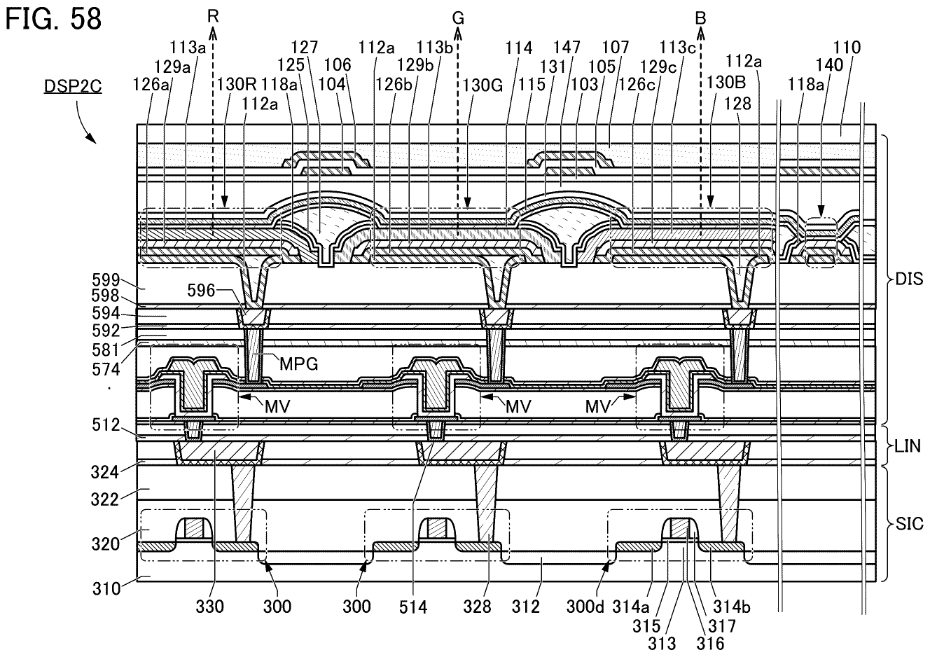

The display apparatus DSP2A illustrated in FIG. 51 may be provided with a panel having a touch sensor function (sometimes referred to as a touch panel), for example. In a display apparatus DSP2C illustrated in FIG. 58, a resin layer 147, an insulating layer 103, a conductive layer 104, an insulating layer 105, and a conductive layer 106 are formed in this order over the protective layer 131, for example.

The resin layer 147 preferably contains an organic insulating material. Examples of the organic insulating material include an acrylic resin, a polyimide resin, an epoxy resin, a polyamide resin, a polyimide-amide resin, a siloxane resin, a benzocyclobutene-based resin, a phenol resin, and a precursor of any of these resins.

The insulating layer 103 preferably contains an inorganic insulating material. Examples of the inorganic insulating material include oxide and nitride such as silicon oxide, silicon oxynitride, silicon nitride oxide, silicon nitride, aluminum oxide, aluminum oxynitride, and hafnium oxide.

The conductive layer 104 and the conductive layer 106 function as electrodes of a touch sensor. In the case of using a mutual capacitive touch sensor, a pulse potential may be supplied to one of the conductive layer 104 and the conductive layer 106, and an analog-digital (A-D) converter circuit or a sensing circuit such as a sense amplifier may be electrically connected to the other of the conductive layer 104 and the conductive layer 106, for example. In that case, capacitance is formed between the conductive layer 104 and the conductive layer 106. When a finger or the like approaches the conductive layer 104 and the conductive layer 106, the capacitance changes (specifically, the capacitance is reduced). This change in the capacitance appears, when a pulse potential is supplied to one of the conductive layer 104 and the conductive layer 106, as a change in the amplitude of a signal that occurs in the other of the conductive layer 104 and the conductive layer 106. Accordingly, the touch and approach of the finger or the like can be sensed.

For the insulating layer 105, an inorganic insulating film or an organic insulating film can be used, for example. Specifically, for the insulating layer 105, a resin such as an acrylic resin or an epoxy resin can be used, for example. Alternatively, for the insulating layer 105, an inorganic insulating material such as silicon oxide, silicon oxynitride, silicon nitride oxide, silicon nitride, or aluminum oxide can be used, for example. Note that the insulating layer 105 may have either a single-layer structure or a stacked-layer structure.

Note that although FIG. 58 illustrates the structure in which the electrode of the touch sensor is provided above the light-emitting device 130, the touch sensor may be provided in the same layer as the light-emitting device 130 (not illustrated). For example, when formed concurrently with the light-emitting device 130, the touch sensor can be provided in the same layer as the light-emitting device 130.

### Cross-Sectional Structure Example 5 of Display Apparatus

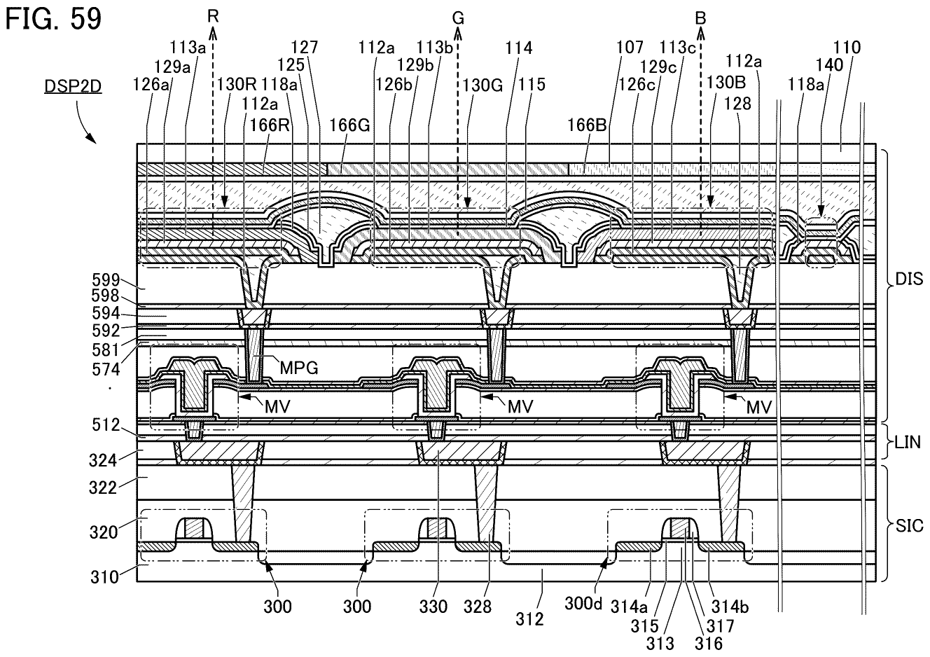

The display apparatus DSP2A illustrated in FIG. 51 may include, for example, a coloring layer (a color filter). A display apparatus DSP2D illustrated in FIG. 59 includes a coloring layer 166R, a coloring layer 166G, and a coloring layer 166B between the adhesive layer 107 and the substrate 110, for example. Note that the coloring layer 166R, the coloring layer 166G, and the coloring layer 166B can be formed on the substrate 110, for example. In the case where the light-emitting device 130R includes a light-emitting layer that emits red (R) light, the light-emitting device 130G includes a light-emitting layer that emits green (G) light, and the light-emitting device 130B includes a light-emitting layer that emits blue (B) light, the coloring layer 166R is a red coloring layer, the coloring layer 166G is a green coloring layer, and the coloring layer 166B is a blue coloring layer.

Note that a black matrix (not illustrated) may be provided between the coloring layer 166R and the coloring layer 166G, between the coloring layer 166G and the coloring layer 166B, and between the coloring layer 166G and the coloring layer 166B. Providing a black matrix in the display apparatus DSP2D can prevent light emitted from the light-emitting device from entering the color layer included in the adjacent pixel. This can enhance the display contrast, improving the display quality of the display apparatus DSP2D.

When one of the above structure examples is applied to a display apparatus, the display apparatus having high screen resolution and high definition can be achieved in some cases. Specifically, for example, a display apparatus with a screen resolution of HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320) can be achieved in some cases. Furthermore, specifically, for example, a display apparatus with a definition of higher than or equal to 100 ppi, higher than or equal to 300 ppi, higher than or equal to 500 ppi, higher than or equal to 1000 ppi, higher than or equal to 2000 ppi, higher than or equal to 3000 ppi, higher than or equal to 5000 ppi, or higher than or equal to 6000 ppi can be achieved in some cases.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 7

In this embodiment, a display module that can be used for the electronic device of one embodiment of the present invention will be described.

### Structure Example of Display Module

First, a display module including a display apparatus that can be used for the electronic device of one embodiment of the present invention will be described.

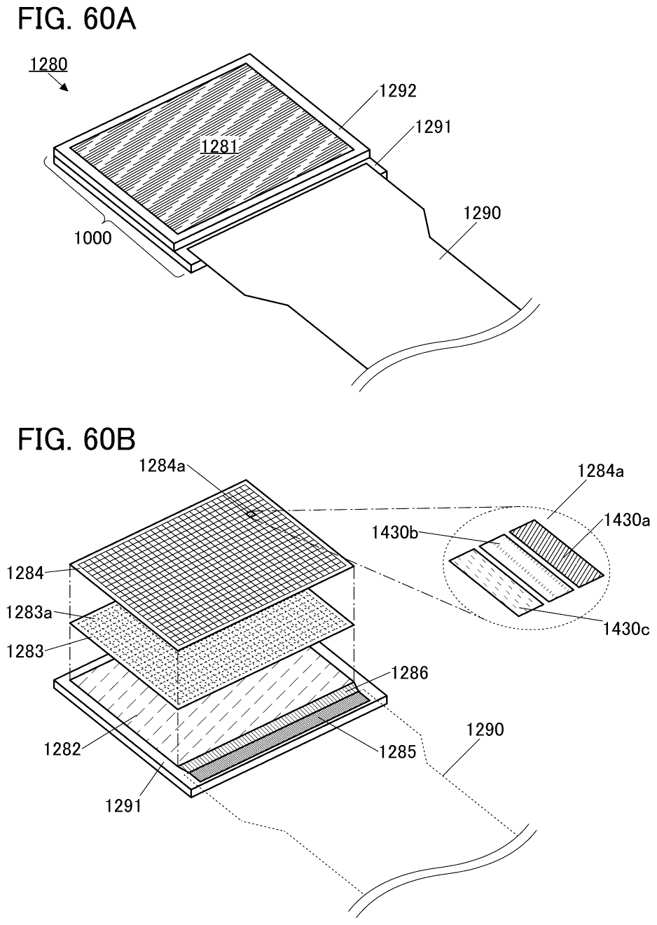

FIG. 60A is a perspective view of a display module 1280. The display module 1280 includes a display apparatus 1000 and an FPC 1290.

The display module 1280 includes a substrate 1291 and a substrate 1292. The display module 1280 includes a display portion 1281. The display portion 1281 is a region of the display module 1280 where an image is displayed, and is a region where light emitted from pixels provided in a pixel portion 1284 described later can be seen.

FIG. 60B is a perspective view schematically illustrating a structure on the substrate 1291 side. A circuit portion 1282, a pixel circuit portion 1283 over the circuit portion 1282, and the pixel portion 1284 over the pixel circuit portion 1283 are stacked over the substrate 1291. In addition, a terminal portion 1285 for connection to the FPC 1290 is provided in a portion not overlapping with the pixel portion 1284 over the substrate 1291. The terminal portion 1285 and the circuit portion 1282 are electrically connected to each other through a wiring portion 1286 formed of a plurality of wirings.

Note that the pixel portion 1284 and the pixel circuit portion 1283 correspond to the display region DIS described above, for example. The circuit portion 1282 corresponds to the circuit region SIC described above, for example.

The pixel portion 1284 includes a plurality of pixels 1284a arranged periodically. An enlarged view of one pixel 1284a is illustrated on the right side in FIG. 60B. The pixel 1284a includes a light-emitting device 1430a, a light-emitting device 1430b, and a light-emitting device 1430c that emit light of different colors. Note that the light-emitting device 1430a, the light-emitting device 1430b, and the light-emitting device 1430c correspond to the light-emitting device 130R, the light-emitting device 130G, and the light-emitting device 130B described above, for example. The above-described plurality of light-emitting devices may be arranged in a stripe pattern as illustrated in FIG. 60B. Alternatively, a variety of arrangement methods, such as S-stripe arrangement, matrix arrangement, delta arrangement, Bayer arrangement, and PenTile arrangement, can be employed.

The pixel circuit portion 1283 includes a plurality of pixel circuits 1283a arranged periodically.

One pixel circuit 1283a is a circuit that controls light emission from three light-emitting devices included in one pixel 1284a. One pixel circuit 1283a may be provided with three circuits each controlling light emission from one light-emitting device. For example, the pixel circuit 1283a can include at least one selection transistor, one current control transistor (driving transistor), and capacitance for one light-emitting device. In that case, a gate signal is input to a gate of the selection transistor, and a source signal is input to one of a source and a drain of the selection transistor. Thus, an active-matrix display apparatus is achieved.

The circuit portion 1282 includes a circuit for driving the pixel circuits 1283a in the pixel circuit portion 1283. For example, one or both of a gate line driver circuit and a source line driver circuit are preferably included. In addition, one or more selected from an arithmetic circuit, a memory circuit, and a power supply circuit may be included.

The FPC 1290 functions as a wiring for supplying a video signal or a power supply potential to the circuit portion 1282 from the outside. In addition, an IC may be mounted on the FPC 1290.

The display module 1280 can have a structure in which one or both of the pixel circuit portion 1283 and the circuit portion 1282 are stacked below the pixel portion 1284; thus, the aperture ratio (the effective display area ratio) of the display portion 1281 can be significantly high. For example, the aperture ratio of the display portion 1281 can be higher than or equal to 40% and lower than 100%, preferably higher than or equal to 50% and lower than or equal to 95%, further preferably higher than or equal to 60% and lower than or equal to 95%. Furthermore, the pixels 1284a can be arranged extremely densely and thus the display portion 1281 can have an extremely high definition. For example, the pixels 1284a are preferably arranged in the display portion 1281 with a definition higher than or equal to 100 ppi, preferably higher than or equal to 300 ppi, further preferably higher than or equal to 500 ppi, still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 6000 ppi, and lower than or equal to 20000 ppi or lower than or equal to 30000 ppi.

Such a display module 1280 has an extremely high definition and thus can be suitably used for a VR device such as a head-mounted display or a glasses-type AR device. For example, even with a structure in which the display portion of the display module 1280 is seen through a lens, pixels of the extremely-high-definition display portion 1281 included in the display module 1280 are prevented from being seen when the display portion is enlarged by the lens, so that display providing a strong sense of immersion can be performed. Without being limited thereto, the display module 1280 can be suitably used for electronic devices including relatively small display portions. For example, the display module 1280 can be suitably used for a display portion of a wearable electronic device such as a wristwatch.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 8

In this embodiment, electronic devices each including a display apparatus fabricated using one embodiment of the present invention will be described. Electronic devices described in this embodiment as examples are each provided with a display apparatus of one embodiment of the present invention in a display portion. Thus, the electronic devices achieve high definition.

One embodiment of the present invention includes the display apparatus and one or more selected from an antenna, a battery, a housing, a camera, a speaker, a microphone, a touch sensor, and an operation button.

The electronic device of one embodiment of the present invention may include a secondary battery, and it is preferable that the secondary battery be capable of being charged by contactless power transmission.

Examples of the secondary battery include a lithium ion secondary battery (such as a lithium polymer battery using a gel electrolyte (a lithium ion polymer battery)), a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. With the antenna receiving a signal, the electronic device can display an image, information, or the like on a display portion. When the electronic device includes an antenna and a secondary battery, the antenna may be used for contactless power transmission.

The display portion of the electronic device of one embodiment of the present invention can display, for example, an image with full high definition, 4K2K, 8K4K, 16K8K, or higher screen resolution.

Examples of the electronic device include electronic devices having a relatively large screen, such as a television device, a laptop personal computer, a monitor device, digital signage, a pachinko machine, and a game machine. Other examples of the electronic device include a digital camera, a digital video camera, a digital photo frame, a mobile phone device, a portable game machine, a portable information terminal, and an audio reproducing device.

An electronic device to which one embodiment of the present invention is applied can be incorporated along an inner wall or an outer wall of a house or a building. The electronic device can be incorporated along a flat surface or a curved surface of an interior, an exterior, or the like of an automobile or the like.

### [Mobile Phone]

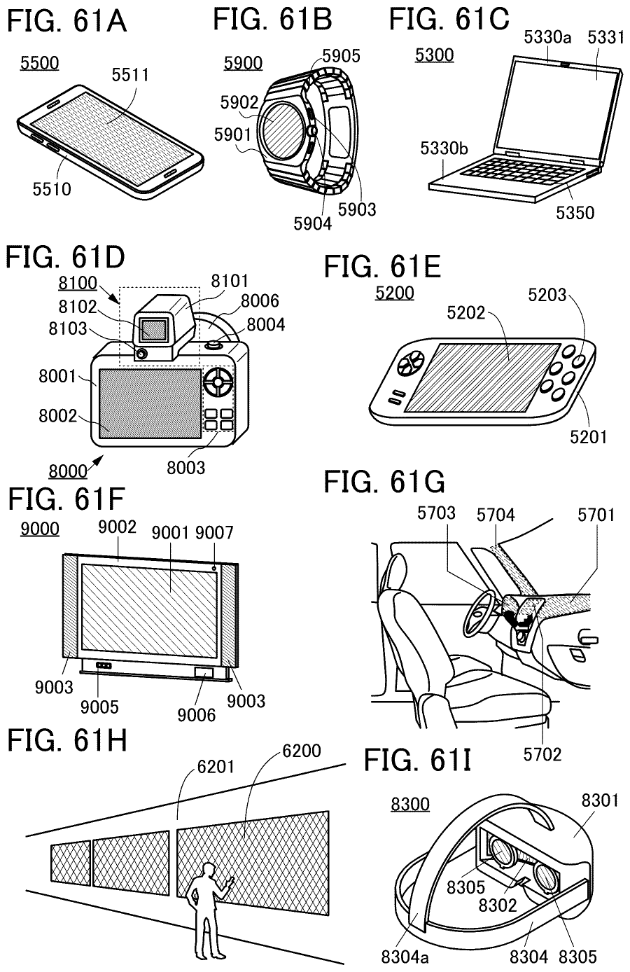

An information terminal 5500 illustrated in FIG. 61A is a mobile phone (smartphone), which is a type of information terminal. The information terminal 5500 includes a housing 5510 and a display portion 5511. As input interfaces, a touch panel and a button are provided in the display portion 5511 and the housing 5510, respectively.

### [Wearable Terminal]

FIG. 61B is an external view of an information terminal 5900, which is an example of a wearable terminal. The information terminal 5900 includes a housing 5901, a display portion 5902, an operation button 5903, a crown 5904, and a band 5905.

### [Information Terminal]

FIG. 61C illustrates a laptop information terminal 5300. The laptop information terminal 5300 illustrated in FIG. 61C includes, for example, a display portion 5331 in a housing 5330a and a keyboard portion 5350 in a housing 5330b.

Note that although FIG. 61A to FIG. 61C illustrate a smartphone, a wearable terminal, and a laptop information terminal as examples of electronic device in the above description, one embodiment of the present invention can also be applied to an information terminal other than a smartphone, a wearable terminal, and a laptop information terminal. Examples of the information terminals other than a smartphone, a wearable terminal, and a laptop information terminal include a PDA (Personal Digital Assistant), a desktop information terminal, and a workstation.

[Camera]

FIG. 61D is an external view of a camera 8000 to which a finder 8100 is attached. The camera 8000 includes a housing 8001, a display portion 8002, operation buttons 8003, and a shutter button 8004. Furthermore, a detachable lens 8006 is attached to the camera 8000. The finder 8100 includes a housing 8101, a display portion 8102, and a button 8103.

Note that the lens 8006 may be included in the housing of the camera 8000.

Images can be taken with the camera 8000 at the press of the shutter button 8004 or the touch of the display portion 8002 serving as a touch panel.

The housing 8001 includes a mount including an electrode, so that a stroboscope, for example, as well as the finder 8100 can be connected to the housing 8001.

The housing 8101 is attached to the camera 8000 by a mount for engagement with the mount of the camera 8000. The finder 8100 can display an image received from the camera 8000 on the display portion 8102.

The button 8103 functions as a power supply button.

The display apparatus of one embodiment of the present invention can be used in the display portion 8002 of the camera 8000 and the display portion 8102 of the finder 8100. Note that a finder may be incorporated in the camera 8000.

### [Game Machine]

FIG. 61E is an external view of a portable game machine 5200, which is an example of a game machine. The portable game machine 5200 includes a housing 5201, a display portion 5202, and a button 5203.

An image displayed on the portable game machine 5200 can be output with a display apparatus included in a television device, a personal computer display, a game display, or a head-mounted display.

When the portable game machine 5200 includes the display apparatus described in the above embodiment, the portable game machine 5200 can have low power consumption. Furthermore, heat generation from a circuit can be reduced owing to low power consumption; thus, the influence of heat generation on the circuit, the peripheral circuit, and the module can be reduced.

Although FIG. 61E illustrates the portable game machine as an example of a game machine, the electronic device of one embodiment of the present invention is not limited thereto. Examples of the electronic device of one embodiment of the present invention include a stationary game machine, an arcade game machine installed in entertainment facilities (e.g., a game center and an amusement park), and a throwing machine for batting practice installed in sports facilities.

### [Television Device]

FIG. 61F is a perspective view illustrating a television device. A television device 9000 includes a housing 9002, a display portion 9001, a speaker 9003, an operation key 9005 (including a power switch or an operation switch), a connection terminal 9006, a sensor 9007 (for example, a sensor having a function of measuring force, displacement, position, speed, acceleration, angular velocity, rotational frequency, distance, light, liquid, magnetism, temperature, chemical substance, sound, time, hardness, electric field, current, voltage, power, radiation, flow rate, humidity, gradient, oscillation, odor, or infrared rays, and for another example, a sensor having a function of sensing or detecting odor or light (including infrared rays)). A memory device of one embodiment of the present invention can be provided in the television device. The television device can include the display portion 9001 having a screen size of, for example, 50 inches or more, or 100 inches or more.

When the television device 9000 includes the display apparatus described in the above embodiment, the television device 9000 can achieve low power consumption. Furthermore, heat generation from a circuit can be reduced owing to low power consumption; thus, the influence of heat generation on the circuit, the peripheral circuit, and the module can be reduced.

### [Moving Vehicle]

The display apparatus of one embodiment of the present invention can also be used around a driver's seat in a car, which is a moving vehicle.

FIG. 61G is a diagram illustrating a windshield and its vicinity inside a car. FIG. 61G illustrates a display panel 5701, a display panel 5702, and a display panel 5703 which are attached to a dashboard, and a display panel 5704 attached to a pillar.

The display panel 5701 to the display panel 5703 can provide various kinds of information by displaying navigation data, a speedometer, a tachometer, a mileage, a fuel meter, a gearshift state, air-conditioning settings, and the like. Items displayed on the display panel and their layout can be changed as appropriate to suit the user's preferences, resulting in more sophisticated design. The display panel 5701 to the display panel 5703 can also be used as lighting devices.

The display panel 5704 can compensate for the view obstructed by the pillar (blind areas) by showing an image taken by an imaging unit provided for the car body. That is, displaying an image taken by the imaging unit provided on the outside of the car leads to elimination of blind areas and enhancement of safety. Moreover, showing an image to compensate for the area that cannot be seen makes it possible for a driver to confirm safety more easily and comfortably. The display panel 5704 can also be used as a lighting device.

The display apparatus of one embodiment of the present invention can be used for each of the display panel 5701 to the display panel 5704, for example.

Although a car is described above as an example of a moving vehicle, moving vehicles are not limited to a car. Examples of the moving vehicles include a train, a monorail train, a ship, and a flying object (for example, a helicopter, an unmanned aircraft (a drone), an airplane, and a rocket), and these moving vehicles can use the display apparatus of one embodiment of the present invention.

### [Digital Signage]

FIG. 61H shows an example of a digital signage that can be attached to a wall. FIG. 61H illustrates a state where a digital signage 6200 is attached to a wall 6201. The display apparatus of one embodiment of the present invention can be used in a display portion in the digital signage 6200, for example. An interface such as a touch panel may be provided in the digital signage 6200.

Note that an electronic device attachable to a wall is described above as an example of a digital signage, the kind of the digital signage is not limited thereto. Examples of the digital signage include a digital signage mounted on a pillar, a freestanding digital signage placed on the ground, and a digital signage mounted on a rooftop or a sidewall of a building.

### [Head-Mounted Display]

FIG. 61I is an external view of an electronic device 8300 which is a head-mounted display for VR. The electronic device 8300 includes a housing 8301, a display portion 8302, a band-like fixing member 8304, a fixture member 8304a worn on a head, and a pair of lenses 8305.

Although not illustrated in FIG. 61I, the electronic device 8300 may include an interface such as an operation button or a power button.

A user can see display on the display portion 8302 through the lenses 8305. The display portion 8302 is preferably curved because the user can feel high realistic sensation. Another image displayed in another region of the display portion 8302 is seen through the lenses 8305, so that three-dimensional display using parallax can be performed. Note that the number of the display portions 8302 is not limited to one; two display portions 8302 may be provided for user's respective eyes.

As the display portion 8302, a display apparatus with extremely high definition is preferably used, for example. With use of a display apparatus with high definition for the display portion 8302, even when the display portion 8302 is enlarged by the lens 8305, the user does not see pixels and thus a more realistic image can be displayed.

The head-mounted display, which is an electronic device of one embodiment of the present invention, may have a structure of an electronic device which is a glasses-type head-mounted display, instead of the electronic device 8300 in FIG. 61I which is a goggles-type head-mounted display. In particular, a glasses-type head-mounted display is suitable for an electronic device for AR.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 9

As described in Embodiment 1 and Embodiment 2, the retention circuit, which is the semiconductor device of one embodiment of the present invention, can be applied to a shift register circuit. In this embodiment, a memory device that can employ the shift register circuit will be described.

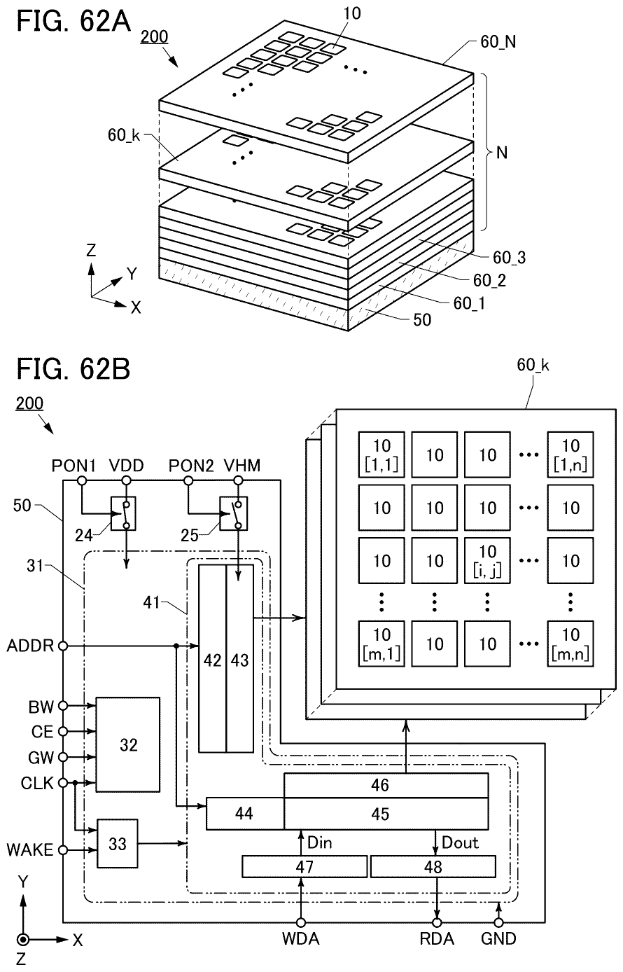

FIG. 62A is a schematic perspective view showing a structure example of a memory device 200. FIG. 62B is a block diagram showing the structure example of the memory device 200. The memory device 200 includes a driver circuit layer 50 and N (N is an integer greater than or equal to 1) memory layers 60. One memory layer 60 includes a plurality of memory cells 10 arranged in a matrix of m rows and n columns. Note that FIG. 62B shows an example in which a memory cell 10[1,1], a memory cell 10[m, 1] (here, m is an integer greater than or equal to 1), a memory cell 10[1,n] (here, n is an integer greater than or equal to 1), a memory cell 10[m, n], and a memory cell 10[i,j] (here, i is an integer greater than or equal to 1 and less than or equal to m, and j is an integer greater than or equal to 1 and less than or equal to n) are provided in a memory layer 60_k.

The N memory layers 60 are provided over the driver circuit layer 50. Provision of the N memory layers 60 over the driver circuit layer 50 can reduce the area occupied by the memory device 200. Furthermore, memory capacity per unit area can be increased.

In this embodiment and the like, the first memory layer 60 is denoted by a memory layer 60_1, the second memory layer 60 is denoted by a memory layer 60_2, and the third memory layer 60 is denoted by a memory layer 60_3. Furthermore, the k-th memory layer 60 (k is an integer greater than or equal to 1 and less than or equal to N) is denoted by a memory layer 60_k, and the N-th memory layer 60 is denoted by a memory layer 60_N. Note that in this embodiment and the like, the simple term “memory layer 60” is sometimes used in the case of describing a matter related to all the N memory layers 60 or showing a matter common to the N memory layers 60.

### Structure Example of Driver Circuit Layer 50

The driver circuit layer 50 includes a PSW 24 (power switch), a PSW 25, and a peripheral circuit 31. The peripheral circuit 31 includes a peripheral circuit 41, a control circuit 32 (Control Circuit), and a voltage generation circuit 33.

In the memory device 200, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 200. For example, the control circuit performs a logical operation on the signal CE, the signal GW, and the signal BW to determine an operation mode (e.g., a writing operation or a reading operation) of the memory device 200. The control circuit 32 generates a control signal for the peripheral circuit 41 so that the operation mode can be executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 includes a row decoder 42, a column decoder 44, a row driver 43, a column driver 45, an input circuit 47, an output circuit 48, and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed.

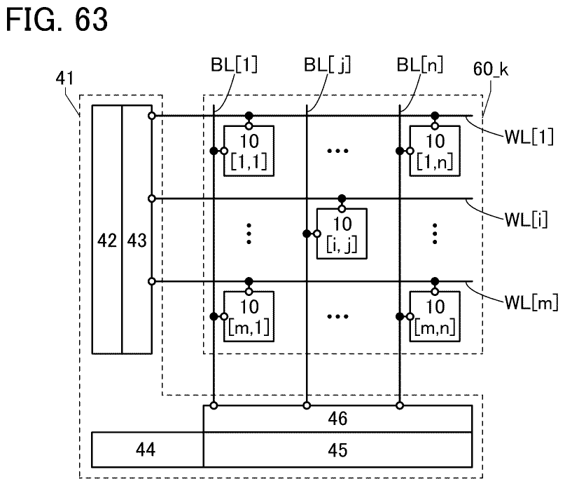

The row driver 43 has a function of selecting any one of word lines for writing and word lines for reading (e.g., any one of a wiring WL[1] to a wiring WL[m] illustrated in FIG. 63A described later) specified by the row decoder 42. Note that the row driver 43 may include the shift register circuit described in the above embodiment. In particular, since the shift register circuit can be a single-polarity circuit including an OS transistor, the shift register circuit can be provided above the circuits formed on a Si wafer, for example.

The column driver 45 has a function of writing data to the memory cells 10, a function of reading data from the memory cells 10, and a function of retaining the read data. The column driver 45 has a function of selecting write bit lines and read bit lines (e.g., any one of a wiring BL[1] to a wiring BL[n] illustrated in FIG. 63A described later) specified by the column decoder 44. Note that the column driver 45 may include the shift register circuit described in the above embodiment. In particular, since the shift register circuit can be a single-polarity circuit including an OS transistor like the shift register circuit in the row driver 43, the shift register circuit can be provided above the circuits formed on a Si wafer, for example.

The input circuit 47 has a function of retaining the signal WDA. Data retained by the input circuit 47 (first data in the above embodiment) is output to the column driver 45. Data output from the input circuit 47 is data (Din) to be written to the memory cells 10. Data (Dout) read from the memory cells 10 by the column driver 45 is output to the output circuit 48. Note that in the above embodiment, the read data (Dout) is treated as arithmetic operation result data. The output circuit 48 has a function of retaining Dout. In addition, the output circuit 48 has a function of outputting Dout to the outside of the memory device 200. Data output from the output circuit 48 is the signal RDA.

The PSW 24 has a function of controlling supply of VDD to the peripheral circuit 31. The PSW 25 has a function of controlling supply of VHM to the row driver 43. Here, in the memory device 200, a high power supply voltage is VDD and a low power supply voltage is GND (a ground potential). In addition, VHM is a high power supply voltage used to set a word line at a high level and is higher than VDD. The on state and the off state of the PSW 24 are switched by the signal PON1, and the on state and the off state of the PSW 25 is switched by the signal PON2. The number of power domains to which VDD is supplied is one in the peripheral circuit 31 in FIG. 62B but can be more than one. In that case, a power switch is provided for each power domain.

Next, electrical connection between the peripheral circuit 41 and the memory layer 60 is described.

FIG. 63 is a block diagram showing a structure example of the peripheral circuit 41 and the memory layer 60_k. In FIG. 63, the row decoder 42 and the row driver 43 are electrically connected to each of the wiring WL[1] to the wiring WL[m], and the column decoder 44, the column driver 45, and the sense amplifier 46 are electrically connected to each of the wiring BL[1] to the wiring BL[n].

The wiring WL[1] to the wiring WL[m] each function as a word line for selecting the memory cell 10 as a target for data writing, for example.

The wiring BL[1] to the wiring BL[n] each function as a bit line for transmitting data to the memory cell 10 selected by the row decoder 42, for example.

The memory cell 10[i,j] located at the i-th row and the j-th column is electrically connected to the wiring WL[i] and the wiring BL[j].

As illustrated in FIG. 63, the memory layer 60_k is electrically connected to the peripheral circuit 41, whereby data writing to the memory layer 60_k and data reading from the memory layer 60_k can be performed.

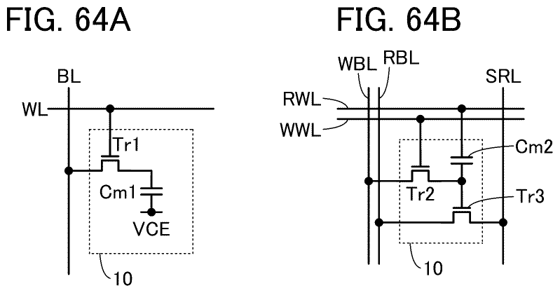

FIG. 64A and FIG. 64B show structure examples of the memory cell 10 illustrated in FIG. 62A, FIG. 62B, and FIG. 63.

The memory cell 10 illustrated in FIG. 64A is an example of a memory cell called a DRAM and includes the transistor Tr1 and a capacitor Cm1. In particular, in this specification and the like, a DRAM where an OS transistor is used as a transistor M1 is referred to as a DOSRAM (Dynamic Oxide Semiconductor Random Access Memory) (registered trademark) in some cases.

The first terminal of the transistor Tr1 is electrically connected to a first terminal of the capacitor Cm1, the second terminal of the transistor Tr1 is electrically connected to the wiring BL, and the gate of the transistor Tr1 is electrically connected to the wiring WL. A second terminal of the capacitor Cm1 is electrically connected to a wiring VCE.

In FIG. 64A, the wiring BL corresponds to the wiring BL[1] to the wiring BL[n] in FIG. 63, and the wiring WL corresponds to the wiring WL[1] to the wiring WL[m] in FIG. 63.

The wiring VCE has a function of a wiring for supplying a fixed potential, for example. Note that the wiring VCE may function as a wiring for supplying not a fixed potential but a variable potential.

The memory cell 10 illustrated in FIG. 64B is an example of a memory cell called a gain cell and includes the transistor Tr2, the transistor Tr3, and a capacitor Cm2. In particular, in this specification and the like, the structure of the memory cell 10 in which OS transistors are used as the transistor Tr2 and the transistor Tr3 is referred to as a NOSRAM (registered trademark) (Nonvolatile Oxide Semiconductor Random Access Memory) in some cases.

The first terminal of the transistor Tr2 is electrically connected to the first terminal of the capacitor Cm1 and the gate of the transistor Tr3, the second terminal of the transistor Tr2 is electrically connected to a wiring WBL, and the gate of the transistor Tr1 is electrically connected to a wiring WWL. The first terminal of the transistor Tr3 is electrically connected to a wiring SRL, and the second terminal of the transistor Tr3 is electrically connected to a wiring RBL. A second terminal of the capacitor Cm2 is electrically connected to a wiring RWL.

In FIG. 64B, the wiring WBL has a function of a write bit line, and the wiring RBL has a function of a read bit line. Note that the wiring WBL and the wiring RBL collectively correspond to one of the wiring BL[1] to the wiring BL[n] in FIG. 63. In FIG. 64B, the wiring WWL has a function of a write word line, and the wiring RWL has a function of a read word line. Note that the wiring WWL and the wiring RWL collectively correspond to one of the wiring WL[1] to the wiring WL[n] in FIG. 63.

The wiring SRL has a function of a wiring for supplying a fixed potential, for example. Note that the wiring SRL may have a function of a wiring for supplying a variable potential and may have a function of a wiring for supplying a current to the first terminal of the transistor Tr3.

Next, electronic devices each employing the above memory device will be described.

### [Electronic Device]

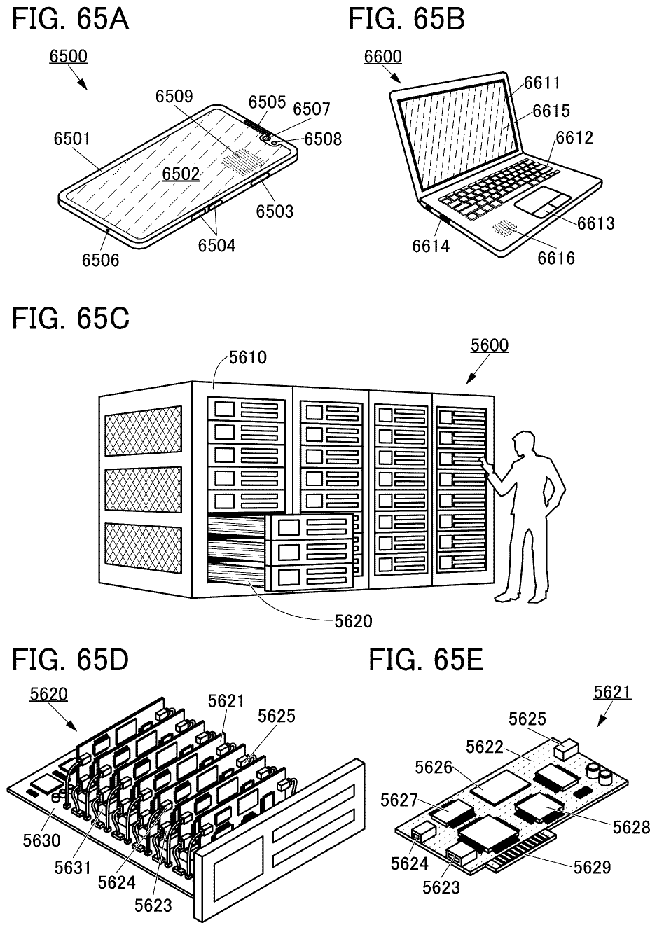

Next, FIG. 65A is a perspective view of an electronic device 6500. The electronic device 6500 illustrated in FIG. 65A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. One or both of a CPU and a GPU are provided as the control device 6509, for example. The memory device can be used for the display portion 6502, the control device 6509, and the like, for example.

An electronic device 6600 illustrated in FIG. 65B is an information terminal that can be used as a laptop personal computer. The electronic device 6600 includes a housing 6611, a keyboard 6612, a pointing device 6613, an external connection port 6614, a display portion 6615, a control device 6616, and the like. One or more selected from a CPU, a GPU, and a memory device are provided as the control device 6616, for example. The semiconductor device of one embodiment of the present invention can be used for the display portion 6615, the control device 6616, and the like. Note that the memory device is preferably used for the control device 6509 and the control device 6616, in which case power consumption can be reduced.

### [Large Computer]

FIG. 65C is a perspective view of a large computer 5600. In the large computer 5600 illustrated in FIG. 65C, a plurality of rack mount computers 5620 are stored in a rack 5610. Note that the large computer 5600 may be referred to as a supercomputer.

The computer 5620 can have a structure in a perspective view shown in FIG. 65D, for example. In FIG. 65D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 65E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Although FIG. 65E illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is the memory device.

The large computer 5600 can also function as a parallel computer. When the large computer 5600 is used as a parallel computer, large-scale computation necessary for artificial intelligence learning and inference can be performed, for example.

### [Space Equipment]

The memory device can be suitably used for space equipment such as equipment that processes and stores information.

The memory device can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

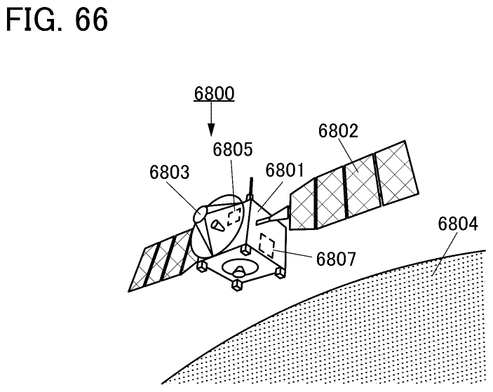

FIG. 66 illustrates an artificial satellite 6800 as an example of space equipment. The artificial satellite 6800 includes a body 6801, a solar panel 6802, an antenna 6803, a secondary battery 6805, and a control device 6807. FIG. 66 illustrates a planet 6804 in outer space, for example. Note that outer space refers to, for example, space at an altitude greater than or equal to 100 km, and outer space in this specification may also include thermosphere, mesosphere, and stratosphere.

Although not illustrated in FIG. 66, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, power required for an operation of the artificial satellite 6800 is generated. However, for example, in the situation where the solar panel is not irradiated with sunlight or in the situation where the amount of sunlight with which the solar panel is irradiated is small, the amount of generated power is small. Accordingly, power required for an operation of the artificial satellite 6800 might not be generated. In order to operate the artificial satellite 6800 even with a small amount of generated power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is formed using one or both of a CPU and a GPU, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of space equipment in this embodiment, one embodiment of the present invention is not limited thereto. The semiconductor device of one embodiment of the present invention can be suitably used for space equipment such as a spacecraft, a space capsule, or a space probe, for example.

As described above, an OS transistor has excellent effects of achieving a wide memory bandwidth and being highly resistant to radiation as compared with a Si transistor.

### [Data Center]

The memory device can be suitably used for a storage system used in a data center, for example. Long-term management of data, such as guarantee of data immutability, is required for the data center. The long-term management of data needs an increase in building size owing to installation of storages and servers for storing an enormous amount of data, a stable power source for data retention, cooling equipment necessary for data retention, and the like.

With use of the memory device for the storage system used in the data center, power required for data retention can be reduced. Thus, downsizing of the storage system, downsizing of the power source for data retention, downscaling of the cooling equipment, and the like can be achieved, for example. This can reduce the space of the data center.

Since the memory device has low power consumption, heat generation from a circuit can be reduced. Accordingly, adverse effects of the heat generation on each of the circuit itself, the peripheral circuit, and the module can be reduced. Furthermore, the use of the memory device enables a data center that operates stably even in a high-temperature environment. Thus, the reliability of the data center can be increased.

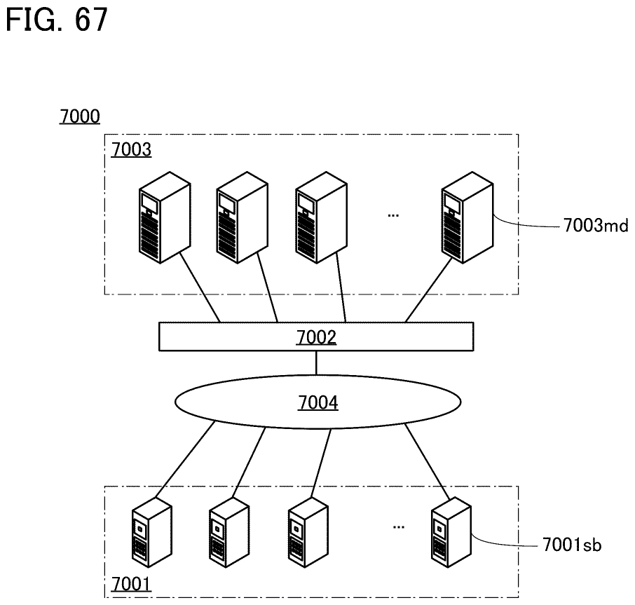

FIG. 67 illustrates a storage system that can be used in a data center. A storage system 7000 illustrated in FIG. 67 includes a plurality of servers 7001sb as a host 7001. The storage system 7000 includes a plurality of memory devices 7003md as a storage 7003. In the illustrated mode, the host 7001 and the storage 7003 are connected to each other through a storage area network 7004 and a storage control circuit 7002.

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but the time is still considerably longer than the time required for a DRAM that can be used as a cache memory in the storage. In the storage system, in order to solve the problem of low access speed of the storage 7003, a cache memory is usually provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic device, a large computer, space equipment, and a data center will produce an effect of reducing power consumption. While the demand for energy will increase with increasing performance and integration degree of semiconductor devices, the use of the semiconductor device of one embodiment of the present invention can thus reduce the emission amount of greenhouse gas typified by carbon dioxide (CO2). The semiconductor device of one embodiment of the present invention can be effectively used as one of the global warming countermeasures because of its low power consumption.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 10

As described in Embodiment 1 and Embodiment 2, the retention circuit, which is the semiconductor device of one embodiment of the present invention, can be applied to a shift register circuit. In this embodiment, an imaging device that can employ the shift register circuit will be described.

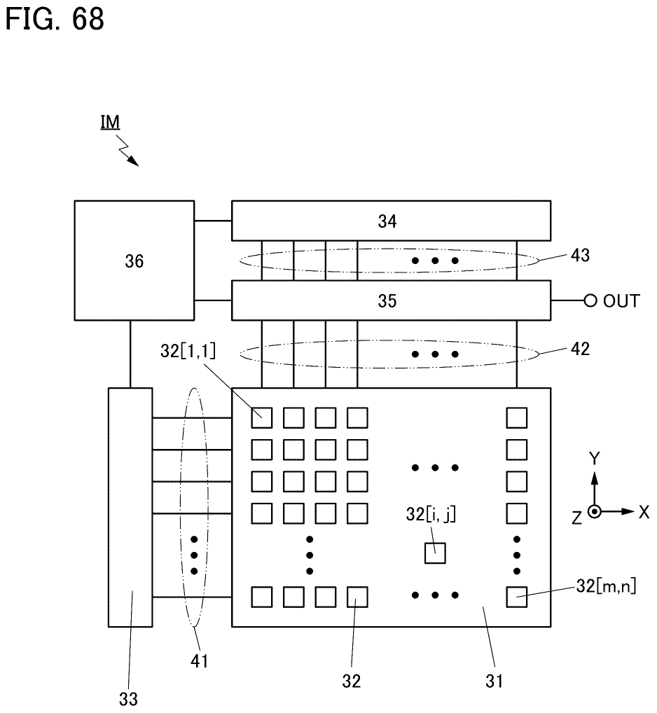

FIG. 68 is a block diagram showing a structure example of the imaging device. An imaging device IM includes an imaging portion 31, a first driver circuit portion 33, a second driver circuit portion 34, a reading circuit portion 35, and a control circuit portion 36. Note that the first driver circuit portion 33, the second driver circuit portion 34, the reading circuit portion 35, and the control circuit portion 36 are collectively called a “functional circuit” in some cases. For the functional circuit, the shift register circuit described in the above embodiment can be used. Besides the shift register circuit, any of a variety of circuits such as a level shifter circuit, an inverter, a latch, an analog switch, and a logic circuit can be used.

Transistors used in the imaging portion 31 and the functional circuit that are provided in the imaging device IM may be n-channel transistors or p-channel transistors. Both n-channel transistors and p-channel transistors may be used. A CMOS circuit in which n-channel transistors and p-channel transistors are combined may be used for the imaging portion 31 and the functional circuit.

The imaging portion 31 includes imaging pixel circuits 32 arranged in a matrix of m rows and n columns (here, each of m and n is an integer greater than or equal to 1). The imaging portion 31 is electrically connected to the first driver circuit portion 33 through a plurality of wirings 41. The imaging portion 31 is electrically connected to the reading circuit portion 35 through a plurality of wirings 42. The reading circuit portion 35 is electrically connected to the second driver circuit portion 34 through a plurality of wirings 43. For example, the imaging pixel circuits 32 arranged in the i-th row (here, i is an integer greater than or equal to 1 and less than or equal to m) are electrically connected to the first driver circuit portion 33 through the i-th wiring 41. The imaging pixel circuits 32 arranged in the j-th column (here, j is an integer greater than or equal to 1 and less than or equal to n) are electrically connected to the reading circuit portion 35 through the j-th wiring 42.

In FIG. 68, the imaging pixel circuit 32 placed in the first row and the first column is denoted as the imaging pixel circuit 32[1,1], and the imaging pixel circuit 32 placed in the m-th row and the n-th column is denoted as the imaging pixel circuit 32[m,n]. The imaging pixel circuit 32 placed in the i-th row and the j-th column is denoted as the imaging pixel circuit 32[i,j].

Note that wirings connected to one imaging pixel circuit 32 are not limited to the wiring 41 and the wiring 42. A wiring other than the wiring 41 and the wiring 42 may be connected to the imaging pixel circuit 32.

The control circuit portion 36 has a function of controlling the operations of the circuits included in the imaging device IM. The first driver circuit portion 33 has a function of selecting the imaging pixel circuits 32 row by row. The imaging pixel circuits 32 in the row selected by the first driver circuit portion 33 output imaging data to the reading circuit portion 35 through the wirings 42.

The reading circuit portion 35 retains imaging data supplied from the imaging pixel circuits 32 in every column, and performs noise removal processing and the like. As the noise removal processing, for example, CDS (Correlated Double Sampling) processing or the like may be performed. The reading circuit portion 35 may have one or both of an amplifying function of imaging data and an AD conversion function of imaging data, for example.

The second driver circuit portion 34 has functions of sequentially selecting imaging data retained in the reading circuit portion 35 and outputting the imaging data from an output terminal OUT to the outside.

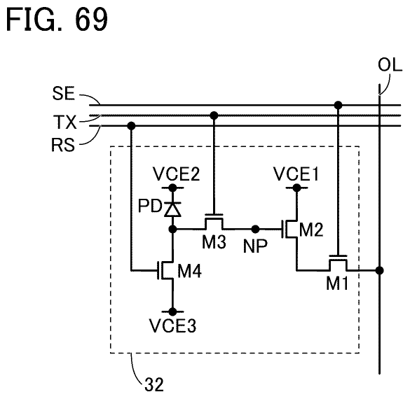

FIG. 69 shows an example of a circuit structure applicable to the imaging pixel circuit 32.

The imaging pixel circuit 32 illustrated in FIG. 69 includes the transistor M1 to a transistor M4 and a photoelectric conversion element PD, for example.

A first terminal of the transistor MI is electrically connected to a first terminal of the transistor M2, a second terminal of the transistor M1 is electrically connected to a wiring OL, and a gate of the transistor M1 is electrically connected to a wiring SE. A second terminal of the transistor M2 is electrically connected to a wiring VCE1, and a gate of the transistor M2 is electrically connected to a first terminal of the transistor M3. A second terminal of the transistor M3 is electrically connected to a first terminal of the transistor M4 and an anode of the photoelectric conversion element PD. A second terminal of the transistor M4 is electrically connected to a wiring VCE3, and a gate of the transistor M4 is electrically connected to a wiring RS. A cathode of the photoelectric conversion element is electrically connected to a wiring VCE2. A point where the gate of the transistor M2 and the first terminal of the transistor M3 are electrically connected is referred to as a node NP.

The wiring VCE1, the wiring VCE2, and the wiring VCE3 each have a function of a wiring for supplying a fixed potential, for example. In particular, a fixed potential supplied by the wiring VCE1 is preferably a high-level potential, a fixed potential supplied by the wiring VCE2 is preferably a high-level potential, and a fixed potential supplied by the wiring VCE3 is preferably a low-level potential. Note that the wiring VCE1, the wiring VCE2, and the wiring VCE3 may each also have a function of a wiring for supplying a variable potential.

The wiring TX has a function of a selection signal line for selecting the imaging pixel circuit 32 that performs image capturing, for example. For example, when a high-level potential is supplied to the wiring TX, a current generated by the photoelectric conversion element PD flows to the node NP, so that the potential of the node NP changes. After that, a low-level potential is supplied to the wiring TX, whereby the potential can be retained in the node NP. The potential corresponds to imaging data captured by the photoelectric conversion element PD.

The wiring SE has a function of a selection signal line for selecting the imaging pixel circuit 32 from which captured imaging data is to be read. For example, when a high-level potential is supplied to the wiring SE, the transistor MI is turned on, and a signal corresponding to a potential difference between the gate and the second terminal of the transistor M2 is output to the wiring OL.

Note that the wiring SE corresponds to the wiring 41 in FIG. 68.

The wiring OL has a function of an output line for outputting a signal from the imaging pixel circuit 32, for example.

Note that the wiring OL corresponds to the wiring 42 in FIG. 68.

The wiring RS has a function of a wiring for resetting imaging data retained in the node NP, for example. Specifically, for example, a high-level potential is supplied to each of the wiring RS and the wiring TX to turn on the transistor M3 and the transistor M4 and a low-level potential from the wiring VCE3 is supplied to the node NP, whereby imaging data retained in the imaging pixel circuit 32 can be erased.

Note that the wiring SE and the wiring RS that are illustrated in FIG. 69 can each be a wiring extending in each row, besides the wiring 41 illustrated in FIG. 68.

The above-described imaging device can be used for, for example, the information terminal 5500 illustrated in FIG. 61A, the laptop information terminal 5300 illustrated in FIG. 61C, the camera 8000 illustrated in FIG. 61D, the portable game machine 5200 illustrated in FIG. 61E, the television device illustrated in FIG. 61F, a dashboard camera that can be provided in the moving vehicle illustrated in FIG. 61G, the electronic device 8300 illustrated in FIG. 61I, or the artificial satellite 6800 illustrated in FIG. 66.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like. [Reference Numerals] BSPR: circuit, BSPRa: circuit, BSPRb: circuit, BSPRi: circuit, BSPRj: circuit, BB: circuit, BBa: circuit, BBb: circuit, BBi: circuit, BBj: circuit, FBa: circuit, FBb: circuit, GD: driver circuit, SD: driver circuit, SR: circuit, LAT: circuit, LGC: circuit, OPC: circuit, DAC: circuit, MDV: circuit, MNa: transistor, MNb: transistor, MNd: transistor, MNe: transistor, MNf: transistor, MN1: transistor, MN4: transistor, MN10: transistor, MN11: transistor, MN12: transistor, MN14: transistor, MN15: transistor, MN16: transistor, MN17: transistor, MN21: transistor, MN24: transistor, MN25: transistor, MN28: transistor, MN31: transistor, MN34: transistor, MN35: transistor, MN36: transistor, MN37: transistor, MN40: transistor, MN41: transistor, MN51: transistor, MN52: transistor, MN53: transistor, MN54: transistor, MN55: transistor, MN56: transistor, MN57: transistor, MN58: transistor, MN59: transistor, MP10: transistor, MP11: transistor, MP12: transistor, MP14: transistor, MP15: transistor, MP16: transistor, ML: transistor, MV: transistor, Ca: capacitor, C1: capacitor, C2: capacitor, C5: capacitor, C25: capacitor, C26: capacitor, ED: light-emitting device, Ti: terminal, To: terminal, Bi: terminal, Bo: terminal, IT: terminal, ITA: terminal, ITB: terminal, CLK1: terminal, CLK2: terminal, CLK3: terminal, PWC: terminal, RT: terminal, GT: terminal, OT: terminal, OTA: terminal, OTB: terminal, Fi: terminal, Fo: terminal, NT: terminal, ST: terminal, N: node, N1: node, N2: node, NP: node, VAL1: wiring, VAL2: wiring, VAL3: wiring, VDE1: wiring, VDE2: wiring, VDE15: wiring, VDE16: wiring, VDE17: wiring, VDE18: wiring, VDE19: wiring, VDE21: wiring, VDE22: wiring, VDE23: wiring, VDE35: wiring, VSE1: wiring, VSE2: wiring, VSE3: wiring, VSE4: wiring, VSE5: wiring, VSE10: wiring, VSE11: wiring, VSE12: wiring, VSE13: wiring, VSE14: wiring, VSE15: wiring, VSE21: wiring, VSE22: wiring, VSE24: wiring, VEL: wiring, VBL: wiring, VCAT: wiring, BG1: wiring, BG2: wiring, BG3: wiring, RST: wiring, COM: wiring, CL1: wiring, CL2: wiring, PL: wiring, CLKLA: wiring, CLKLB: wiring, CLKLC: wiring, CLKLD: wiring, PWCLA: wiring, PWCLB: wiring, PWCLC: wiring, PWCLD: wiring, VDL: wiring, SPR: wiring, IL: wiring, INIL: wiring, GLS: wiring, GLS[1]: wiring, GLS[m]: wiring, GL: wiring, GL[1]: wiring, GL[2]: wiring, GL[m]: wiring, SLS: wiring, SLS[1]: wiring, SLS[n]: wiring, SL: wiring, SL[1]: wiring, SL[2]: wiring, SL[3]: wiring, SL[4]: wiring, SL[5]: wiring, SL[6]: wiring, VCOM: wiring, CSL: wiring, SS: signal, BW: signal, CE: signal, RDA: signal, GW: signal, ADDR: signal, WAKE: signal, CLK: signal, WDA: signal, SMC: semiconductor layer, SDMT: conductive layer, SDMB: conductive layer, GEM: conductive layer, MPG: conductive layer, MPGa: conductive layer, MPGb: conductive layer, MPGc: conductive layer, DSP: display apparatus, DSP1: display apparatus, DSP1A: display apparatus, DSP2: display apparatus, DSP2A: display apparatus, DSP2AA: display apparatus, DSP2AB: display apparatus, DSP2AC: display apparatus, DSP2B: display apparatus, DSP2C: display apparatus, DSP2D: display apparatus, DIS: display region, SIC: circuit region, DRV: driver circuit region, MFNC: functional circuit region, GDR: driver circuit, GDR1: driver circuit, GDR2: driver circuit, SDR: driver circuit, PDA: sensor, DAD: digital-to-analog converter circuit, LVS: level shifter circuit, TMR: terminal region, BS: substrate, SCC: sensor controller, EPS: power supply circuit, MEM: memory device, TMC: timing controller, ECR: EL correction circuit, SNCL: wiring, BSL: bus wiring, PX: pixel circuit, 21: CPU, 22: GPU, 22a: circuit, 22b: circuit, 24: PSW, 25: PSW, 100A1: circuit, 100A2: circuit, 100A3: circuit, 100A4: circuit, 100A5: circuit, 100A6: circuit, 100A[1]: circuit, 100A[2]: circuit, 100A[m]: circuit, 100B1: circuit, 100B2: circuit, 100B[1]: circuit, 100B[2]: circuit, 100B[3]: circuit, 100B[4]: circuit, 100B[5]: circuit, 100B[6]: circuit, 100C1: circuit, 100C2: circuit, 103: insulating layer, 104: conductive layer, 105: insulating layer, 106: conductive layer, 107: adhesive layer, 110: substrate, 112a: conductive layer, 112b: conductive layer, 112c: conductive layer, 113a: first layer, 113b: second layer, 113c: third layer, 114: common layer, 115: common electrode, 118a: mask layer, 125: insulating layer, 126a: conductive layer, 126b: conductive layer, 126c: conductive layer, 127: insulating layer, 128: layer, 129a: conductive layer, 129b: conductive layer, 129c: conductive layer, 130R: light-emitting device, 130G: light-emitting device, 130B: light-emitting device, 131: protective layer, 140: connection portion, 147: resin layer, 166R: coloring layer, 166G: coloring layer, 166B: coloring layer, 200: memory device, 300: transistor, 300d: transistor, 300LT: transistor, 310: substrate, 312: element isolation layer, 313: semiconductor region, 314a: low-resistance region, 314b: low-resistance region, 315: insulating layer, 316: conductive layer, 317: insulating layer, 320: insulating layer, 322: insulating layer, 324: insulating layer, 326: insulating layer, 328: conductive layer, 330: conductive layer, 350: insulating layer, 352: insulating layer, 354: insulating layer, 356: conductive layer, 361: insulating layer, 362: insulating layer, 363: insulating layer, 364: insulating layer, 366: conductive layer, 367: conductive layer, 368: semiconductor layer, 368p: low-resistance region, 368i: semiconductor region, 369: conductive layer, 329: conductive layer, 512: insulating layer, 514: conductive layer, 574: insulating layer, 581: insulating layer, 592: insulating layer, 594: insulating layer, 596: conductive layer, 597: conductive layer, 598: insulating layer, 599: insulating layer, 1000: display apparatus, 1281: display portion, 1283a: pixel circuit, 1284a: pixel, 1291: substrate, 1292: substrate, 1430a: light-emitting device, 1430b: light-emitting device, 1430c: light-emitting device, 5200: portable game machine, 5201: housing, 5202: display portion, 5203: button, 5300: laptop information terminal, 5330a: housing, 5330b: housing, 5331: display portion, 5350: keyboard portion, 5500: information terminal, 5510: housing, 5511: display portion, 5623: connection terminal, 5624: connection terminal, 5625: connection terminal, 5629: connection terminal, 5701: display panel, 5702: display panel, 5703: display panel, 5704: display panel, 5900: information terminal, 5901: housing, 5902: display portion, 5903: operation button, 5904: crown, 5905: band, 6200: digital signage, 6201: wall, 6500: electronic device, 6501: housing, 6502: display portion, 6504: button, 6505: speaker, 6507: camera, 6519: control device, 6600: electronic device, 6611: housing, 6615: display portion, 6616: control device, 6807: control device, 7003md: memory device, 8000: camera, 8001: housing, 8002: display portion, 8003: operation button, 8004: shutter button, 8006: lens, 8100: finder, 8101: housing, 8102: display portion, 8103: button, 8300: electronic device, 8301: housing, 8302: display portion, 8304a: fixture member, 8304: fixture member, 8305: lens, 9000: television device, 9001: display portion, 9002: housing, 9003: speaker, 9005: operation key, 9006: connection terminal, 9007: sensor

1. A semiconductor device comprising:
a first transistor, a second transistor, a third transistor, a fourth transistor, a fifth transistor, a sixth transistor, a seventh transistor, a first capacitor, and a second capacitor,
wherein a first gate of the first transistor is electrically connected to a first gate of the second transistor,
wherein one of a source and a drain of the third transistor is electrically connected to one of a source and a drain of the second transistor, a first gate of the fourth transistor, a first gate of the seventh transistor, and one of a pair of electrodes of the first capacitor,
wherein one of a source and a drain of the first transistor is electrically connected to one of a source and a drain of the fourth transistor and one of a source and a drain of the fifth transistor,
wherein the other of the source and the drain of the fifth transistor is electrically connected to one of a pair of electrodes of the second capacitor and a gate of the sixth transistor,
wherein one of a source and a drain of the sixth transistor is electrically connected to the other of the pair of electrodes of the second capacitor and one of a source and a drain of the seventh transistor,
wherein the second transistor and the fourth transistor each comprise a first conductive layer configured to be the one of the source and the drain, a second conductive layer configured to be the other of the source and the drain, a third conductive layer configured to be the first gate, a semiconductor layer, and a gate insulating film,
wherein the first conductive layer and the second conductive layer each comprise a region in contact with a top surface of a first insulating layer,
wherein the semiconductor layer comprises a region in contact with a side surface of an opening formed in the first insulating layer, a top surface of a second insulating layer in a bottom portion of the opening, a top surface of the first conductive layer, and a top surface of the second conductive layer,
wherein the gate insulating film comprises a region in contact with a top surface of the semiconductor layer, the top surface of the first conductive layer, and the top surface of the second conductive layer,
wherein the third conductive layer comprises a region overlapping with at least part of the semiconductor layer and in contact with a top surface of the gate insulating film, and
wherein the second transistor and the fourth transistor each comprise a channel formation region in the semiconductor layer.

2. The semiconductor device according to claim 1,
wherein the second transistor and the fourth transistor each comprise a fourth conductive layer configured to be a second gate, and
wherein the fourth conductive layer comprises a region overlapping with at least part of the semiconductor layer and in contact with a bottom surface of the second insulating layer.

3. The semiconductor device according to claim 1,
wherein the semiconductor layer comprises one or more selected from indium, zinc, and an element M, and
wherein the element M is one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.

4. The semiconductor device according to claim 1, further comprising:
an eighth transistor,
wherein a gate of the eighth transistor is electrically connected to the one of the source and the drain of the sixth transistor, the other of the pair of electrodes of the second capacitor, and the one of the source and the drain of the seventh transistor, and
wherein one of a source and a drain of the eighth transistor is electrically connected to the one of the source and the drain of the first transistor, the one of the source and the drain of the fourth transistor, and the one of the source and the drain of the fifth transistor.

5. A display apparatus comprising:
a driver circuit and a display device,
wherein the driver circuit comprises the semiconductor device according to claim 1, and
wherein the driver circuit is configured to transmit a signal for displaying an image to the display device.

6. The display apparatus according to claim 5,
wherein the display device comprises a light-emitting device or a liquid crystal display device.

7. An electronic device comprising:
the display apparatus according to claim 6 and a housing.

8. A semiconductor device comprising:
a first transistor, a second transistor, a third transistor, a fourth transistor, a fifth transistor, a sixth transistor, a seventh transistor, a first capacitor, and a second capacitor,
wherein a first gate of the first transistor is electrically connected to a first gate of the second transistor,
wherein one of a source and a drain of the third transistor is electrically connected to one of a source and a drain of the second transistor, a first gate of the fourth transistor, a first gate of the seventh transistor, and one of a pair of electrodes of the first capacitor,
wherein one of a source and a drain of the first transistor is electrically connected to one of a source and a drain of the fourth transistor and one of a source and a drain of the fifth transistor,
wherein the other of the source and the drain of the fifth transistor is electrically connected to one of a pair of electrodes of the second capacitor and a gate of the sixth transistor,
wherein one of a source and a drain of the sixth transistor is electrically connected to the other of the pair of electrodes of the second capacitor and one of a source and a drain of the seventh transistor,
wherein the second transistor and the fourth transistor each comprise a first conductive layer configured to be the one of the source and the drain, a second conductive layer configured to be the other of the source and the drain, a third conductive layer configured to be the first gate, and a semiconductor layer,
wherein the first conductive layer and the second conductive layer each comprise a region in contact with a top surface of a first insulating layer,
wherein the semiconductor layer comprises a region in contact with a side surface of an opening formed in the first insulating layer, a top surface of a second insulating layer in a bottom portion of the opening, a top surface of the first conductive layer, and a top surface of the second conductive layer,
wherein the third conductive layer comprises a region overlapping with at least part of the semiconductor layer, and
wherein the second transistor and the fourth transistor each comprise a channel formation region in the semiconductor layer.

9. The semiconductor device according to claim 8,
wherein the second transistor and the fourth transistor each comprise a fourth conductive layer configured to be a second gate, and
wherein the fourth conductive layer comprises a region overlapping with at least part of the semiconductor layer and in contact with a bottom surface of the second insulating layer.

10. The semiconductor device according to claim 8,
wherein the semiconductor layer comprises one or more selected from indium, zinc, and an element M, and
wherein the element M is one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.

11. The semiconductor device according to claim 8, further comprising:
an eighth transistor,
wherein a gate of the eighth transistor is electrically connected to the one of the source and the drain of the sixth transistor, the other of the pair of electrodes of the second capacitor, and the one of the source and the drain of the seventh transistor, and
wherein one of a source and a drain of the eighth transistor is electrically connected to the one of the source and the drain of the first transistor, the one of the source and the drain of the fourth transistor, and the one of the source and the drain of the fifth transistor.

12. A display apparatus comprising:
a driver circuit and a display device,
wherein the driver circuit comprises the semiconductor device according to claim 8, and
wherein the driver circuit is configured to transmit a signal for displaying an image to the display device.

13. The display apparatus according to claim 12,
wherein the display device comprises a light-emitting device or a liquid crystal display device.

14. An electronic device comprising:
the display apparatus according to claim 13 and a housing.
